(19) United States
(12) Patent Application Publication
(10) Pub. No.: US 2025/0133958 A1
(43) Pub. Date: Apr. 24, 2025

(54) COMPOUND FOR QUANTUM DOT LIGHT EMITTING DEVICE, QUANTUM DOT LIGHT EMITTING DEVICE USING THE SAME, AND ELECTRONIC DEVICE THEREOF

(71) Applicant: DUK SAN NEOLUX CO., LTD., Cheonan-si, Chungcheongnam-do (KR)

(72) Inventors: Yun Hee PARK, Cheonan-si, Chungcheongnam-do (KR); Jong Moon SHIN, Cheonan-si, Chungcheongnam-do (KR); Changmin LEE, Cheonan-si, Chungcheongnam-do (KR); Soung Yun MUN, Cheonan-si, Chungcheongnam-do (KR); Hyun Ji OH, Cheonan-si, Chungcheongnam-do (KR)

(73) Assignee: DUK SAN NEOLUX CO., LTD., Cheonan-si, Chungcheongnam-do (KR)

(21) Appl. No.: 18/560,116

(22) PCT Filed: Mar. 16, 2022
(86) PCT No.: PCT/KR2022/003697

§ 371 Date: Nov. 25, 2024

(30) Foreign Application Priority Data
Jun. 1, 2021 (KR) 10-2021-0071056

(51) Int. Cl. H10K 85/60; C09K 11/06; C09K 11/56; C09K 11/70; C09K 11/88; H10K 50/115

(52) U.S. Cl. CPC H10K 85/636; C09K 11/06; C09K 11/565; C09K 11/70; C09K 11/883; H10K 85/633; C09K 2211/1018; H10K 50/115; H10K 85/615; H10K 85/622; H10K 85/6572; H10K 85/6574; H10K 85/6576

(57) ABSTRACT

The present disclosure relates to a compound for a quantum dot light emitting device, a quantum dot light emitting device using the same, and an electronic device including the quantum dot light emitting device. The quantum dot light emitting device of the present disclosure, by including an auxiliary light emitting layer material having appropriate HOMO and LUMO energy levels between a hole transport layer and a quantum dot light emitting layer, can efficiently control the movement of holes from the hole transport layer and act as a barrier to electron injection, and as a result, the hole and charge balance in the quantum dot light emitting layer is improved, thereby improving the overall device performance of the quantum dot light emitting device.

### TECHNICAL FIELD

The present disclosure relates to a quantum dot (QD) light emitting device, and in particular to a quantum dot light emitting device with improved charge balance, a quantum dot light emitting display device, and a method of manufacturing a quantum dot light emitting device.

### BACKGROUND

Recently, many studies have been conducted to use quantum dots in display devices.

Quantum dots (QDs) are nano-sized semiconductor particles that exhibit excellent optical and electrical properties not possessed by bulk semiconductor materials. For example, quantum dots are characterized in that they emit light by photoluminescence (PL), in which light is emitted when electrons excited by external light move down from the conduction band to the valence band, or electroluminescence (EL), which emits light by an external charge, the color of light emitted varies depending on the size of the quantum dot even if they are made of the same material.

Due to these characteristics, quantum dots are attracting attention as next-generation high-brightness light emitting diodes (LEDs), bio sensors, lasers, and solar cell nanomaterials. That is, light-emitting layers containing quantum dots and various electronic devices using them generally have lower manufacturing costs than organic light emitting devices using light emitting layers containing phosphorescent and/or fluorescent materials, desired colors can be emitted by varying the size of the quantum dots without the need to use other organic materials in the light emitting layer so as to emit light of different colors.

However, the light emission efficiency of the light emitting layer containing quantum dots is determined by the quantum efficiency of the quantum dots, the balance of electric charge carriers, light extraction efficiency, etc. In particular, in order to improve quantum efficiency, excitons should be confined to the light emitting layer, and if the excitons are not confined inside the light emitting layer due to various factors, problems such as exciton quenching may occur.

Meanwhile, in the case of an electroluminescent device, electrons are generally transferred from the electron transport layer to the light-emitting layer, and holes are transferred from the hole transport layer to the light emitting layer, and excitons are generated by recombination.

However, since the materials used in the hole transport layer should have a low HOMO value, most of them have a low T1 value. As a result, excitons generated in the light emitting layer pass to the hole transport layer, thereby causing an imbalance of electric charge within the light emitting layer, resulting in light emission at the interface of the hole transport layer. When light is emitted from the hole transport layer interface, the color purity and efficiency of the electroluminescent device are reduced and its lifetime is shortened.

In order to solve the problem of light emission from the hole transport layer in an electroluminescent device, an auxiliary light emitting layer should be present between the hole transport layer and the light emitting layer, and different auxiliary light emitting layers are being developed in accordance with each light emitting layer (R, G, B).

However, in order to fully exhibit the excellent characteristics possessed by an electroluminescent device, the materials that make up the organic layer in the device, such as a hole injection material, a hole transport material, a light emitting material, an electron transport material, an electron injection material, and an auxiliary light emitting layer material, should first be supported by stable and efficient materials, and in particular, development of an auxiliary luminescent layer material is needed.

Due to the various and difficult problems mentioned above, there have been no attempts to apply an auxiliary light emitting layer to a quantum dot light emitting device, and the present inventors, after numerous trials and errors, have completed the present disclosure by applying a light emitting auxiliary layer to a quantum dot light emitting device.

### SUMMARY

An object of the present disclosure is to lower the operation voltage of the quantum dot light emitting device and improve the light emission efficiency and lifetime of the device by introducing an auxiliary light emitting layer into the quantum dot light emitting device.

The present disclosure provides a quantum dot light emitting device which includes a first electrode; a second electrode; a light emitting layer including quantum dots and a hole transport layer between the first electrode and the second electrode; an auxiliary light emitting layer between the hole transport layer and the light emitting layer, wherein the auxiliary light emitting layer includes a compound represented by Formula 1.

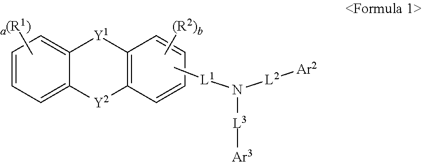

In another aspect, the present disclosure provides an electronic device including a quantum dot light emitting device.

### Advantageous Effects

The quantum dot light emitting device of the present disclosure, by including an auxiliary light emitting layer material having appropriate HOMO and LUMO energy levels between a hole transport layer and a quantum dot light emitting layer, can efficiently control the movement of holes from the hole transport layer and act as a barrier to electron injection, and as a result, the hole and charge balance in the quantum dot light emitting layer is improved, thereby improving the overall device performance of the quantum dot light emitting device.

### BRIEF DESCRIPTION OF THE DRAWINGS

FIGS. 1 to 3 schematically show experimental results of quantum dot light emitting devices according to embodiments of the present disclosure.

FIG. 4 shows a formula according to one aspect of the present disclosure.

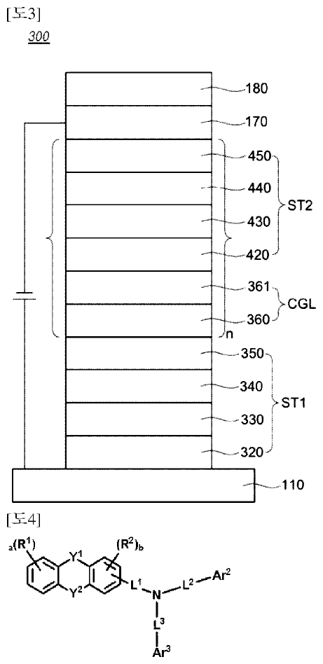

### BEST MODE FOR CARRYING OUT THE INVENTION

The present disclosure provides a quantum dot light emitting device which includes a first electrode; a second electrode; a light emitting layer including quantum dots and a hole transport layer between the first electrode and the second electrode; an auxiliary light emitting layer between the hole transport layer and the light emitting layer, wherein the auxiliary light emitting layer includes a compound represented by Formula 1.

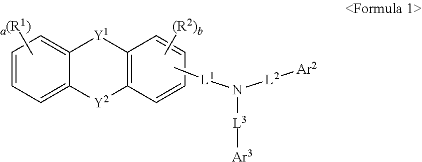

### DETAILED DESCRIPTION

Hereinafter, preferred embodiments of the present disclosure will be described with reference to the attached drawings.

It should be noted that in order to describe the present embodiments, in adding reference numerals to the components in each drawing, the same numerals are used for the same components as much as possible even if they are shown in different drawings. Additionally, in describing the present disclosure, if it is determined that a detailed description of a related known constitution or function may obscure the gist of the present disclosure, the detailed description will be omitted. In the drawings referenced below, the scale ratio does not apply.

In describing the components of the present disclosure, terms such as first, second, A, B, (a), (b), etc. may be used. These terms are only for distinguishing the components from other components, and the essence, order, sequence, etc. of the components are not limited by the terms.

When a component is described as being “connected”, “linked”, or “fused”, etc., the component may be directly connected or linked, but it should be understood that another component may be “connected”, “linked”, or “fused” between each component.

Additionally, when a component (e.g., a layer, a film, a region, a plate, etc.) is described to be “on top” or “on” of another component, it should be understood that this may also include a case where another component is “immediately on top of” as well as a case where another component is disposed therebetween. In contrast, it should be understood that when a component is described to be “immediately on top of” another component, it should be understood that there is no other component disposed therebetween.

In the description of the temporal flow relationship relating to the components, the operation method, or the preparation method, for example, when the temporal precedence or flow precedence is described by way of “after”, “subsequently”, “thereafter”, “before”, etc., it may also include cases where the flow is not continuous unless terms such as “immediately” or “directly” are used.

Meanwhile, when the reference is made to numerical values or corresponding information for components, numerical values or corresponding information may be interpreted as including an error range that may occur due to various factors (e.g., procedural factors, internal or external shocks, noise, etc.) even if it is it not explicitly stated.

The terms used in this specification and the appended claims are as follows, unless otherwise stated, without departing from the spirit of the present disclosure.

As used herein, the term “halo” or “halogen” includes fluorine (F), chlorine (Cl), bromine (Br), and iodine (I), unless otherwise specified.

As used herein, the term “alkyl” or “alkyl group” refers to a radical of a saturated aliphatic functional group, including a linear chain alkyl group, a branched chain alkyl group, a cycloalkyl (alicyclic) group, an alkyl-substituted cycloalkyl group, and a cycloalkyl-substituted alkyl group, which has 1 to 60 carbons linked by a single bond unless otherwise specified.

As used herein, the term “haloalkyl group” or “halogenalkyl group” refers to an alkyl group in which a halogen is substituted, unless otherwise specified.

As used herein, the term “alkenyl” or “alkynyl” has a double bond or triple bond, respectively, includes a linear or branched chain group, and has 2 to 60 carbon atoms unless otherwise specified, but is not limited thereto.

As used herein, the term “cycloalkyl” refers to an alkyl which forms a ring having 3 to 60 carbon atoms unless otherwise specified, but is not limited thereto.

As used herein, the term “alkoxy group” or “alkyloxy group” refers to an alkyl group to which an oxygen radical is linked, and has 1 to 60 carbon atoms unless otherwise specified, but is not limited thereto.

As used herein, the term “alkenoxyl group”, “alkenoxy group”, “alkenyloxyl group”, or “alkenyloxy group” refers to an alkenyl group to which an oxygen radical is linked, and has 2 to 60 carbon atoms unless otherwise specified, but is not limited thereto.

As used herein, the terms “aryl group” and “arylene group” each have 6 to 60 carbon atoms unless otherwise specified, but are not limited thereto. As used herein, the aryl group or arylene group includes a single ring type, a ring assembly, a fused multiple ring compound, etc. For example, the aryl group may include a phenyl group, a monovalent functional group of biphenyl, a monovalent functional group of naphthalene, a fluorenyl group, and a substituted fluorenyl group, and the arylene group may include a fluorenylene group and a substituted fluorenylene group.

As used herein, the term “ring assembly” means that two or more ring systems (monocyclic or fused ring systems) are directly connected to each other through a single bond or double bond, in which the number of direct links between such rings is one less than the total number of ring systems in the compound. In the ring assembly, the same or different ring systems may be directly connected to each other through a single bond or double bond.

As used herein, since the aryl group includes a ring assembly, the aryl group includes biphenyl and terphenyl in which a benzene ring, which is a single aromatic ring, is connected by a single bond. Additionally, since the aryl group also includes a compound in which an aromatic ring system fused to an aromatic single ring is connected by a single bond, it also includes, for example, a compound in which a benzene ring (which is a single aromatic ring) and fluorine (which is a fused aromatic ring system) are linked by a single bond.

As used herein, the term “fused multiple ring system” refers to a fused ring form in which at least two atoms are shared, and it includes a form in which ring systems of two or more hydrocarbons are fused, a form in which at least one heterocyclic system including at least one heteroatom is fused, etc. Such a fused multiple ring system may be an aromatic ring, a heteroaromatic ring, an aliphatic ring, or a combination of these rings. For example, in the case of an aryl group, it may be a naphthalenyl group, a phenanthrenyl group, a fluorenyl group, etc., but is not limited thereto.

As used herein, the term “a spiro compound” has a spiro union, and the spiro union refers to a linkage in which two rings share only one atom. In particular, the atom shared by the two rings is called a “spiro atom”, and they are each called “monospiro-”, “dispiro-”, and “trispiro-” compounds depending on the number of spiro atoms included in a compound.

As used herein, the terms “fluorenyl group”, “fluorenylene group”, and “fluorenetriyl group” refer to a monovalent, divalent, or trivalent functional group in which R, R′, R″, and R″′ are all hydrogen in the following structures, respectively, unless otherwise specified; “substituted fluorenyl group”, “substituted fluorenylene group”, or “substituted fluorenetriyl group” means that at least one of the substituents R, R′, R″, and R″′ is a substituent other than hydrogen, and includes cases where R and R′ are bound to each other to form a spiro compound together with the carbon to which they are linked. As used herein, all of the fluorenyl group, the fluorenylene group, and the fluorenetriyl group may also be referred to as a fluorene group regardless of valences such as monovalent, divalent, trivalent, etc.

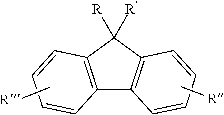

Additionally, the R, R′, R″, and R″′ may each independently be an alkyl group having 1 to 20 carbon atoms, an alkenyl group having 1 to 20 carbon atoms, an aryl group having 6 to carbon atoms, and a heterocyclic group having 2 to 30 carbon atoms and, for example, the aryl group may be phenyl, biphenyl, naphthalene, anthracene, or phenanthrene, and the heterocyclic group may be pyrrole, furan, thiophene, pyrazole, imidazole, triazole, pyridine, pyrimidine, pyridazine, pyrazine, triazine, indole, benzofuran, quinazoline, or quinoxaline. For example, the substituted fluorenyl group and the fluorenylene group may each be a monovalent functional group or divalent functional group of 9,9-dimethylfluorene, 9,9-diphenylfluorene, and 9,9′-spirobi[9H-fluorene].

As used herein, the term “heterocyclic group” includes not only aromatic rings (e.g., “heteroaryl group” and “heteroarylene group”), but also non-aromatic rings, and may refer to a ring having 2 to 60 carbon atoms each including one or more heteroatoms unless otherwise specified, but is not limited thereto. As used herein, the term “heteroatom” refers to N, O, S, P, or Si unless otherwise specified, and a heterocyclic group refers to a monocyclic group including a heteroatom, a ring assembly, a fused multiple ring system, a spiro compound, etc.

For example, the “heterocyclic group” may include a compound including a heteroatom group (e.g., SO₂, P═O, etc.), such as the compound shown below, instead of carbon that forms a ring.

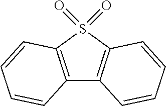 [SMILES: O=S1(=O)c2ccccc2-c2ccccc21]

As used herein, the term “ring” includes monocyclic and polycyclic rings, and includes heterocycles containing at least one heteroatom as well as hydrocarbon rings, and includes aromatic and non-aromatic rings.

As used herein, the term “polycyclic” includes ring assemblies (e.g., biphenyl, terphenyl, etc.), fused multiple ring systems, and spiro compounds, includes non-aromatic as well as aromatic compounds, and includes heterocycles containing at least one heteroatom as well as hydrocarbon rings.

As used herein, the term “alicyclic group” refers to cyclic hydrocarbons other than aromatic hydrocarbons, and it includes monocyclic, ring assemblies, fused multiple ring systems, spiro compounds, etc., and refers to a ring having 3 to 60 carbon atoms unless otherwise specified, but is not limited thereto. For example, when benzene (i.e., an aromatic ring) and cyclohexane (i.e., a non-aromatic ring) are fused, it also corresponds to an aliphatic ring.

Additionally, when prefixes are named consecutively, it means that the substituents are listed in the order they are described. For example, in the case of an arylalkoxy group, it means an alkoxy group substituted with an aryl group; in the case of an alkoxycarbonyl group, it means a carbonyl group substituted with an alkoxy group; additionally, in the case of an arylcarbonyl alkenyl group, it means an alkenyl group substituted with an arylcarbonyl group, in which the arylcarbonyl group is a carbonyl group substituted with an aryl group.

Additionally, unless otherwise specified, the term “substituted” in the expression “substituted or unsubstituted” as used herein refers to a substitution with one or more substituents selected from the group consisting of deuterium, a halogen, an amino group, a nitrile group, a nitro group, a C₁₋₂₀ alkyl group, a C₁₋₂₀ alkoxy group, a C₁₋₂₀ alkylamine group, a C₁₋₂₀ alkylthiophene group, a C₆₋₂₀ arylthiophene group, a C₂₋₂₀ alkenyl group, a C₂₋₂₀ alkynyl group, a C₃₋₂₀ cycloalkyl group, a C₆₋₂₀ aryl group, a C₆₋₂₀ aryl group substituted with deuterium, a C₈₋₂₀ arylalkenyl group, a silane group, a boron group, a germanium group, and a C₂₋₂₀ heterocyclic group containing one or more heteroatoms selected from the group consisting of O, N, S, Si, and P, but is not limited to these substituents.

As used herein, the “names of functional groups” corresponding to the aryl group, arylene group, heterocyclic group, etc. exemplified as examples of each symbol and a substituent thereof may be described as “a name of the functional group reflecting its valence”, and may also be described as the “name of its parent compound”. For example, in the case of “phenanthrene”, which is a type of an aryl group, the names of the groups may be described such that the monovalent group is described as “phenanthryl (group)”, and the divalent group is described as “phenanthrylene (group)”, etc., but may also be described as “phenanthrene”, which is the name of its parent compound, regardless of its valence.

Similarly, in the case of pyrimidine as well, it may be described regardless of its valence, or in the case of being monovalent, it may be described as pyrimidinyl (group); and in the case of being divalent, it may be described as the “name of the group” of the valence (e.g., pyrimidinylene (group)). Therefore, as used herein, when the type of a substituent is described as the name of its parent compound, it may refer to an n-valent “group” formed by detachment of a hydrogen atom linked to a carbon atom and/or hetero atom of its parent compound.

Additionally, in describing the names of the compounds or the substituents in the present specification, the numbers, letters, etc. indicating positions may be omitted. For example, pyrido[4,3-d]pyrimidine may be described as pyridopyrimidine; benzofuro[2,3-d]pyrimidine as benzofuropyrimidine; 9,9-dimethyl-9H-fluorene as dimethylfluorene, etc. Therefore, both benzo[g]quinoxaline and benzo[f]quinoxaline may be described as benzoquinoxaline.

Additionally, unless there is an explicit description, the formulas used in the present disclosure are applied in the same manner as in the definition of substituents by the exponent definition of the formula below.

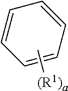

In particular, when a is an integer of 0, it means that the substituent R¹ is absent, that is, when a is 0, it means that hydrogens are linked to all carbons that form a benzene ring, and in this case, the formula or compound may be described while omitting the indication of the hydrogen linked to the carbon. Additionally, when a is an integer of 1, one substituent R¹ may be linked to any one of the carbons forming a benzene ring; when a is an integer of 2 or 3, it may be linked, for example, as shown below; even when a is an integer of 4 to 6, it may be linked to the carbon of a benzene ring in a similar manner; and when a is an integer of 2 or greater, R¹ may be the same as or different from each other.

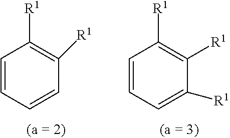

Unless otherwise specified in the present application, forming a ring means that neighboring groups bind to one another to form a single ring or fused multiple ring, and the single ring and the formed fused multiple ring include a heterocycle containing at least one heteroatom as well as a hydrocarbon ring, and may include aromatic and non-aromatic rings.

Additionally, unless otherwise specified in the present specification, when indicating a condensed ring, the number in “number-condensed ring” indicates the number of rings to be condensed. For example, a form in which three rings are condensed with one another (e.g., anthracene, phenanthrene, benzoquinazoline, etc.) may be expressed as a 3-condensed ring.

Additionally, as used herein, the term “bridged bicyclic compound” refers to a compound in which two rings share 3 or more atoms to form a ring, unless otherwise specified. In particular, the shared atoms may include carbon or a hetero atom.

As used herein, the term “precursor”, which is a chemical substance prepared in advance to react quantum dots, is a concept referring to all compounds including metals, ions, elements, compounds, complex compounds, complexes, clusters, etc. It is not necessarily limited to the final substance of a certain reaction, but refers to a substance that can be obtained in any arbitrarily determined step.

As used herein, the term “cluster” refers to particles in which single atoms, molecules, or other types of atoms are aggregated or combined within tens to thousands of atoms.

As used herein, the term “Group” refers to a group in the periodic table of elements. In particular, “Group I” may include Group IA (or TA) and Group IB (or 1B), and includes Li, Na, K, Ru, and Cs, but is not limited thereto. “Group II” or Group 2 may include Groups IIA (or 2A) and IIB (or 2B), and examples of Group II metals include Cd, Zn, Hg, and Mg, but are not limited thereto. “Group III” or Group 3 may include Groups IIIA (or 3A) and IIIB (or 3B), and examples of Group III metals include Al, In, Ga, and TI, but are not limited thereto. “Group IV” may include Group IVA (or 4A) and Group IVB (or 4B), and examples of Group IV metals include Si, Ge, and Sn, but are not limited thereto.

According to embodiments of the present disclosure, quantum dots are provided. Quantum dots according to embodiments of the present disclosure may have a multilayer structure having a core/shell structure. Additionally, quantum dots may have a core/multi-shell structure with two or more shells. For example, a quantum dot with a core and two shells can be expressed as core/shell/shell.

The core and shell of the quantum dot may consist of a Group II-VI compound, a Group II-V compound, a Group III-V compound, a Group III-IV compound, a Group III-VI compound, a Group IV-VI compound, or a mixture thereof, and a dopant may be doped or alloyed in the core or shell of a quantum dot, and the compound constituting the core and the compound constituting the shell may be different from each other.

Quantum dots according to embodiments of the present disclosure include a core including a first semiconductor nanocrystal.

The first semiconductor nanocrystal includes a Group II element, a Group III element, and a Group V element.

The Group II element may be, for example, one or more selected from Zn, Cd, and Hg. For example, the first semiconductor nanocrystal may include Zn as a Group II element.

The Group III element may be, for example, one or more selected from Al, Ga, In, and Ti. For example, the first semiconductor nanocrystal may include In as a Group III element.

The Group V element may be, for example, one or more selected from N, P, As, Sb, and Bi. For example, the first semiconductor nanocrystal may include P as a Group V element.

The first semiconductor nanocrystal may include a ternary compound. For example, the first semiconductor nanocrystal may include one or more ternary compounds selected from InZnN, InZnP, InZnAs, InZnSb, InZnBi, GaZnN, GaZnP, GaZnAs, GaZnSb, GaZnBi, AlZnN, AlZnP, AlZnAs, AlZnSb, and AlZnTi.

The first semiconductor nanocrystal may include a quaternary compound. For example, the first semiconductor nanocrystal may include one or more ternary compounds selected from InGaZnN, InGaZnP, InGaZnAs, InGaZnSb, InGaZnBi, InAlZnN, InAlZnP, InAlZnAs, InAlZnSb, InAlZnBi, GaAlZnN, GaAlZnP, GaAlZnAs, GaAlZnSb, and GaAlZnBi.

Quantum dots may include a shell including a second semiconductor nanocrystal. The shell is located surrounding the outer surface of the core. The shell can increase stability by coating the outer surface of the core to prevent surface defects in the nanocrystals.

The second semiconductor nanocrystal may include a Group VI element. For example, the second semiconductor nanocrystal may include one or more selected from Group II-VI compounds, Group III-VI compounds, and Group IV-VI compounds. For example, the second semiconductor nanocrystal may include a Group II-VI compound.

The Group II element included in the second semiconductor nanocrystal may be one or more selected from Zn, Cd, and Hg.

The Group III element included in the second semiconductor nanocrystal may be one or more selected from Al, Ga, In, and Ti.

The Group IV element included in the second semiconductor nanocrystal may be one or more selected from Si, Ge, Sn, and Pb.

The Group VI element included in the second semiconductor nanocrystal may be one or more selected from O, S, Se, and Te. The Group VI element may be referred to as a chalcogen element.

The second semiconductor nanocrystal may be one or more selected from CdS, CdSe, CdTe, ZnS, ZnSe, ZnTe, ZnSeS, PbS, PbSe, PbSeS, PbTe, GaAs, GaP, InP, InGaP, InZnP, InAs, CuS, InN, GaN, InGaN, AlP, AlAs, InAs, GaAs, GaSb, InSb, AlSb, HgS, HgTe, HgCdTe, ZnCdS, ZnCdSe, CdSeTe, CuInSe₂, CuInS₂, AgInS₂, and SnTe.

The structure of the core including the first semiconductor nanocrystal and the shell including the second semiconductor nanocrystal may be expressed as ‘core/shell’, ‘core/shell/shell’, ‘first semiconductor nanocrystal/second semiconductor nanocrystal’ or ‘first semiconductor nanocrystal/second semiconductor nanocrystal/third semiconductor nanocrystal’, etc. For example, it may be indicated as InZnP/ZnSeS, InZnP/ZnSeS/ZnS, etc.

The quantum dot may have a single layer rather than a multilayer structure (a core/shell structure), and for example, may be composed of only Group II-VI compounds.

The core/shell or core/multishell may further include a cluster molecule as a seed. The cluster molecule is a compound that acts as a seed during the process of manufacturing the core/shell or core/multishell, and as the precursors of compounds constituting the core/shell or core/multishell grow on the cluster molecule, the core/shell or core/multishell can be formed.

The particle size of the quantum dots may be 1 nm to 30 nm, or 5 nm to 15 nm.

Quantum dots preferably have a Group III-V core, and more preferably have a G group III-II-V core. In another aspect, a method for manufacturing quantum dots may be provided according to embodiments of the present disclosure.

The method for manufacturing quantum dots according to embodiments of the present disclosure includes a core forming step that forms a core, which includes a first semiconductor nanocrystal including a Group II element, a Group III element, and a Group V element.

In the method of manufacturing quantum dots according to embodiments of the present disclosure, unless otherwise specified, the details regarding the quantum dots, core, and first semiconductor nanocrystal are the same as those described in the description of the quantum dot according to the embodiments of the present disclosure.

The core forming step may be a step of forming a first semiconductor nanocrystal including a Group III-II-V compound by applying a nucleation-doping method.

The method of manufacturing quantum dots according to embodiments of the present disclosure may include a shell forming step. The core forming step and the shell forming step may be performed as a one-pot reaction.

For example, the method of manufacturing quantum dots may include a core forming step (step 1), a shell forming step (step 2), and a purification step (step 3). The name of each step is merely a name given to distinguish each step from other steps, and each step is not limited by these names.

The core forming step (step 1) may be performed using a hot injection method. The core forming step is a step of forming a first semiconductor nanocrystal core including a Group III element, a Group II element, and a Group V metal.

The core forming step (step 1) may include steps 1-1 and 1-2.

The step 1-1 may be a step of increasing the temperature of a mixed solution, in which a Group II element precursor solution is injected into a Group III element precursor solution, to 100° C. to 200° C. while reducing the pressure.

The temperature increase may proceed for 5 to 20 minutes. After raising the temperature, the mixed solution may be allowed to react for 50 to 100 minutes. When the mixed solution is heated to the above temperature, impurities in the precursors are effectively removed and quantum dots can be grown efficiently.

The first and second steps may be a step in which the temperature-elevated mixed solution is heated to 200° C. to 400° C. in an inert atmosphere and a Group V element precursor solution is injected into the heated mixed solution. The temperature elevating step may last from a few seconds to an hour. When the temperature is raised to the above temperature, quantum dots that emit light in the visible wavelength can be effectively formed.

The Group III element precursor solution may include a Group III element precursor, a solvent, and a surfactant. The Group III element precursor is not particularly limited as long as it is a precursor including a Group III element, such as a halogen salt of a Group III element.

For example, when the Group III element is indium, the Group III element precursor may be one or more selected from the group consisting of indium (III) acetylacetonate, indium (III) chloride, indium (III) acetate, trimethyl indium, alkyl indium, aryl indium, indium (III) myristate, and indium (III) myristate acetate, and for example, it may be one or more selected from indium (III) chloride and indium (III) acetylacetonate.

The solvent used in the Group III element precursor solution may be one or more selected from the group consisting of 2, 6, 10, 15, 19, 23-hexamethyltetracosane (squalane), 1-octadecene (ODE), trioctylamine (TOA), tributylphosphine oxide, octadecene, octadecylamine, trioctylphosphine (TOP), and trioctylphosphine oxide (TOPO).

The surfactant may be used selectively, and may be a carboxylic acid-based compound, a phosphonic acid-based compound, or a mixture of these two compounds.

The carboxylic acid-based compound may be one or more selected from the group consisting of oleic acid, palmitic acid, stearic acid, linoleic acid, myristic acid, and lauric acid; and the phosphonic acid-based compound may be one or more selected from the group consisting of hexylphosphonic acid, octadecylphosphonic acid, tetradecylphosphonic acid, hexadecylphosphonic acid, decylphosphonic acid, octylphosphonic acid, and butylphosphonic acid.

The Group II element precursor solution may include a Group II element precursor and a solvent.

The Group II element precursor may be, for example, a carboxylate of a Group II element (M). The carboxylate may be expressed as M(carboxylate)ₙ. For example, when the Group II element is zinc, the carboxylate may be Zn(oleate)₂, but the type of Group II element precursor is not limited to Zn(oleate)₂.

The carboxylate may be prepared by mixing a Group II element pre-precursor with carboxylic acid. For example, when the Group II element is zinc, the Group II element pre-precursor may be one or more selected from the group consisting of dimethyl zinc, diethyl zinc, zinc acetate, zinc acetate dihydrate, zinc acetylacetonate, zinc acetylacetonate hydrate, zinc iodide, zinc bromide, zinc chloride, zinc fluoride, zinc fluoride tetrahydrate, zinc carbonate, zinc cyanide, zinc nitrate, zinc nitrate hexahydrate, zinc oxide, zinc peroxide, zinc perchlorate, zinc perchlorate hexahydrate, zinc sulfate, diphenyl zinc, zinc naphthenate, and zinc stearate.

The carboxylic acid for preparing the carboxylate of the Group II element (M) may be, for example, one or more selected from the group consisting of palmitic acid, myristate acid, oleic acid, and stearic acid.

For example, when the Group II element precursor is Zn(oleate)₂, Zn(oleate)₂ may be prepared by reacting zinc acetate and oleic acid.

The Group II element precursor may be, for example, a metal oxo cluster. For example, when the Group II element is zinc, the metal oxo cluster may be a zinc oxo (Zn oxo) cluster.

The metal oxo cluster may be represented by the following formula 1-A.

TₓO_{y}(carboxylate)_{z} [Formula 1-A]

In Formula 1-A, T is a metal. T may be, for example, one or more selected from the group consisting of Zn, Mn, Cu, Fe, Ni, Co, Cr, Ti, Zr, Nb, Mo, and Ru.

The x, y, z are natural numbers, x>y, and satisfy the relationship of x+y=z or 2x=2y+z.

For example, the metal oxo cluster may be one or more selected from the group consisting of Zn₇O₂ (carboxylate)₉, Zn₄O(carboxylate)₆, and Zn₇O₂ (carboxylate)₁₀.

The metal oxo cluster may be prepared by heating a solution including the carboxylate of the Group II element (M) described above. For example, when the Group II element is zinc, Zn(oleate)₂ may be thermally decomposed to form zinc oxo clusters such as Zn₇O₂ (carboxylate)₉, Zn₄O(carboxylate)₆, and Zn₇O₂ (carboxylate)₁₀.

The carboxylate is a salt or carboxylate ester of carboxylic acid. The salt of carboxylic acid may be represented by the following Formula 1-B, and the carboxylate ester may be represented by the following Formula 1-C.

M(RCOO)ₙ [Formula 1-B]

RCOOR′ [Formula 1-C]

In Formula 1-B or Formula 1-C above, M is a metal, n is a natural number, and Rand R′ are hydrogen or an organic group.

The metals refer to metals such as alkali metals, alkaline earth metals, and transition metals shown in the periodic table, and natural numbers refer to positive integers.

The organic group may be one or more selected from the group consisting of deuterium; a halogen; a silane group; a boron group; a germanium group; an amide group; an amide group; an amino group; a cyano group; a nitrile group; a nitro group; a C₆₋₆₀ aryl group; a fluorenyl group; a C₂₋₆₀ heterocyclic group including at least one heteroatom among O, N, S, Si, and P; a fused ring group of a C₃₋₆₀ aliphatic ring and a C₆₋₆₀ aromatic ring; a C₁₋₅₀ alkyl group; a C₁₋₅₀ alkoxyl group; a C₆₋₆₀ aryloxy group; a C₁₋₅₀ alkylamine group; a C₆₋₅₀ arylamine group; a C₁₋₅₀ alkylthio group; a C₆₋₅₀ arylthio group; a C₂₋₅₀ alkenyl group; a C₂₋₅₀ alkynyl group; a C₃₋₆₀ cycloalkyl group; a C₈₋₅₀ arylalkene group; a C₇₋₅₀ arylalkyl group; or a combination thereof, but is not limited thereto.

When the organic group is an aryl group, it may preferably be a C₆₋₃₀ aryl group, and more preferably a C₆₋₁₈ aryl group, for example, phenyl, biphenyl, naphthyl, terphenyl, etc.

When the organic group is a heterocyclic group, it may preferably be a heterocyclic group of C₂-30; and more preferably a C₂₋₁₆ heterocyclic group.

When the organic group is a fluorenyl group, it may be 9,9-dimethyl-9H-fluorene, a 9,9-diphenyl-9H-fluorenyl group, 9,9′-spirobifluorene, etc.

When the organic group is an alkyl group, it may preferably be an alkyl group of; it may be a C₁₋₂₀ alkyl group, and more preferably a C₁₋₁₀ alkyl group, for example, methyl, t-butyl, etc.

When the organic group is an alkoxy group, it may preferably be a C₁₋₂₀ alkoxyl group, and more preferably a C₁₋₁₀ alkoxyl group, for example, methyoxy, t-butoxy, etc.

When the organic group is an aryloxy group it may preferably be a C₆₋₃₀ aryloxy group, and more preferably a C₆₋₁₈ aryloxy group.

When the organic group is an alkylamine group, it may preferably be a C₁₋₂₀ alkylamine group, and more preferably a C₁₋₁₀ alkylamine group.

When the organic group is an arylamine group, it may preferably be a C₆₋₃₀ arylamine group, and more preferably a C₆₋₂₀ arylamine group.

When the organic group is an alkylthio group, it may preferably be a C₁₋₂₀ alkylthio group, and more preferably a C₁₋₁₀ alkylthio group.

When the organic group is an arylthio group, it may preferably be a C₆₋₃₀ arylthio group, and more preferably a C₆₋₂₀ arylthio group.

When the organic group is an alkenyl group, it may preferably be a C₂₋₂₀ alkenyl group, and more preferably a C₂₋₁₀ alkenyl group.

When the organic group is an alkynyl group, it may preferably be a C₂₋₂₀ alkynyl group, and more preferably a C₂₋₁₀ alkynyl group.

When the organic group is a cycloalkyl group, it may preferably be a C₃₋₃₀ cycloalkyl group, and more preferably a C₃₋₂₀ cycloalkyl group.

When the organic group is an arylalkenyl group, it may preferably be a C₈₋₃₀ arylalkenyl group, and more preferably a C₈₋₂₀ arylalkenyl group.

When the organic group is an arylalkyl group, it may preferably be a C₇₋₃₀ arylalkyl group, and more preferably a C₇₋₂₀ arylalkyl group.

The R and R′ may be further substituted with one or more substituents selected from the group consisting of deuterium; a halogen; a C₁₋₂₀ group; a silane group substituted or unsubstituted with a C₁₋₂₀ alkyl group or C₆₋₂₀ aryl group; a siloxane group; a boron group; a germanium group; a cyano group; a nitro group; a C₁₋₂₀ alkylthio group; a C₁₋₂₀ alkoxy group; a C₆₋₂₀ aryloxy group; a C₆₋₂₀ arylthio group; a C₁₋₂₀ alkyl group; a C₁₋₂₀ alkylamine group; a C₆₋₂₀ arylamine group; a C₂₋₂₀ alkenyl group; a C₂₋₂₀ alkynyl group; a C₆₋₂₀ aryl group; a C₂₋₂₀ heterocyclic group including at least one heteroatom among O, N, S, Si, and P; a C₃₋₂₀ alicyclic group; a C₇₋₂₀ arylalkyl group; and a C₈₋₂₀ arylalkenyl group.

The solvent used in the Group II element precursor solution may be one or more substituents selected from the group consisting of 2, 6, 10, 15, 19, 23-hexamethyltetracosane (squalane), 1-octadecene (ODE), trioctylamine (TOA), tributylphosphine oxide, octadecene, octadecylamine, trioctylphosphine (TOP), and trioctylphosphine oxide (TOPO).

Specifically, the method of synthesizing the Group II element precursor consists of a precursor processing step (step 0), and the precursor processing step includes step 0-1, step 0-2, step 0-3, and step 0-4.

The step 0-1 is a step of mixing a Group II element pre-precursor and carboxylic acid and reducing the pressure.

For example, when the Group II element is zinc, the Group II element pre-precursor may be one or more substituents selected from the group consisting of dimethyl zinc, diethyl zinc, zinc acetate, zinc acetate dihydrate, zinc acetylacetonate, zinc acetylacetonate hydrate, zinc iodide, zinc bromide, zinc chloride, zinc fluoride, zinc fluoride tetrahydrate, zinc carbonate, zinc cyanide, zinc nitrate, zinc nitrate hexahydrate, zinc oxide, zinc peroxide, zinc perchlorate, zinc perchlorate hexahydrate, zinc sulfate, diphenyl zinc, zinc naphthenate, and zinc stearate. Preferably, the Group II element pre-precursor may be zinc acetate or zinc chloride.

The same can be applied as above even when the Group II element is not zinc.

The carboxylic acid is required to react with the Group II element pre-precursor so as to produce a Group II element-carboxylate, which is a Group II element precursor, and palmitic acid, myristic acid, oleic acid, stearic acid, etc. may be used.

The Group II element pre-precursor and carboxylic acid are mixed at a molar ratio of, for example, 1:1 to 1:3 to prepare a mixed solution. When the molar ratio is outside the above range, problems may occur as unreacted excess salt or acid may unintentionally participate in the subsequent process. Additionally, the reduced pressure is preferably 100 torr to 0.001 torr. When the reduced pressure is outside the above range, removal of impurities or additionally generated products may not proceed smoothly.

Step 0-2 is a step in which the mixed solution after step 0-1 is heated to the first temperature and then the mixed solution is subjected to a primary reaction. The range of the first temperature varies depending on the type of carboxylic acid used, and for example, room temperature (25° C.) to 200° C. is preferable. In the above, the pressure is maintained as-is. In addition, the time for temperature elevation is preferably 10 minutes to 1 hour, and the reaction time, for example, is preferably 10 minutes to 3 hours. The product produced after step 0-2 is a Group II element-carboxylate.

The following steps 0-3 and 0-4 are optional steps, in which the Group II element-carboxylate prepared in steps 0-1 and 0-2 is pyrolyzed to form a Group II element oxide-carboxylate (hereinafter, referred to as a Group II element nanocluster).

Step 0-3 is a step in which the mixed solution after step 0-2 is heated to a second temperature higher than the first temperature, and then the mixed solution is subjected to a secondary reaction. The second temperature may range from 200° C. to 500° C., for example, and is preferably higher than the first temperature. In particular, the pressure is maintained as-is. In addition, the time for temperature elevation is preferably 10 minutes to 1 hour, and the reaction time is, for example, preferably 10 minutes to 3 hours.

Step 0-4 is a step of lowering the temperature (temperature reduction) to the third temperature after injecting the mixed solution into the solvent under an inert atmosphere. The solvent is used to control the concentration of the mixed solution, and both coordinating and non-coordinating solvents may be used, and octadecene may generally be used. The third temperature range may be room temperature, and the pressure may be maintained at atmospheric pressure. The temperature reduction time is preferably 20 minutes to 2 hours.

The Group V element precursor solution includes a Group V element precursor and a solvent.

The Group V element precursor may be one or more organometallic phosphorus selected from the group consisting of tris(trimethylsilyl)phosphine (TMSP), aminophosphine, white phosphorus, tris(pyrazolyl)phosphane, and calcium phosphide. For example, the Group V element precursor may be one or more selected from the group consisting of tris(trimethylsilyl)phosphine (TMSP) and aminophosphine.

The solvent used in the Group V element precursor solution may be trioctylphosphine (TOP), tributylphosphine (TBP), octadecene (ODE), amines (primary amine, secondary amine, and third amine), etc.

The Group V element precursor solution may include an alkylphosphine-based surfactant. When an alkylphosphine-based surfactant is added to the Group V element precursor solution, the Group V element and the alkylphosphine-based surfactant may bind to form an organic complex, enabling a more stable reaction and making it more suitable for mass production. Additionally, the size of the quantum dots produced may be adjusted by changing the type of alkylphosphine-based surfactant.

The alkylphosphine-based surfactant may be one or more selected from the group consisting of triethyl phosphine, tributyl phosphine, trioctyl phosphine, triphenyl phosphine, and tricyclohexyl phosphine.

The shell forming step (step 2) is a step of forming a shell on the surface of the core after the core forming step. The shell forming step includes step 2-1, step 2-2, and step 2-3.

In the method for manufacturing quantum dots according to embodiments of the present disclosure, matters regarding the shell of the quantum dots are the same as those described for the shell of the quantum dots according to the embodiments of the present disclosure, unless otherwise specified.

In step 2-1, the temperature of the solution in the core forming step is reduced to 100° C. to 250° C. Then, the shell is formed by injecting one or both of the Group III element precursor solution and the Group V element precursor solution, or by injecting one or both of the Group II element precursor solution and the Group VI element precursor solution. That is, the shell is formed by injecting a Group II element precursor or/and a Group VI element precursor or a Group III element precursor or/and a Group V element precursor.

Step 2-2 is a step in which the solution in step 2-1 is heated to 200° C. to 400° C. for 10 to 120 minutes and then reacted for 2 to 4 hours. When the temperature is outside the above range, there is a problem in that effective shell coating cannot be achieved.

The 2-3 step is a step of cooling the solution in step 2-2 to room temperature by blowing the same with an inert gas. When the blowing with an inert gas is not performed, there is a problem in that the surface of the quantum dots is oxidized due to the injection of air at high temperatures.

The purification step (step 3) includes step 3-1, step 3-2, and step 3-3.

The step 3-1 is a step, in which the solution after the shell forming step is placed in a centrifugable container, for example, an alcohol-based solvent and a polar solvent (e.g., 2-propanol) are added and centrifuged, and the supernatant is discarded to thereby obtain the precipitate.

During centrifugation, the rotation speed may be, for example, 1,000 rpm to 20,000 rpm.

The 3-2 step is a step of dissolving the precipitate in an organic solvent (e.g., hexane, toluene, octadecane, heptane, etc.).

The 3-3 step is a step in which steps 3-1 and 3-2 are repeated at least once and then the resultant is stored in a dissolved state in a non-polar solvent.

Meanwhile, the semiconductor nanoparticles, which are the quantum dot emitting layer material of the present disclosure, may further include a ligand. For example, the ligand may include a C₆₋₃₀ alkyl group or C₆₋₃₀ alkenyl group, (poly)ethyleneoxy, an amine compound having an aryl group, a thiol compound or carboxylic acid compound, etc. Examples of amine compounds having an alkyl group include hexadecylamine, octylamine, etc.

In contrast, another example of the ligand may include phosphine compounds including trioctylphosphine, triphenolphosphine, t-butylphosphine, etc.; phosphine oxides (e.g., trioctylphosphine oxide, etc.); pyridine or thiophene, etc.

The types of ligands proposed in the present disclosure are not limited to those exemplified above.

The ligand of the semiconductor nanoparticle-ligand complex can prevent neighboring cores/shells or cores/multishells from being coagulated and thereby quenched. The ligand may bind to the core/shells or core/multishells and thereby have hydrophobic properties.

In another aspect, according to embodiments of the present disclosure, a photosensitive resin composition for inkjet printing may be provided using a semiconductor nanoparticle-ligand complex. A quantum dot light-emitting layer may be formed through an inkjet printing method by providing the photosensitive resin composition.

The photosensitive resin composition includes (A) a semiconductor nanoparticle-ligand complex, (B) a photocrosslinkable monomer, and (C) an initiator.

In describing the photosensitive resin composition according to embodiments of the present disclosure, unless otherwise specified, details regarding the semiconductor nanoparticle-ligand complex are the same as those described for the semiconductor nanoparticle-ligand complex according to the embodiments of the present disclosure described above, and will therefore be omitted.

The photosensitive resin composition may include 10 wt % to 60 wt % of the semiconductor nanoparticle-ligand complex based on the total amount of the photosensitive resin composition. The lower limit of the content of the semiconductor nanoparticle-ligand complex may be 20 wt % or more or 30 wt % or more. The upper limit of the content of the semiconductor nanoparticle-ligand complex may be 50 wt % or less. When the photosensitive resin composition includes the semiconductor nanoparticle-ligand complex in the above-described content, it can have a viscosity suitable for coating and ink jetting while having a sufficient luminous effect.

The photocrosslinkable monomer may be a monofunctional ester of (meth)acrylic acid having one ethylenically unsaturated double bond or a polyfunctional ester of (meth)acrylic acid having at least two ethylenically unsaturated double bonds. The polyfunctional ester may be, for example, a difunctional ester, a trifunctional ester, or a tetrafunctional ester.

The photocrosslinkable monomer, by having the ethylenically unsaturated double bond, can generate sufficient polymerization when exposed to light in the pattern forming process and thereby form a pattern having excellent heat resistance, light resistance, and chemical resistance.

The photocrosslinkable monomer may be used after treating with an acid anhydride so as to provide better developability. The photocrosslinkable monomer may be included in an amount of 30 wt % to 90 wt % or 35 wt % to 85 wt % based on the total amount of the photosensitive resin composition.

The photosensitive resin composition may further include a binder resin.

The binder resin may be one or more selected from the group consisting of an acryl-based resin and an epoxy resin.

As the initiator, one or more selected from a photopolymerization initiator and a thermal polymerization initiator may be used.

As the photopolymerization initiator, for example, one or more selected from an acetophenone-based compound, a benzophenone-based compound, a thioxanthone-based compound, a benzoin-based compound, an oxime ester-based compound, a phosphorus-based compound, and a triazine-based compound may be used.

As the photopolymerization initiator, a carbazole-based compound, a diketone-based compound, a sulfonium borate-based compound, a diazo-based compound, an imidazole-based compound, a biimidazole-based compound, etc. may be used in addition to the compounds described above.

As the thermal polymerization initiator, a peroxide-based compound, an azobis-based compound, etc. may be used.

The content of the initiator may be in an amount of 0.1 wt % to 10 wt %, or preferably 0.1 wt % to 8 wt %, based on the total amount of the photosensitive resin composition. When the content of the initiator satisfies the above range, curing occurs sufficiently during exposure to light or heating in the pattern forming process using the photosensitive resin composition and thus can obtain excellent reliability, and has excellent heat resistance, light resistance, and chemical resistance of the pattern, and also has excellent resolution and adhesion, and additionally, a decrease in transmittance due to unreacted initiators can be prevented.

The photosensitive resin composition may further include a light diffusion agent, for example, the light diffusion agent may include barium sulfate, calcium carbonate, titanium dioxide, zirconia, or a combination thereof.

In particular, the content of the light diffusion agent may be in an amount of 0.1 wt % to 10 wt % or 0.1 wt % to 8 wt % based on the total amount of the photosensitive resin composition. When the content of the light diffusion agent satisfies the above-described range, the light diffusion agent may have a viscosity suitable for coating and inkjetting while having a sufficient light diffusion effect.

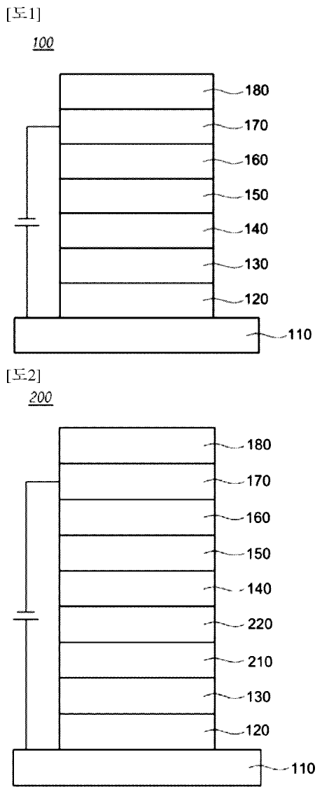

Hereinafter, the structure of a quantum dot light emitting device including the compound of the present disclosure will be described with reference to FIGS. 1 to 3.

Referring to FIG. 1, the quantum dot light emitting device 100 according to an embodiment of the present disclosure includes a first electrode 110, a second electrode 170, formed on a substrate (not shown), a quantum dot light-emitting layer 140 disposed between the first electrode 110 and the second electrode 170, and an organic layer, which includes a compound according to the present disclosure.

The first electrode 110 may be an anode (a positive electrode), and the second electrode 170 may be a cathode (a negative electrode), and in the case of an inverted type, the first electrode may be a cathode and the second electrode may be an anode.

The organic layer may include a hole injection layer 120, a hole transport layer 150, and an electron injection layer 160. Specifically, a hole injection layer 120, a hole transport layer 130, a quantum dot light emitting layer 140, an electron transport layer 150, and an electron injection layer 160 may be formed sequentially on the first electrode 110.

Preferably, a capping layer 180 may be formed on one side of the first electrode 110 or the second electrode 170 that is not in contact with the organic layer, and when the capping layer 180 is formed, the optical efficiency of the quantum dot emitting device can be improved.

For example, the capping layer 180 may be formed on the second electrode 170, and in the case of atop emission organic light emitting device, an optical energy loss due to surface plasmon polaritons (SPPs) in the second electrode 170 may be reduced by forming the capping layer 180, whereas in the case of a bottom emission organic light emitting device, the capping layer 180 may serve as a buffer for the second electrode 170.

Meanwhile, a buffer layer 210 or auxiliary light emitting layer 220 may be further formed between the hole transport layer 130 and the quantum dot light emitting layer 140, which will be described with reference to FIG. 2.

Referring to FIG. 2, the quantum dot light emitting device 200 according to another embodiment of the present disclosure may include, on the first electrode 110, a hole injection layer 120, a hole transport layer 130, a buffer layer 210, an auxiliary light emitting layer 220, a quantum dot light emitting layer 140, an electron transport layer 150, an electron injection layer are sequentially formed, a layer 160, and a second electrode 170, and on the second electrode, a capping layer 180 may be formed.

Although not shown in FIG. 2, an auxiliary electron transport layer or buffer layer may be further included between the quantum dot light emitting layer 140 and the electron transport layer 150. A study was reported in the paper, in which, as an example of the auxiliary electron transport layer or buffer layer, polymethyl methacrylate (PMMA) was formed on the light emitting layer by spin coating, by reducing electron injection by forming a ZnO layer, which is an electron transport layer and thereby the charge balance within the light emitting layer was improved [Peng et al., Nature, 515, 96-99 (2014)].

In the case of an inverted structure, a study was reported in a paper with regard to a structure in which poly[(9,9-bis(30-(N,N-dimethylamino)propyl)-2,7-fluorene)-alt-2,7-(9,9-ioctylfluorene (PFN)) was formed as an auxiliary electron transport layer or buffer layer on the ZnO layer, which is an electron transport layer, and then a light emitting layer was formed [Kookheon Char et al., ACS Nano., 2013, 7, 10, 9019-9026]. By forming a thin PFN, the energy level of the quantum dot emitting layer (QD) layer, which is a light emitting layer, was adjusted to facilitate electron injection into the light emitting layer.

Similarly, a study was reported as a paper in which polyethylenimine epoxylate (PEIE) or polyethylenimine (PEI) was formed on ZnO or together therewith so as to control the energy level of the electron transport layer to thereby control the electron injection into the light emitting layer [Liang-Sheng Liao et al., Nanoscale, 2017, 9, 14792-14797], [Lei Wang et al., ACS Appl. Mater. Interfaces, 2017, 9, 23].

In addition, a study was reported in a paper with regard to a structure in which an auxiliary electron transport layer or buffer layer was additionally introduced to prevent electron injection by forming a thin Al₂O₃ between ZnO and the light-emitting layer [Heeyeop Chae et al., RSC Adv., 2019, 9, 11634-11640].

As such, studies have been reported with regard to the improvement of characteristics and stability of devices compared to those of existing devices by controlling electron injection and energy level by additionally including an auxiliary electron transport layer or buffer layer between the light emitting layer and the electron transport layer.

Additionally, according to another embodiment of the present disclosure, a plurality of stacks including a hole transport layer, a quantum dot light emitting layer, and an electron transport layer may be formed. This will be described with reference to FIG. 3.

Referring to FIG. 3, in the quantum dot light emitting device 300 according to another embodiment of the present disclosure, two or more sets of stacks (ST1, ST2) consisting of multi-layered organic material layers between the first electrode 110 and the second electrode 170 may be formed, and a charge generation layer (CGL) may be formed between the stacks of the organic material layers.

Specifically, the quantum dot light emitting device according to an embodiment of the present disclosure includes a first electrode 110, a first stack (ST1), a charge generation layer (CGL), a second stack (ST2), and a second electrode 170, and a capping layer 180.

The first stack (ST1) is an organic material layer formed on the first electrode 110, which includes a first hole injection layer 320, a first hole transport layer 330, a first quantum dot light emitting layer 340, and a first electron transport layer 350.

The second stack (ST2) may include a second hole injection layer 420, a second hole transport layer 430, a second quantum dot light emitting layer 440, and a second electron transport layer 450.

As such, the first stack and the second stack may be organic material layers having the same stacked structure, or they may be organic material layers having different stacked structures.

A charge generation layer (CGL) may be formed between the first stack (ST1) and the second stack (ST2). The charge generation layer (CGL) may include a first charge generation layer 360 and a second charge generation layer 361. Such charge generation layer (CGL) is formed between the first quantum dot light emitting layer 340 and the second quantum dot light emitting layer 440, and serves to increase the efficiency of the current generated in each light emitting layer and to smoothly distribute charges.

The quantum dot light emitting material may be used for the first quantum dot light emitting layer 340 and the second quantum dot light emitting layer 440, but is not limited thereto.

In particular, the second hole transport layer 430 is made to include a second stack (ST2) whose energy level is set higher than the excited state energy level of the second quantum dot light emitting layer 440.

Since the energy level of the second hole transport layer 430 is higher than that of the second quantum dot light emitting layer 440, the triplet exciton of the second quantum dot light emitting layer 440 can be prevented from crossing over to the second hole transport layer 430 and reducing luminous efficiency. That is, the second hole transport layer 430 may function to transport holes from the intrinsic second quantum dot light emitting layer 440 and simultaneously function as an exciton blocking layer that prevents excitons from crossing over.

Additionally, in order to function as an exciton blocking layer, the first hole transport layer 330 may also be set to an energy level higher than the exciton energy level of the first quantum dot light emitting layer 340. In addition, it is desirable that the first electron transport layer 350 be also set to an energy level higher than the energy level of the exciton state of the first quantum dot light emitting layer 340, and the second electron transport layer 450 be also set to an energy level higher than the energy level of the exciton state of the second quantum dot light emitting layer 440.

In FIG. 3, n may be an integer between 1 and 5, and when n is 2, a charge generation layer (CGL) and a third stack may be further stacked on the second stack (ST2).

When a plurality of light emitting layers are formed by the method of a multi-layer stack structure as shown in FIG. 3, not only it is possible to a quantum dot light emitting device that emits white light be manufactured by mixing the light emitted from each light emitting layer, but it is also possible to manufacture a quantum dot light emitting device that emits light of various colors.

The compound according to the present disclosure may be used as a material for the hole injection layers (120, 320, 420), the hole transport layers (130, 330, 430), the buffer layer 210, the auxiliary light emitting layer 220, the electron transport layers (150, 350, 450), and the electron transport layer (150, 350, 450), the injection layer 160, or the capping layer 180, but preferably, the compound may be used as a material for the hole transport layers (130, 330, 430) or the auxiliary light emitting layer 220.

The quantum dot light emitting device according to FIGS. 1 to 3 may further include a protective layer (not shown) and an encapsulation layer (not shown). The protective layer may be located on the capping layer. The encapsulation layer may be located on the capping layer, and may be formed to cover the side portion of one or more of the first electrode, the second electrode, the quantum dot light emitting layer, and the organic material layer in order to protect the first electrode, the second electrode, the quantum dot light emitting layer, and the organic material layer.

The protective layer can provide a flat surface so that the encapsulation layer can be formed uniformly, and can serve to protect the first electrode, the second electrode, the quantum dot emitting layer, and the organic material layer during the manufacturing process of the encapsulation layer.

The encapsulation layer can play a role in preventing external oxygen and moisture from penetrating into the quantum dot light emitting device.

Meanwhile, even in the same similar cores, the band gap, electrical properties, and interface properties may vary depending on which substituent is attached to which position; therefore, studies on the selection of the core and the combination of sub-substituents attached thereto are required, and in particular, when the energy level and T1 value between the quantum dot emitting layer and each organic material layer, and the intrinsic properties of the material (mobility, interface properties, etc.) are optimally combined, long lifetime and high efficiency can be achieved simultaneously.

Therefore, by using the compound according to the present disclosure as a material for the electron transport layer 150 or the light emitting auxiliary layer 220, it was possible to optimize the energy level and T1 value between each organic material layer and the intrinsic properties of the material (mobility, interface properties, etc.), thereby simultaneously improving the lifetime and efficiency of the quantum dot light emitting device.

A quantum dot light emitting device according to an embodiment of the present disclosure may be manufactured using various deposition methods. The quantum dot light emitting device may be manufactured using deposition methods such as PVD or CVD, for example, it may be manufactured in such a way that the anode 110 is formed by depositing a metal or conductive metal oxide or an alloy thereof on the substrate, and on top of that, hole injection layers (120, 320, 420), hole transport layers (130, 330, 430), quantum dot light emitting layers (140, 340, 440), electron transport layers (150, 350, 450), and an electron injection layer 160 may be sequentially formed, and then a material that can be used as the cathode 170 may be deposited thereon. In the case of an invert, the quantum dot light emitting device may be manufactured by forming a cathode on a substrate, and sequentially forming on top of the same an electron injection layer, an electron transport layer, a quantum dot light emitting layer, a hole transport layer, a hole injection layer, and an anode thereon.

In addition, a light emitting auxiliary layer 220 may be formed between the hole transport layers (130, 330, 430) and the quantum dot light emitting layers (140, 340, 440), and an auxiliary electron transport layer (not shown) may be formed between the quantum dot light emitting layer 140 and the electron transport layer 150, and may also be formed in a stacked structure as described above.

In addition, the organic material layer may be manufactured with a smaller number of layers using various polymer materials by methods such as a solution process or solvent process (e.g., a spin coating process, a nozzle printing process, an inkjet printing process, a slot coating process, a dip coating process, a roll-to-roll process, a doctor blading process, a screen printing process) instead of a deposition method, or thermal transfer method. Since the organic material layer according to the present disclosure may be formed by various methods, the scope of the present disclosure is not limited by the formation method.

The quantum dot light emitting device according to an embodiment of the present disclosure may be a front surface emitting type, a rear surface emitting type, or a double surface emitting type depending on the material to be used.

The quantum dot light emitting device according to an embodiment of the present disclosure includes next-generation high-brightness light emitting diodes (LEDs), biosensors, lasers, solar cell nanomaterials, etc.

Another embodiment of the present disclosure may include a display device including the quantum dot light emitting device of the present disclosure described above, and an electronic device including a control unit that controls the display device. In particular, electronic devices may be current or future wired or wireless communication terminals, and include all electronic devices such as mobile communication terminals (e.g., mobile phones), PDAs, electronic dictionaries, PMPs, remote controls, navigation systems, game consoles, various TVs, and various computers.

Hereinafter, a compound according to one aspect of the present disclosure will be described.

The quantum dot light emitting device according to one aspect of the present disclosure includes a first electrode; a second electrode; a light emitting layer including quantum dots and a hole transport layer between the first electrode and the second electrode; an auxiliary light emitting layer between the hole transport layer and the light emitting layer, wherein the auxiliary light emitting layer includes a compound represented by Formula 1.

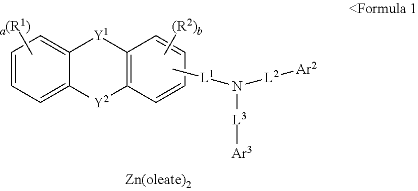

In Formula 1 above,
1) Ar² and Ar³ are each independently selected from the group consisting of a C₆₋₆₀ aryl group; a fluorenyl group; a C₂₋₆₀ heterocyclic group including at least one heteroatom among O, N, S, Si, and P; a fused ring group of a C₃₋₆₀ aliphatic ring and a C₆₋₆₀ aromatic ring; a C₁₋₅₀ alkyl group; a C₂₋₂₀ alkenyl group; a C₂₋₂₀ alkynyl group; a C₁₋₃₀ alkoxyl group; a C₆₋₃₀ aryloxy group; and -L′-N(Rₐ)(R_{b});
2) L¹ and L² are each independently selected from the group consisting of a single bond; a C₆₋₆₀ arylene group; a fluorenylene group; a fused ring group of a C₃₋₆₀ aliphatic ring and a C₆₋₆₀ aromatic ring; and a C₂₋₆₀ heterocyclic ring group;
3) R¹ and R² are each the same or different, and are each independently selected from the group consisting of hydrogen; deuterium, tritium; a halogen; a cyano group; a nitro group; a C₆₋₆₀ aryl group; a fluorenyl group; a C₂₋₆₀ heterocyclic group including at least one heteroatom among O, N, S, Si, and P; a fused ring group of a C₃₋₆₀ aliphatic ring and a C₆₋₆₀ aromatic ring; a C₁₋₅₀ alkyl group; a C₂₋₂₀ alkenyl group; a C₂₋₂₀ alkynyl group; a C₁₋₃₀ alkoxyl group; a C₆₋₃₀ aryloxy group; and -L′-N(Rₐ)(R_{b});
4) Y¹ and Y² are each independently absent or a single bond, NR, O, S, or CR′R″; excluding where Y¹ and Y² are simultaneously a single bond or absent;
5) R, R′, and R″ are each independently selected from the group consisting of hydrogen; deuterium, tritium; a halogen; a cyano group; a nitro group; a C₆₋₆₀ aryl group; a fluorenyl group; a C₂₋₆₀ heterocyclic group including at least one heteroatom among O, N, S, Si, and P; a fused ring group of a C₃₋₆₀ aliphatic ring and a C₆₋₆₀ aromatic ring; a C₁₋₅₀ alkyl group; a C₂₋₂₀ alkenyl group; a C₂₋₂₀ alkynyl group; a C₁₋₃₀ alkoxyl group; a C₆₋₃₀ aryloxy group; and -L′-N(Rₐ)(R_{b}); wherein R′ and R″ may bind to each other to form a spiro ring;
6) a is an integer from 0 to 4; b is an integer from 0 to 3; with the proviso that when Y¹ or Y² is absent, a is an integer from 0 to 5, and b is an integer from 0 to 4; 7) when a or b is 2 or greater, R¹ and R² are each plural and the same or different from each other; wherein a plurality of neighboring R¹ or a plurality of neighboring R² are able to bind between them, respectively, to thereby form a ring;
8) the L′ is each independently selected from the group consisting of a single bond; a C₆₋₆₀ arylene group; a fluorenylene group; a C₂₋₆₀ heterocyclic group including at least one heteroatom among O, N, S, Si, and P; a C₃₋₆₀ aliphatic ring; and a fused ring group of a C₃₋₆₀ aliphatic ring and a C₆₋₆₀ aromatic ring;
9) the Rₐ and R_{b} may each be independently selected from the group consisting of a C₆₋₆₀ aryl group: a fluorenyl group; a C₂₋₆₀ heterocyclic group including at least one heteroatom among O, N, S, Si, and P; a C₃₋₆₀ aliphatic ring; and a fused ring group of a C₃₋₆₀ aliphatic ring and a C₆₋₆₀ aromatic ring; and
10) the rings formed by binding between the L′, L¹ to L³, Rₐ, R_{b}, Ar² and Ar³, R¹ and R², R, R′, R″, and neighboring groups thereof may each be further substituted with one or more substituents selected from the group consisting of deuterium; a halogen; a silane group substituted or unsubstituted with a C₁₋₃₀ alkyl group or C₆₋₃₀ aryl group; a siloxane group; a boron group; a germanium group; a cyano group; an amino group; a nitro group; a C₁₋₃₀ alkylthio group; a C₁₋₃₀ alkoxy group; a C₆₋₃₀ arylalkoxy group; a C₁₋₃₀ alkyl group; a C₂₋₃₀ alkenyl group; a C₂₋₃₀ alkynyl group; a C₆₋₃₀ aryl group; a C₆₋₃₀ aryl group substituted with deuterium; a fluorenyl group; a C₂₋₃₀ heterocyclic group including at least one heteroatom among O, N, S, Si, and P; a C₃₋₃₀ alicyclic group; a C₇₋₃₀ arylalkyl group; a C₈₋₃₀ arylalkenyl group; and a combination thereof; or may form a ring between the neighboring substituents.

When Ra, Rb, Ar² and Ar³, R¹ and R², R, R′, and R″ are an aryl group, it may preferably be a C₆₋₃₀ aryl group, and more preferably a C₆₋₁₈ aryl group (e.g., phenyl, biphenyl, naphthyl, terphenyl, etc.).

When L′, L¹ to L³, Rₐ, R_{b}, Ar² and Ar³, R¹ and R², R, R′, R″ are a heterocyclic group, it may preferably be a C₂₋₃₀ heterocyclic group, and more preferably a C₂₋₁₈ heterocyclic group (e.g., dibenzofuran, dibenzothiophene, naphthobenzothiophene, naphthobenzofuran, etc.).

When Ra, Rb, Ar² and Ar³, R¹ and R², R, R′, and R″ are a fluorenyl group, and it may preferably be 9,9-dimethyl-9H-fluorene, 9,9-diphenyl-9H-fluorenyl group, 9,9′-spirobifluorene, etc.

When L′ and L¹ to L³ are an arylene group, it may preferably be a C₆₋₃₀ arylene group, and more preferably a C₆₋₁₈ arylene group (e.g., phenyl, biphenyl, naphthyl, terphenyl, etc.).

When Ar² and Ar³, R¹ and R², R, R′, and R″ are an alkyl group, it may preferably be a C₁₋₁₀ alkyl group (e.g., methyl, t-butyl, etc.).

When Ar² and Ar³, R¹ and R², R, R′, and R″ are an alkoxyl group, it may preferably be a C₁₋₂₀ alkoxyl group, and more preferably a C₁₋₁₀ alkoxyl group (e.g., methoxy, t-buthoxy, etc.).

The rings formed by binding between neighboring groups of the L′, L¹ to L³, Rₐ, R_{b}, Ar² and Ar³, R¹ and R², R, R′, R″ may be a C₆₋₆₀ aromatic ring group; a fluorenyl group; a C₂₋₆₀ heterocyclic group including at least one heteroatom among O, N, S, Si, and P; or a C₃₋₆₀ alicyclic group, and for example, when neighboring groups bind to each other and form an aromatic ring, the ring may form a C₆₋₂₀ aromatic ring, and more preferably a C₆₋₁₄ aromatic ring (e.g., benzene, naphthalene, phenanthrene, etc.).

Also preferably, Formula 1 may be represented by any one of the following Formulas 1-1 to 1-3, but is not limited thereto.

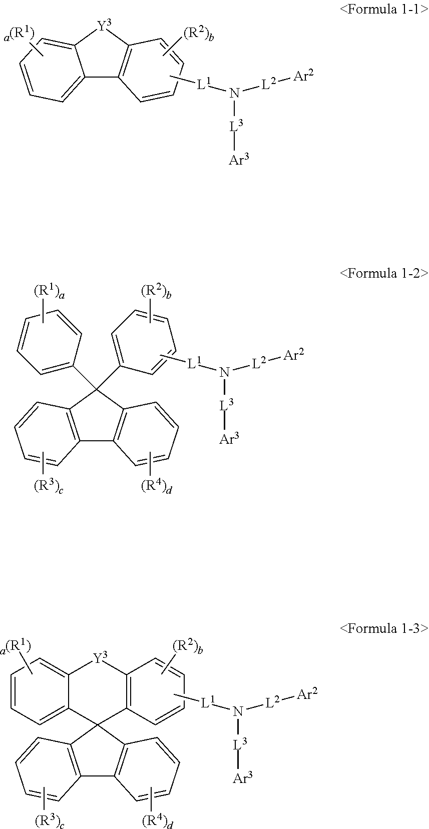

In Formula 1-1 to Formula 1-3 above,
1) the L¹ to L³, Ar² and Ar³, R¹ and R², and a and b are the same as defined in Formula 1 above;
2) Y³ is NR_{c}, O, S, or CR_{d}Rₑ;
3) R³ and R⁴, and R_{c} to Rₑ may each be independently selected from the group consisting of hydrogen; deuterium, tritium; a halogen; a cyano group; a nitro group; a C₆₋₆₀ aryl group; a fluorenyl group: a C₂₋₆₀ heterocyclic group including at least one heteroatom among O, N, S, Si, and P; a fused ring group of a C₃₋₆₀ aliphatic ring and a C₆₋₆₀ aromatic ring; a C₁₋₅₀ alkyl group; a C₂₋₂₀ alkenyl group; a C₂₋₂₀ alkynyl group; a C₁₋₃₀ alkoxyl group; a C₆₋₃₀ aryloxy group; and -L′-N(Rₐ)(R_{b}); or R_{d} and Rₑ may bind to each other to form a spiro ring;
4) the L′ is each independently selected from the group consisting of a single bond; a C₆₋₆₀ arylene group; a fluorenylene group; a C₂₋₆₀ heterocyclic group including at least one heteroatom among O, N, S, Si, and P; a C₃₋₆₀ aliphatic ring; and a fused ring group of a C₃₋₆₀ aliphatic ring and a C₆₋₆₀ aromatic ring;
5) the Rₐ and R_{b} may each be independently selected from the group consisting of a C₆₋₆₀ aryl group; a fluorenyl group; a C₂₋₆₀ heterocyclic group including at least one heteroatom among O, N, S, Si, and P; a C₃₋₆₀ aliphatic ring; and a fused ring group of a C₃₋₆₀ aliphatic ring and a C₆₋₆₀ aromatic ring; and
6) c and d are independently integers from 0 to 4.

Also preferably, Formula 1 may be represented by the following Formula 2-1 or Formula 2-2, but is not limited thereto.

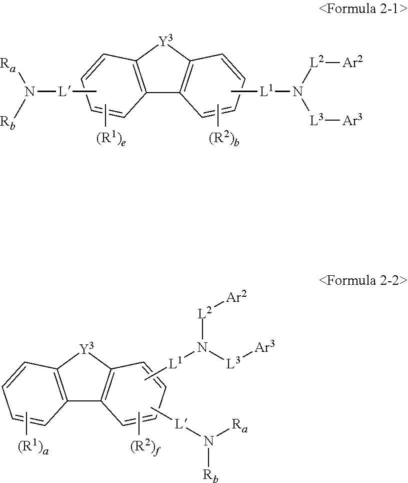

In Formula 2-1 or Formula 2-2 above,
1) the L¹ to L³, Ar² and Ar³, R¹ and R², and a and b are the same as defined in Formula 1 above;
2) Y³ is NR_{c}, O, S, or CR_{d}Rₑ;
3) R_{c} to Rₑ may each be independently selected from the group consisting of hydrogen; deuterium, tritium; a halogen; a cyano group; a nitro group; a C₆₋₆₀ aryl group: a fluorenyl group; a C₂₋₆₀ heterocyclic group including at least one heteroatom among O, N, S, Si, and P; a fused ring group of a C₃₋₆₀ aliphatic ring and a C₆₋₆₀ aromatic ring; a C₁₋₅₀ alkyl group; a C₂₋₂₀ alkenyl group; a C₂₋₂₀ alkynyl group; a C₁₋₃₀ alkoxyl group; a C₆₋₃₀ aryloxy group; and -L′—N(Rₐ)(R_{b}); or R_{d} and Rₑ may bind to each other to form a spiro ring;
4) the L′ is each independently selected from the group consisting of a single bond; a C₆₋₆₀ arylene group; a fluorenylene group; a C₂₋₆₀ heterocyclic group including at least one heteroatom among O, N, S, Si, and P; a C₃₋₆₀ aliphatic ring; and a fused ring group of a C₃₋₆₀ aliphatic ring and a C₆₋₆₀ aromatic ring;
5) the Rₐ and R_{b} may each be independently selected from the group consisting of a C₆₋₆₀ aryl group: a fluorenyl group; a C₂₋₆₀ heterocyclic group including at least one heteroatom among O, N, S, Si, and P; a C₃₋₆₀ aliphatic ring; and a fused ring group of a C₃₋₆₀ aliphatic ring and a C₆₋₆₀ aromatic ring; and
6) the e is an integer from 0 to 3; and f is an integer from 0 to 2.

Also preferably, Formula 1 may be represented by the following Formula 2-3 or Formula 2-4, but is not limited thereto.

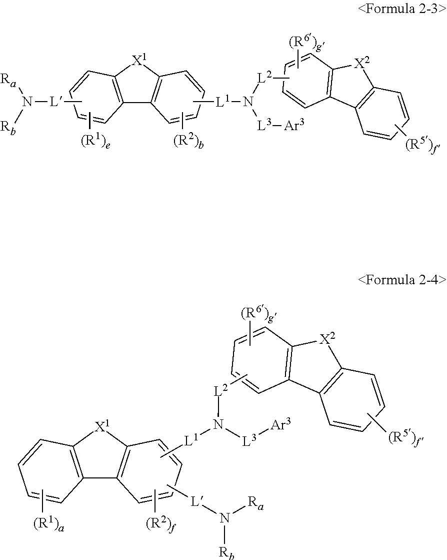

In Formula 2-3 or Formula 2-4 above,
1) the L¹ to L³, Ar³, R¹ and R², and a and b are the same as defined in Formula 1 of claim 1 above;
2) the e is an integer from 0 to 3; and f is an integer from 0 to 2;
3) X¹ is O or S;
4) X² is NRₑ, O, S, or CR_{d}Rₑ;
5) R_{c} to Rₑ may each be independently selected from the group consisting of hydrogen; deuterium, tritium; a halogen; a cyano group; a nitro group; a C₆₋₆₀ aryl group: a fluorenyl group, a C₂₋₆₀ heterocyclic group including at least one heteroatom among O, N, S, Si, and P; a fused ring group of a C₃₋₆₀ aliphatic ring and a C₆₋₆₀ aromatic ring; a C₁₋₅₀ alkyl group; a C₂₋₂₀ alkenyl group; a C₂₋₂₀ alkynyl group; a C₁₋₃₀ alkoxyl group; a C₆₋₃₀ aryloxy group; and -L′-N(Rₐ)(R_{b}); or R_{d} and Rₑ may bind to each other to form a spiro ring;
6) the L′ is each independently selected from the group consisting of a single bond; a C₆₋₆₀ arylene group; a fluorenylene group; a C₂₋₆₀ heterocyclic group including at least one heteroatom among O, N, S, Si, and P; a C₃₋₆₀ aliphatic ring; and a fused ring group of a C₃₋₆₀ aliphatic ring and a C₆₋₆₀ aromatic ring;
7) the Rₐ and R_{b} may each be independently selected from the group consisting of a C₆₋₆₀ aryl group; a fluorenyl group; a C₂₋₆₀ heterocyclic group including at least one heteroatom among O, N, S, Si, and P; a C₃₋₆₀ aliphatic ring; and a fused ring group of a C₃₋₆₀ aliphatic ring and a C₆₋₆₀ aromatic ring;
8) R^{5′} and R^{6′} are each independently selected from the group consisting of hydrogen; deuterium, tritium; a halogen; a cyano group; a nitro group; a C₆₋₆₀ aryl group: a fluorenyl group, a C₂₋₆₀ heterocyclic group including at least one heteroatom among O, N, S, Si, and P; a fused ring group of a C₃₋₆₀ aliphatic ring and a C₆₋₆₀ aromatic ring; a C₁₋₅₀ alkyl group; a C₂₋₂₀ alkenyl group; a C₂₋₂₀ alkynyl group; a C₁₋₃₀ alkoxyl group; a C₆₋₃₀ aryloxy group; and -L′-N(Rₐ)(R_{b}); and
9) f is an integer from 0 to 4; and f is an integer from 0 to 2.

Meanwhile, the compound represented by Formula 1 may be one of Compounds 1-1 to 1-80 and 2-1 to 2-80 below, but is not limited thereto.

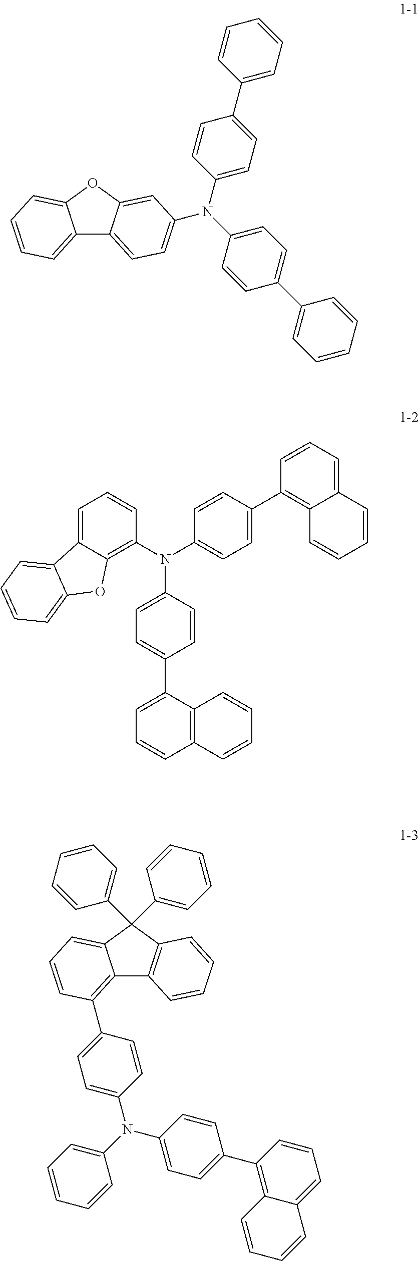 [SMILES: c1ccc(-c2ccc(N(c3ccc(-c4ccccc4)cc3)c3ccc4c(c3)oc3ccccc34)cc2)cc1 ; c1ccc2c(-c3ccc(N(c4ccc(-c5cccc6ccccc56)cc4)c4cccc5c4oc4ccccc45)cc3)cccc2c1 ; c1ccc(N(c2ccc(-c3cccc4c3-c3ccccc3C4(c3ccccc3)c3ccccc3)cc2)c2ccc(-c3cccc4ccccc34)cc2)cc1]

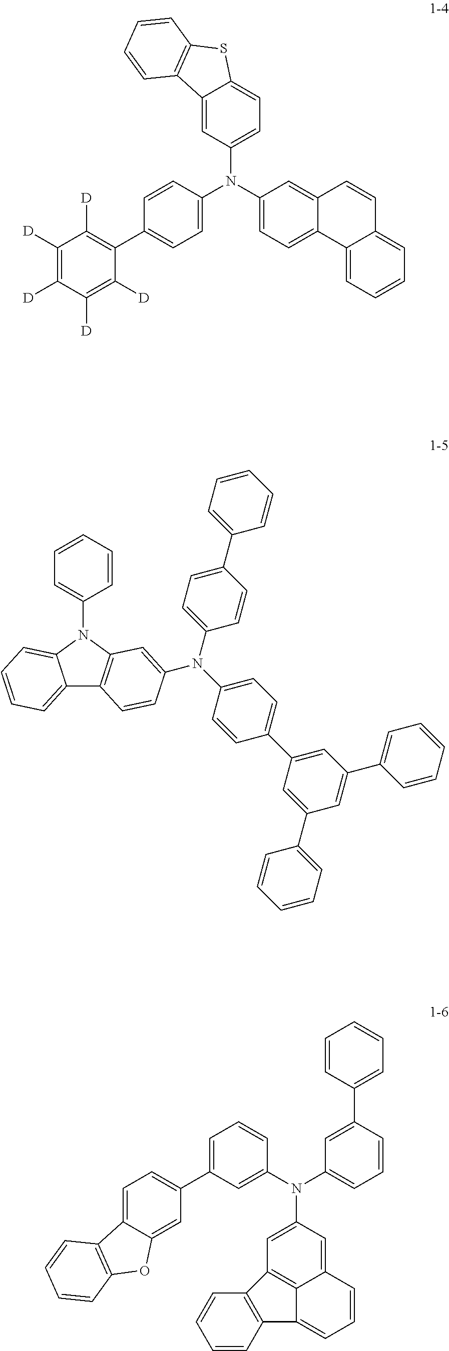 [SMILES: [2H]c1c([2H])c([2H])c(-c2ccc(N(c3ccc4c(ccc5ccccc54)c3)c3ccc4sc5ccccc5c4c3)cc2)c([2H])c1[2H] ; c1ccc(-c2ccc(N(c3ccc(-c4cc(-c5ccccc5)cc(-c5ccccc5)c4)cc3)c3ccc4c5ccccc5n(-c5ccccc5)c4c3)cc2)cc1 ; c1ccc(-c2cccc(N(c3cccc(-c4ccc5c(c4)oc4ccccc45)c3)c3cc4c5c(cccc5c3)-c3ccccc3-4)c2)cc1]

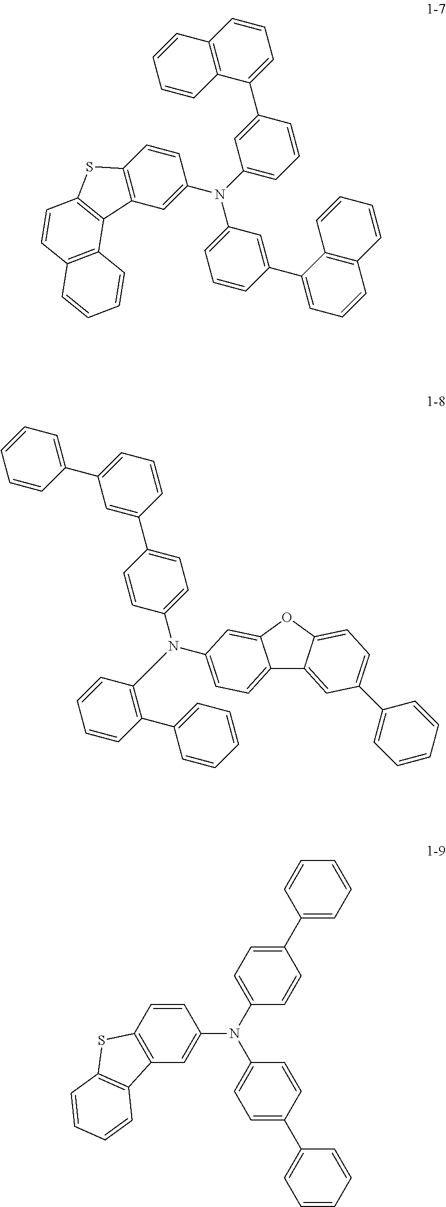 [SMILES: c1cc(-c2cccc3ccccc23)cc(N(c2cccc(-c3cccc4ccccc34)c2)c2ccc3sc4ccc5ccccc5c4c3c2)c1 ; c1ccc(-c2cccc(-c3ccc(N(c4ccc5c(c4)oc4ccc(-c6ccccc6)cc45)c4ccccc4-c4ccccc4)cc3)c2)cc1 ; c1ccc(-c2ccc(N(c3ccc(-c4ccccc4)cc3)c3ccc4sc5ccccc5c4c3)cc2)cc1]

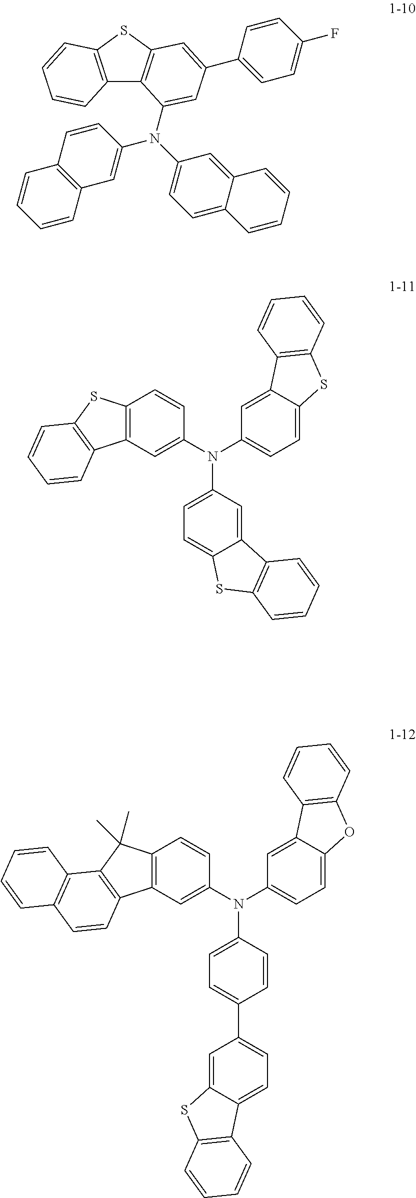 [SMILES: Fc1ccc(-c2cc(N(c3ccc4ccccc4c3)c3ccc4ccccc4c3)c3c(c2)sc2ccccc23)cc1 ; c1ccc2c(c1)sc1ccc(N(c3ccc4sc5ccccc5c4c3)c3ccc4sc5ccccc5c4c3)cc12 ; CC1(C)c2ccc(N(c3ccc(-c4ccc5c(c4)sc4ccccc45)cc3)c3ccc4oc5ccccc5c4c3)cc2-c2ccc3ccccc3c21]

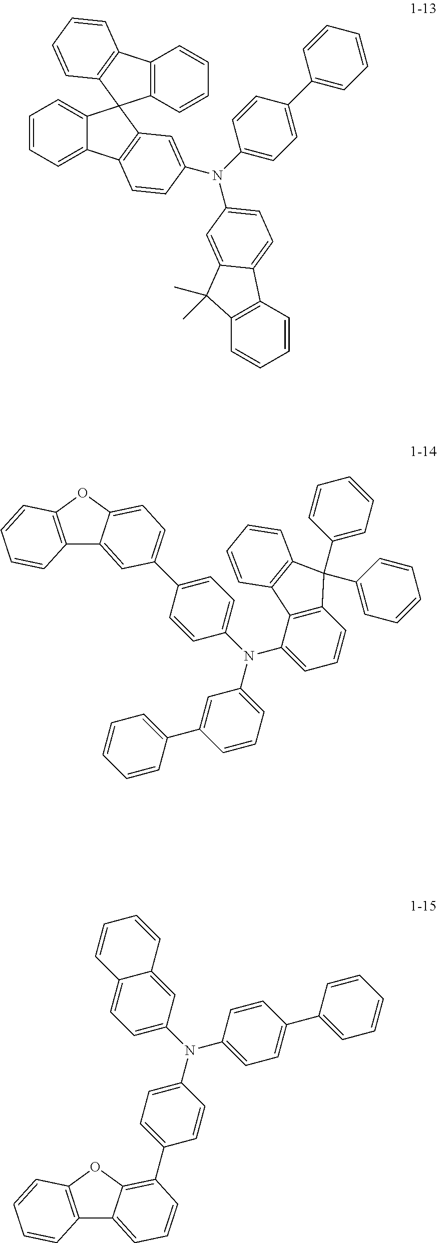 [SMILES: CC1(C)c2ccccc2-c2ccc(N(c3ccc(-c4ccccc4)cc3)c3ccc4c(c3)C3(c5ccccc5-c5ccccc53)c3ccccc3-4)cc21 ; c1ccc(-c2cccc(N(c3ccc(-c4ccc5oc6ccccc6c5c4)cc3)c3cccc4c3-c3ccccc3C4(c3ccccc3)c3ccccc3)c2)cc1 ; c1ccc(-c2ccc(N(c3ccc(-c4cccc5c4oc4ccccc45)cc3)c3ccc4ccccc4c3)cc2)cc1]

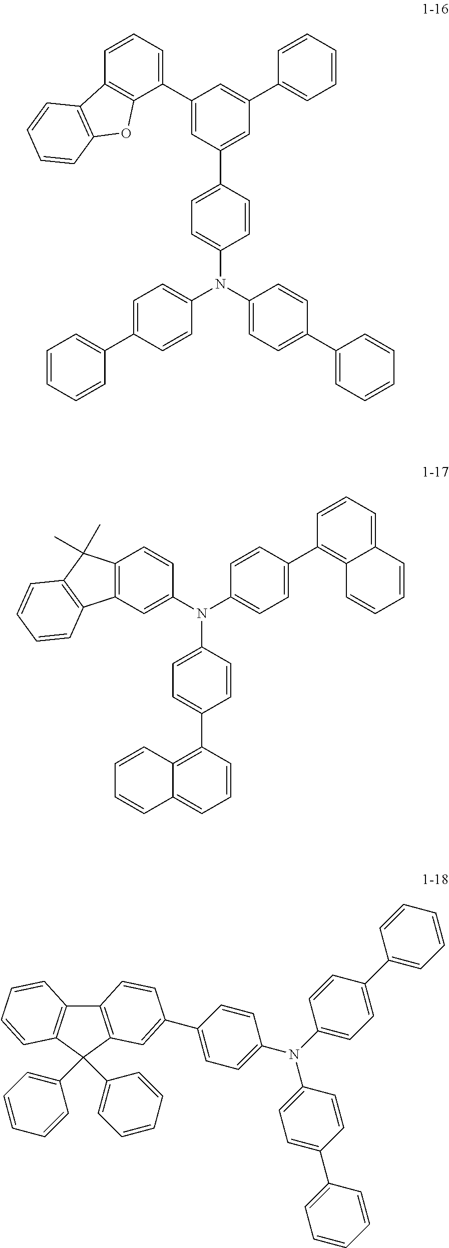 [SMILES: c1ccc(-c2ccc(N(c3ccc(-c4ccccc4)cc3)c3ccc(-c4cc(-c5ccccc5)cc(-c5cccc6c5oc5ccccc56)c4)cc3)cc2)cc1 ; CC1(C)c2ccccc2-c2cc(N(c3ccc(-c4cccc5ccccc45)cc3)c3ccc(-c4cccc5ccccc45)cc3)ccc21 ; c1ccc(-c2ccc(N(c3ccc(-c4ccccc4)cc3)c3ccc(-c4ccc5c(c4)C(c4ccccc4)(c4ccccc4)c4ccccc4-5)cc3)cc2)cc1]

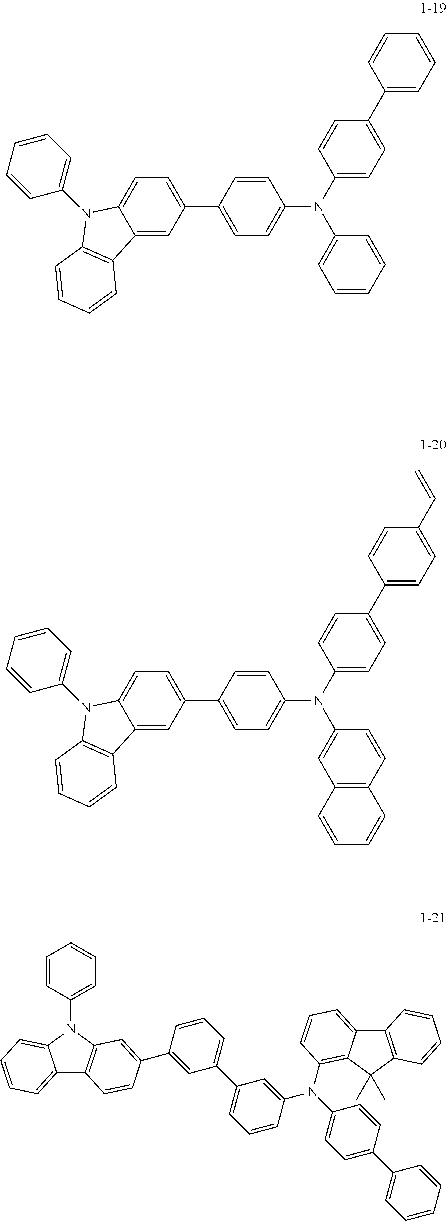 [SMILES: c1ccc(-c2ccc(N(c3ccccc3)c3ccc(-c4ccc5c(c4)c4ccccc4n5-c4ccccc4)cc3)cc2)cc1 ; C=Cc1ccc(-c2ccc(N(c3ccc(-c4ccc5c(c4)c4ccccc4n5-c4ccccc4)cc3)c3ccc4ccccc4c3)cc2)cc1 ; CC1(C)c2ccccc2-c2cccc(N(c3ccc(-c4ccccc4)cc3)c3cccc(-c4cccc(-c5ccc6c7ccccc7n(-c7ccccc7)c6c5)c4)c3)c21]

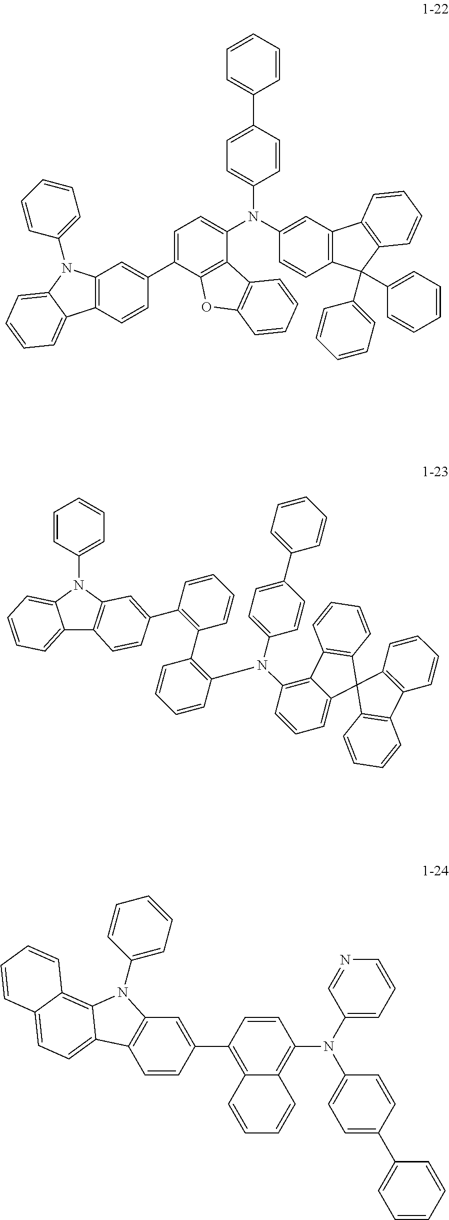 [SMILES: c1ccc(-c2ccc(N(c3ccc4c(c3)-c3ccccc3C4(c3ccccc3)c3ccccc3)c3ccc(-c4ccc5c6ccccc6n(-c6ccccc6)c5c4)c4oc5ccccc5c34)cc2)cc1 ; c1ccc(-c2ccc(N(c3ccccc3-c3ccccc3-c3ccc4c5ccccc5n(-c5ccccc5)c4c3)c3cccc4c3-c3ccccc3C43c4ccccc4-c4ccccc43)cc2)cc1 ; c1ccc(-c2ccc(N(c3cccnc3)c3ccc(-c4ccc5c6ccc7ccccc7c6n(-c6ccccc6)c5c4)c4ccccc34)cc2)cc1]

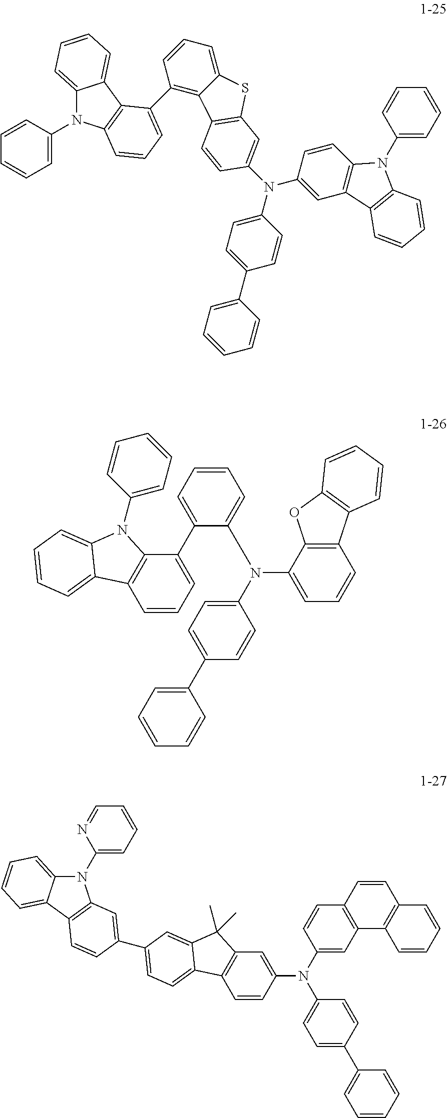 [SMILES: c1ccc(-c2ccc(N(c3ccc4c(c3)sc3cccc(-c5cccc6c5c5ccccc5n6-c5ccccc5)c34)c3ccc4c(c3)c3ccccc3n4-c3ccccc3)cc2)cc1 ; c1ccc(-c2ccc(N(c3ccccc3-c3cccc4c5ccccc5n(-c5ccccc5)c34)c3cccc4c3oc3ccccc34)cc2)cc1 ; CC1(C)c2cc(-c3ccc4c5ccccc5n(-c5ccccn5)c4c3)ccc2-c2ccc(N(c3ccc(-c4ccccc4)cc3)c3ccc4ccc5ccccc5c4c3)cc21]

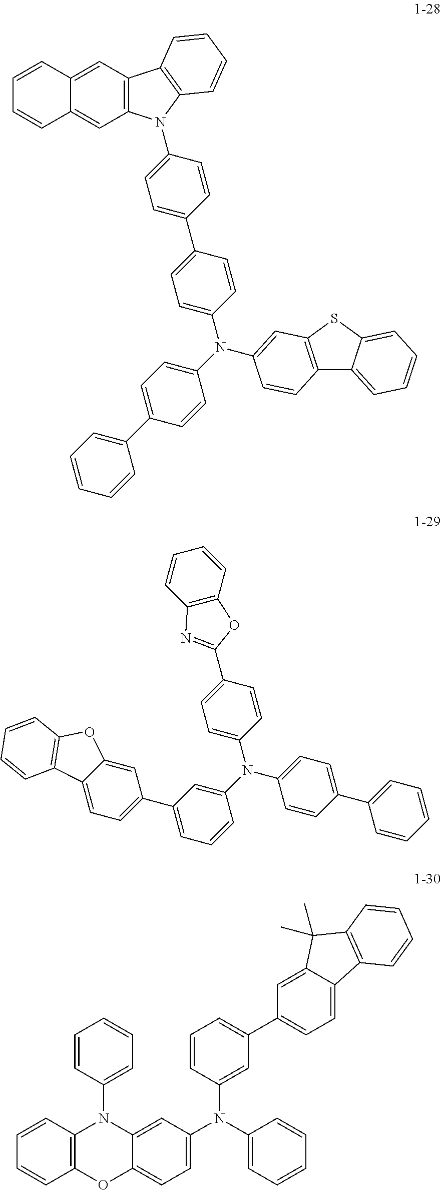 [SMILES: c1ccc(-c2ccc(N(c3ccc(-c4ccc(-n5c6ccccc6c6cc7ccccc7cc65)cc4)cc3)c3ccc4c(c3)sc3ccccc34)cc2)cc1 ; c1ccc(-c2ccc(N(c3ccc(-c4nc5ccccc5o4)cc3)c3cccc(-c4ccc5c(c4)oc4ccccc45)c3)cc2)cc1 ; CC1(C)c2ccccc2-c2ccc(-c3cccc(N(c4ccccc4)c4ccc5c(c4)N(c4ccccc4)c4ccccc4O5)c3)cc21]

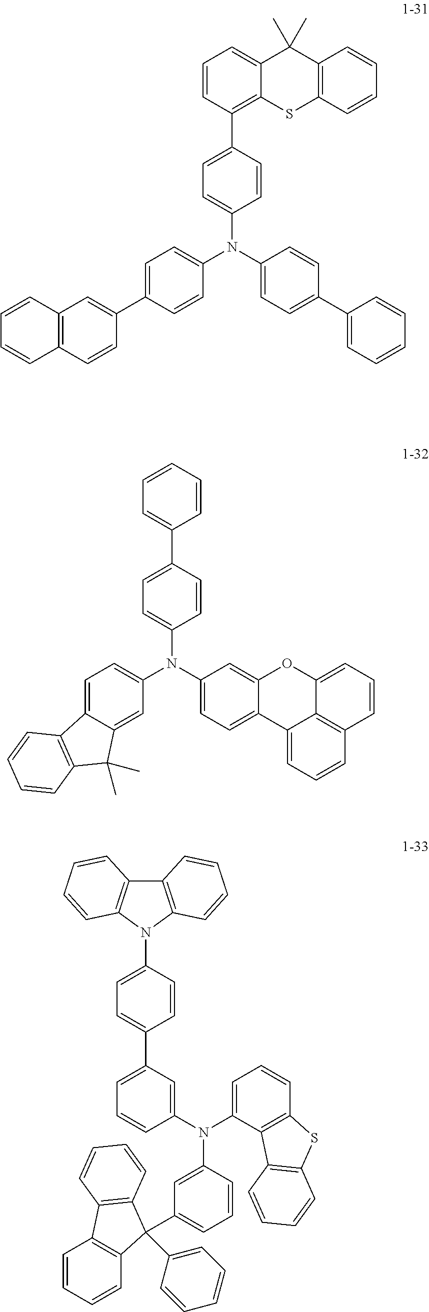 [SMILES: CC1(C)c2ccccc2Sc2c(-c3ccc(N(c4ccc(-c5ccccc5)cc4)c4ccc(-c5ccc6ccccc6c5)cc4)cc3)cccc21 ; CC1(C)c2ccccc2-c2ccc(N(c3ccc(-c4ccccc4)cc3)c3ccc4c(c3)Oc3cccc5cccc-4c35)cc21 ; c1ccc(C2(c3cccc(N(c4cccc(-c5ccc(-n6c7ccccc7c7ccccc76)cc5)c4)c4cccc5sc6ccccc6c45)c3)c3ccccc3-c3ccccc32)cc1]

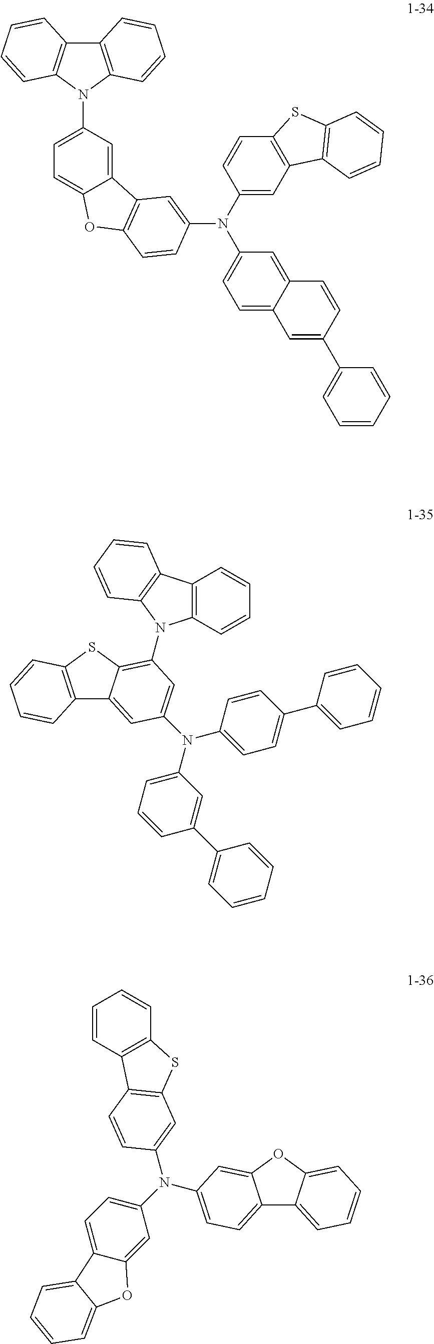 [SMILES: c1ccc(-c2ccc3cc(N(c4ccc5oc6ccc(-n7c8ccccc8c8ccccc87)cc6c5c4)c4ccc5sc6ccccc6c5c4)ccc3c2)cc1 ; c1ccc(-c2ccc(N(c3cccc(-c4ccccc4)c3)c3cc(-n4c5ccccc5c5ccccc54)c4sc5ccccc5c4c3)cc2)cc1 ; c1ccc2c(c1)oc1cc(N(c3ccc4c(c3)oc3ccccc34)c3ccc4c(c3)sc3ccccc34)ccc12]

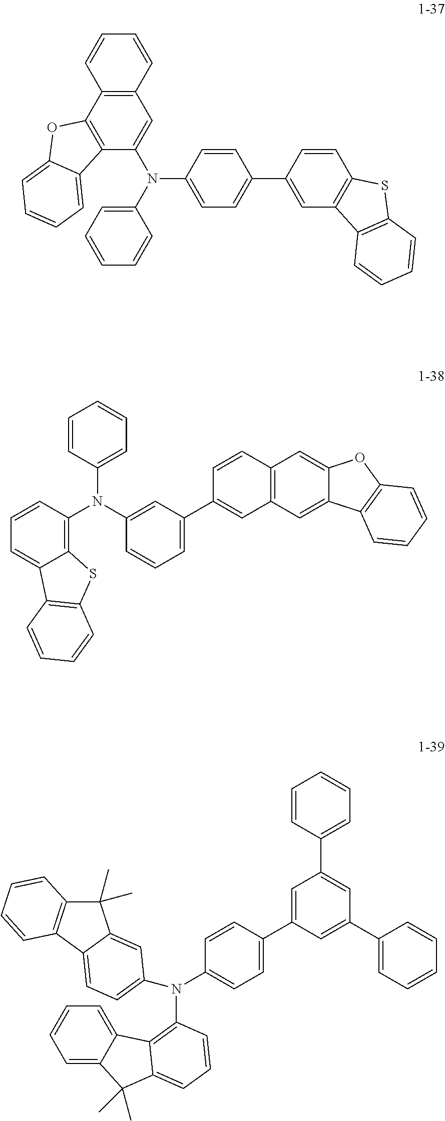 [SMILES: c1ccc(N(c2ccc(-c3ccc4sc5ccccc5c4c3)cc2)c2cc3ccccc3c3oc4ccccc4c23)cc1 ; c1ccc(N(c2cccc(-c3ccc4cc5oc6ccccc6c5cc4c3)c2)c2cccc3c2sc2ccccc23)cc1 ; CC1(C)c2ccccc2-c2ccc(N(c3ccc(-c4cc(-c5ccccc5)cc(-c5ccccc5)c4)cc3)c3cccc4c3-c3ccccc3C4(C)C)cc21]

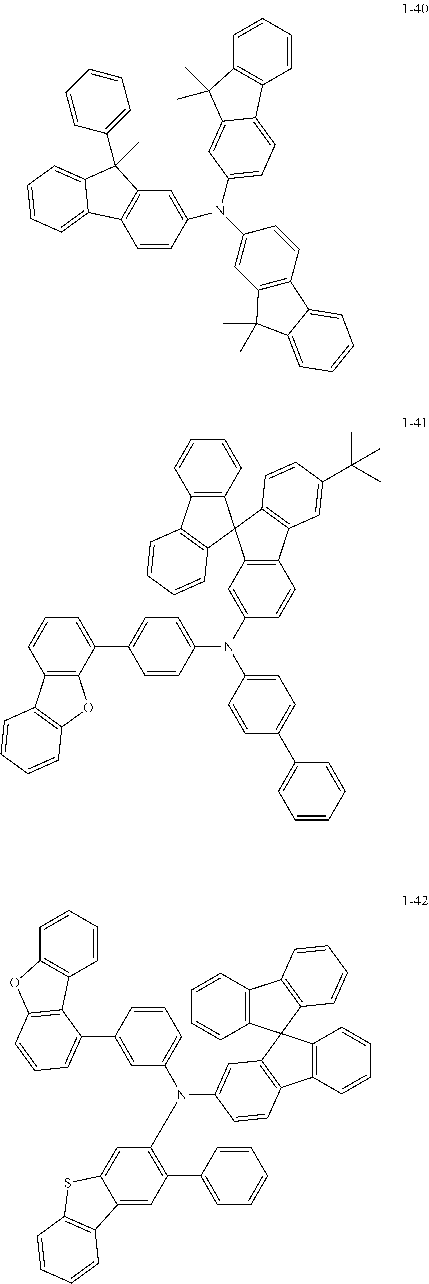 [SMILES: CC1(C)c2ccccc2-c2ccc(N(c3ccc4c(c3)C(C)(C)c3ccccc3-4)c3ccc4c(c3)C(C)(c3ccccc3)c3ccccc3-4)cc21 ; CC(C)(C)c1ccc2c(c1)-c1ccc(N(c3ccc(-c4ccccc4)cc3)c3ccc(-c4cccc5c4oc4ccccc45)cc3)cc1C21c2ccccc2-c2ccccc21 ; c1ccc(-c2cc3c(cc2N(c2cccc(-c4cccc5oc6ccccc6c45)c2)c2ccc4c(c2)C2(c5ccccc5-c5ccccc52)c2ccccc2-4)sc2ccccc23)cc1]

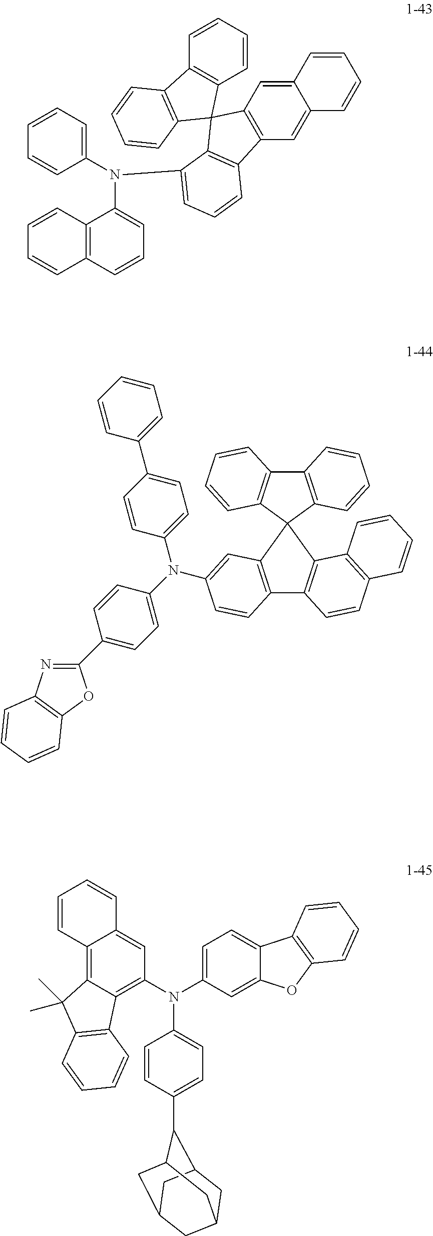 [SMILES: c1ccc(N(c2cccc3c2C2(c4ccccc4-c4ccccc42)c2cc4ccccc4cc2-3)c2cccc3ccccc23)cc1 ; c1ccc(-c2ccc(N(c3ccc(-c4nc5ccccc5o4)cc3)c3ccc4c(c3)C3(c5ccccc5-c5ccccc53)c3c-4ccc4ccccc34)cc2)cc1 ; CC1(C)c2ccccc2-c2c(N(c3ccc(C4C5CC6CC(C5)CC4C6)cc3)c3ccc4c(c3)oc3ccccc34)cc3ccccc3c21]

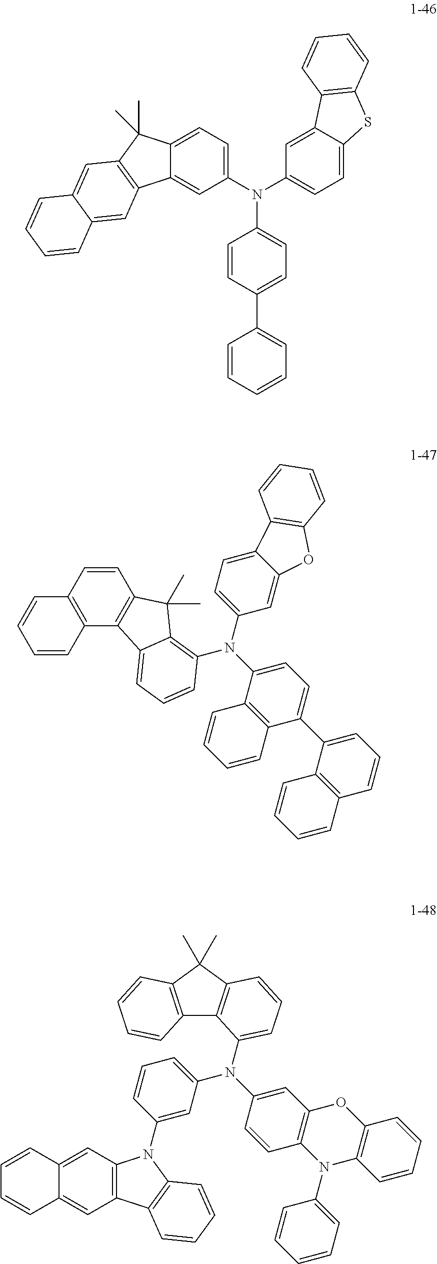 [SMILES: CC1(C)c2ccc(N(c3ccc(-c4ccccc4)cc3)c3ccc4sc5ccccc5c4c3)cc2-c2cc3ccccc3cc21 ; CC1(C)c2ccc3ccccc3c2-c2cccc(N(c3ccc4c(c3)oc3ccccc34)c3ccc(-c4cccc5ccccc45)c4ccccc34)c21 ; CC1(C)c2ccccc2-c2c(N(c3cccc(-n4c5ccccc5c5cc6ccccc6cc54)c3)c3ccc4c(c3)Oc3ccccc3N4c3ccccc3)cccc21]

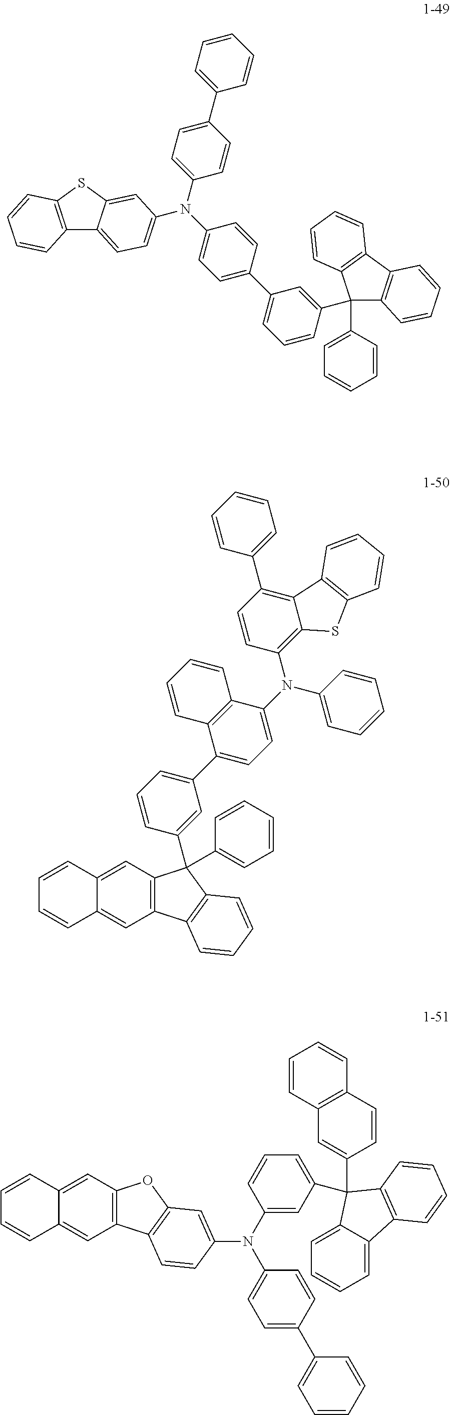 [SMILES: c1ccc(-c2ccc(N(c3ccc(-c4cccc(C5(c6ccccc6)c6ccccc6-c6ccccc65)c4)cc3)c3ccc4c(c3)sc3ccccc34)cc2)cc1 ; c1ccc(-c2ccc(N(c3ccccc3)c3ccc(-c4cccc(C5(c6ccccc6)c6ccccc6-c6cc7ccccc7cc65)c4)c4ccccc34)c3sc4ccccc4c23)cc1 ; c1ccc(-c2ccc(N(c3cccc(C4(c5ccc6ccccc6c5)c5ccccc5-c5ccccc54)c3)c3ccc4c(c3)oc3cc5ccccc5cc34)cc2)cc1]

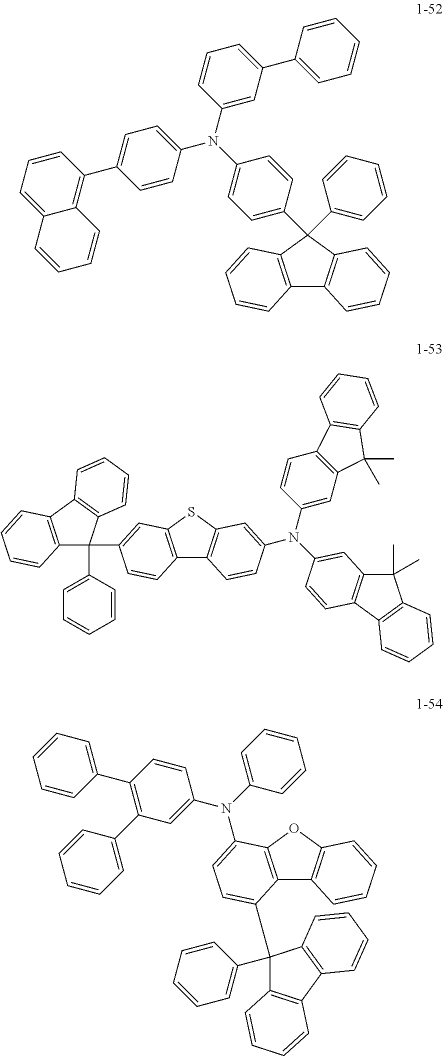 [SMILES: c1ccc(-c2cccc(N(c3ccc(-c4cccc5ccccc45)cc3)c3ccc(C4(c5ccccc5)c5ccccc5-c5ccccc54)cc3)c2)cc1 ; CC1(C)c2ccccc2-c2ccc(N(c3ccc4c(c3)C(C)(C)c3ccccc3-4)c3ccc4c(c3)sc3cc(C5(c6ccccc6)c6ccccc6-c6ccccc65)ccc34)cc21 ; c1ccc(-c2ccc(N(c3ccccc3)c3ccc(C4(c5ccccc5)c5ccccc5-c5ccccc54)c4c3oc3ccccc34)cc2-c2ccccc2)cc1]

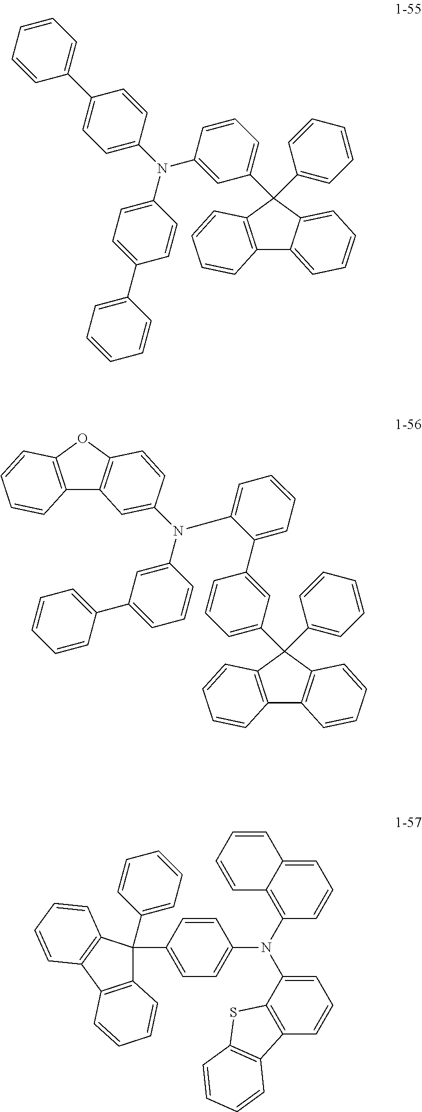 [SMILES: c1ccc(-c2ccc(N(c3ccc(-c4ccccc4)cc3)c3cccc(C4(c5ccccc5)c5ccccc5-c5ccccc54)c3)cc2)cc1 ; c1ccc(-c2cccc(N(c3ccc4oc5ccccc5c4c3)c3ccccc3-c3cccc(C4(c5ccccc5)c5ccccc5-c5ccccc54)c3)c2)cc1 ; c1ccc(C2(c3ccc(N(c4cccc5ccccc45)c4cccc5c4sc4ccccc45)cc3)c3ccccc3-c3ccccc32)cc1]

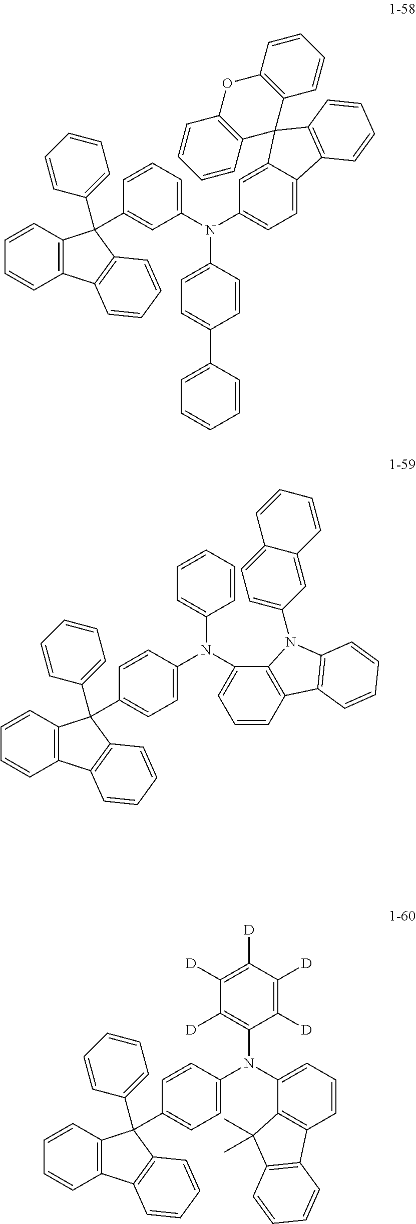 [SMILES: c1ccc(-c2ccc(N(c3cccc(C4(c5ccccc5)c5ccccc5-c5ccccc54)c3)c3ccc4c(c3)C3(c5ccccc5Oc5ccccc53)c3ccccc3-4)cc2)cc1 ; c1ccc(N(c2ccc(C3(c4ccccc4)c4ccccc4-c4ccccc43)cc2)c2cccc3c4ccccc4n(-c4ccc5ccccc5c4)c23)cc1 ; [2H]c1c([2H])c([2H])c(N(c2ccc(C3(c4ccccc4)c4ccccc4-c4ccccc43)cc2)c2cccc3c2C(C)(C)c2ccccc2-3)c([2H])c1[2H]]

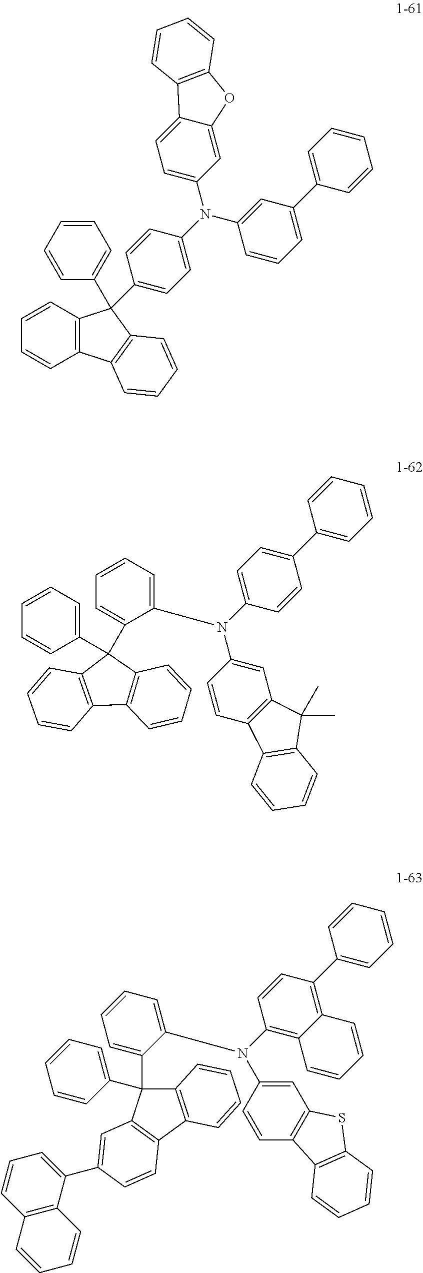 [SMILES: c1ccc(-c2cccc(N(c3ccc(C4(c5ccccc5)c5ccccc5-c5ccccc54)cc3)c3ccc4c(c3)oc3ccccc34)c2)cc1 ; CC1(C)c2ccccc2-c2ccc(N(c3ccc(-c4ccccc4)cc3)c3ccccc3C3(c4ccccc4)c4ccccc4-c4ccccc43)cc21 ; c1ccc(-c2ccc(N(c3ccc4c(c3)sc3ccccc34)c3ccccc3C3(c4ccccc4)c4ccccc4-c4ccc(-c5cccc6ccccc56)cc43)c3ccccc23)cc1]

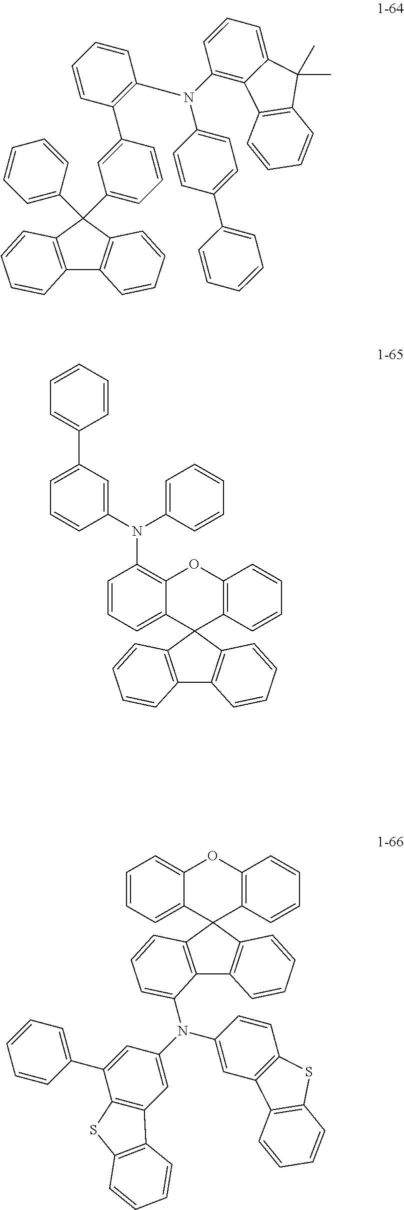 [SMILES: CC1(C)c2ccccc2-c2c(N(c3ccc(-c4ccccc4)cc3)c3ccccc3-c3cccc(C4(c5ccccc5)c5ccccc5-c5ccccc54)c3)cccc21 ; c1ccc(-c2cccc(N(c3ccccc3)c3cccc4c3Oc3ccccc3C43c4ccccc4-c4ccccc43)c2)cc1 ; c1ccc(-c2cc(N(c3ccc4sc5ccccc5c4c3)c3cccc4c3-c3ccccc3C43c4ccccc4Oc4ccccc43)cc3c2sc2ccccc23)cc1]

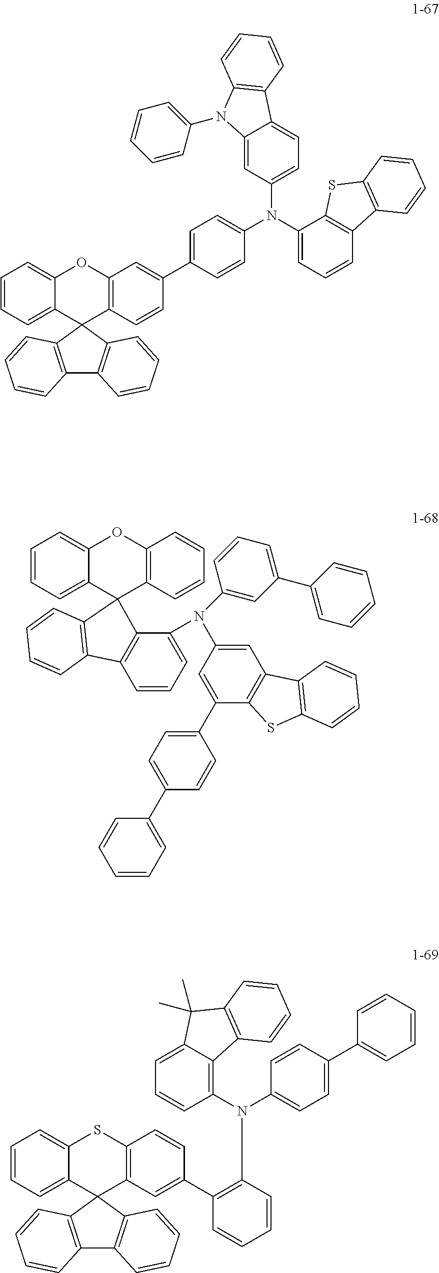 [SMILES: c1ccc(-n2c3ccccc3c3ccc(N(c4ccc(-c5ccc6c(c5)Oc5ccccc5C65c6ccccc6-c6ccccc65)cc4)c4cccc5c4sc4ccccc45)cc32)cc1 ; c1ccc(-c2ccc(-c3cc(N(c4cccc(-c5ccccc5)c4)c4cccc5c4C4(c6ccccc6Oc6ccccc64)c4ccccc4-5)cc4c3sc3ccccc34)cc2)cc1 ; CC1(C)c2ccccc2-c2c(N(c3ccc(-c4ccccc4)cc3)c3ccccc3-c3ccc4c(c3)C3(c5ccccc5S4)c4ccccc4-c4ccccc43)cccc21]

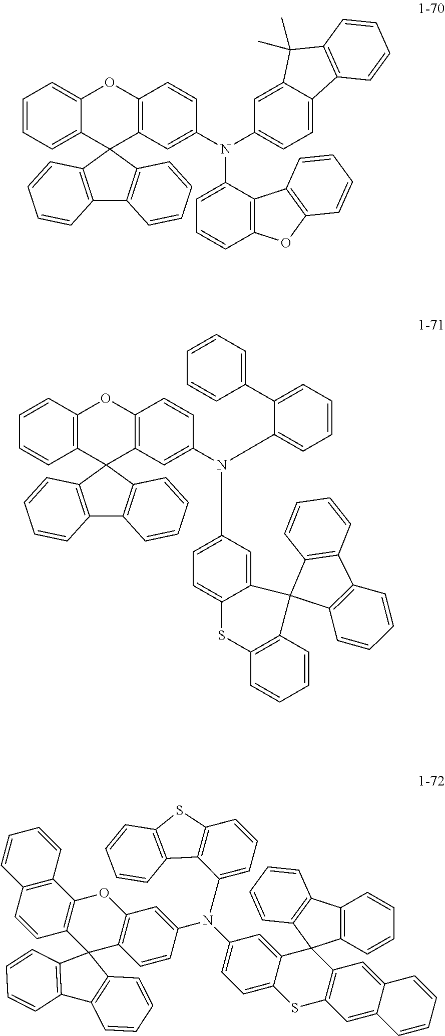 [SMILES: CC1(C)c2ccccc2-c2ccc(N(c3ccc4c(c3)C3(c5ccccc5O4)c4ccccc4-c4ccccc43)c3cccc4oc5ccccc5c34)cc21 ; c1ccc(-c2ccccc2N(c2ccc3c(c2)C2(c4ccccc4O3)c3ccccc3-c3ccccc32)c2ccc3c(c2)C2(c4ccccc4S3)c3ccccc3-c3ccccc32)cc1 ; c1ccc2c(c1)-c1ccccc1C21c2cc(N(c3ccc4c(c3)Oc3c(ccc5ccccc35)C43c4ccccc4-c4ccccc43)c3cccc4sc5ccccc5c34)ccc2Sc2cc3ccccc3cc21]

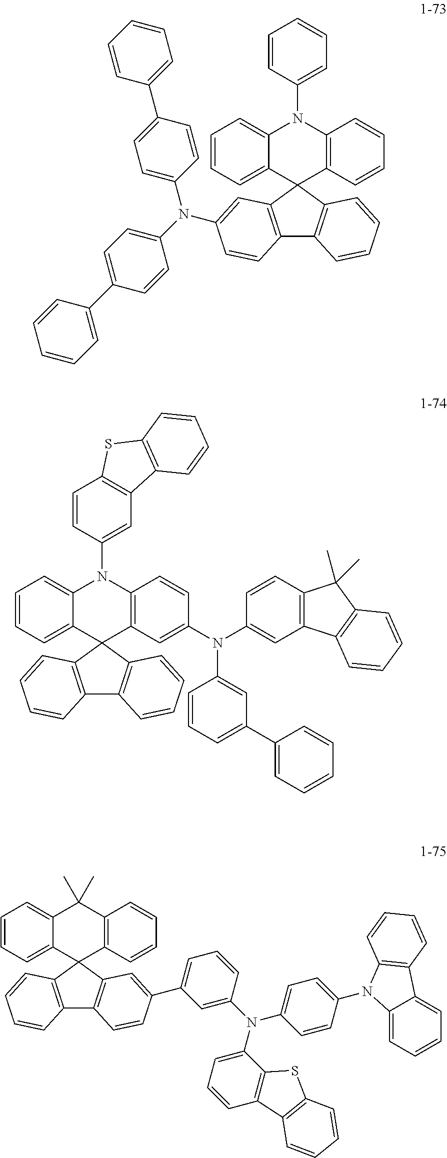 [SMILES: c1ccc(-c2ccc(N(c3ccc(-c4ccccc4)cc3)c3ccc4c(c3)C3(c5ccccc5-4)c4ccccc4N(c4ccccc4)c4ccccc43)cc2)cc1 ; CC1(C)c2ccccc2-c2cc(N(c3cccc(-c4ccccc4)c3)c3ccc4c(c3)C3(c5ccccc5-c5ccccc53)c3ccccc3N4c3ccc4sc5ccccc5c4c3)ccc21 ; CC1(C)c2ccccc2C2(c3ccccc3-c3ccc(-c4cccc(N(c5ccc(-n6c7ccccc7c7ccccc76)cc5)c5cccc6c5sc5ccccc56)c4)cc32)c2ccccc21]

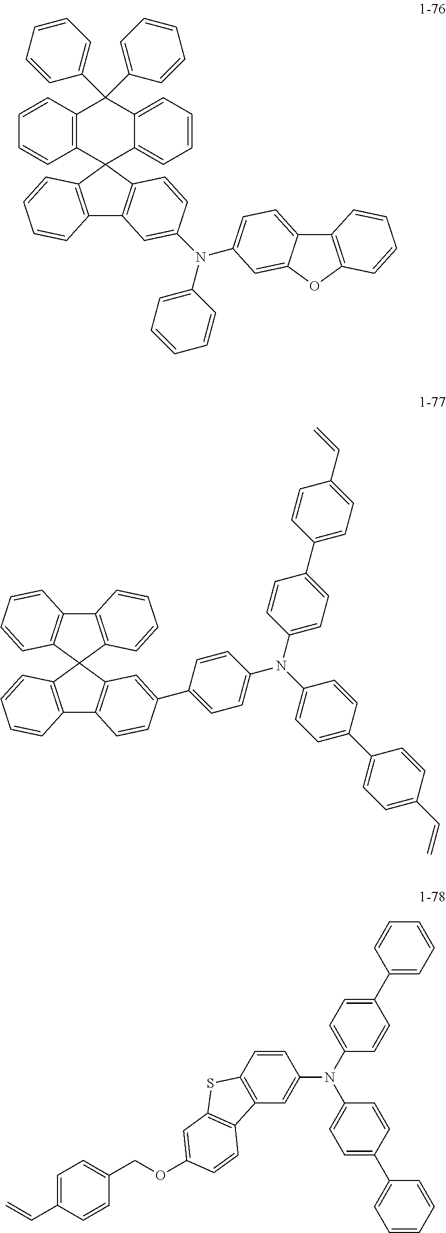 [SMILES: c1ccc(N(c2ccc3c(c2)-c2ccccc2C32c3ccccc3C(c3ccccc3)(c3ccccc3)c3ccccc32)c2ccc3c(c2)oc2ccccc23)cc1 ; C=Cc1ccc(-c2ccc(N(c3ccc(-c4ccc(C=C)cc4)cc3)c3ccc(-c4ccc5c(c4)C4(c6ccccc6-c6ccccc64)c4ccccc4-5)cc3)cc2)cc1 ; C=Cc1ccc(COc2ccc3c(c2)sc2ccc(N(c4ccc(-c5ccccc5)cc4)c4ccc(-c5ccccc5)cc4)cc23)cc1]

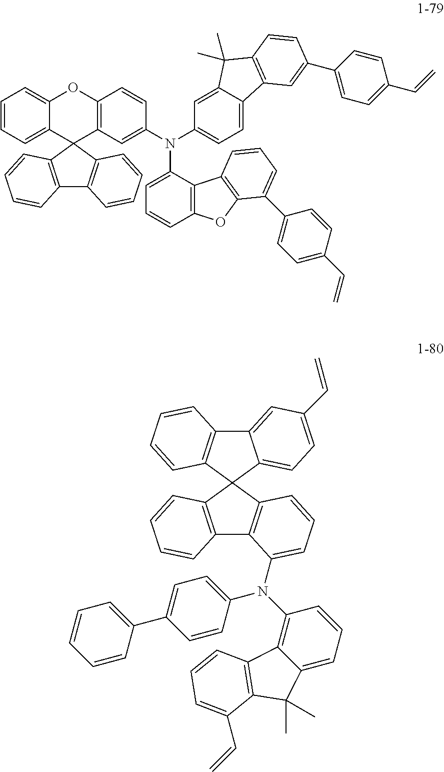 [SMILES: C=Cc1ccc(-c2ccc3c(c2)-c2ccc(N(c4ccc5c(c4)C4(c6ccccc6O5)c5ccccc5-c5ccccc54)c4cccc5oc6c(-c7ccc(C=C)cc7)cccc6c45)cc2C3(C)C)cc1 ; C=Cc1ccc2c(c1)-c1ccccc1C21c2ccccc2-c2c(N(c3ccc(-c4ccccc4)cc3)c3cccc4c3-c3cccc(C=C)c3C4(C)C)cccc21]

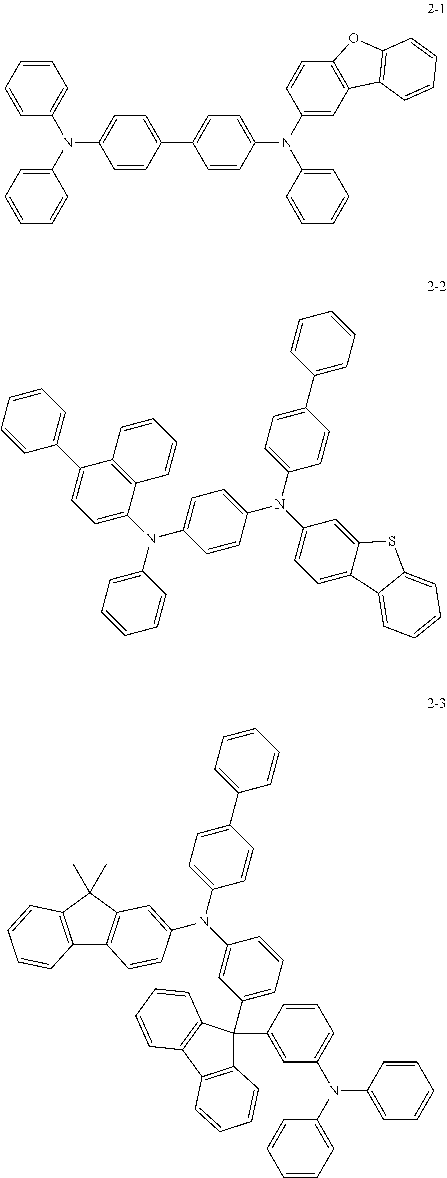 [SMILES: c1ccc(N(c2ccccc2)c2ccc(-c3ccc(N(c4ccccc4)c4ccc5oc6ccccc6c5c4)cc3)cc2)cc1 ; c1ccc(-c2ccc(N(c3ccc(N(c4ccccc4)c4ccc(-c5ccccc5)c5ccccc45)cc3)c3ccc4c(c3)sc3ccccc34)cc2)cc1 ; CC1(C)c2ccccc2-c2ccc(N(c3ccc(-c4ccccc4)cc3)c3cccc(C4(c5cccc(N(c6ccccc6)c6ccccc6)c5)c5ccccc5-c5ccccc54)c3)cc21]

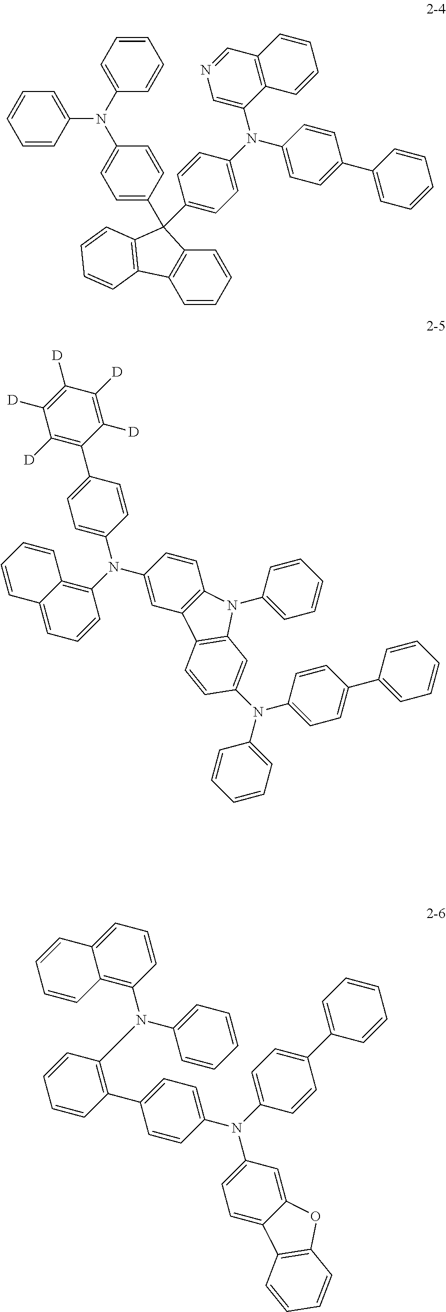 [SMILES: c1ccc(-c2ccc(N(c3ccc(C4(c5ccc(N(c6ccccc6)c6ccccc6)cc5)c5ccccc5-c5ccccc54)cc3)c3cncc4ccccc34)cc2)cc1 ; [2H]c1c([2H])c([2H])c(-c2ccc(N(c3ccc4c(c3)c3ccc(N(c5ccccc5)c5ccc(-c6ccccc6)cc5)cc3n4-c3ccccc3)c3cccc4ccccc34)cc2)c([2H])c1[2H] ; c1ccc(-c2ccc(N(c3ccc(-c4ccccc4N(c4ccccc4)c4cccc5ccccc45)cc3)c3ccc4c(c3)oc3ccccc34)cc2)cc1]

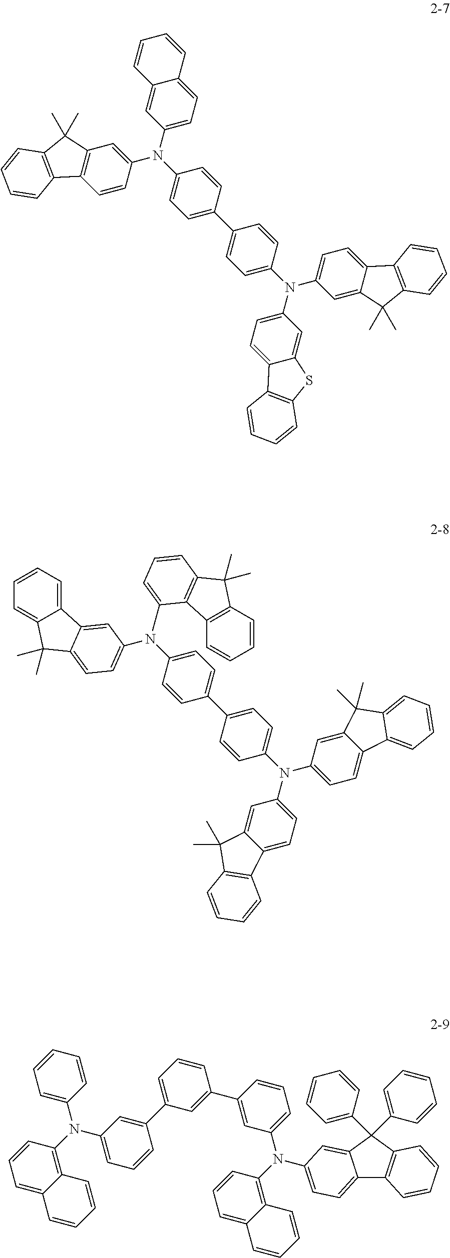 [SMILES: CC1(C)c2ccccc2-c2ccc(N(c3ccc(-c4ccc(N(c5ccc6c(c5)C(C)(C)c5ccccc5-6)c5ccc6c(c5)sc5ccccc56)cc4)cc3)c3ccc4ccccc4c3)cc21 ; CC1(C)c2ccccc2-c2cc(N(c3ccc(-c4ccc(N(c5ccc6c(c5)C(C)(C)c5ccccc5-6)c5ccc6c(c5)C(C)(C)c5ccccc5-6)cc4)cc3)c3cccc4c3-c3ccccc3C4(C)C)ccc21 ; c1ccc(N(c2cccc(-c3cccc(-c4cccc(N(c5ccc6c(c5)C(c5ccccc5)(c5ccccc5)c5ccccc5-6)c5cccc6ccccc56)c4)c3)c2)c2cccc3ccccc23)cc1]

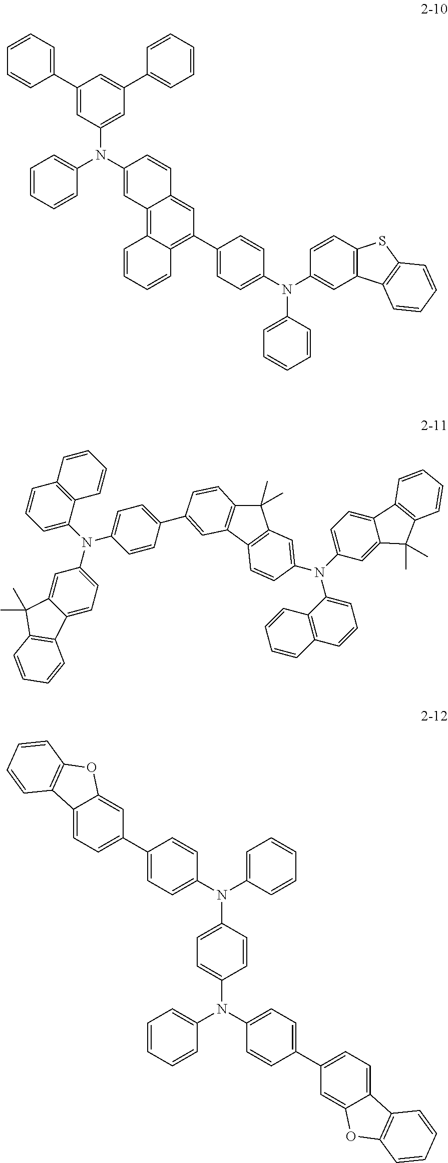 [SMILES: c1ccc(-c2cc(-c3ccccc3)cc(N(c3ccccc3)c3ccc4cc(-c5ccc(N(c6ccccc6)c6ccc7sc8ccccc8c7c6)cc5)c5ccccc5c4c3)c2)cc1 ; CC1(C)c2ccccc2-c2ccc(N(c3ccc(-c4ccc5c(c4)-c4ccc(N(c6ccc7c(c6)C(C)(C)c6ccccc6-7)c6cccc7ccccc67)cc4C5(C)C)cc3)c3cccc4ccccc34)cc21 ; c1ccc(N(c2ccc(-c3ccc4c(c3)oc3ccccc34)cc2)c2ccc(N(c3ccccc3)c3ccc(-c4ccc5c(c4)oc4ccccc45)cc3)cc2)cc1]

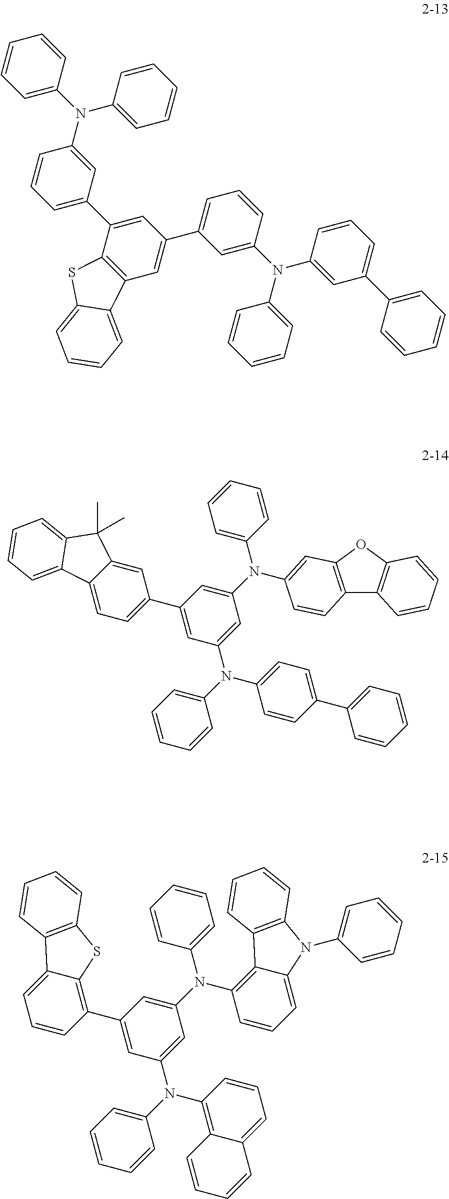 [SMILES: c1ccc(-c2cccc(N(c3ccccc3)c3cccc(-c4cc(-c5cccc(N(c6ccccc6)c6ccccc6)c5)c5sc6ccccc6c5c4)c3)c2)cc1 ; CC1(C)c2ccccc2-c2ccc(-c3cc(N(c4ccccc4)c4ccc(-c5ccccc5)cc4)cc(N(c4ccccc4)c4ccc5c(c4)oc4ccccc45)c3)cc21 ; c1ccc(N(c2cc(-c3cccc4c3sc3ccccc34)cc(N(c3ccccc3)c3cccc4c3c3ccccc3n4-c3ccccc3)c2)c2cccc3ccccc23)cc1]

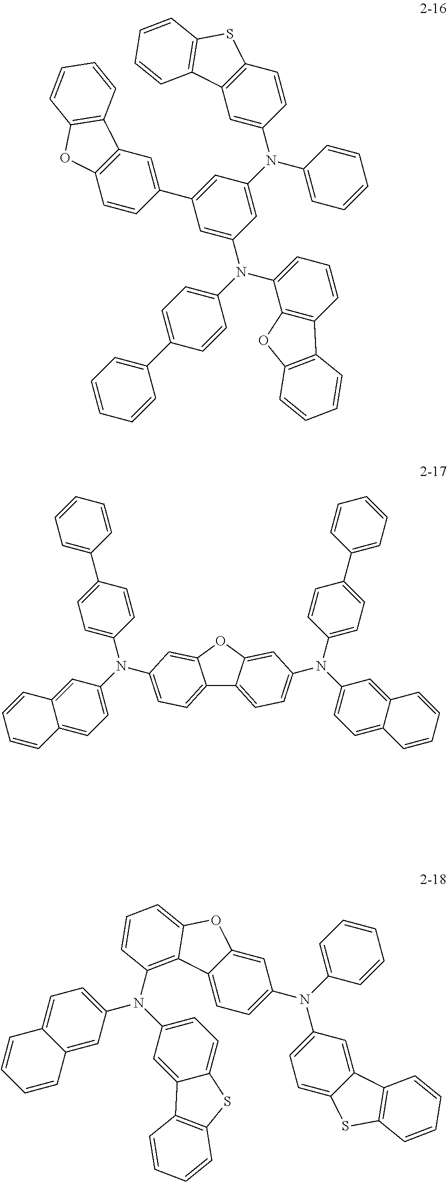 [SMILES: c1ccc(-c2ccc(N(c3cc(-c4ccc5oc6ccccc6c5c4)cc(N(c4ccccc4)c4ccc5sc6ccccc6c5c4)c3)c3cccc4c3oc3ccccc34)cc2)cc1 ; c1ccc(-c2ccc(N(c3ccc4ccccc4c3)c3ccc4c(c3)oc3cc(N(c5ccc(-c6ccccc6)cc5)c5ccc6ccccc6c5)ccc34)cc2)cc1 ; c1ccc(N(c2ccc3c(c2)oc2cccc(N(c4ccc5ccccc5c4)c4ccc5sc6ccccc6c5c4)c23)c2ccc3sc4ccccc4c3c2)cc1]

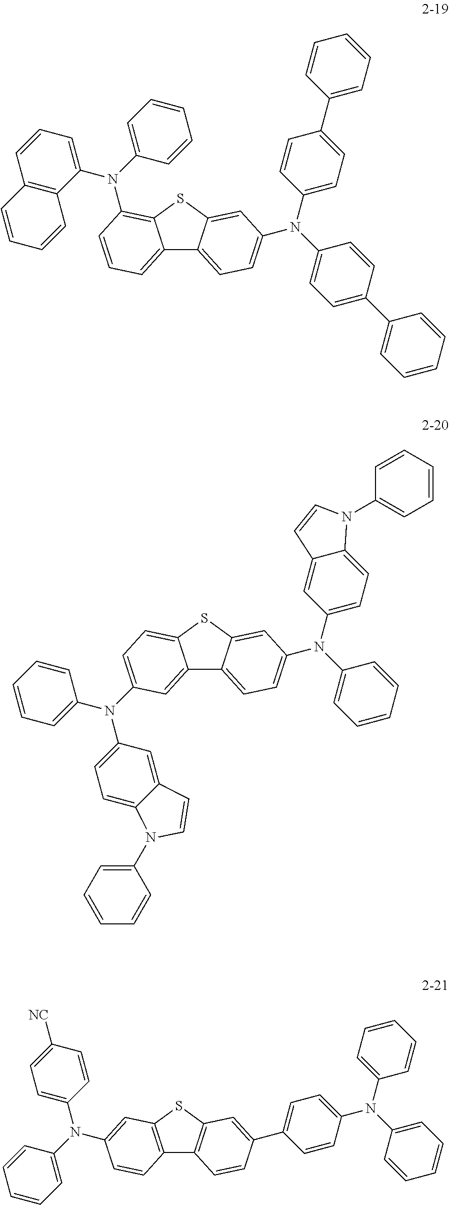 [SMILES: c1ccc(-c2ccc(N(c3ccc(-c4ccccc4)cc3)c3ccc4c(c3)sc3c(N(c5ccccc5)c5cccc6ccccc56)cccc34)cc2)cc1 ; c1ccc(N(c2ccc3c(ccn3-c3ccccc3)c2)c2ccc3c(c2)sc2ccc(N(c4ccccc4)c4ccc5c(ccn5-c5ccccc5)c4)cc23)cc1 ; N#Cc1ccc(N(c2ccccc2)c2ccc3c(c2)sc2cc(-c4ccc(N(c5ccccc5)c5ccccc5)cc4)ccc23)cc1]

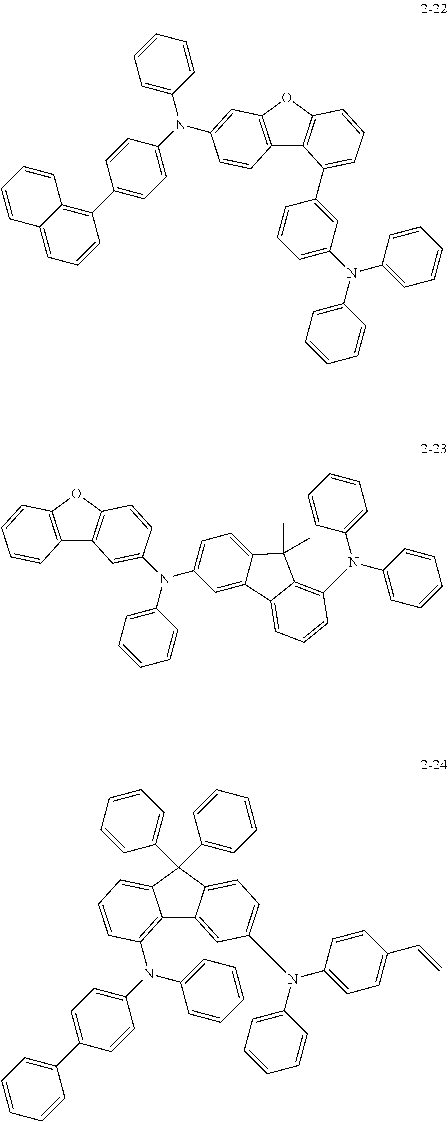 [SMILES: c1ccc(N(c2ccccc2)c2cccc(-c3cccc4oc5cc(N(c6ccccc6)c6ccc(-c7cccc8ccccc78)cc6)ccc5c34)c2)cc1 ; CC1(C)c2ccc(N(c3ccccc3)c3ccc4oc5ccccc5c4c3)cc2-c2cccc(N(c3ccccc3)c3ccccc3)c21 ; C=Cc1ccc(N(c2ccccc2)c2ccc3c(c2)-c2c(N(c4ccccc4)c4ccc(-c5ccccc5)cc4)cccc2C3(c2ccccc2)c2ccccc2)cc1]

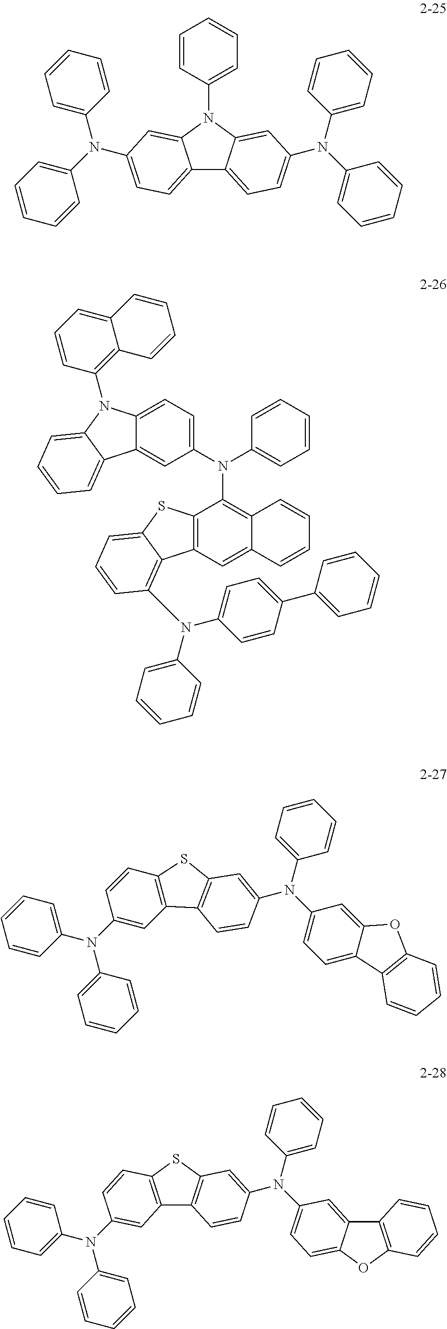 [SMILES: c1ccc(N(c2ccccc2)c2ccc3c4ccc(N(c5ccccc5)c5ccccc5)cc4n(-c4ccccc4)c3c2)cc1 ; c1ccc(-c2ccc(N(c3ccccc3)c3cccc4sc5c(N(c6ccccc6)c6ccc7c(c6)c6ccccc6n7-c6cccc7ccccc67)c6ccccc6cc5c34)cc2)cc1 ; c1ccc(N(c2ccc3c(c2)oc2ccccc23)c2ccc3c(c2)sc2ccc(N(c4ccccc4)c4ccccc4)cc23)cc1 ; c1ccc(N(c2ccc3c(c2)sc2ccc(N(c4ccccc4)c4ccccc4)cc23)c2ccc3oc4ccccc4c3c2)cc1]

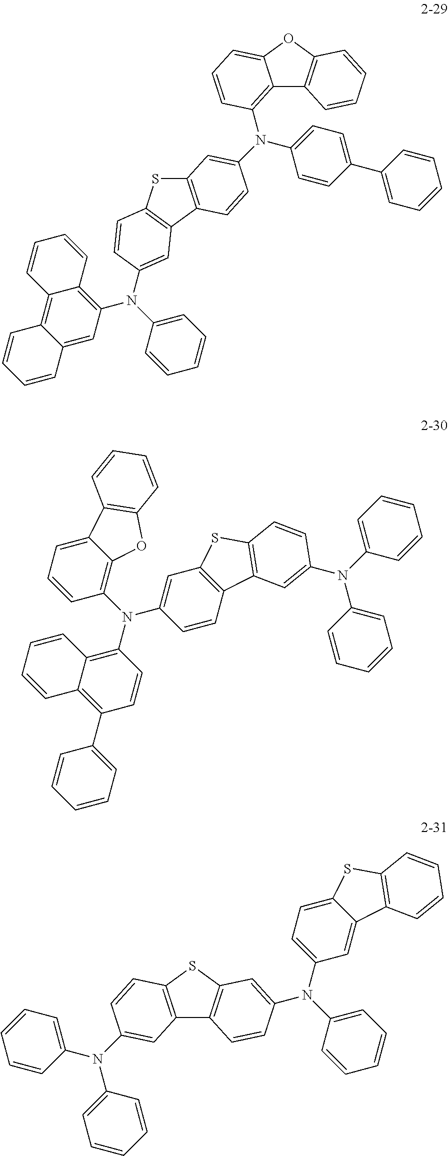 [SMILES: c1ccc(-c2ccc(N(c3ccc4c(c3)sc3ccc(N(c5ccccc5)c5cc6ccccc6c6ccccc56)cc34)c3cccc4oc5ccccc5c34)cc2)cc1 ; c1ccc(-c2ccc(N(c3ccc4c(c3)sc3ccc(N(c5ccccc5)c5ccccc5)cc34)c3cccc4c3oc3ccccc34)c3ccccc23)cc1 ; c1ccc(N(c2ccc3c(c2)sc2ccc(N(c4ccccc4)c4ccccc4)cc23)c2ccc3sc4ccccc4c3c2)cc1]

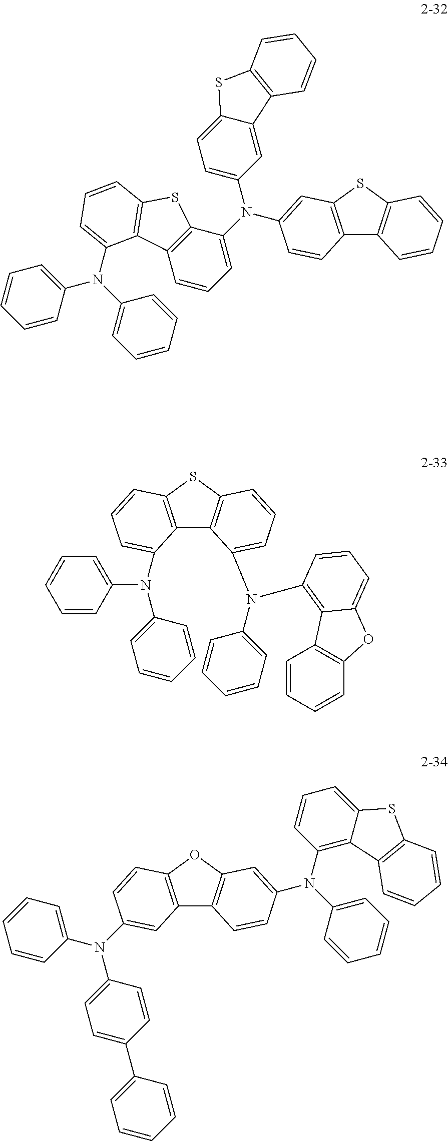 [SMILES: c1ccc(N(c2ccccc2)c2cccc3sc4c(N(c5ccc6c(c5)sc5ccccc56)c5ccc6sc7ccccc7c6c5)cccc4c23)cc1 ; c1ccc(N(c2ccccc2)c2cccc3sc4cccc(N(c5ccccc5)c5cccc6oc7ccccc7c56)c4c23)cc1 ; c1ccc(-c2ccc(N(c3ccccc3)c3ccc4oc5cc(N(c6ccccc6)c6cccc7sc8ccccc8c67)ccc5c4c3)cc2)cc1]

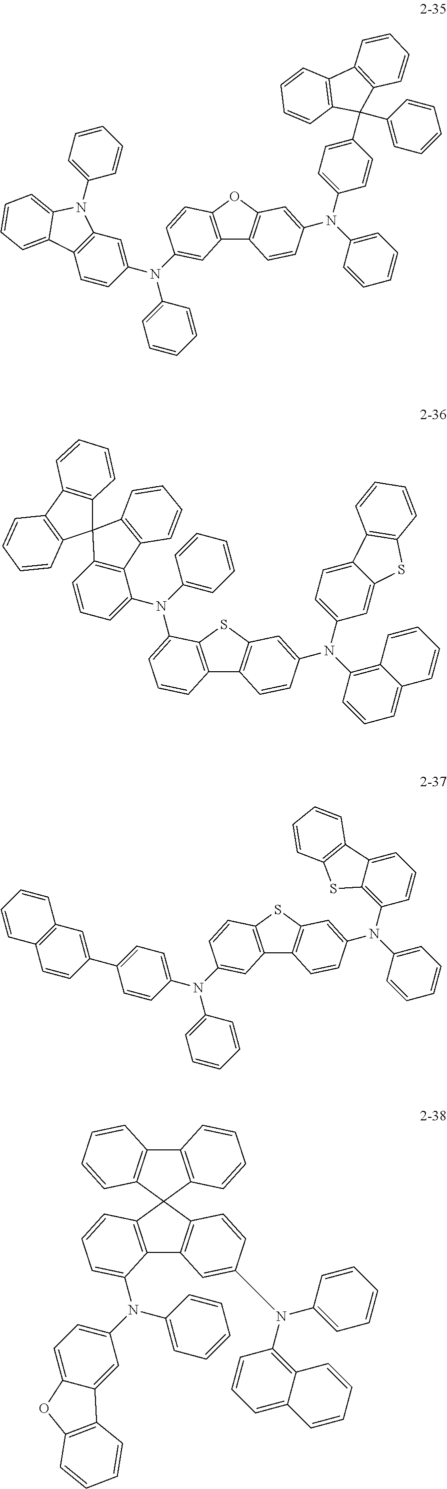 [SMILES: c1ccc(N(c2ccc(C3(c4ccccc4)c4ccccc4-c4ccccc43)cc2)c2ccc3c(c2)oc2ccc(N(c4ccccc4)c4ccc5c6ccccc6n(-c6ccccc6)c5c4)cc23)cc1 ; c1ccc(N(c2cccc3c2-c2ccccc2C32c3ccccc3-c3ccccc32)c2cccc3c2sc2cc(N(c4ccc5c(c4)sc4ccccc45)c4cccc5ccccc45)ccc23)cc1 ; c1ccc(N(c2ccc(-c3ccc4ccccc4c3)cc2)c2ccc3sc4cc(N(c5ccccc5)c5cccc6c5sc5ccccc56)ccc4c3c2)cc1 ; c1ccc(N(c2ccc3oc4ccccc4c3c2)c2cccc3c2-c2cc(N(c4ccccc4)c4cccc5ccccc45)ccc2C32c3ccccc3-c3ccccc32)cc1]

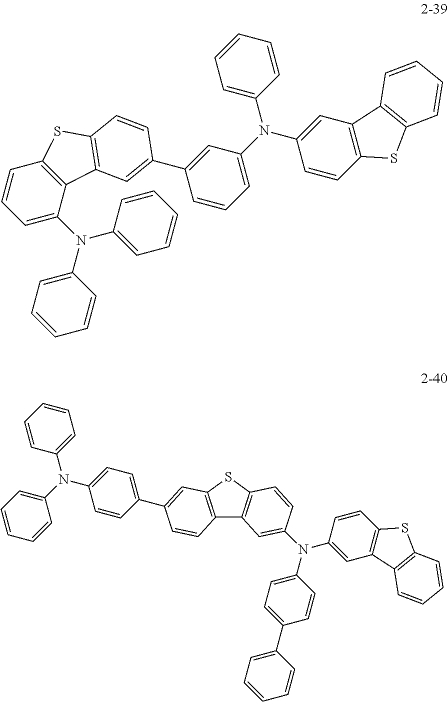 [SMILES: c1ccc(N(c2cccc(-c3ccc4sc5cccc(N(c6ccccc6)c6ccccc6)c5c4c3)c2)c2ccc3sc4ccccc4c3c2)cc1 ; c1ccc(-c2ccc(N(c3ccc4sc5ccccc5c4c3)c3ccc4sc5cc(-c6ccc(N(c7ccccc7)c7ccccc7)cc6)ccc5c4c3)cc2)cc1]

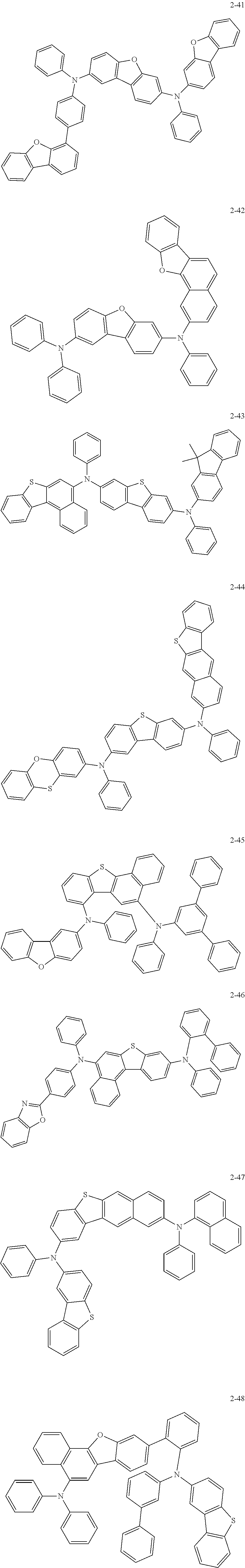

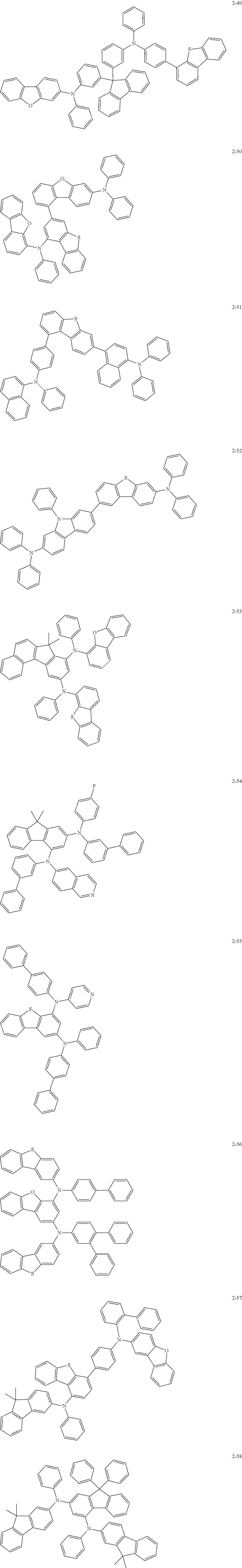

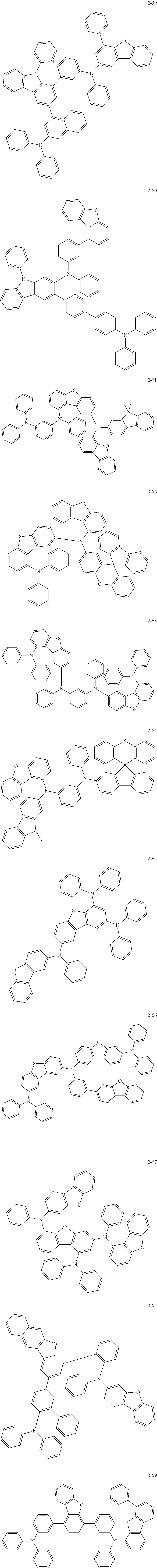

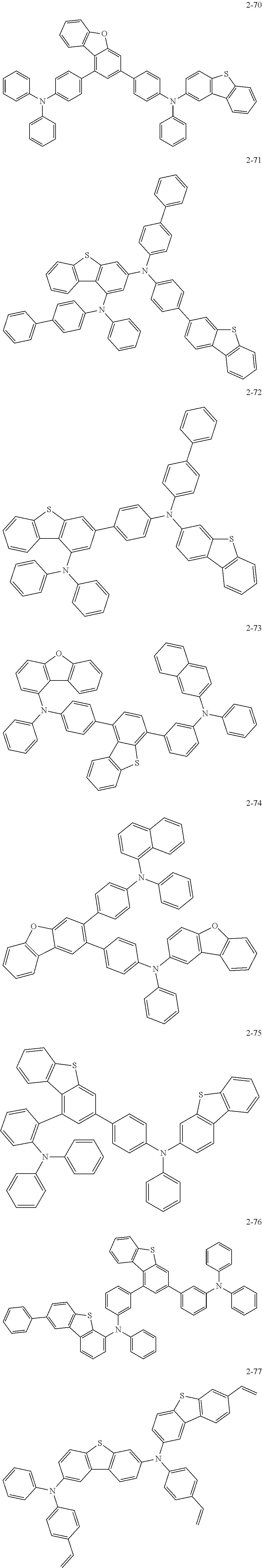

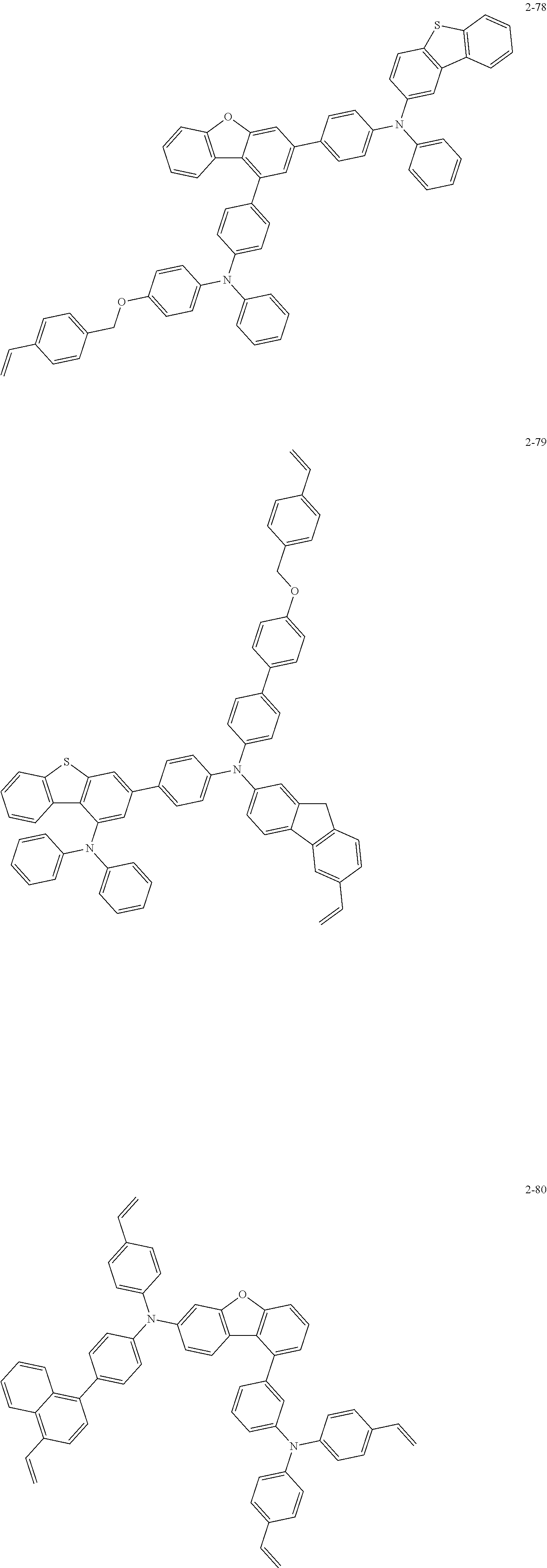 [SMILES: C=Cc1ccc(COc2ccc(N(c3ccccc3)c3ccc(-c4cc(-c5ccc(N(c6ccccc6)c6ccc7sc8ccccc8c7c6)cc5)cc5oc6ccccc6c45)cc3)cc2)cc1 ; C=Cc1ccc(COc2ccc(-c3ccc(N(c4ccc(-c5cc(N(c6ccccc6)c6ccccc6)c6c(c5)sc5ccccc56)cc4)c4ccc5c(c4)Cc4ccc(C=C)cc4-5)cc3)cc2)cc1 ; C=Cc1ccc(N(c2ccc(C=C)cc2)c2cccc(-c3cccc4oc5cc(N(c6ccc(C=C)cc6)c6ccc(-c7ccc(C=C)c8ccccc78)cc6)ccc5c34)c2)cc1]

In another embodiment of the present disclosure, the hole transport layer of the quantum dot light emitting device according to the present disclosure includes a compound represented by any one of the following Formulas 3 to 5.

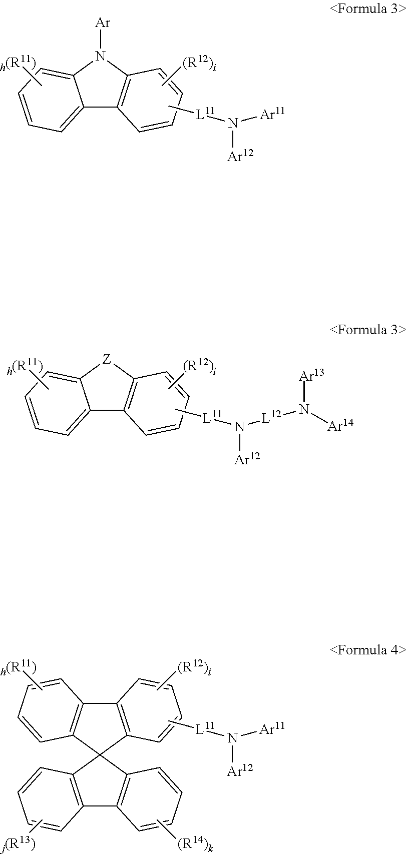

In Formula 3 to Formula 5 above,
1) Z is O or S;
2) Ar and Ar¹¹ to Ar¹⁴ are each independently selected from the group consisting of a C₆₋₆₀ aryl group; a fluorenyl group; a C₂₋₆₀ heterocyclic group including at least one heteroatom among O, N, S, Si, and P; a fused ring group of a C₃₋₆₀ aliphatic ring and a C₆₋₆₀ aromatic ring; a C₁₋₆₀ alkyl group; a C₂₋₂₀ alkenyl group; a C₂₋₂₀ alkynyl group; a C₁₋₃₀ alkoxyl group; and a C₆₋₃₀ aryloxy group;
3) L¹¹ is selected from the group consisting of a single bond; a C₆₋₆₀ arylene group; a fluorenylene group; a fused ring group of a C₃₋₆₀ aliphatic ring and a C₆₋₆₀ aromatic ring; and a C₂₋₆₀ heterocyclic ring group;
4) L¹² is selected from the group consisting of a C₆₋₆₀ arylene group; a fluorenylene group; a fused ring group of a C₃₋₆₀ aliphatic ring and a C₆₋₆₀ aromatic ring; and a C₂₋₆₀ heterocyclic ring group;
5) R¹¹ to R¹⁴ are each the same or different, and are each independently selected from the group consisting of hydrogen; deuterium, tritium; a halogen; a cyano group; a nitro group; a C₆₋₆₀ aryl group; a fluorenyl group: a C₂₋₆₀ heterocyclic group including at least one heteroatom among O, N, S, Si, and P; a fused ring group of a C₃₋₆₀ aliphatic ring and a C₆₋₆₀ aromatic ring; a C₁₋₅₀ alkyl group; a C₂₋₂₀ alkenyl group; a C₂₋₂₀ alkynyl group; a C₁₋₃₀ alkoxyl group; a C₆₋₃₀ aryloxy group; and -L′-N(Rₐ)(R_{b});
6) h, j, and k are each independently an integer from 0 to 4; and i is an integer from 0 to 3;
7) when h to k are 2 or greater, R¹¹ to R¹⁴ are each plural and are each the same or different; and a plurality of neighboring R¹¹, or a plurality of neighboring R¹², or a plurality of neighboring R¹³ are able to bind between them, respectively, to thereby form a ring;
8) the L′ is each independently selected from the group consisting of a single bond; a C₆₋₆₀ arylene group; a fluorenylene group; a C₂₋₆₀ heterocyclic group including at least one heteroatom among O, N, S, Si, and P; a C₃₋₆₀ aliphatic ring; and a fused ring group of a C₃₋₆₀ aliphatic ring and a C₆₋₆₀ aromatic ring;
9) the Rₐ and R_{b} may each be independently selected from the group consisting of a C₆₋₆₀ aryl group; a fluorenyl group; a C₂₋₆₀ heterocyclic group including at least one heteroatom among O, N, S, Si, and P; a C₃₋₆₀ aliphatic ring; and a fused ring group of a C₃₋₆₀ aliphatic ring and a C₆₋₆₀ aromatic ring; and
10) the rings formed by binding between Ar, Ar¹¹ to Ar¹⁴, L′, L¹¹ and L¹², Rₐ, R_{b}, R¹¹ to R¹⁴ and neighboring groups thereof may each be further substituted with one or more substituents selected from the group consisting of deuterium; a halogen; a silane group substituted or unsubstituted with a C₁₋₃₀ alkyl group or C₆₋₃₀ aryl group; a siloxane group; a boron group; a germanium group; a cyano group; an amino group; a nitro group; a C₁₋₃₀ alkylthio group; a C₁₋₃₀ alkoxy group; a C₆₋₃₀ arylalkoxy group; a C₁₋₃₀ alkyl group; a C₂₋₃₀ alkenyl group; a C₂₋₃₀ alkynyl group; a C₆₋₃₀ aryl group; a C₆₋₃₀ aryl group substituted with deuterium; a fluorenyl group; a C₂₋₃₀ heterocyclic group including at least one heteroatom among O, N, S, Si, and P; a C₃₋₃₀ alicyclic group; a C₇₋₃₀ arylalkyl group; a C₈₋₃₀ arylalkenyl group; and a combination thereof; or may form a ring between the neighboring substituents.

When Ar, Ar¹¹ to Ar¹⁴, Rₐ, R_{b}, and R″ to R¹⁴ are an aryl group, it may preferably be a C₆₋₃₀ aryl group, and more preferably a C₆₋₁₈ aryl group (e.g., phenyl, biphenyl, naphthyl, terphenyl, etc.).

When Ar, Ar¹¹ to Ar¹⁴, L′, L¹¹ and L¹², Rₐ, R_{b}, and R″ to R¹⁴ are a heterocyclic group, it may preferably be a C₂₋₃₀ heterocyclic group, and more preferably a C₂₋₁₈ heterocyclic group (e.g., dibenzofuran, dibenzothiophene, naphthobenzothiophene, naphthobenzofuran, etc.).

When Ar. Ar¹¹ to Ar¹⁴, Rₐ, R_{b}, and R″ to R¹⁴ are a fluorenyl group, it may preferably be 9,9-dimethyl-9H-fluorene, 9,9-diphenyl-9H-fluorenyl group, 9,9′-spirobifluorene, etc.

When L′ and L¹¹ and L¹² are an arylene group, it may preferably be a C₆₋₃₀ arylene group, and more preferably a C₆₋₁₈ arylene group (e.g., phenyl, biphenyl, naphthyl, terphenyl, etc.).

When Ar, Ar¹¹ to Ar¹⁴ and R″ to R¹⁴ are an alkyl group, it may preferably be C₁₋₁₀ alkyl group (e.g., methyl, t-butyl, etc.).

When Ar, Ar¹¹ to Ar¹⁴ and R″ to R¹⁴ are an alkoxyl group, it may preferably be a C₁₋₂₀ alkoxyl group, and more preferably a C₁₋₁₀ alkoxyl group (e.g., methoxy, t-buthoxy, etc.).

The rings formed by binding between neighboring groups the L′, L¹ to L³, Rₐ, R_{b}, Ar² and Ar³, R¹ and R², R, R′, R″ may be a C₆₋₆₀ aromatic ring group; a fluorenyl group; a C₂₋₆₀ heterocyclic group including at least one heteroatom among O, N, S, Si, and P; or a C₃₋₆₀ alicyclic group, and for example, when neighboring groups bind to each other and form an aromatic ring, the ring may form a C₆₋₂₀ aromatic ring, and more preferably a C₆₋₁₄ aromatic ring (e.g., benzene, naphthalene, phenanthrene, etc.).

Meanwhile, the compound included in the hole transport layer may be one of the following Compounds H-1 to H-80, but is not limited thereto.

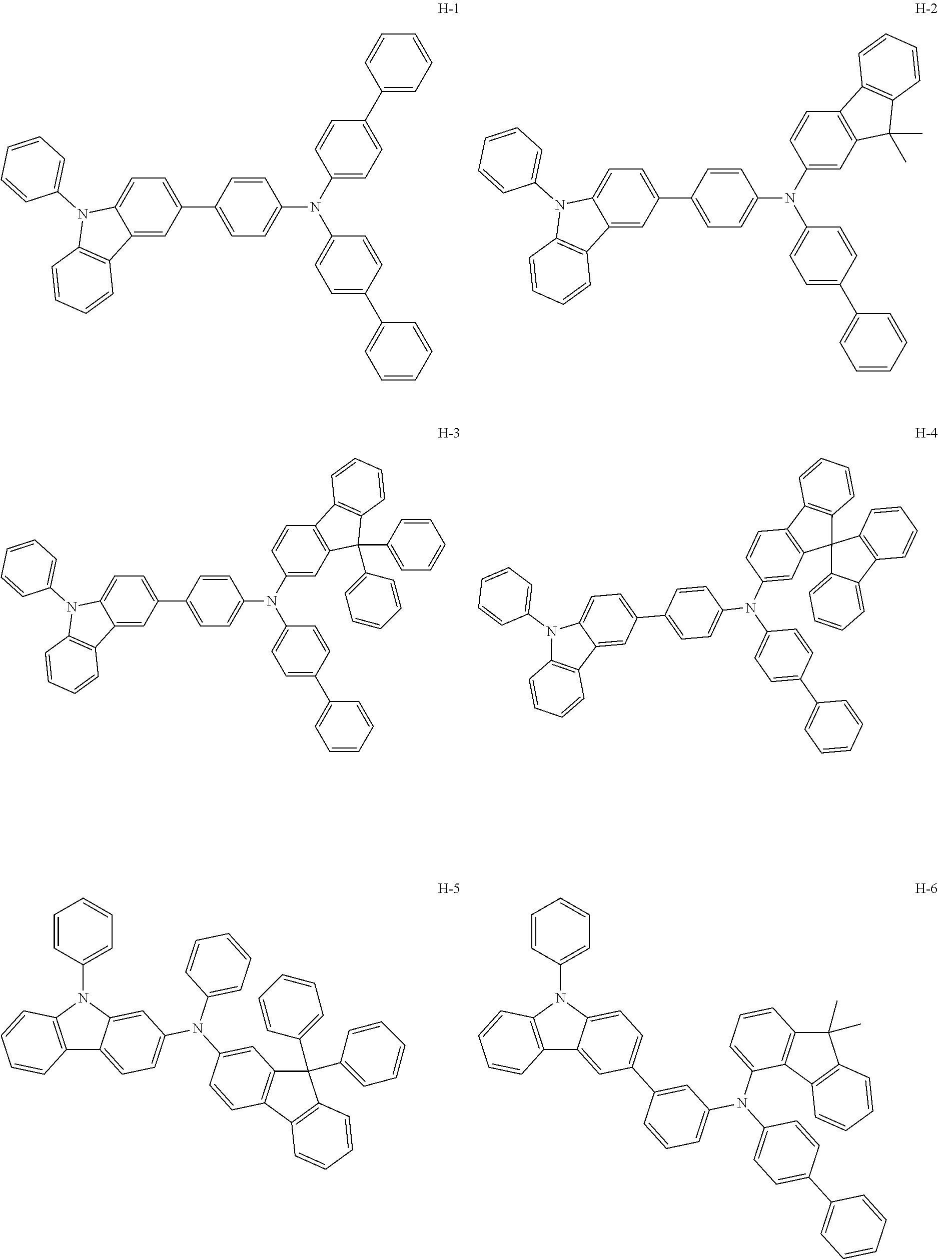

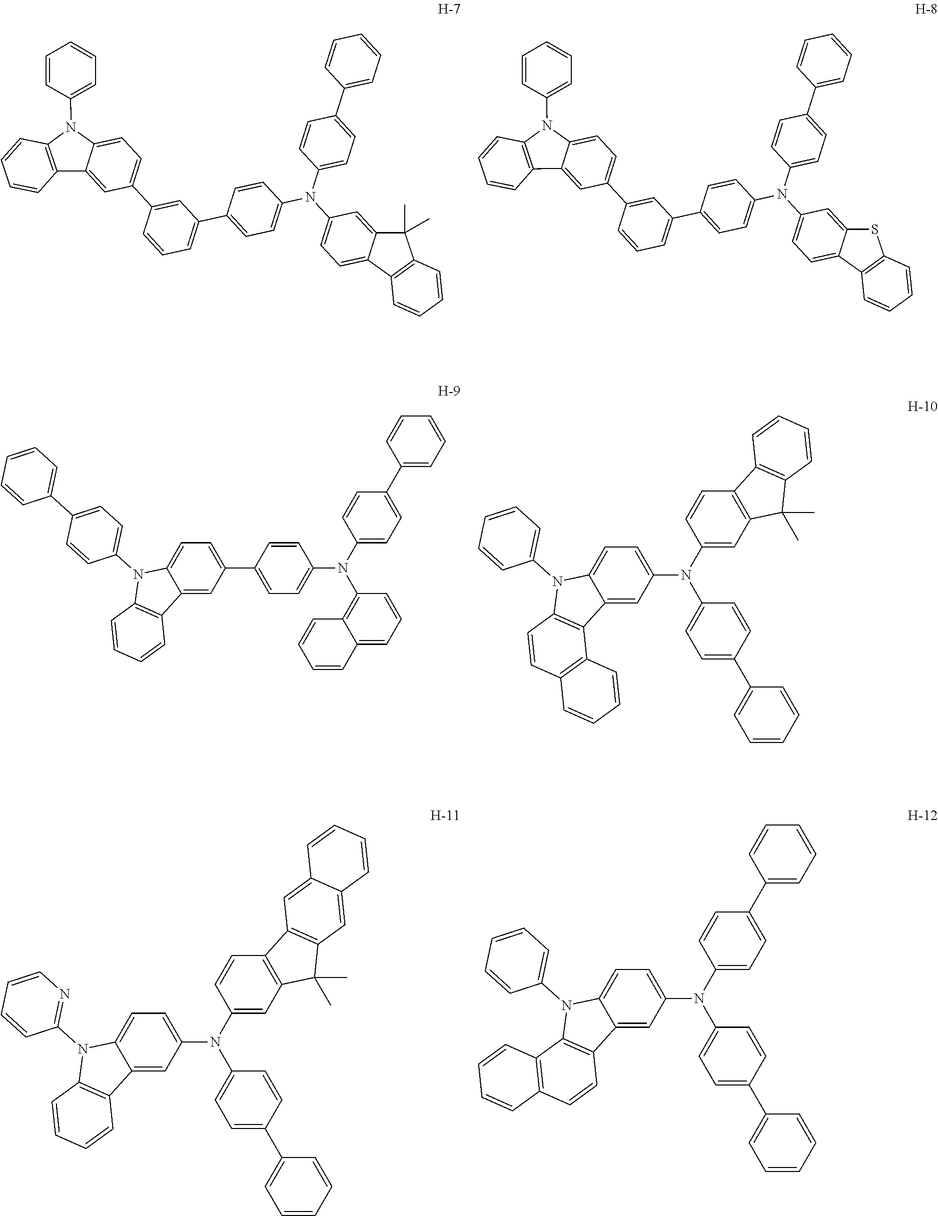

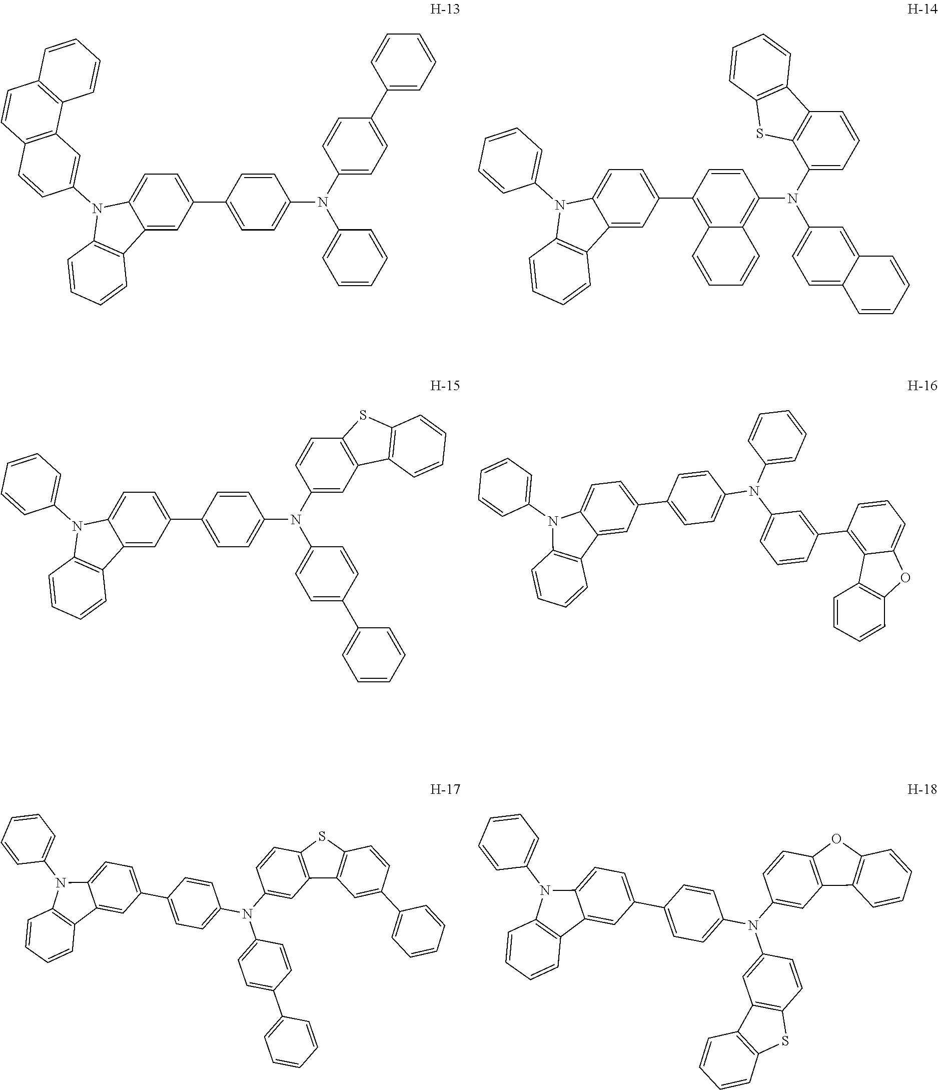

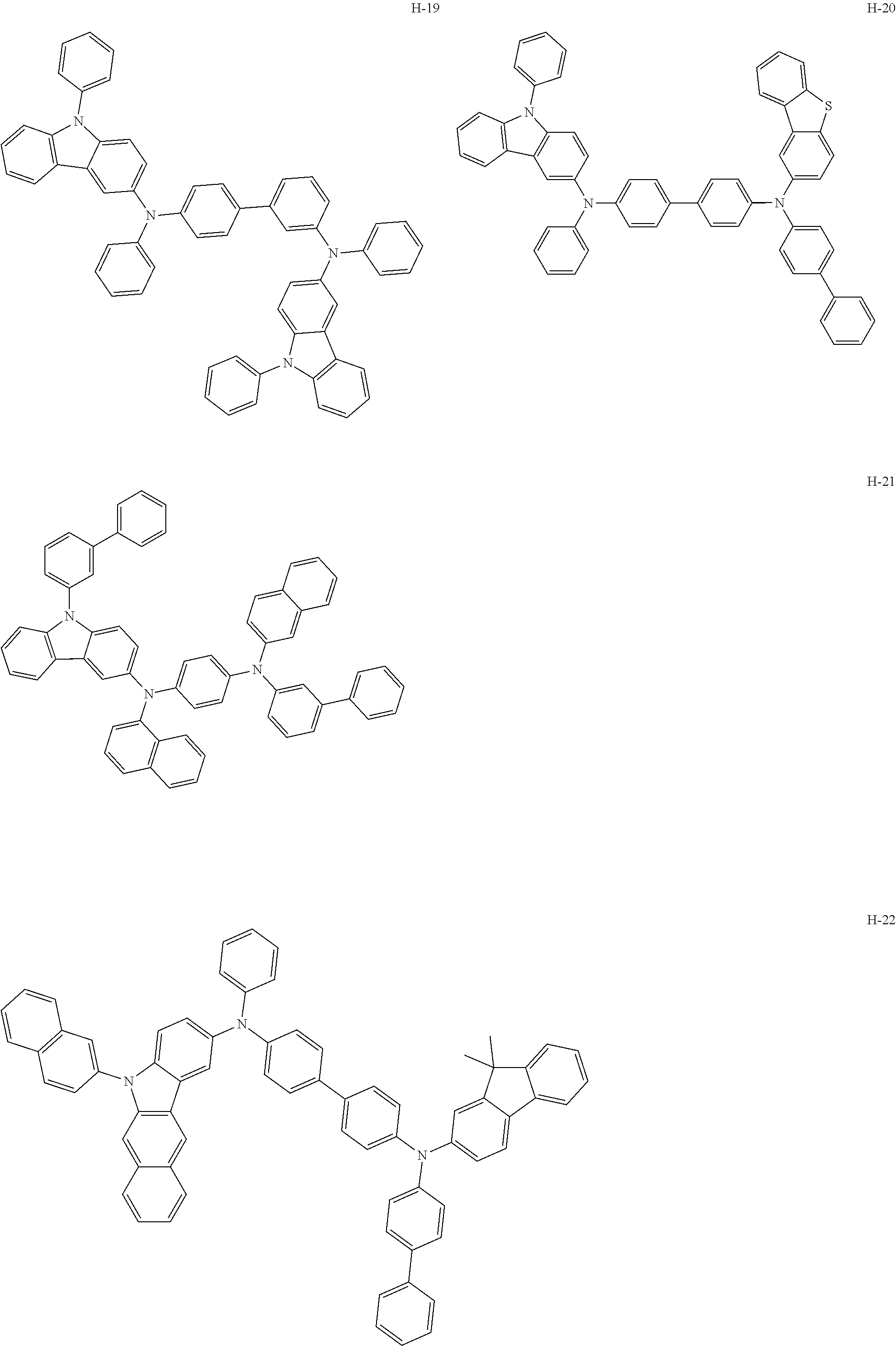 [SMILES: c1ccc(N(c2ccc(-c3cccc(N(c4ccccc4)c4ccc5c(c4)c4ccccc4n5-c4ccccc4)c3)cc2)c2ccc3c(c2)c2ccccc2n3-c2ccccc2)cc1 ; c1ccc(-c2ccc(N(c3ccc(-c4ccc(N(c5ccccc5)c5ccc6c(c5)c5ccccc5n6-c5ccccc5)cc4)cc3)c3ccc4sc5ccccc5c4c3)cc2)cc1 ; c1ccc(-c2cccc(N(c3ccc(N(c4ccc5c(c4)c4ccccc4n5-c4cccc(-c5ccccc5)c4)c4cccc5ccccc45)cc3)c3ccc4ccccc4c3)c2)cc1 ; CC1(C)c2ccccc2-c2ccc(N(c3ccc(-c4ccccc4)cc3)c3ccc(-c4ccc(N(c5ccccc5)c5ccc6c(c5)c5cc7ccccc7cc5n6-c5ccc6ccccc6c5)cc4)cc3)cc21]

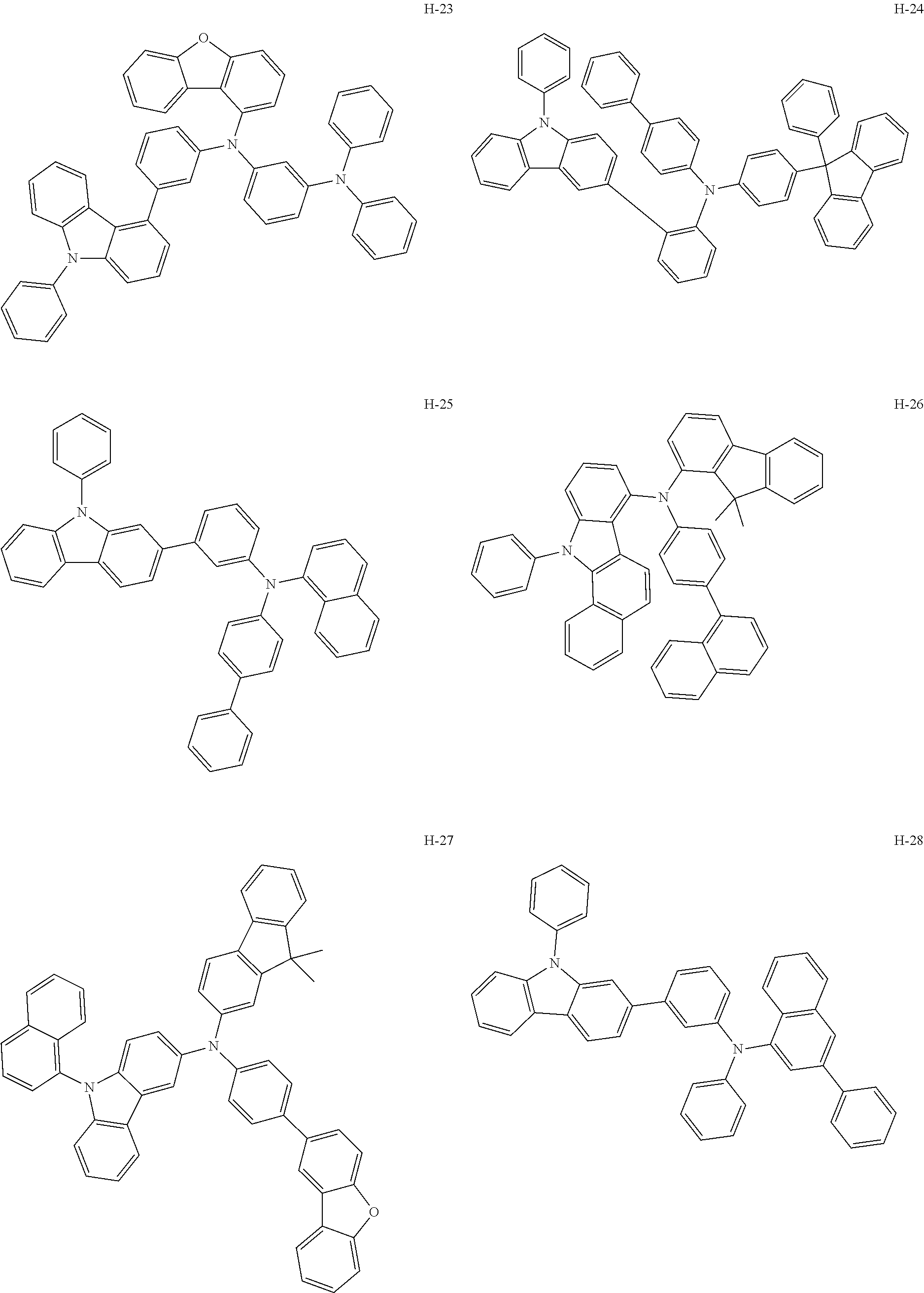

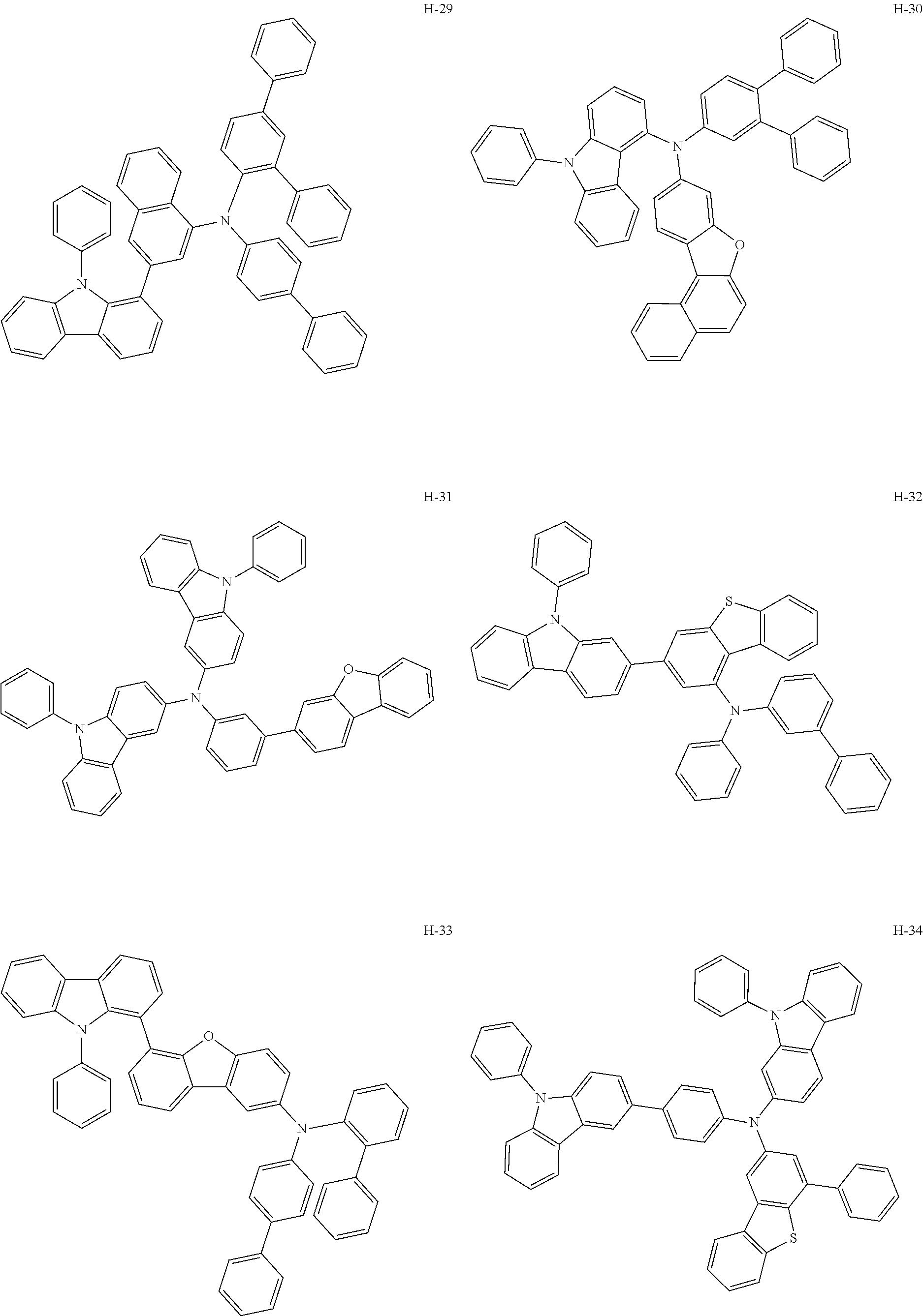

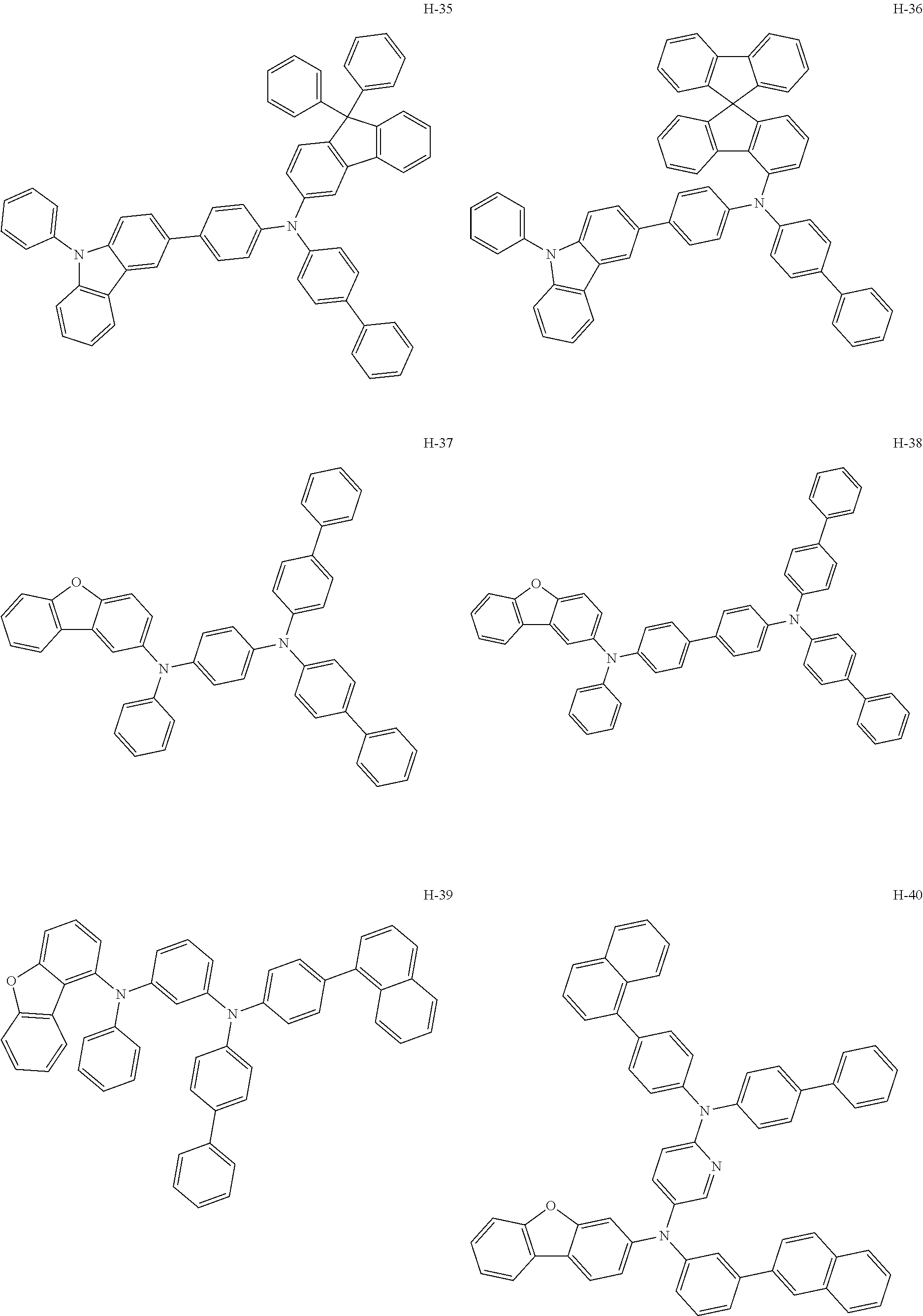

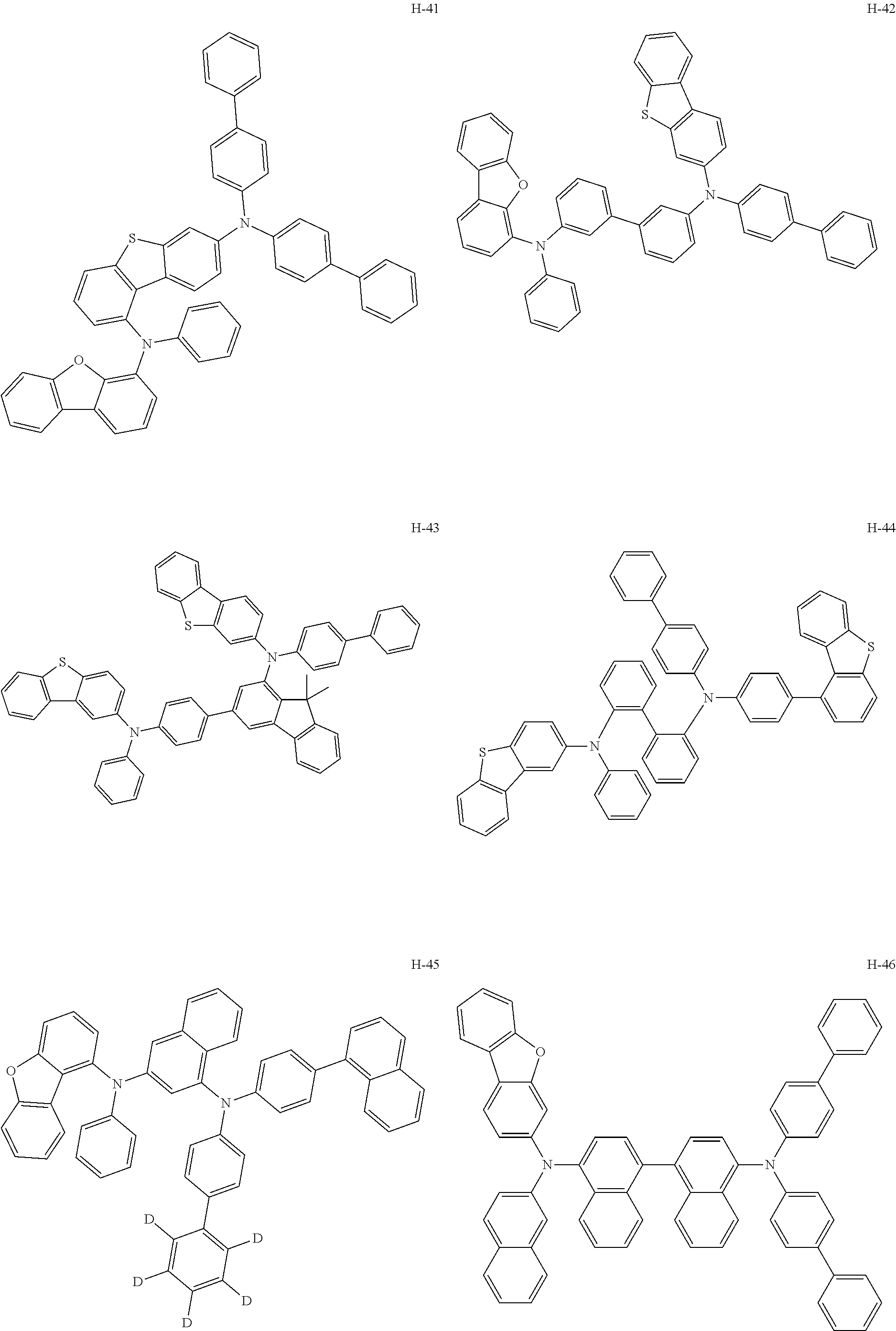

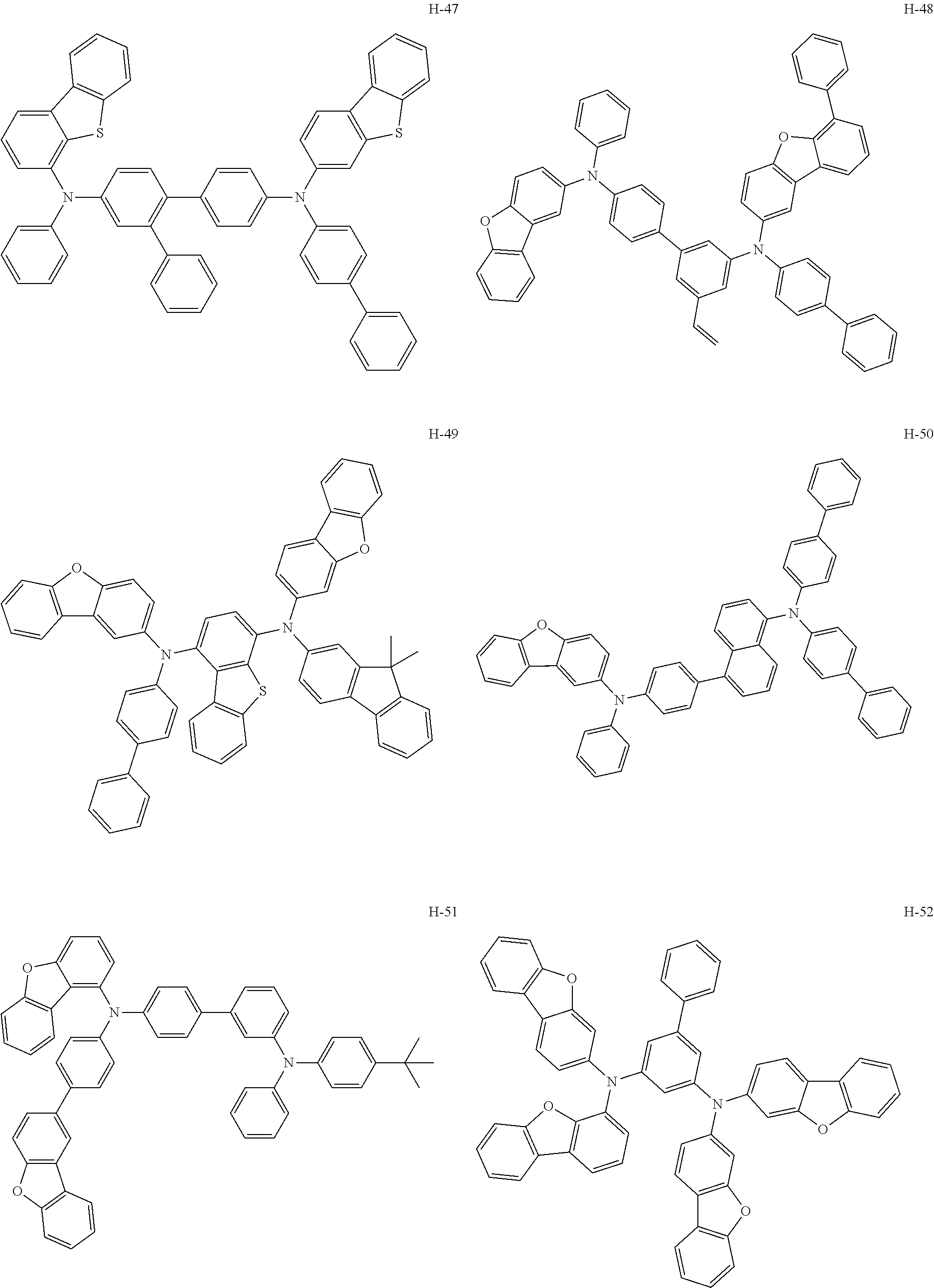

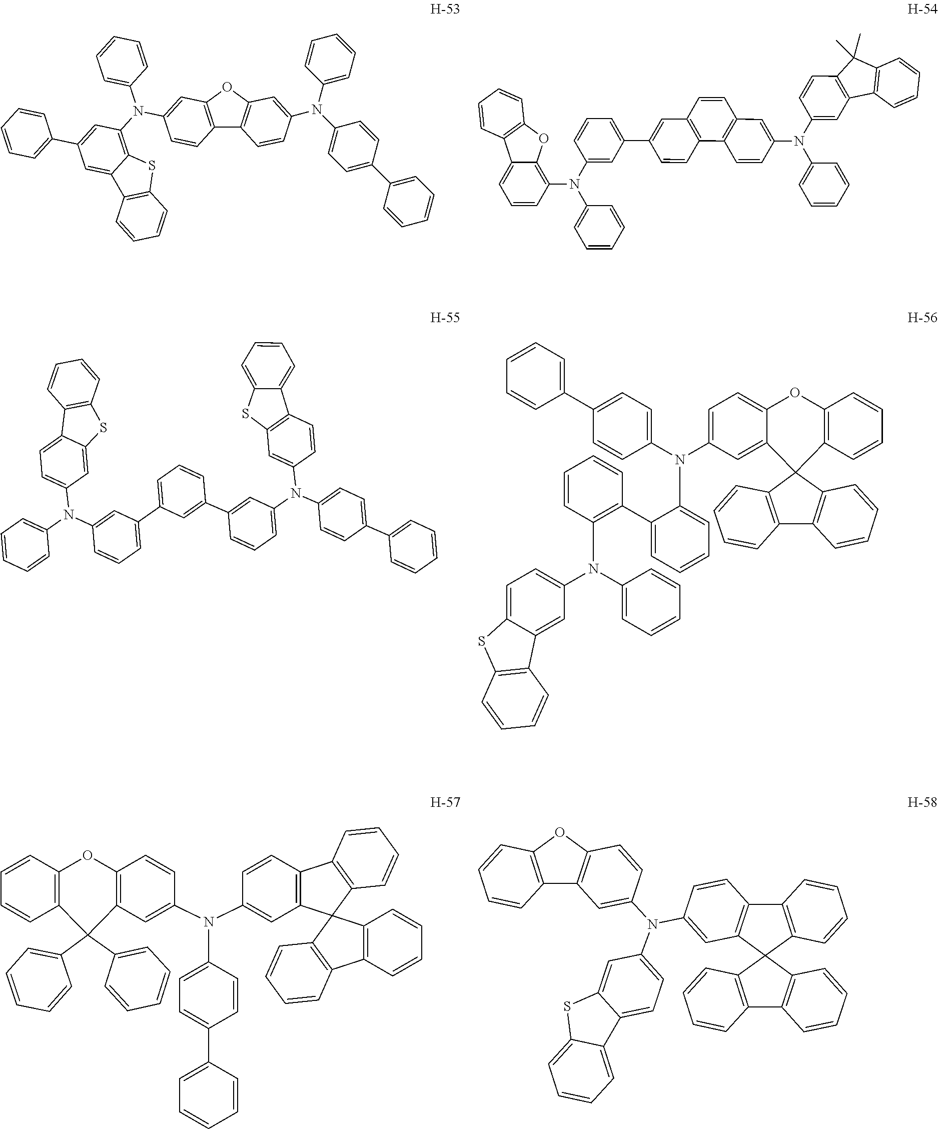

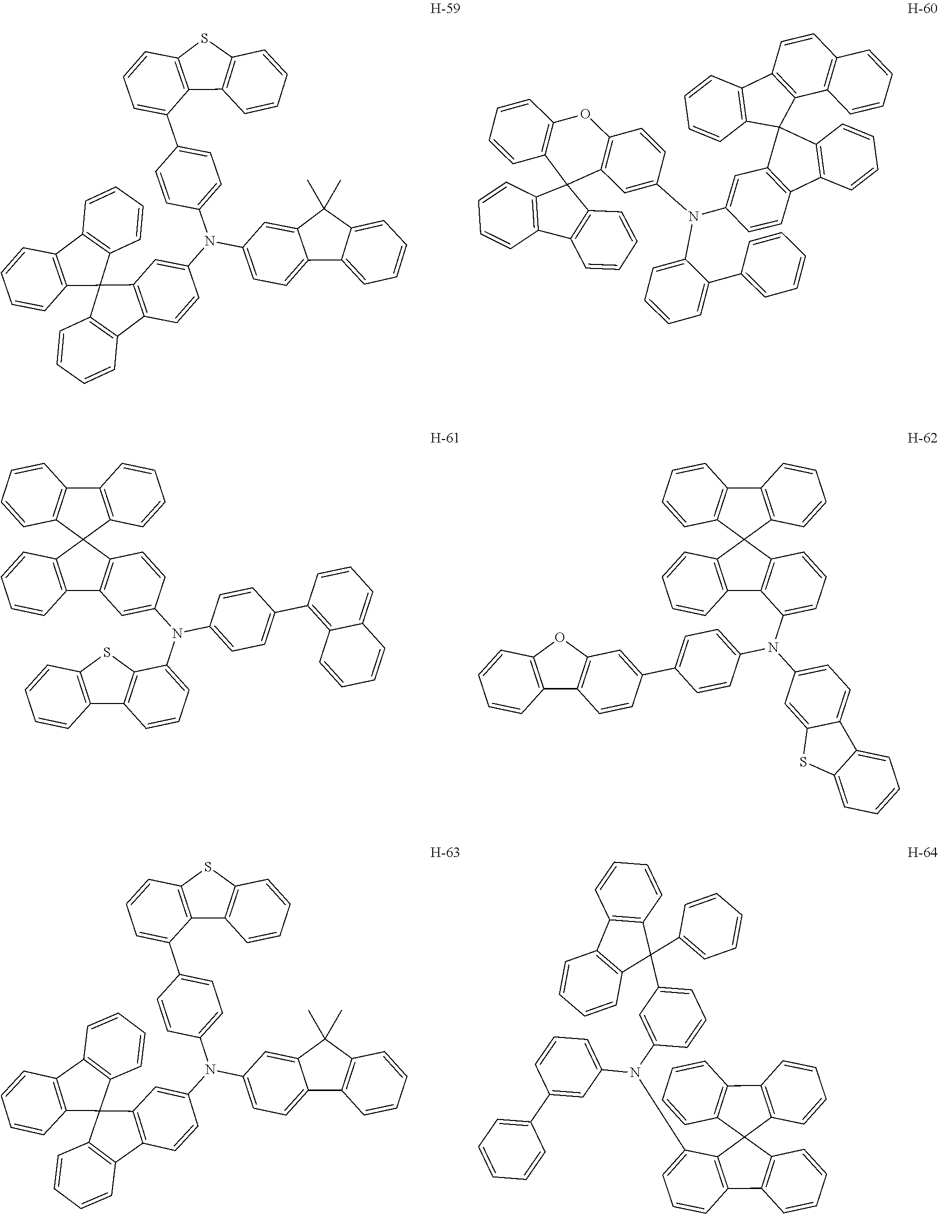

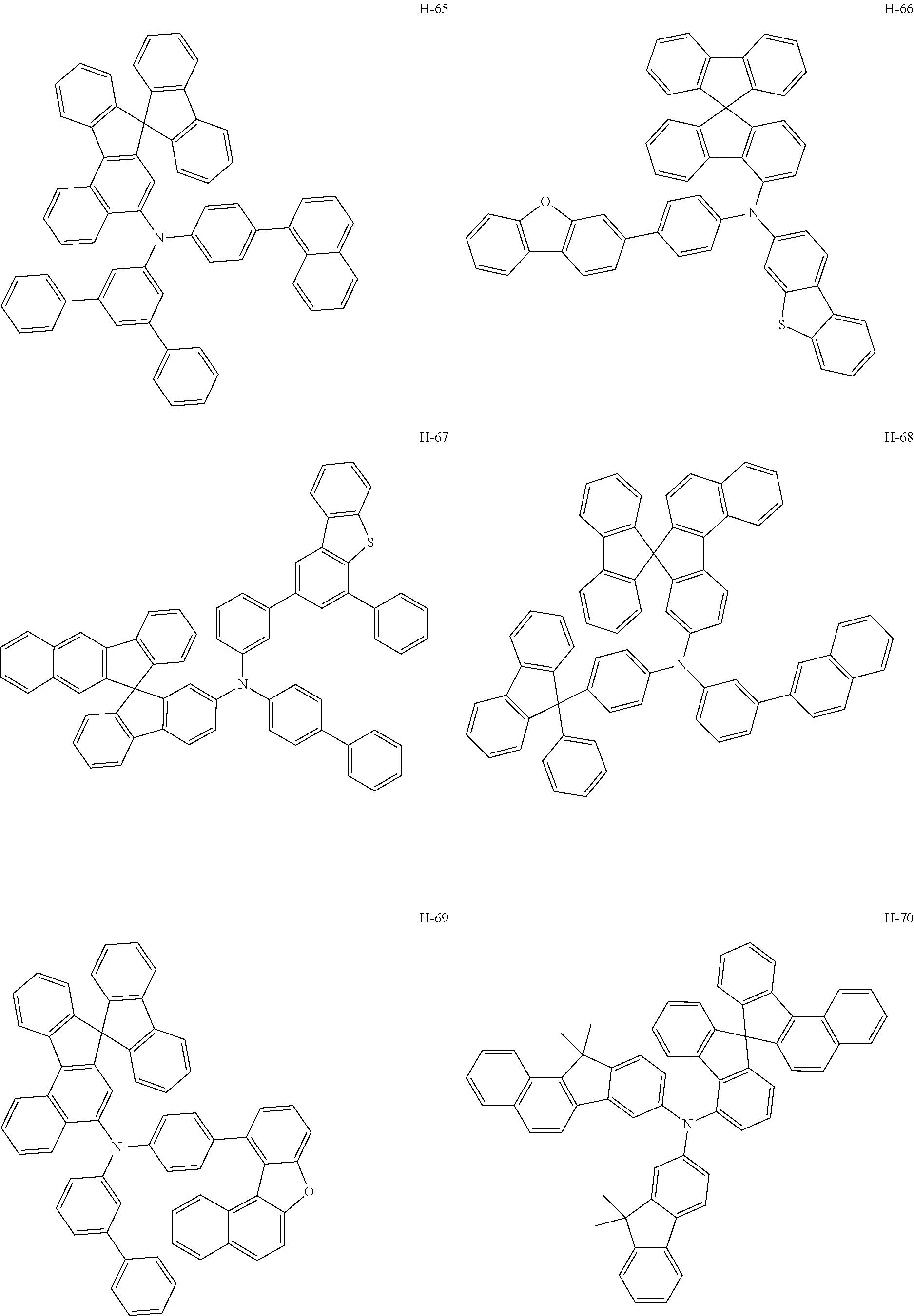

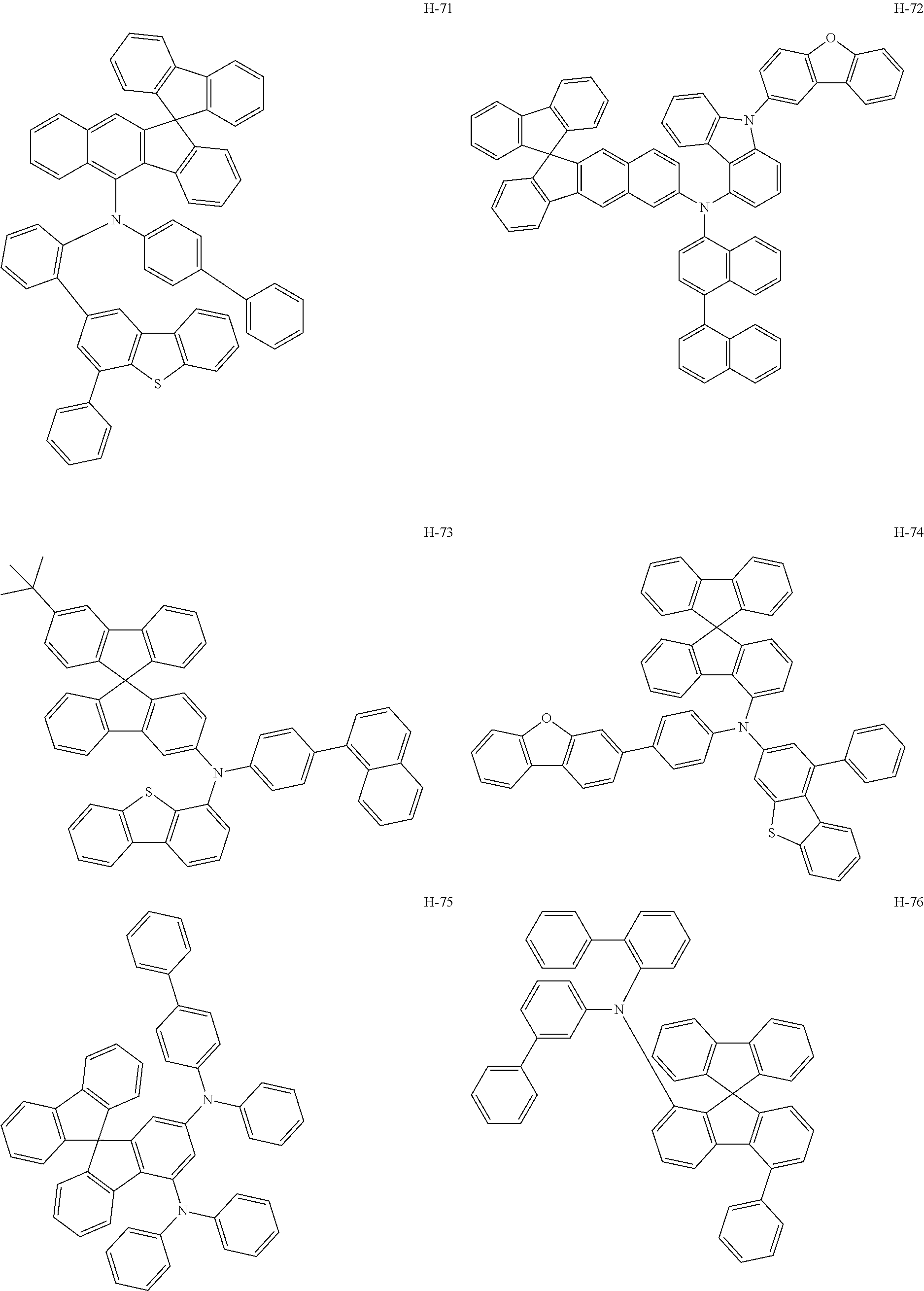

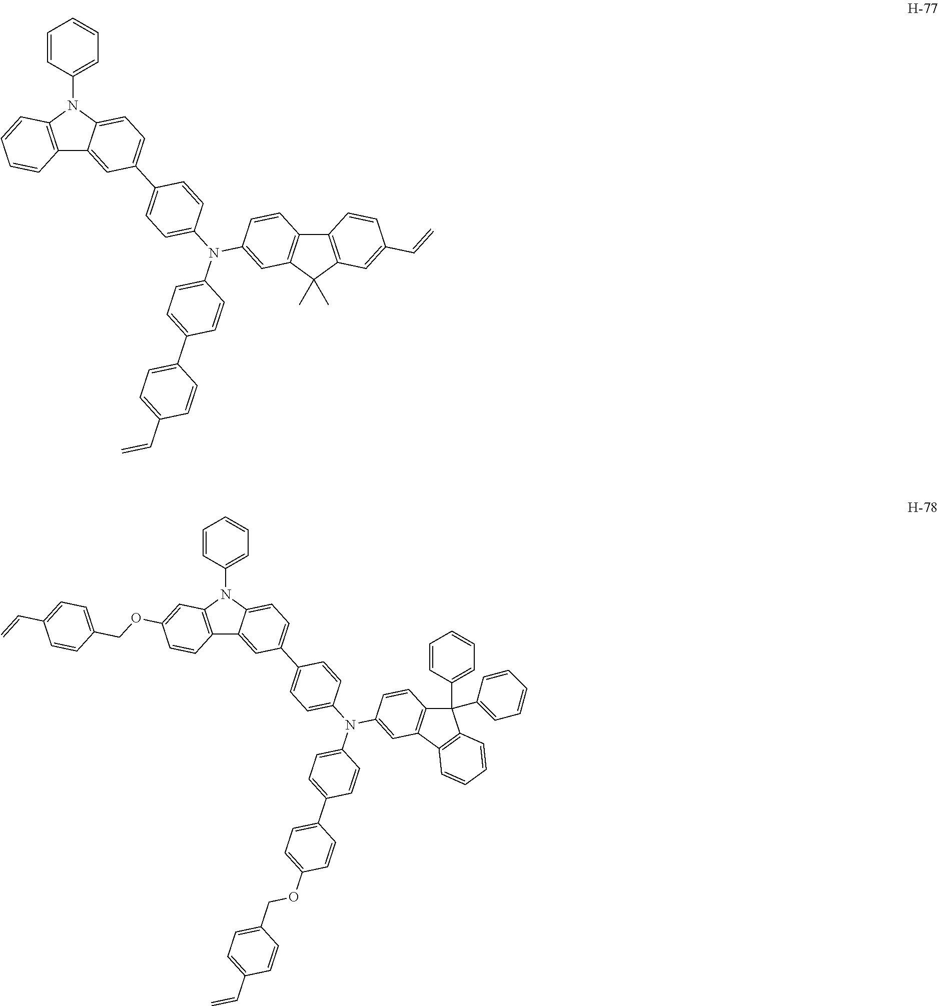

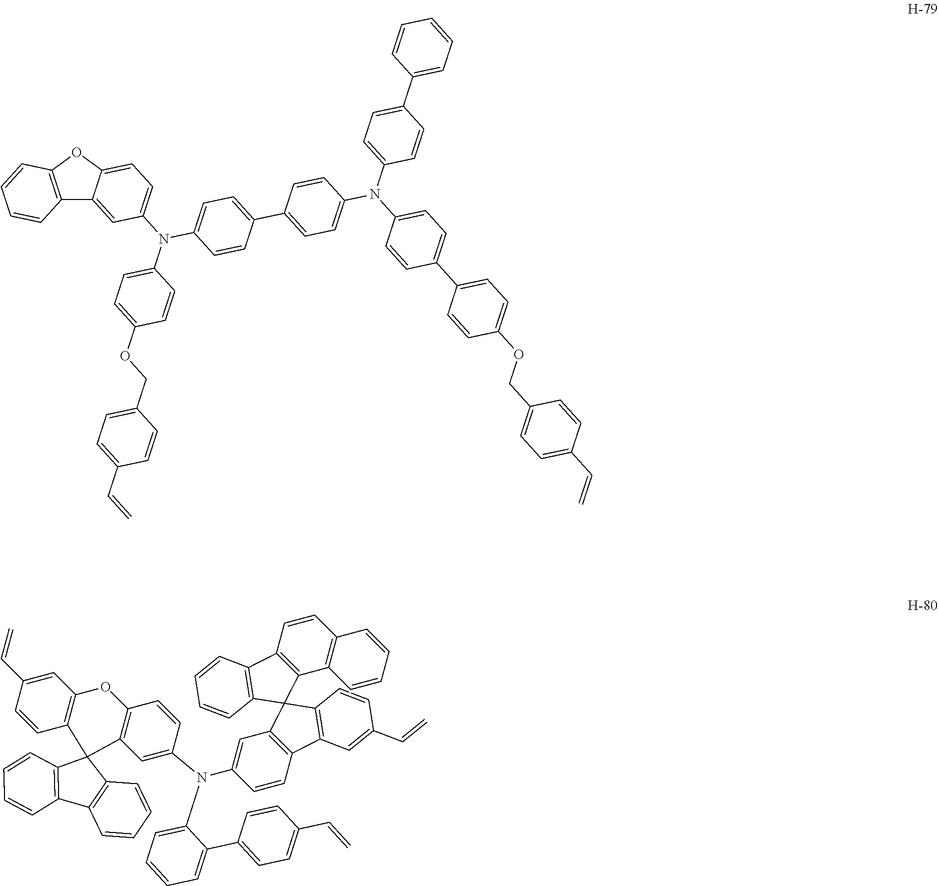 [SMILES: C=Cc1ccc(COc2ccc(-c3ccc(N(c4ccc(-c5ccccc5)cc4)c4ccc(-c5ccc(N(c6ccc(OCc7ccc(C=C)cc7)cc6)c6ccc7oc8ccccc8c7c6)cc5)cc4)cc3)cc2)cc1 ; C=Cc1ccc(-c2ccccc2N(c2ccc3c(c2)C2(c4ccc(C=C)cc4O3)c3ccccc3-c3ccccc32)c2ccc3c(c2)C2(c4ccc(C=C)cc4-3)c3ccccc3-c3ccc4ccccc4c32)cc1]

In another embodiment of the present disclosure, the present disclosure provides a quantum dot light emitting device, which includes a first electrode; a second electrode; and a light emitting layer including quantum dots and a hole transport layer between the first electrode and the second electrode; wherein the organic material layer includes the compound according to the present disclosure alone or in combination.

In still another embodiment of the present disclosure, the present disclosure provides a quantum dot light emitting device, which includes a first electrode; a second electrode; a light emitting layer including quantum dots and a hole transport layer between the first electrode and the second electrode and a capping layer; wherein the capping layer is formed on one side of both surfaces of the first electrode and the second electrode that is not in contact with the organic material layer, and the organic material layer or capping layer includes the compound according to the present disclosure alone or in combination.

The organic material layer includes at least one of a hole injection layer, a hole transport layer, an auxiliary light emitting layer, an auxiliary electron transport layer, an electron transport layer, and an electron injection layer. That is, at least one layer of the hole injection layer, hole transport layer, auxiliary light emitting layer, auxiliary electron transport layer, electron transport layer, and electron injection layer included in the organic material layer may include the compound according to the present disclosure.

Preferably, the organic material layer includes at least one of a hole transport layer, an auxiliary light emitting layer, and an auxiliary electron transport layer including the compound according to the present disclosure.

The organic material layer may include two or more stacks including a hole transport layer and an electron transport layer sequentially formed on the anode.

Preferably, the organic material layer may further include a charge generation layer formed between the two or more stacks.

In another specific embodiment of the present disclosure, an object of the present disclosure is to provide an electronic device, which includes a display device including a quantum dot light emitting device including the compound according to the present disclosure; and a control unit for operating the display device.

In an embodiment of the present disclosure, the compound according to the present disclosure may be included alone, may be included in a combination of two or mutually-different types, or the compound may be included in combination of two or more types with other compound(s).

Meanwhile, the quantum dot light emitting layer may include a semiconductor nanocrystal core including a Group III-V element, and a shell layer which is disposed on the semiconductor nanocrystal core and includes a Group II-VI element.

Also preferably, the quantum dot light emitting layer may include a semiconductor nanocrystal core that includes a Group III element and a Group V element.

Also preferably, the semiconductor nanocrystal core may further include a Group II element.

Also preferably, the molar ratio of the Group III element and the Group II element in the semiconductor nanocrystal core is 1:5 to 1:30.

Also preferably, a semiconductor nanocrystal shell, which includes a Group II element and a Group VI element, may be included on the semiconductor nanocrystal core.

Also preferably, the average diameter of the quantum dots is 3 nm to 12 nm.

Also preferably, the LUMO level of the quantum dot is −2.7 eV to −4.0 eV, and the HOMO level is −4.5 eV to −6.5 eV.

Hereinafter, examples of synthesis of compounds for quantum dot light emitting devices and manufacturing examples of quantum dot light emitting devices according to the present disclosure will be described in detail through examples, but the present disclosure is not limited to the following examples.

### Synthesis Examples

### I. Synthesis of Compounds of Auxiliary Light Emitting Layer

The compound (final product) represented by Formula 1 according to the present disclosure may be prepared by reacting as shown in Scheme 1 below, but is not limited thereto. (Hal=Br, I, or Cl).

In addition, the compound corresponding to the hole transport layer may also be prepared through the same reaction, but is not limited thereto.

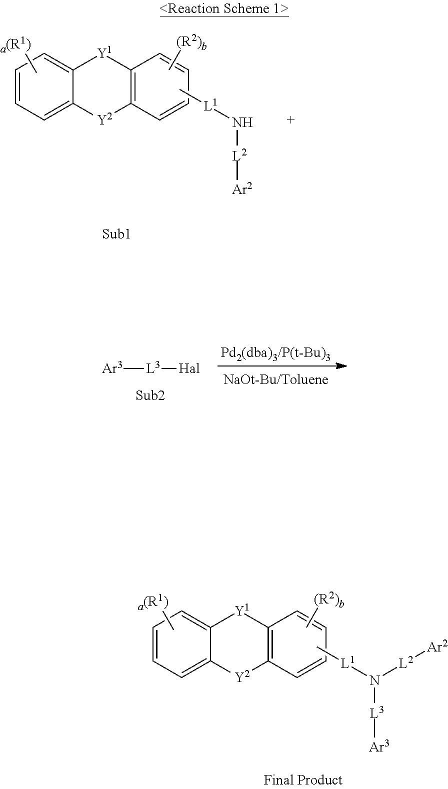

### 1. Synthesis of Sub 1

Sub 1 of Reaction Scheme 1 may be synthesized through the reaction route of Reaction Scheme 2 below, but is not limited thereto.

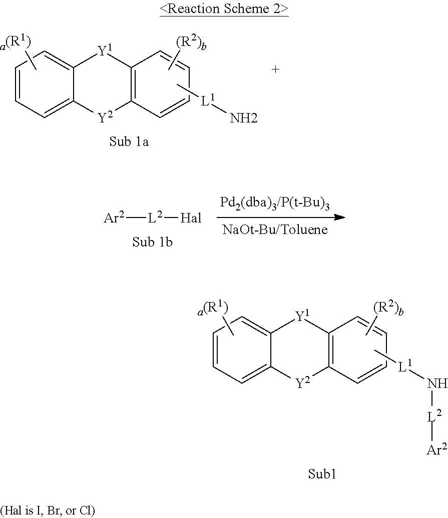

Synthesis examples of specific compounds belonging to Sub 1 are as follows.

### 1. Synthesis Example of Sub 1-1

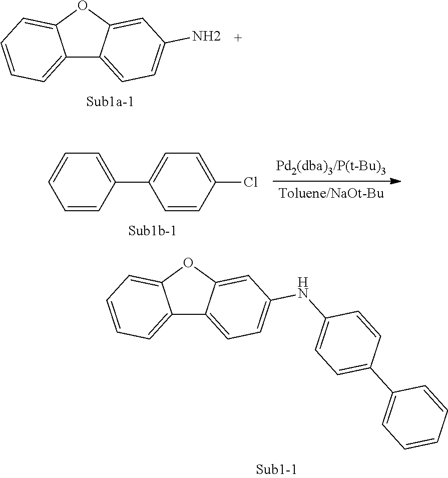 [SMILES: Nc1ccc2c(c1)oc1ccccc12 ; Clc1ccc(-c2ccccc2)cc1 ; c1ccc(-c2ccc(Nc3ccc4c(c3)oc3ccccc34)cc2)cc1]

Sub 1a-1 (15.0 g, 81.9 mmol), Sub 1b-1 (15.5 g, 81.9 mmol), Pd2(dba)₃ (3.8 g, 4.1 mmol), P(t-Bu)₃ (50 wt % Sol) (3.3 mL, 8.2 mmol), NaOt-Bu (23.6 g, 245.6 mmol), and toluene (300 mL) were added into a round bottom flask and stirred at 80° C. Upon completion of the reaction, the resultant was extracted with CH₂Cl₂ and water, and the organic layer was dried over MgSO₄ and concentrated, and the resulting compound was subjected to a silica gel column and recrystallized to obtain 24.4 g of the product (yield: 89%).

### 2) Synthesis of Sub 1-32

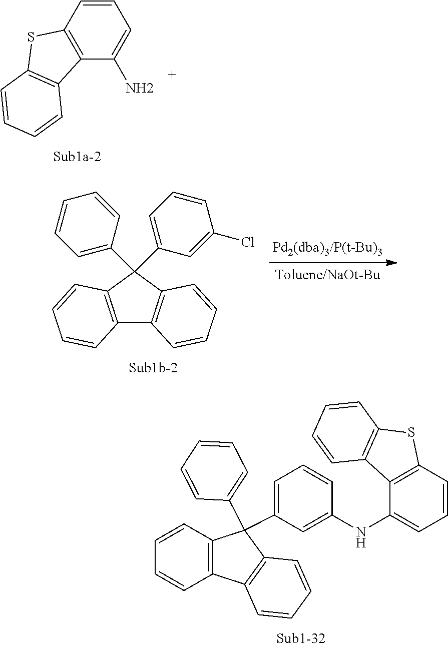 [SMILES: Nc1cccc2sc3ccccc3c12 ; Clc1cccc(C2(c3ccccc3)c3ccccc3-c3ccccc32)c1 ; c1ccc(C2(c3cccc(Nc4cccc5sc6ccccc6c45)c3)c3ccccc3-c3ccccc32)cc1]

Sub 1a-2 (12.5 g, 32.7 mmol), Sub 1b-2 (22.1 g, 62.7 mmol), Pd₂(dba)₃ (2.9 g, 3.1 mmol), P(t-Bu)₃ (1.3 g, 2.5 mmol), NaOt-Bu (18.1 g, 188.2 mmol), and toluene (250 mL) were added into a round bottom flask and the experiment was performed in the same manner as in Sub 1-1 above to obtain 26.5 g of the product (yield: 82%).

Meanwhile, the compounds belonging to Sub 1 may be the following compounds, but are not limited thereto.

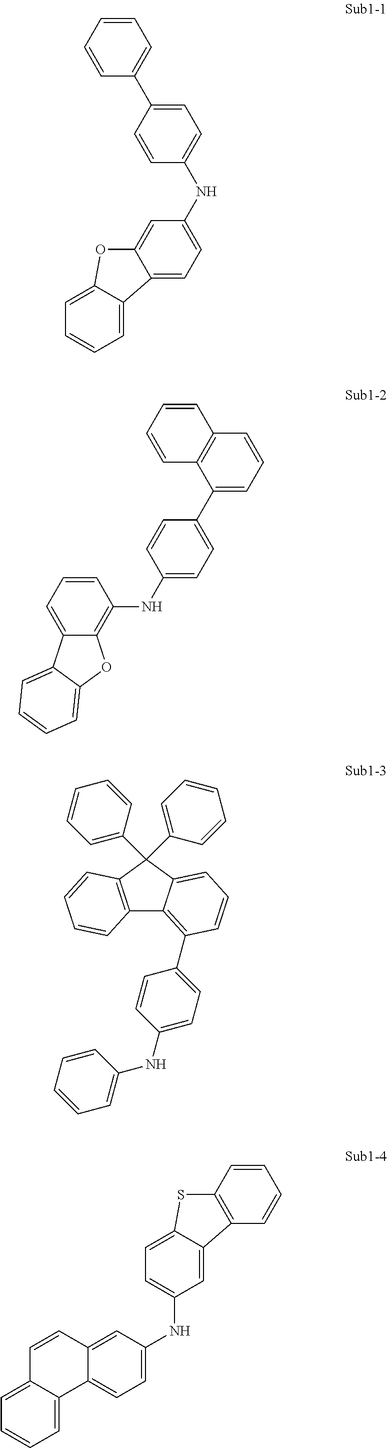 [SMILES: c1ccc(-c2ccc(Nc3ccc4c(c3)oc3ccccc34)cc2)cc1 ; c1ccc2c(-c3ccc(Nc4cccc5c4oc4ccccc45)cc3)cccc2c1 ; c1ccc(Nc2ccc(-c3cccc4c3-c3ccccc3C4(c3ccccc3)c3ccccc3)cc2)cc1 ; c1ccc2c(c1)ccc1cc(Nc3ccc4sc5ccccc5c4c3)ccc12]

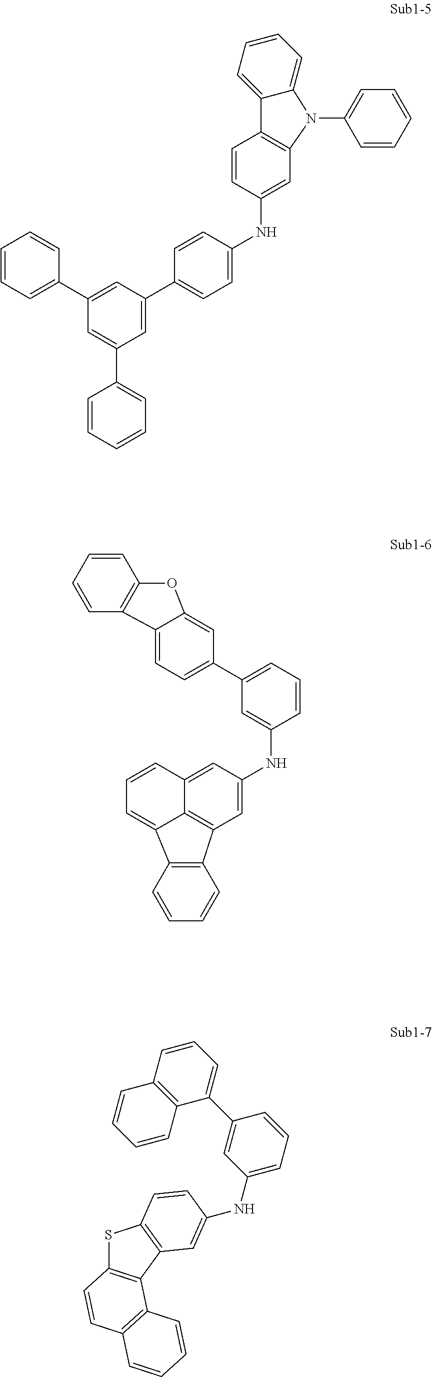 [SMILES: c1ccc(-c2cc(-c3ccccc3)cc(-c3ccc(Nc4ccc5c6ccccc6n(-c6ccccc6)c5c4)cc3)c2)cc1 ; c1cc(Nc2cc3c4c(cccc4c2)-c2ccccc2-3)cc(-c2ccc3c(c2)oc2ccccc23)c1 ; c1cc(Nc2ccc3sc4ccc5ccccc5c4c3c2)cc(-c2cccc3ccccc23)c1]

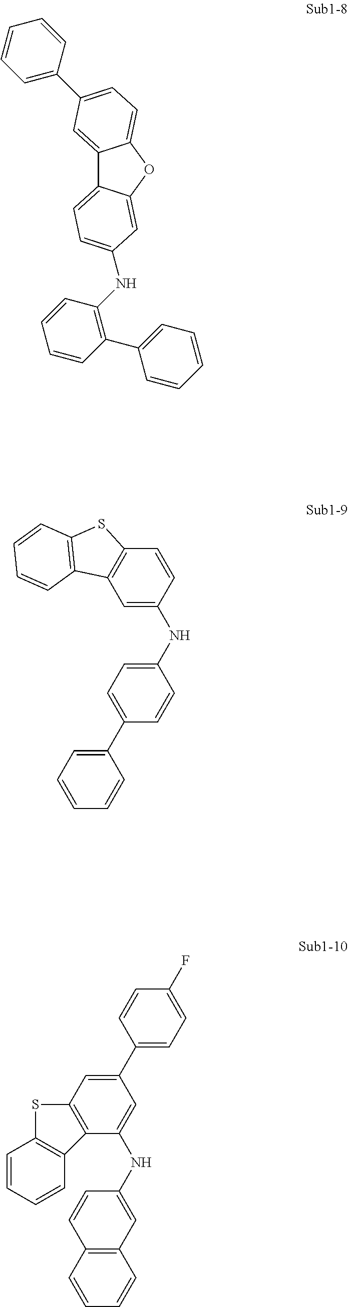 [SMILES: c1ccc(-c2ccc3oc4cc(Nc5ccccc5-c5ccccc5)ccc4c3c2)cc1 ; c1ccc(-c2ccc(Nc3ccc4sc5ccccc5c4c3)cc2)cc1 ; Fc1ccc(-c2cc(Nc3ccc4ccccc4c3)c3c(c2)sc2ccccc23)cc1]

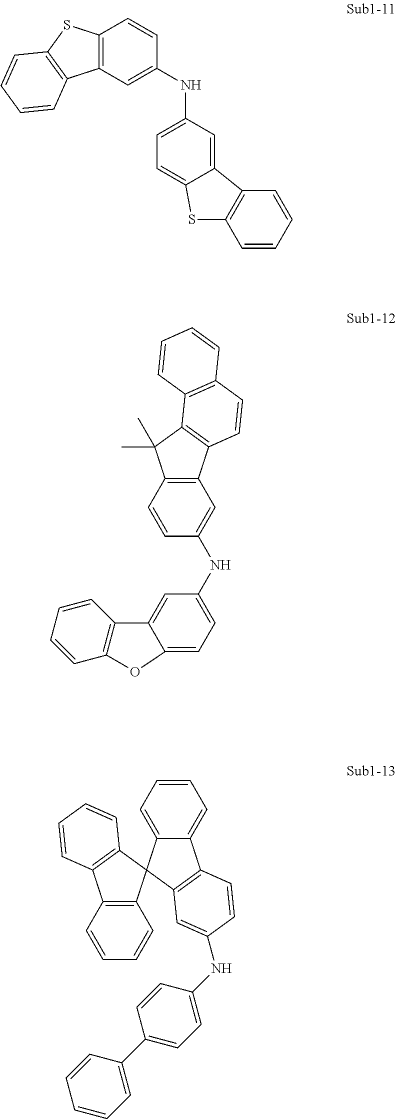 [SMILES: c1ccc2c(c1)sc1ccc(Nc3ccc4sc5ccccc5c4c3)cc12 ; CC1(C)c2ccc(Nc3ccc4oc5ccccc5c4c3)cc2-c2ccc3ccccc3c21 ; c1ccc(-c2ccc(Nc3ccc4c(c3)C3(c5ccccc5-c5ccccc53)c3ccccc3-4)cc2)cc1]

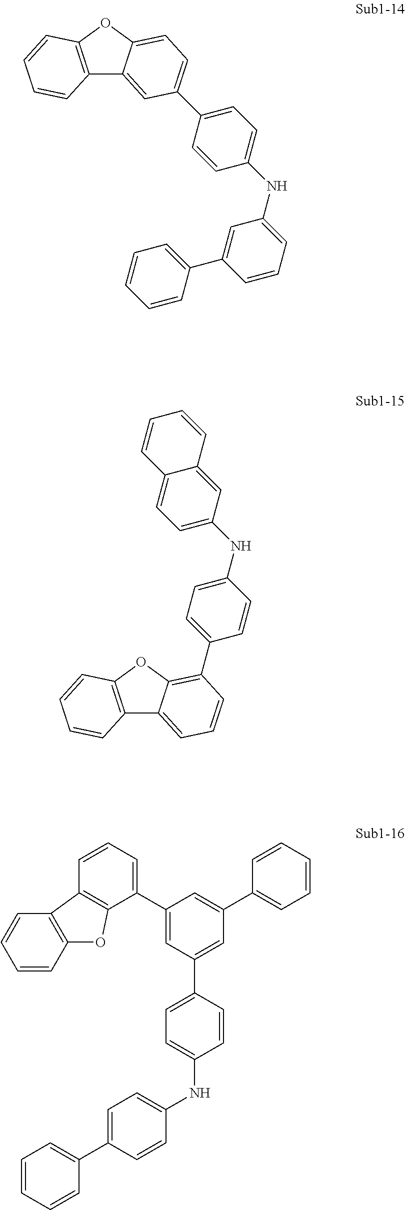 [SMILES: c1ccc(-c2cccc(Nc3ccc(-c4ccc5oc6ccccc6c5c4)cc3)c2)cc1 ; c1ccc2cc(Nc3ccc(-c4cccc5c4oc4ccccc45)cc3)ccc2c1 ; c1ccc(-c2ccc(Nc3ccc(-c4cc(-c5ccccc5)cc(-c5cccc6c5oc5ccccc56)c4)cc3)cc2)cc1]

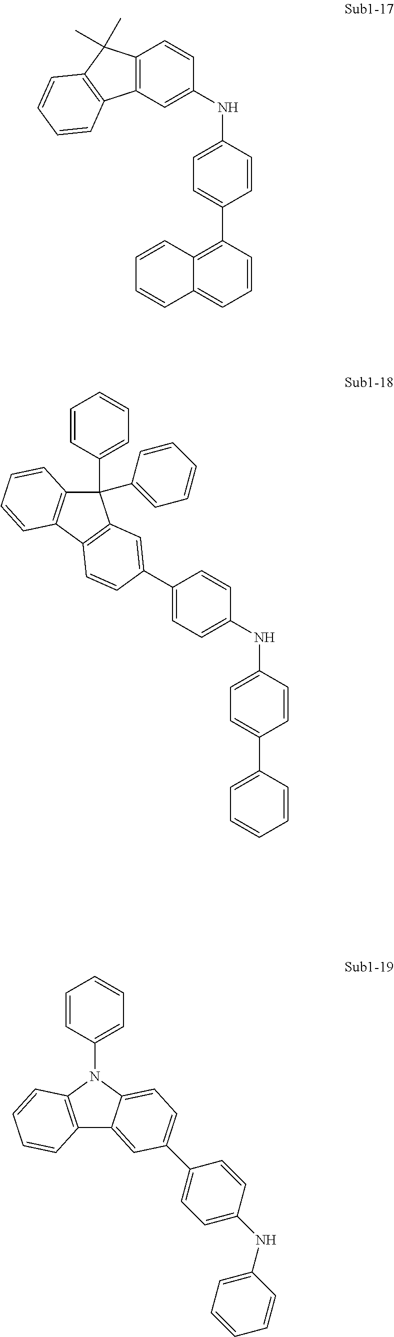 [SMILES: CC1(C)c2ccccc2-c2cc(Nc3ccc(-c4cccc5ccccc45)cc3)ccc21 ; c1ccc(-c2ccc(Nc3ccc(-c4ccc5c(c4)C(c4ccccc4)(c4ccccc4)c4ccccc4-5)cc3)cc2)cc1 ; c1ccc(Nc2ccc(-c3ccc4c(c3)c3ccccc3n4-c3ccccc3)cc2)cc1]

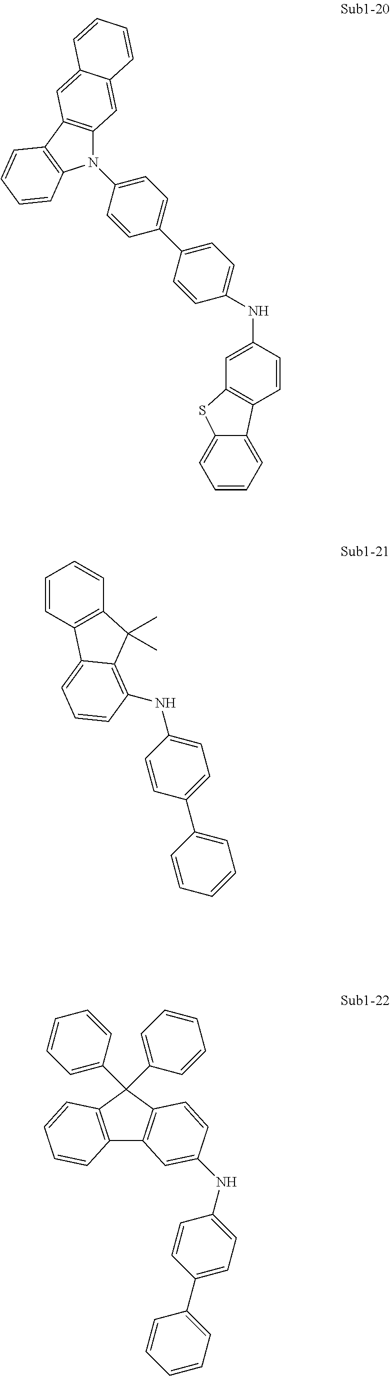 [SMILES: c1ccc2cc3c(cc2c1)c1ccccc1n3-c1ccc(-c2ccc(Nc3ccc4c(c3)sc3ccccc34)cc2)cc1 ; CC1(C)c2ccccc2-c2cccc(Nc3ccc(-c4ccccc4)cc3)c21 ; c1ccc(-c2ccc(Nc3ccc4c(c3)-c3ccccc3C4(c3ccccc3)c3ccccc3)cc2)cc1]

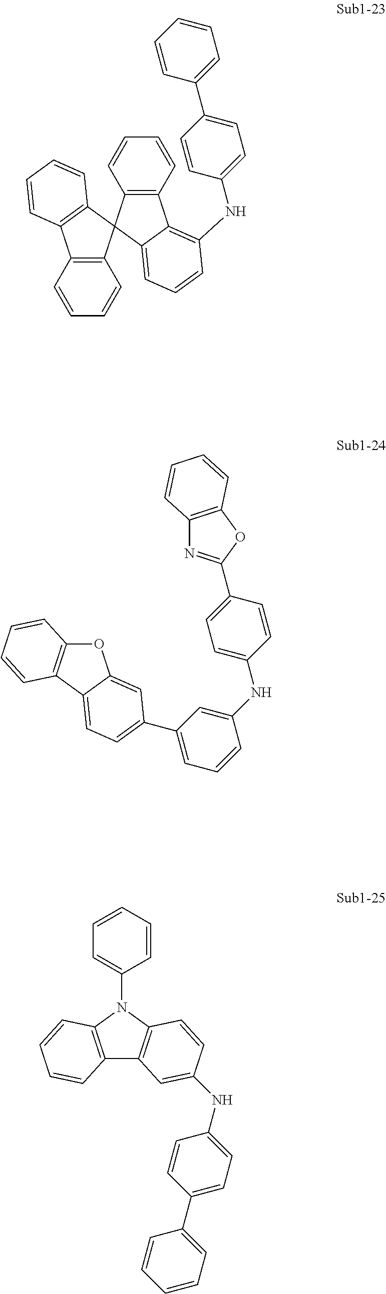 [SMILES: c1ccc(-c2ccc(Nc3cccc4c3-c3ccccc3C43c4ccccc4-c4ccccc43)cc2)cc1 ; c1cc(Nc2ccc(-c3nc4ccccc4o3)cc2)cc(-c2ccc3c(c2)oc2ccccc23)c1 ; c1ccc(-c2ccc(Nc3ccc4c(c3)c3ccccc3n4-c3ccccc3)cc2)cc1]

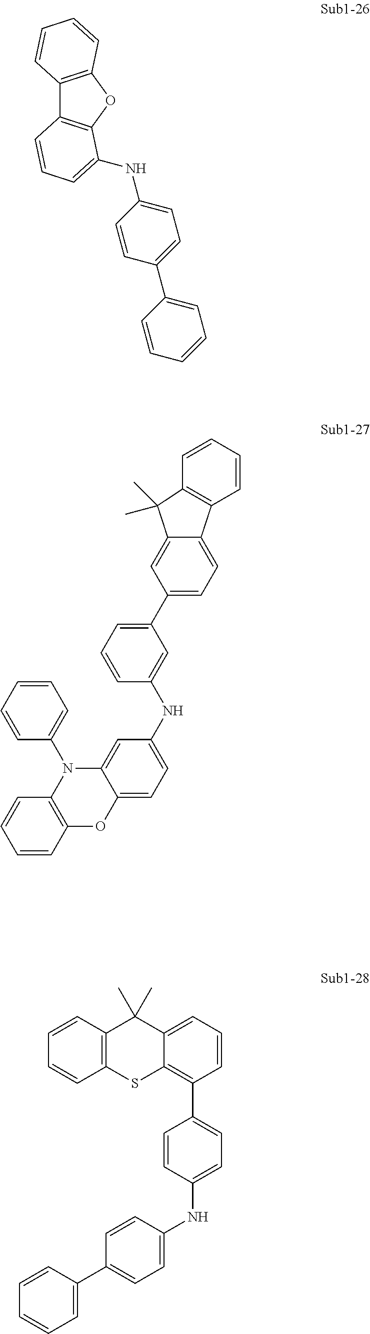 [SMILES: c1ccc(-c2ccc(Nc3cccc4c3oc3ccccc34)cc2)cc1 ; CC1(C)c2ccccc2-c2ccc(-c3cccc(Nc4ccc5c(c4)N(c4ccccc4)c4ccccc4O5)c3)cc21 ; CC1(C)c2ccccc2Sc2c(-c3ccc(Nc4ccc(-c5ccccc5)cc4)cc3)cccc21]

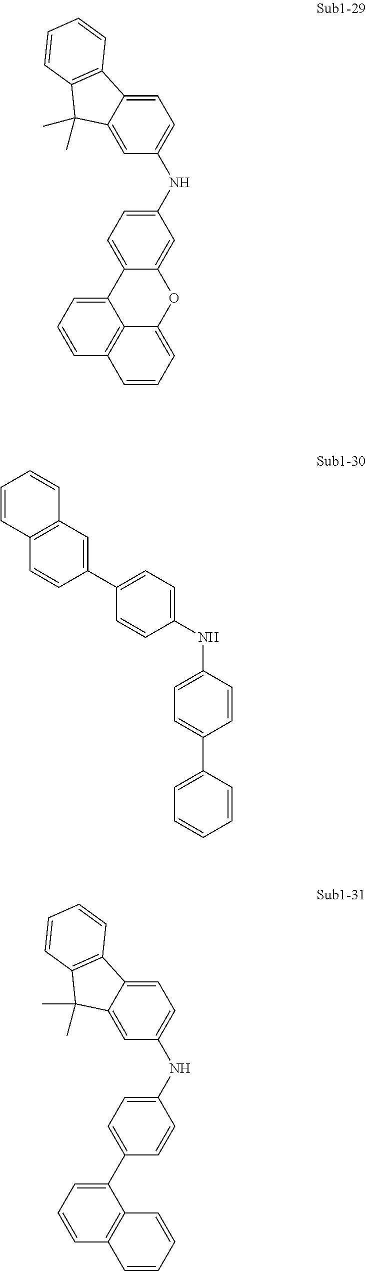 [SMILES: CC1(C)c2ccccc2-c2ccc(Nc3ccc4c(c3)Oc3cccc5cccc-4c35)cc21 ; c1ccc(-c2ccc(Nc3ccc(-c4ccc5ccccc5c4)cc3)cc2)cc1 ; CC1(C)c2ccccc2-c2ccc(Nc3ccc(-c4cccc5ccccc45)cc3)cc21]

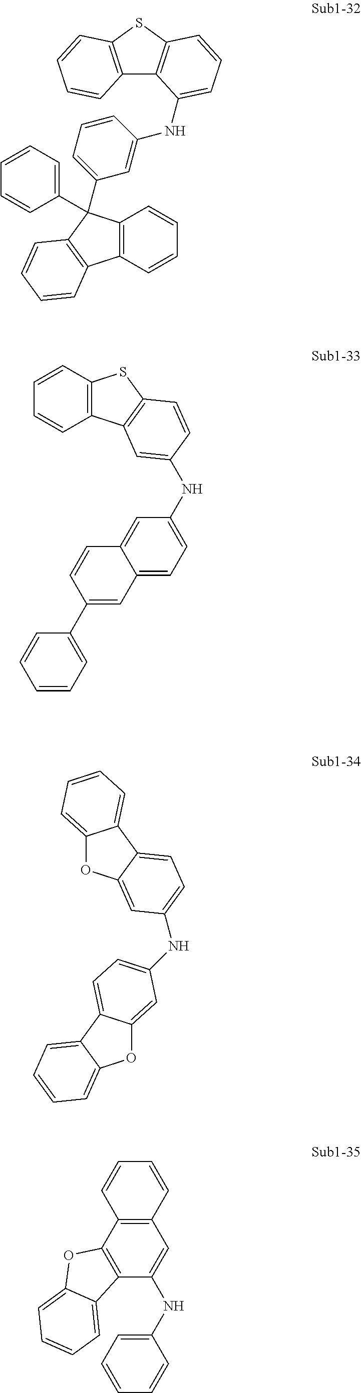 [SMILES: c1ccc(C2(c3cccc(Nc4cccc5sc6ccccc6c45)c3)c3ccccc3-c3ccccc32)cc1 ; c1ccc(-c2ccc3cc(Nc4ccc5sc6ccccc6c5c4)ccc3c2)cc1 ; c1ccc2c(c1)oc1cc(Nc3ccc4c(c3)oc3ccccc34)ccc12 ; c1ccc(Nc2cc3ccccc3c3oc4ccccc4c23)cc1]

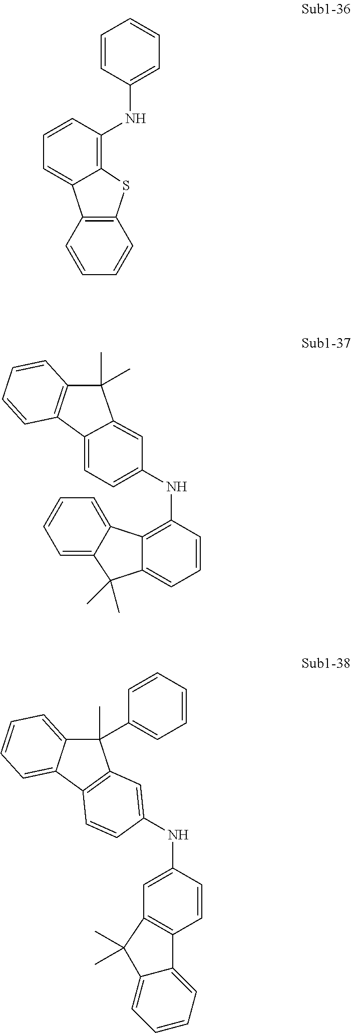 [SMILES: c1ccc(Nc2cccc3c2sc2ccccc23)cc1 ; CC1(C)c2ccccc2-c2ccc(Nc3cccc4c3-c3ccccc3C4(C)C)cc21 ; CC1(C)c2ccccc2-c2ccc(Nc3ccc4c(c3)C(C)(c3ccccc3)c3ccccc3-4)cc21]

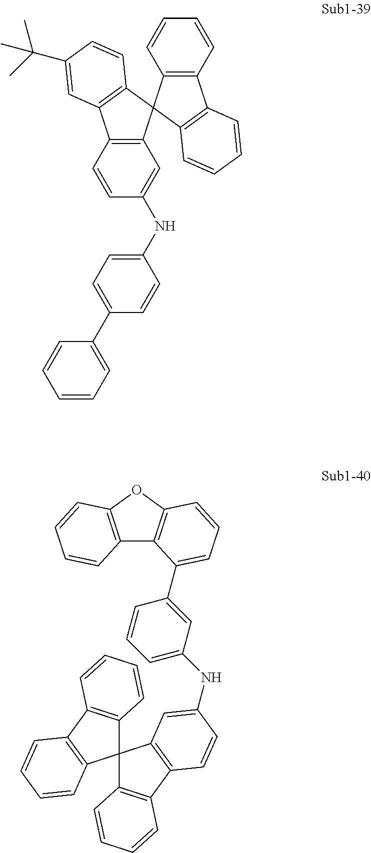 [SMILES: CC(C)(C)c1ccc2c(c1)-c1ccc(Nc3ccc(-c4ccccc4)cc3)cc1C21c2ccccc2-c2ccccc21 ; c1cc(Nc2ccc3c(c2)C2(c4ccccc4-c4ccccc42)c2ccccc2-3)cc(-c2cccc3oc4ccccc4c23)c1]

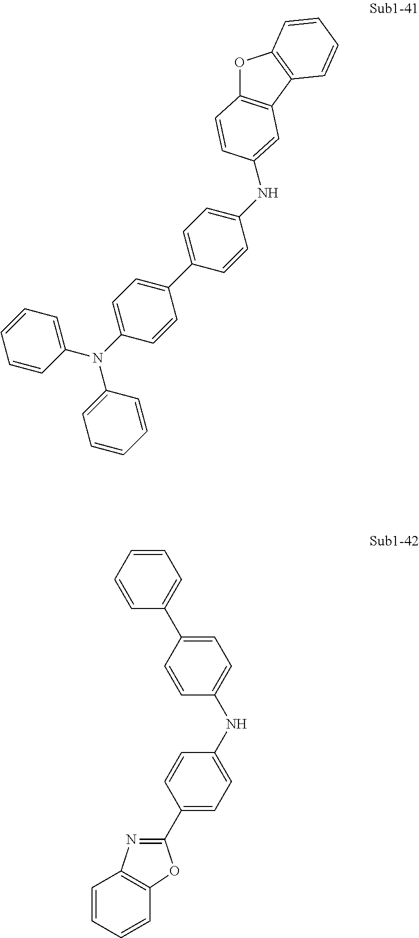 [SMILES: c1ccc(N(c2ccccc2)c2ccc(-c3ccc(Nc4ccc5oc6ccccc6c5c4)cc3)cc2)cc1 ; c1ccc(-c2ccc(Nc3ccc(-c4nc5ccccc5o4)cc3)cc2)cc1]

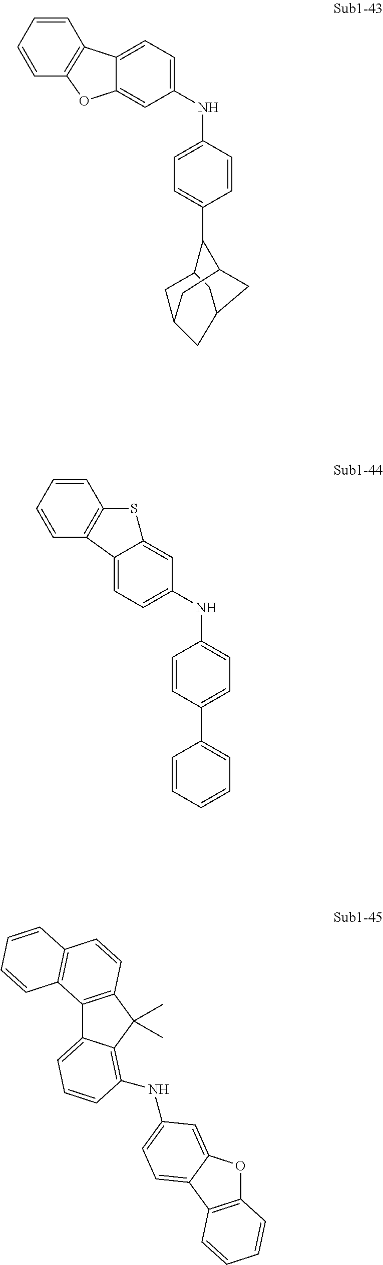 [SMILES: c1ccc2c(c1)oc1cc(Nc3ccc(C4C5CC6CC(C5)CC4C6)cc3)ccc12 ; c1ccc(-c2ccc(Nc3ccc4c(c3)sc3ccccc34)cc2)cc1 ; CC1(C)c2ccc3ccccc3c2-c2cccc(Nc3ccc4c(c3)oc3ccccc34)c21]

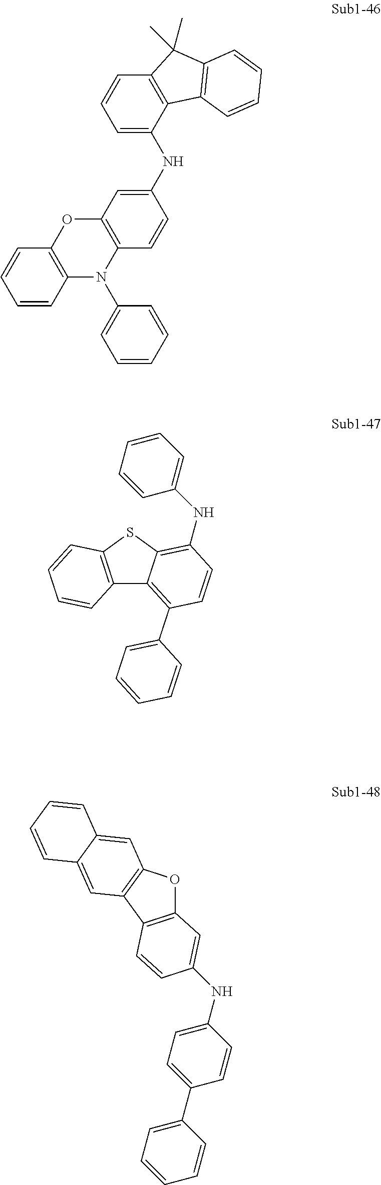 [SMILES: CC1(C)c2ccccc2-c2c(Nc3ccc4c(c3)Oc3ccccc3N4c3ccccc3)cccc21 ; c1ccc(Nc2ccc(-c3ccccc3)c3c2sc2ccccc23)cc1 ; c1ccc(-c2ccc(Nc3ccc4c(c3)oc3cc5ccccc5cc34)cc2)cc1]

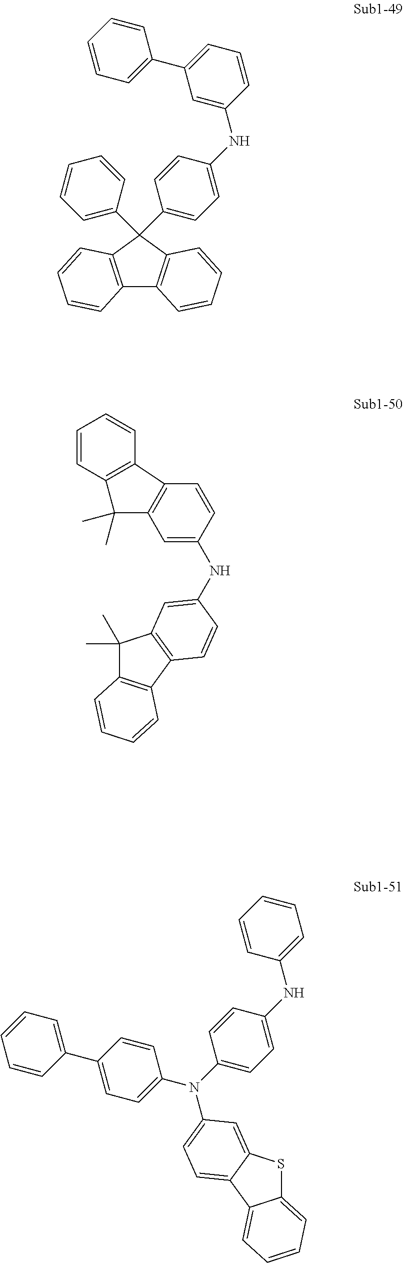 [SMILES: c1ccc(-c2cccc(Nc3ccc(C4(c5ccccc5)c5ccccc5-c5ccccc54)cc3)c2)cc1 ; CC1(C)c2ccccc2-c2ccc(Nc3ccc4c(c3)C(C)(C)c3ccccc3-4)cc21 ; c1ccc(Nc2ccc(N(c3ccc(-c4ccccc4)cc3)c3ccc4c(c3)sc3ccccc34)cc2)cc1]

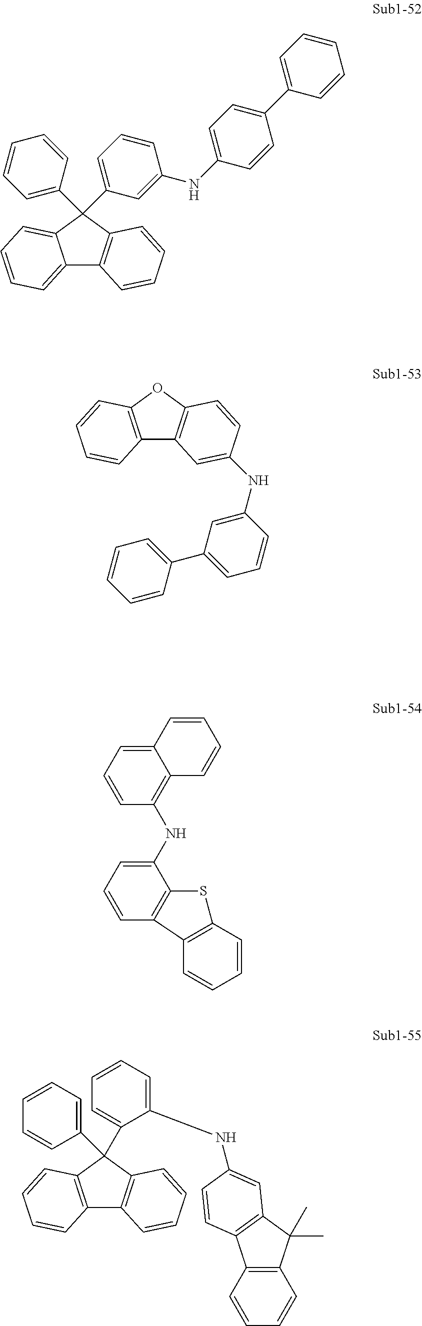 [SMILES: c1ccc(-c2ccc(Nc3cccc(C4(c5ccccc5)c5ccccc5-c5ccccc54)c3)cc2)cc1 ; c1ccc(-c2cccc(Nc3ccc4oc5ccccc5c4c3)c2)cc1 ; c1ccc2c(Nc3cccc4c3sc3ccccc34)cccc2c1 ; CC1(C)c2ccccc2-c2ccc(Nc3ccccc3C3(c4ccccc4)c4ccccc4-c4ccccc43)cc21]

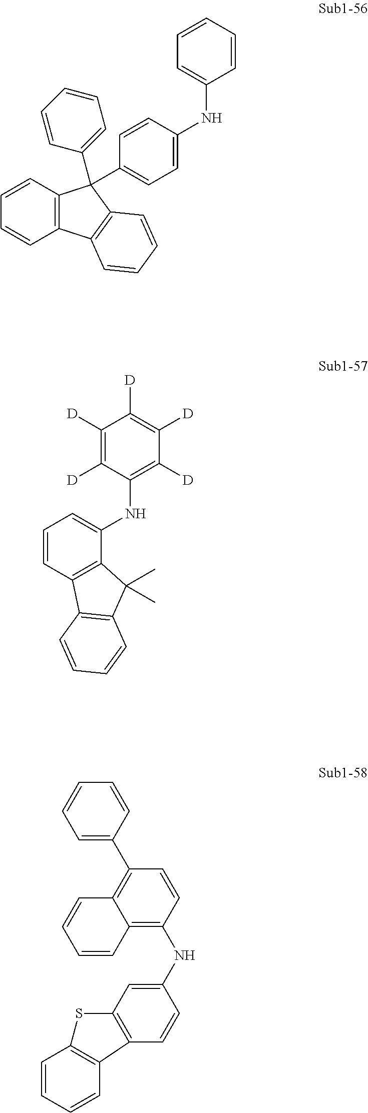 [SMILES: c1ccc(Nc2ccc(C3(c4ccccc4)c4ccccc4-c4ccccc43)cc2)cc1 ; [2H]c1c([2H])c([2H])c(Nc2cccc3c2C(C)(C)c2ccccc2-3)c([2H])c1[2H] ; c1ccc(-c2ccc(Nc3ccc4c(c3)sc3ccccc34)c3ccccc23)cc1]

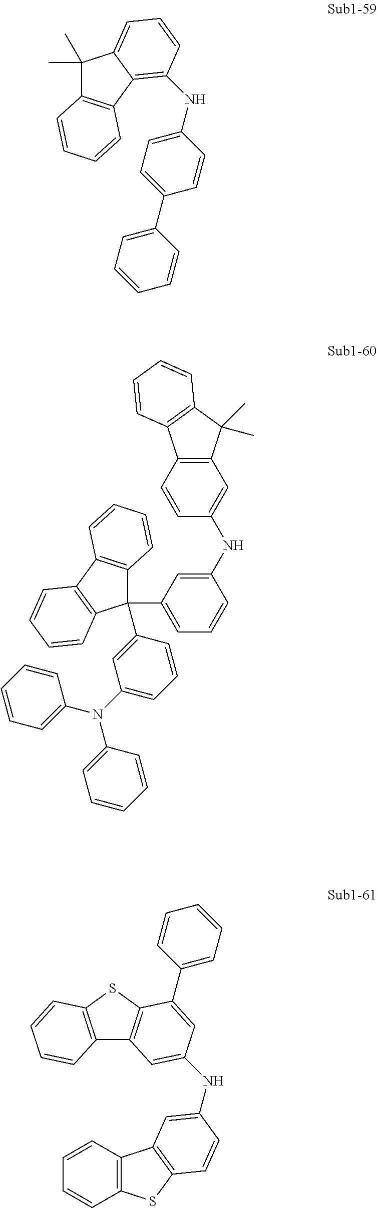 [SMILES: CC1(C)c2ccccc2-c2c(Nc3ccc(-c4ccccc4)cc3)cccc21 ; CC1(C)c2ccccc2-c2ccc(Nc3cccc(C4(c5cccc(N(c6ccccc6)c6ccccc6)c5)c5ccccc5-c5ccccc54)c3)cc21 ; c1ccc(-c2cc(Nc3ccc4sc5ccccc5c4c3)cc3c2sc2ccccc23)cc1]

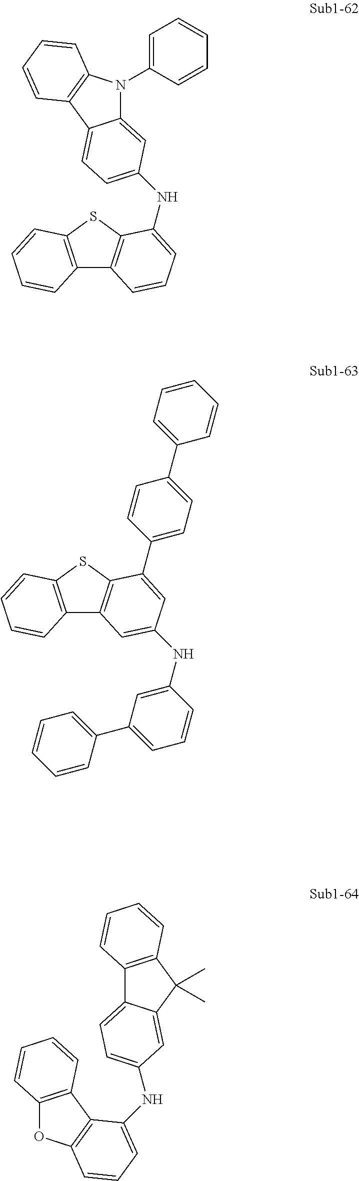 [SMILES: c1ccc(-n2c3ccccc3c3ccc(Nc4cccc5c4sc4ccccc45)cc32)cc1 ; c1ccc(-c2ccc(-c3cc(Nc4cccc(-c5ccccc5)c4)cc4c3sc3ccccc34)cc2)cc1 ; CC1(C)c2ccccc2-c2ccc(Nc3cccc4oc5ccccc5c34)cc21]

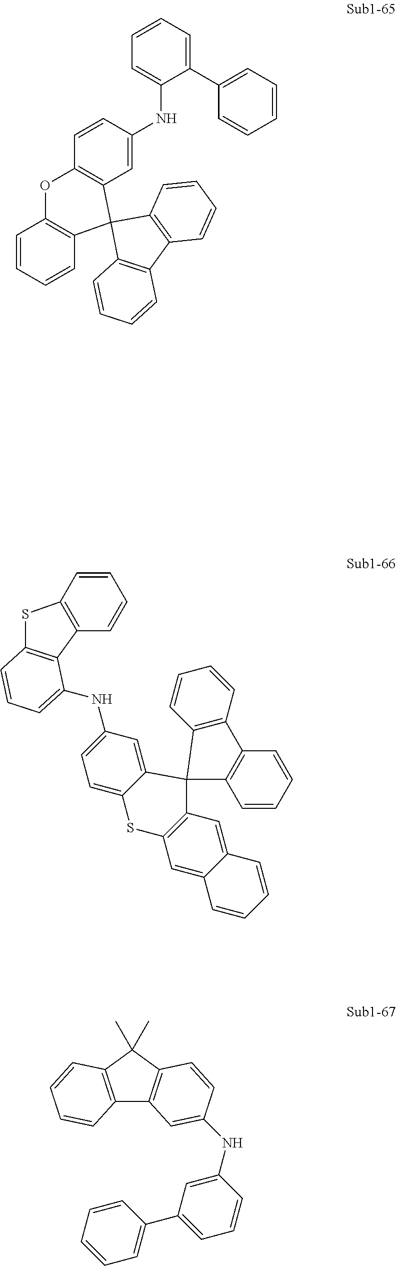 [SMILES: c1ccc(-c2ccccc2Nc2ccc3c(c2)C2(c4ccccc4O3)c3ccccc3-c3ccccc32)cc1 ; c1ccc2c(c1)-c1ccccc1C21c2cc(Nc3cccc4sc5ccccc5c34)ccc2Sc2cc3ccccc3cc21 ; CC1(C)c2ccccc2-c2cc(Nc3cccc(-c4ccccc4)c3)ccc21]

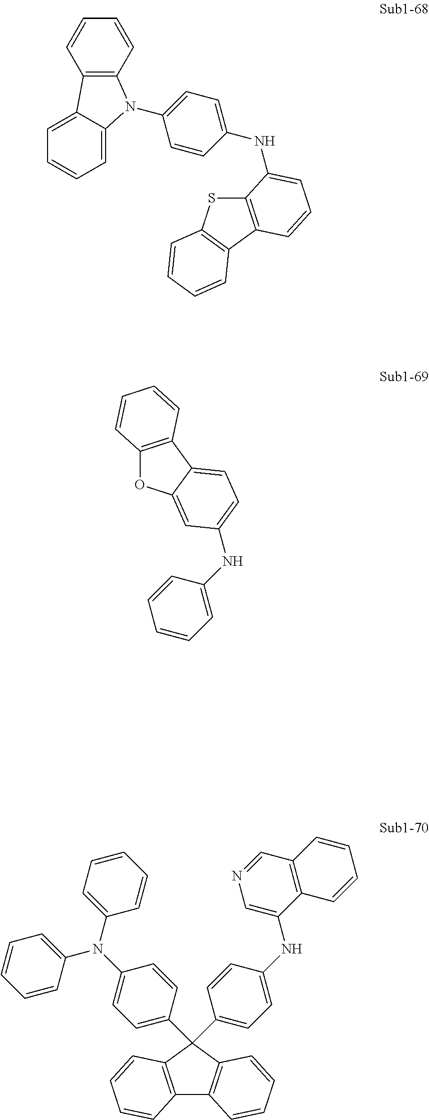 [SMILES: c1ccc2c(c1)sc1c(Nc3ccc(-n4c5ccccc5c5ccccc54)cc3)cccc12 ; c1ccc(Nc2ccc3c(c2)oc2ccccc23)cc1 ; c1ccc(N(c2ccccc2)c2ccc(C3(c4ccc(Nc5cncc6ccccc56)cc4)c4ccccc4-c4ccccc43)cc2)cc1]

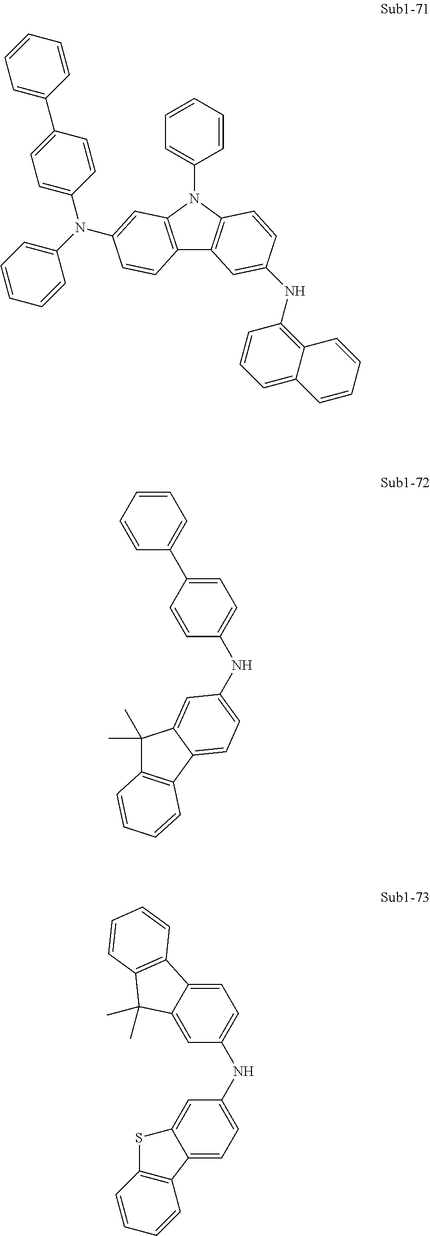 [SMILES: c1ccc(-c2ccc(N(c3ccccc3)c3ccc4c5cc(Nc6cccc7ccccc67)ccc5n(-c5ccccc5)c4c3)cc2)cc1 ; CC1(C)c2ccccc2-c2ccc(Nc3ccc(-c4ccccc4)cc3)cc21 ; CC1(C)c2ccccc2-c2ccc(Nc3ccc4c(c3)sc3ccccc34)cc21]

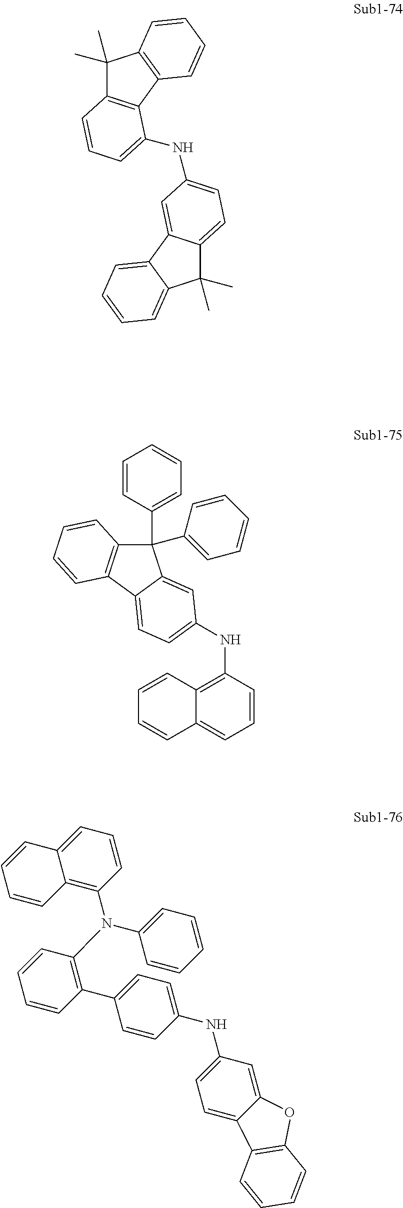

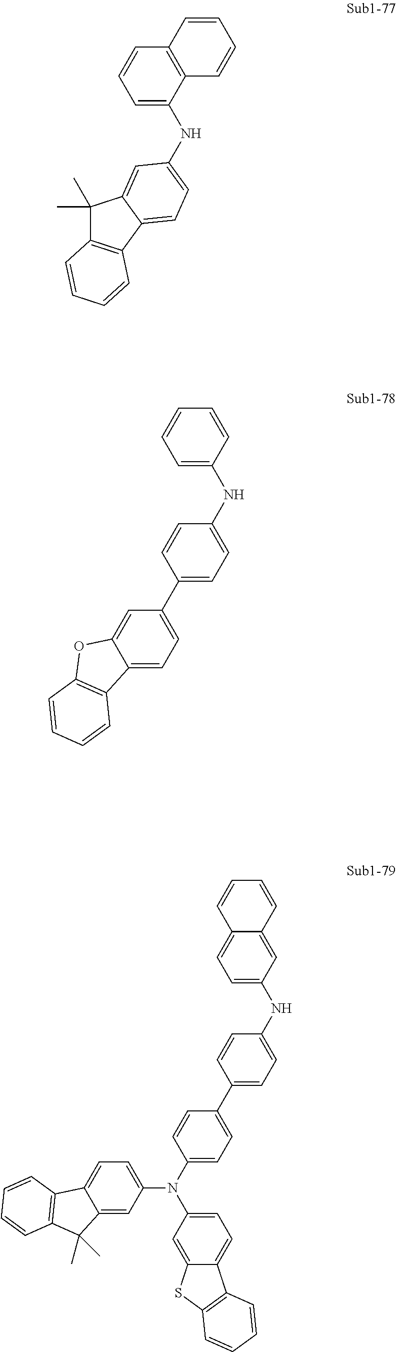 [SMILES: CC1(C)c2ccccc2-c2ccc(Nc3cccc4ccccc34)cc21 ; c1ccc(Nc2ccc(-c3ccc4c(c3)oc3ccccc34)cc2)cc1 ; CC1(C)c2ccccc2-c2ccc(N(c3ccc(-c4ccc(Nc5ccc6ccccc6c5)cc4)cc3)c3ccc4c(c3)sc3ccccc34)cc21]

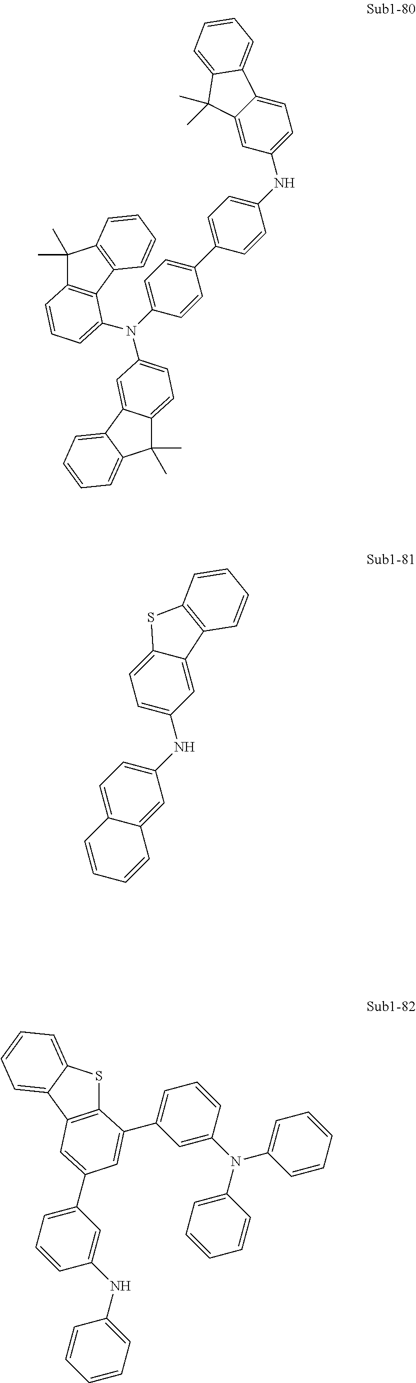 [SMILES: CC1(C)c2ccccc2-c2cc(N(c3ccc(-c4ccc(Nc5ccc6c(c5)C(C)(C)c5ccccc5-6)cc4)cc3)c3cccc4c3-c3ccccc3C4(C)C)ccc21 ; c1ccc2cc(Nc3ccc4sc5ccccc5c4c3)ccc2c1 ; c1ccc(Nc2cccc(-c3cc(-c4cccc(N(c5ccccc5)c5ccccc5)c4)c4sc5ccccc5c4c3)c2)cc1]

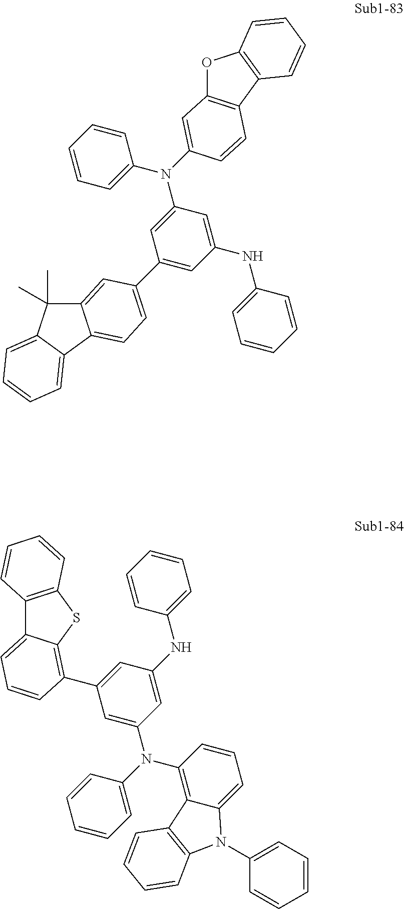 [SMILES: CC1(C)c2ccccc2-c2ccc(-c3cc(Nc4ccccc4)cc(N(c4ccccc4)c4ccc5c(c4)oc4ccccc45)c3)cc21 ; c1ccc(Nc2cc(-c3cccc4c3sc3ccccc34)cc(N(c3ccccc3)c3cccc4c3c3ccccc3n4-c3ccccc3)c2)cc1]

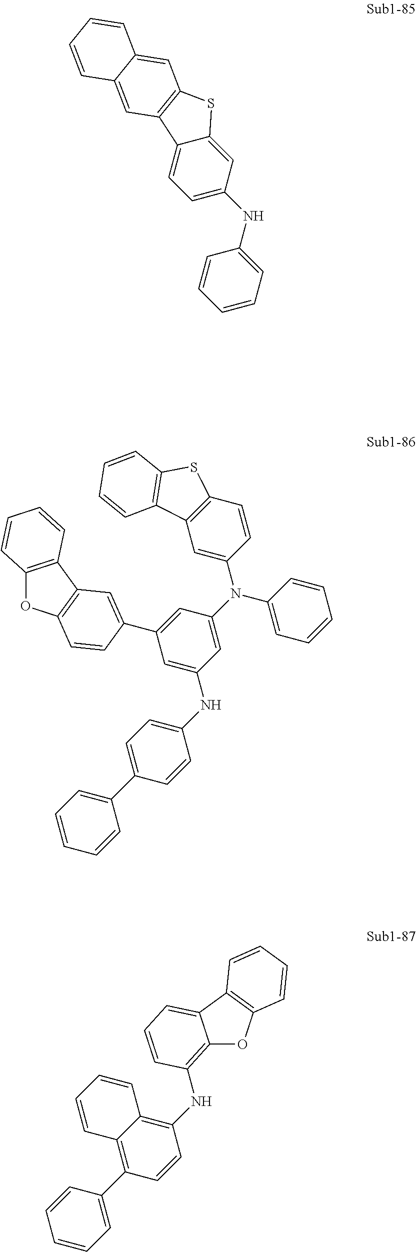 [SMILES: c1ccc(Nc2ccc3c(c2)sc2cc4ccccc4cc23)cc1 ; c1ccc(-c2ccc(Nc3cc(-c4ccc5oc6ccccc6c5c4)cc(N(c4ccccc4)c4ccc5sc6ccccc6c5c4)c3)cc2)cc1 ; c1ccc(-c2ccc(Nc3cccc4c3oc3ccccc34)c3ccccc23)cc1]

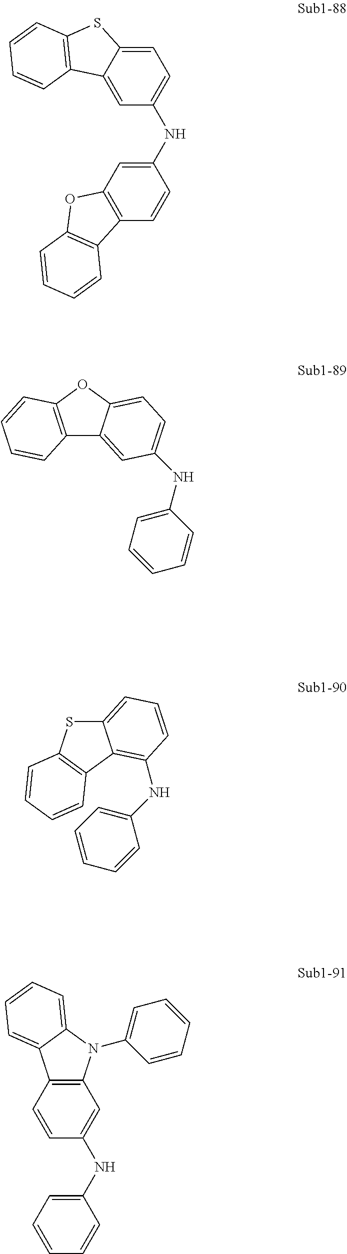 [SMILES: c1ccc2c(c1)oc1cc(Nc3ccc4sc5ccccc5c4c3)ccc12 ; c1ccc(Nc2ccc3oc4ccccc4c3c2)cc1 ; c1ccc(Nc2cccc3sc4ccccc4c23)cc1 ; c1ccc(Nc2ccc3c4ccccc4n(-c4ccccc4)c3c2)cc1]

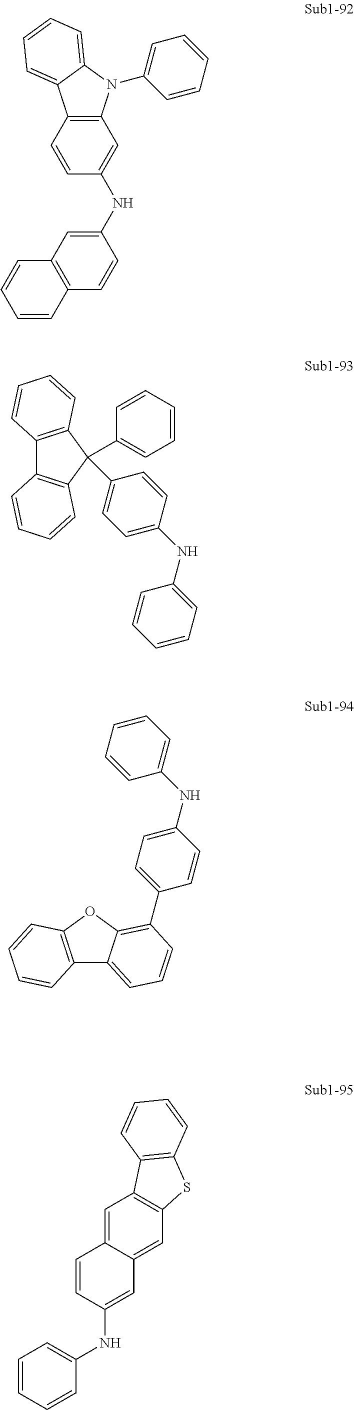 [SMILES: c1ccc(-n2c3ccccc3c3ccc(Nc4ccc5ccccc5c4)cc32)cc1 ; c1ccc(Nc2ccc(C3(c4ccccc4)c4ccccc4-c4ccccc43)cc2)cc1 ; c1ccc(Nc2ccc(-c3cccc4c3oc3ccccc34)cc2)cc1 ; c1ccc(Nc2ccc3cc4c(cc3c2)sc2ccccc24)cc1]

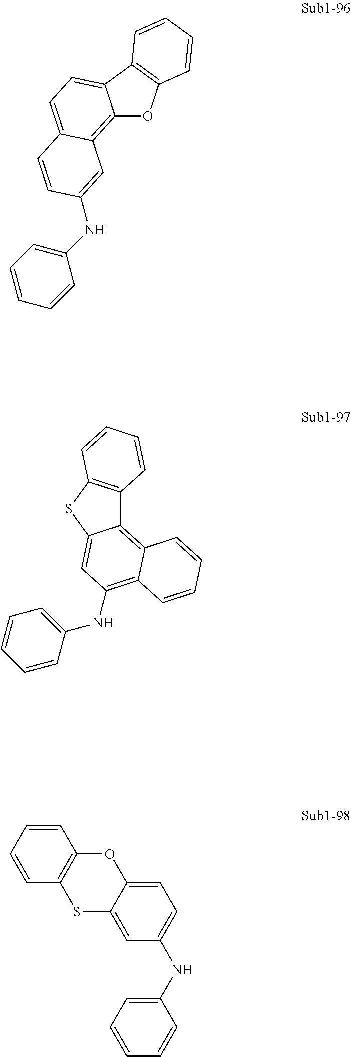 [SMILES: c1ccc(Nc2ccc3ccc4c5ccccc5oc4c3c2)cc1 ; c1ccc(Nc2cc3sc4ccccc4c3c3ccccc23)cc1 ; c1ccc(Nc2ccc3c(c2)Sc2ccccc2O3)cc1]

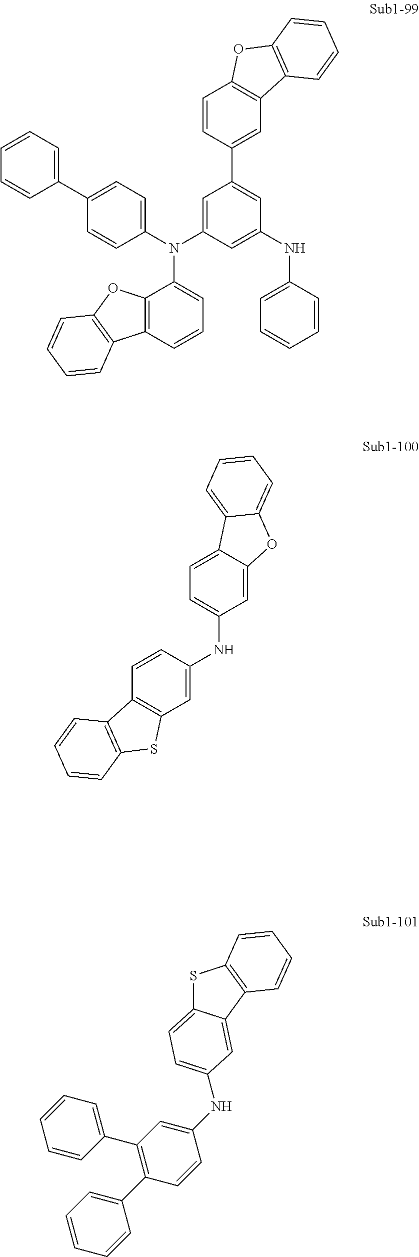 [SMILES: c1ccc(Nc2cc(-c3ccc4oc5ccccc5c4c3)cc(N(c3ccc(-c4ccccc4)cc3)c3cccc4c3oc3ccccc34)c2)cc1 ; c1ccc2c(c1)oc1cc(Nc3ccc4c(c3)sc3ccccc34)ccc12 ; c1ccc(-c2ccc(Nc3ccc4sc5ccccc5c4c3)cc2-c2ccccc2)cc1]

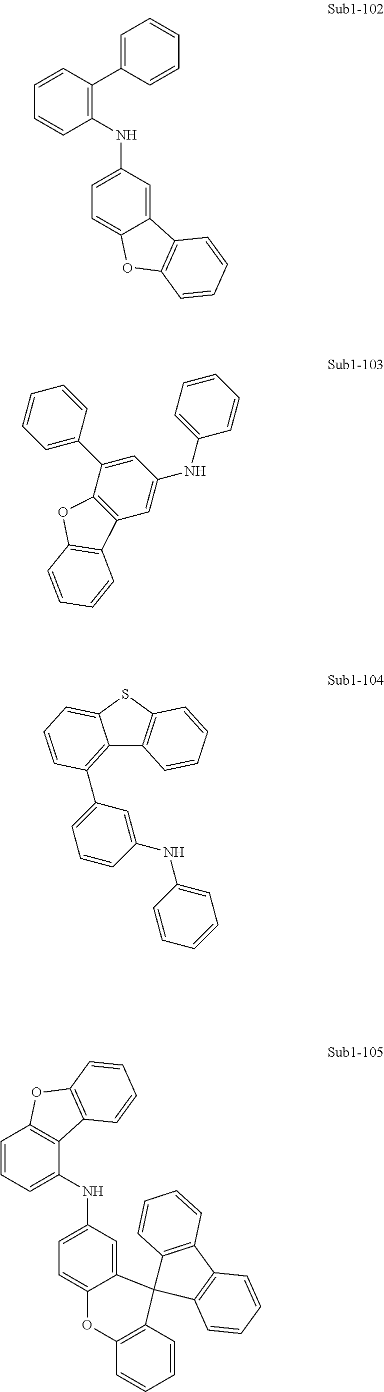 [SMILES: c1ccc(-c2ccccc2Nc2ccc3oc4ccccc4c3c2)cc1 ; c1ccc(Nc2cc(-c3ccccc3)c3oc4ccccc4c3c2)cc1 ; c1ccc(Nc2cccc(-c3cccc4sc5ccccc5c34)c2)cc1 ; c1ccc2c(c1)Oc1ccc(Nc3cccc4oc5ccccc5c34)cc1C21c2ccccc2-c2ccccc21]

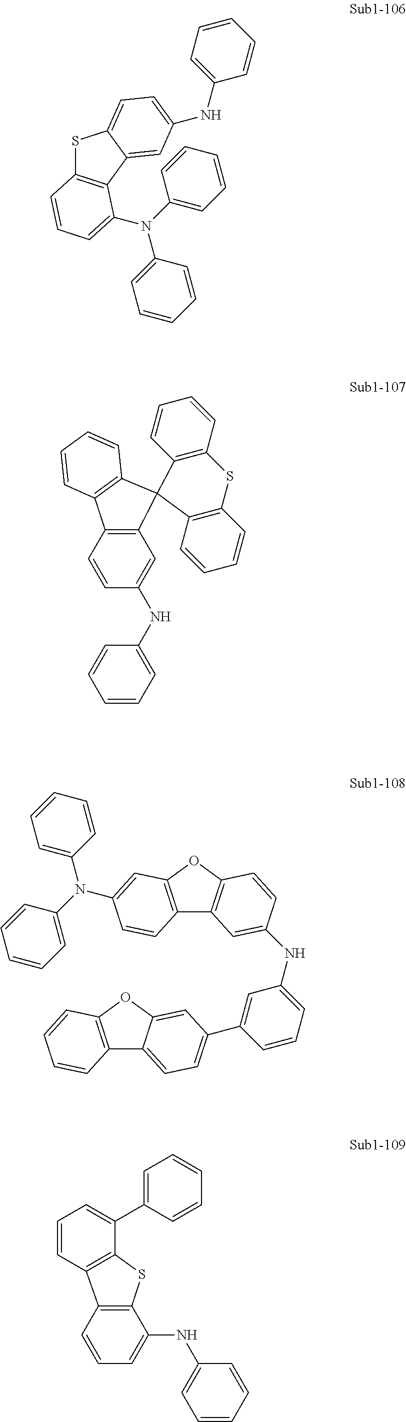 [SMILES: c1ccc(Nc2ccc3sc4cccc(N(c5ccccc5)c5ccccc5)c4c3c2)cc1 ; c1ccc(Nc2ccc3c(c2)C2(c4ccccc4Sc4ccccc42)c2ccccc2-3)cc1 ; c1ccc(N(c2ccccc2)c2ccc3c(c2)oc2ccc(Nc4cccc(-c5ccc6c(c5)oc5ccccc56)c4)cc23)cc1 ; c1ccc(Nc2cccc3c2sc2c(-c4ccccc4)cccc23)cc1]

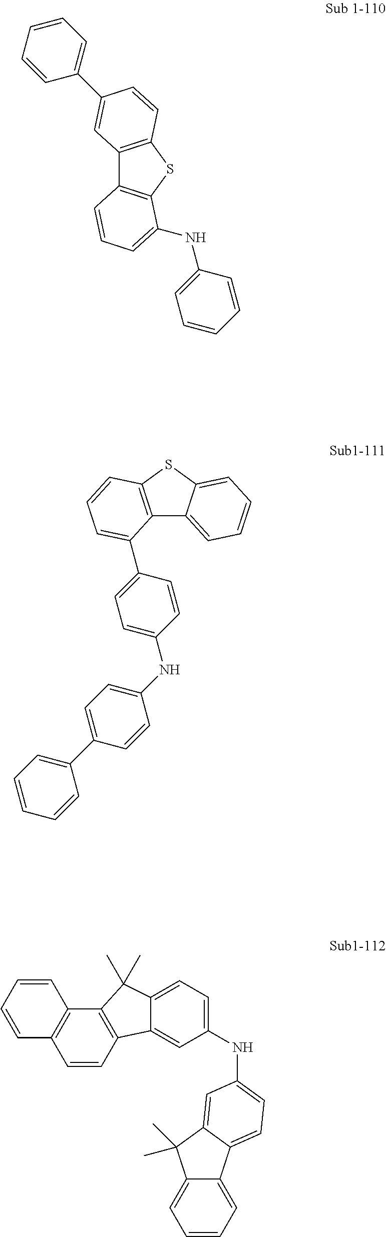 [SMILES: c1ccc(Nc2cccc3c2sc2ccc(-c4ccccc4)cc23)cc1 ; c1ccc(-c2ccc(Nc3ccc(-c4cccc5sc6ccccc6c45)cc3)cc2)cc1 ; CC1(C)c2ccccc2-c2ccc(Nc3ccc4c(c3)-c3ccc5ccccc5c3C4(C)C)cc21]

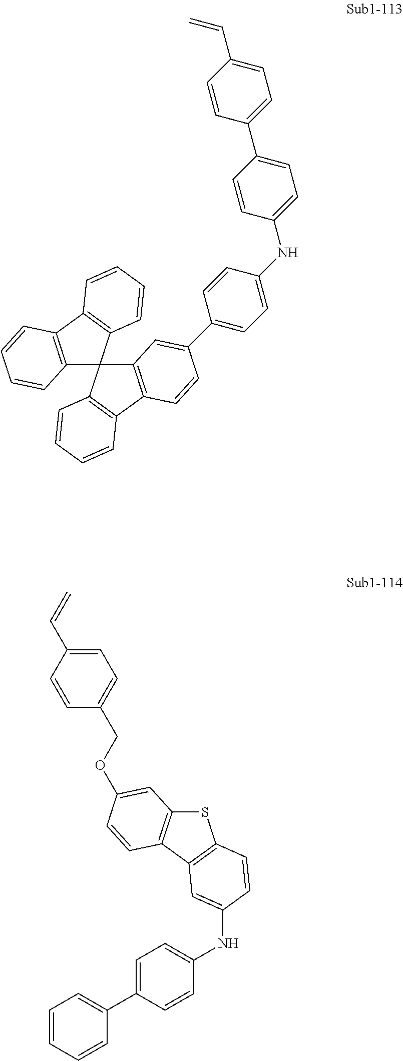 [SMILES: C=Cc1ccc(-c2ccc(Nc3ccc(-c4ccc5c(c4)C4(c6ccccc6-c6ccccc64)c4ccccc4-5)cc3)cc2)cc1 ; C=Cc1ccc(COc2ccc3c(c2)sc2ccc(Nc4ccc(-c5ccccc5)cc4)cc23)cc1]

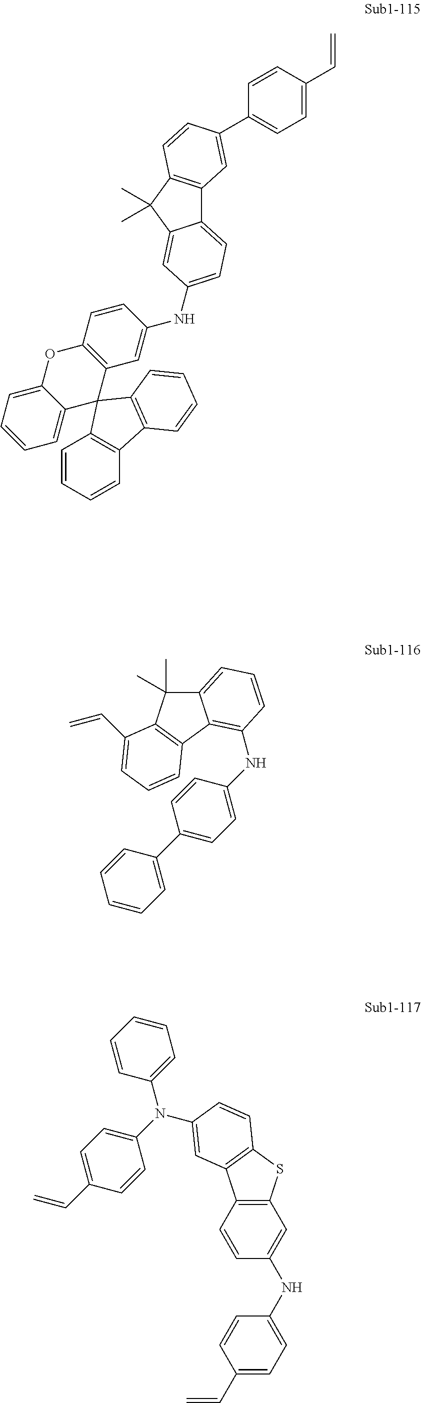

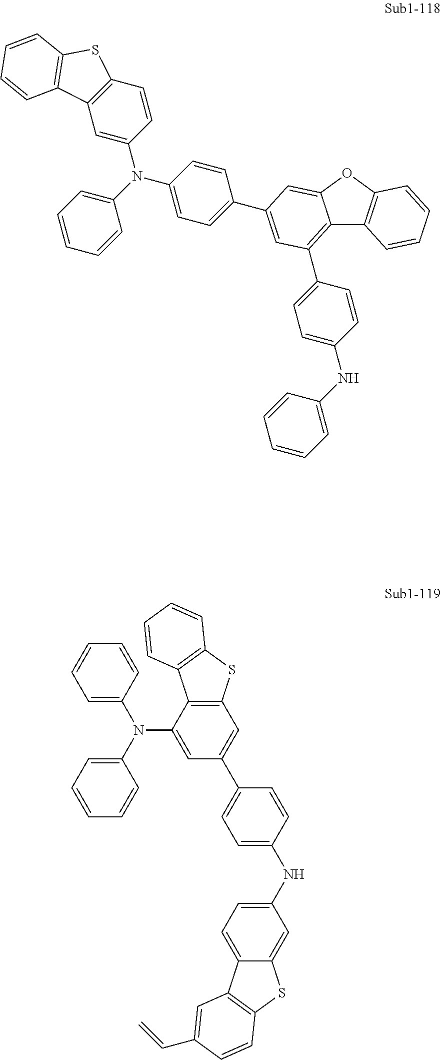 [SMILES: c1ccc(Nc2ccc(-c3cc(-c4ccc(N(c5ccccc5)c5ccc6sc7ccccc7c6c5)cc4)cc4oc5ccccc5c34)cc2)cc1 ; C=Cc1ccc2sc3cc(Nc4ccc(-c5cc(N(c6ccccc6)c6ccccc6)c6c(c5)sc5ccccc56)cc4)ccc3c2c1]

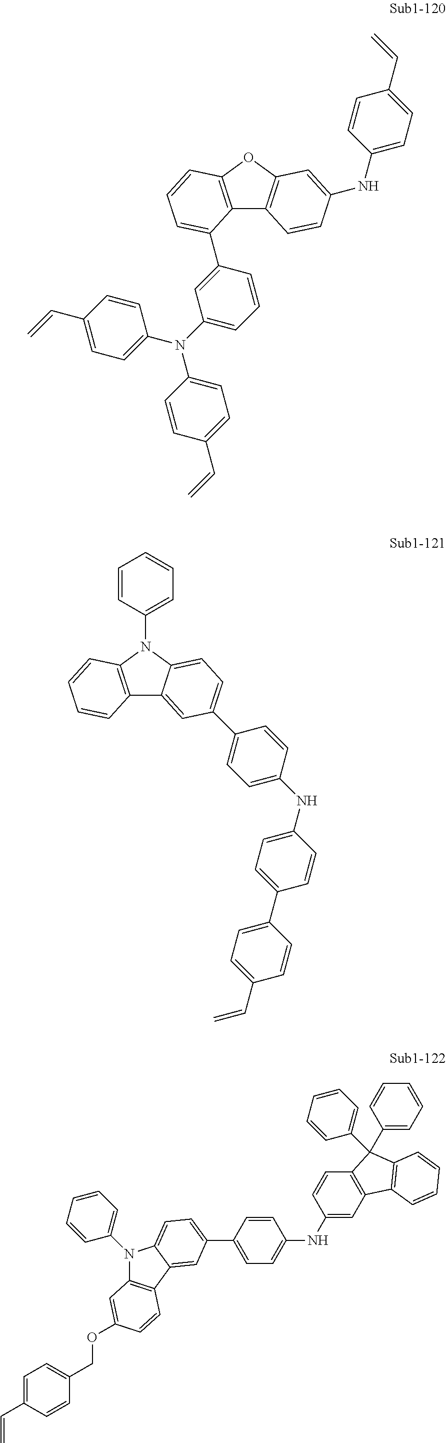 [SMILES: C=Cc1ccc(Nc2ccc3c(c2)oc2cccc(-c4cccc(N(c5ccc(C=C)cc5)c5ccc(C=C)cc5)c4)c23)cc1 ; C=Cc1ccc(-c2ccc(Nc3ccc(-c4ccc5c(c4)c4ccccc4n5-c4ccccc4)cc3)cc2)cc1 ; C=Cc1ccc(COc2ccc3c4cc(-c5ccc(Nc6ccc7c(c6)-c6ccccc6C7(c6ccccc6)c6ccccc6)cc5)ccc4n(-c4ccccc4)c3c2)cc1]

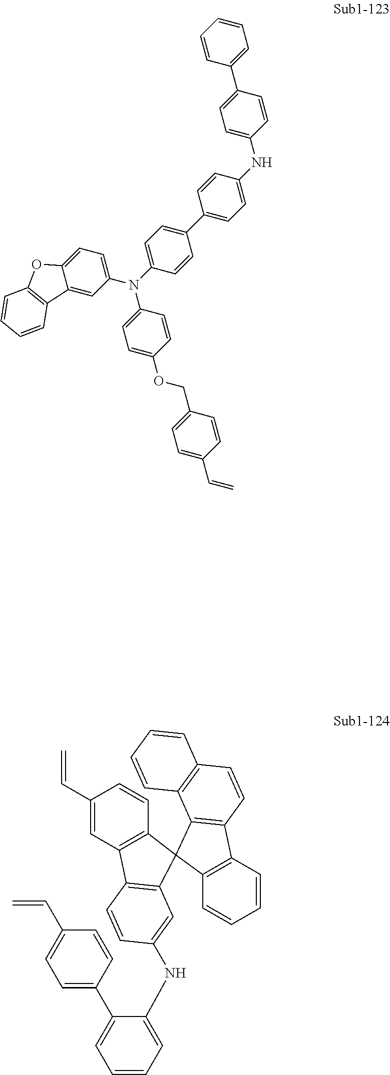 [SMILES: C=Cc1ccc(COc2ccc(N(c3ccc(-c4ccc(Nc5ccc(-c6ccccc6)cc5)cc4)cc3)c3ccc4oc5ccccc5c4c3)cc2)cc1 ; C=Cc1ccc(-c2ccccc2Nc2ccc3c(c2)C2(c4ccc(C=C)cc4-3)c3ccccc3-c3ccc4ccccc4c32)cc1]

Table 1 below shows the Field Desorption-Mass Spectrometry (FD-MS) values of compounds belonging to Sub 1.

TABLE 1

| Compound | FD-MS | Compound | FD-MS |
|---|---|---|---|
| Sub1-1 | m/z = 335.13(C24H17NO = 335.41) | Sub1-2 | m/z = 385.15(C28H19NO = 385.47) |
| Sub1-3 | m/z = 485.21(C37H27N = 485.63) | Sub1-4 | m/z = 375.11(C26H17NS = 375.49) |
| Sub1-5 | m/z = 562.24(C42H30N2-562.72) | Sub1-6 | m/z = 459.16(C34H21NO = 459.55) |
| Sub1-7 | m/z = 451.14(C32H21NS = 451.59) | Sub1-8 | m/z = 411.16(C30H21NO = 411.50) |
| Sub1-9 | m/z = 351.11(C24H17NS = 351.47) | Sub1-10 | m/z = 419.11(C28H18FNS = 419.52) |
| Sub1-11 | m/z = 381.06(C24H15NS2 = 381.51) | Sub1-12 | m/z = 425.18(C31H23NO = 425.53) |
| Sub1-13 | m/z = 483.20(C37H25N = 483.61) | Sub1-14 | m/z = 411.16(C30H21NO = 411.50) |
| Sub1-15 | m/z = 385.15(C28H19NO = 385.47) | Sub1-16 | m/z = 563.22(C42H29NO = 563.70) |
| Sub1-17 | m/z = 411.20(C31H25N = 411.55) | Sub1-18 | m/z = 561.25(C43H31N = 561.73) |
| Sub1-19 | m/z = 410.18(C30H22N2 = 410.52) | Sub1-20 | m/z = 566.18(C40H26N2S = 566.72) |
| Sub1-21 | m/z = 361.18(C27H23N = 361.49) | Sub1-22 | m/z = 485.21(C37H27N = 485.63) |
| Sub1-23 | m/z = 483.20(C37H25N = 483.61) | Sub1-24 | m/z = 452.15(C31H20N2O2 = 452.51) |
| Sub1-25 | m/z = 410.18(C30H22N2 = 410.52) | Sub1-26 | m/z = 335.13(C24H17NO = 335.41) |
| Sub1-27 | m/z = 542.24(C39H30N2O = 542.68) | Sub1-28 | m/z = 469.19(C33H27NS = 469.65) |
| Sub1-29 | m/z = 425.18(C31H23NO = 425.53) | Sub1-30 | m/z = 371.17(C28H21N = 371.48) |
| Sub1-31 | m/z = 411.20(C31H25N = 411.55) | Sub1-32 | m/z = 515.17(C37H25NS = 515.67) |
| Sub1-33 | m/z = 401.12(C28H19NS = 401.53) | Sub1-34 | m/z = 349.11(C24H15NO2 = 349.39) |
| Sub1-35 | m/z = 309.12(C22H15NO = 309.37) | Sub1-36 | m/z = 275.08(C18H13NS = 275.37) |
| Sub1-37 | m/z = 401.21(C30H27N = 401.55) | Sub1-38 | m/z = 463.23(C35H29N = 463.62) |
| Sub1-39 | m/z = 539.26(C41H33N = 539.72) | Sub1-40 | m/z = 573.21(C43H27NO = 573.70) |
| Sub1-41 | m/z = 502.20(C36H26N2O = 502.62) | Sub1-42 | m/z = 362.14(C25H18N2O = 362.43) |
| Sub1-43 | m/z = 393.21(C28H27NO = 393.53) | Sub1-44 | m/z = 351.11(C24H17NS = 351.47) |
| Sub1-45 | m/z = 425.18(C31H23NO = 425.53) | Sub1-46 | m/z = 466.20(C33H26N2O = 466.58) |
| Sub1-47 | m/z = 351.11(C24H17NS = 351.47) | Sub1-48 | m/z = 385.15(C28H19NO = 385.47) |
| Sub1-49 | m/z = 485.21(C37H27N = 485.63) | Sub1-50 | m/z = 401.21(C30H27N = 401.55) |
| Sub1-51 | m/z = 518.18(C36H26N2S = 518.68) | Sub1-52 | m/z = 485.21(C37H27N = 485.63) |
| Sub1-53 | m/z = 335.13(C24H17NO = 335.41) | Sub1-54 | m/z = 325.09(C22H15NS = 325.43) |
| Sub1-55 | m/z = 525.25(C40H31N = 525.70) | Sub1-56 | m/z = 409.18(C31H23N = 409.53) |
| Sub1-57 | m/z = 290.18(C21H14D5N = 290.42) | Sub1-58 | m/z = 401.12(C28H19NS = 401.53) |
| Sub1-59 | m/z = 361.18(C27H23N = 361.49) | Sub1-60 | m/z = 692.32(C52H40N2 = 692.91) |
| Sub1-61 | m/z = 457.10(C30H19NS2 = 457.61) | Sub1-62 | m/z = 440.13(C30H20N2S = 440.56) |
| Sub1-63 | m/z = 503.17(C36H25NS = 503.66) | Sub1-64 | m/z = 375.16(C27H21NO = 375.47) |
| Sub1-65 | m/z = 499.19(C37H25NO = 499.61) | Sub1-66 | m/z = 595.14(C41H25NS2 = 595.78) |
| Sub1-67 | m/z = 361.18(C27H23N = 361.49) | Sub1-68 | m/z = 440.13(C30H20N2S = 440.56) |
| Sub1-69 | m/z = 259.10(C18H13NO = 259.31) | Sub1-70 | m/z = 627.27(C46H33N3 = 627.79) |
| Sub1-71 | m/z = 627.27(C46H33N3 = 627.79) | Sub1-72 | m/z = 361.18(C27H23N = 361.49) |
| Sub1-73 | m/z = 391.14(C27H21NS = 391.53) | Sub1-74 | m/z = 401.21(C30H27N = 401.55) |
| Sub1-75 | m/z = 459.20(C35H25N = 459.59) | Sub1-76 | m/z = 552.22(C40H28N2O = 552.68) |
| Sub1-77 | m/z = 335.17(C25H21N = 335.45) | Sub1-78 | m/z = 335.13(C24H17NO = 335.41) |
| Sub1-79 | m/z = 684.26(C49H36N2S = 684.90) | Sub1-80 | m/z = 760.38(C57H48N2 = 761.03) |
| Sub1-81 | m/z = 325.09(C22H15NS = 325.43) | Sub1-82 | m/z = 594.21(C42H30N2S = 594.78) |
| Sub1-83 | m/z = 618.27(C45H34N2O = 618.78) | Sub1-84 | m/z = 683.24(C48H33N3S = 683.87) |
| Sub1-85 | m/z = 325.09(C22H15NS = 325.43) | Sub1-86 | m/z = 684.22(C48H32N2OS = 684.86) |
| Sub1-87 | m/z = 385.15(C28H19NO = 385.47) | Sub1-88 | m/z = 365.09(C24H15NOS = 365.45) |
| Sub1-89 | m/z = 259.10(C18H13NO = 259.31) | Sub1-90 | m/z = 275.08(C18H13NS = 275.37) |
| Sub1-91 | m/z = 334.15(C24H18N2 = 334.42) | Sub1-92 | m/z = 384.16(C28H20N2 = 384.48) |
| Sub1-93 | m/z = 409.18(C31H23N = 409.53) | Sub1-94 | m/z = 335.13(C24H17NO = 335.41) |
| Sub1-95 | m/z = 325.09(C22H15NS = 325.43) | Sub1-96 | m/z = 309.12(C22H15NO = 309.37) |
| Sub1-97 | m/z = 325.09(C22H15NS = 325.43) | Sub1-98 | m/z = 291.07(C18H13NOS = 291.37) |
| Sub1-99 | m/z = 668.25(C48H32N2O2 = 668.80) | Sub1-100 | m/z = 365.09(C24H15NOS = 365.45) |
| Sub1-101 | m/z = 427.14(C30H21NS = 427.57) | Sub1-102 | m/z = 335.13(C24H17NO = 335.41) |
| Sub1-103 | m/z = 335.13(C24H17NO = 335.41) | Sub1-104 | m/z = 351.11(C24H17NS = 351.47) |
| Sub1-105 | m/z = 513.17(C37H23NO2 = 513.60) | Sub1-106 | m/z = 442.15(C30H22N2S = 442.58) |
| Sub1-107 | m/z = 439.14(C31H21NS = 439.58) | Sub1-108 | m/z = 592.22(C42H28N2O2 = 592.70) |
| Sub1-109 | m/z = 351.11(C24H17NS = 351.47) | Sub1-110 | m/z = 351.11(C24H17NS = 351.47) |
| Sub1-111 | m/z = 427.14(C30H21NS = 427.57) | Sub1-112 | m/z = 451.23(C34H29N = 451.61) |
| Sub1-113 | m/z = 585.25(C45H31N = 585.75) | Sub1-114 | m/z = 483.17(C33H25NOS = 483.63) |
| Sub1-115 | m/z = 641.27(C48H35NO = 641.81) | Sub1-116 | m/z = 387.20(C29H25N = 387.53) |
| Sub1-117 | m/z = 494.18(C34H26N2S = 494.66) | Sub1-118 | m/z = 684.22(C48H32N2OS = 684.86) |
| Sub1-119 | m/z = 650.19(C44H30N2S2 = 650.86) | Sub1-120 | m/z = 580.25(C42H32N2O = 580.73) |
| Sub1-121 | m/z = 512.23(C38H28N2 = 512.66) | Sub1-122 | m/z = 782.33(C58H42N2O = 782.99) |
| Sub1-123 | m/z = 710.29(C51H38N2O2 = 710.88) | Sub1-124 | m/z = 585.25(C45H31N = 585.75) |

### 2. Synthesis of Sub 2

Sub 2 of Reaction Scheme 1 may be synthesized through the reaction routes of Reaction Schemes 3-1 and 3-2 below, but is not limited thereto. (Hal and Hal¹=Br, I, or Cl)

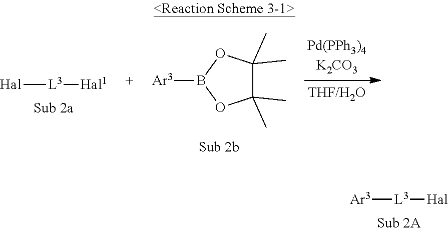

However, when Ar3 is −L′-N(Ra)(Rb), the compound may be synthesized through the reaction route of Reaction Scheme 3-2 below, but is not limited thereto.

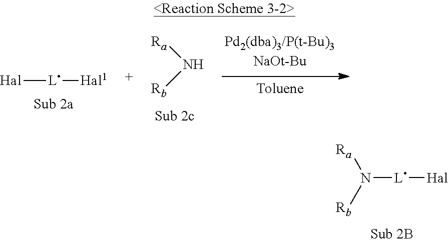

Synthesis examples of specific compounds belonging to Sub 2 are as follows.

### 1) Synthesis Example of Sub 2-6

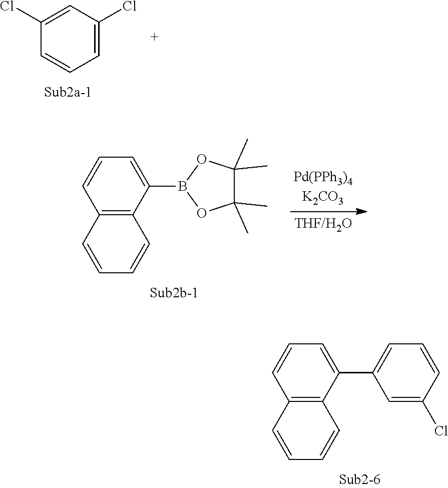 [SMILES: Clc1cccc(Cl)c1 ; CC1(C)OB(c2cccc3ccccc23)OC1(C)C ; Clc1cccc(-c2cccc3ccccc23)c1]

After dissolving Sub 2a-1 (9.6 g, 65.3 mmol) in THF (140 mL) in around bottom flask, Sub 2b-1 (16.6 g, 65.3 mmol), Pd(PPh₃)₄ (3.8 g, 3.3 mmol), K₂CO₃ (27.1 g, 195.9 mmol), and water (70 mL) were added thereto and stirred at 80° C. Upon completion of the reaction, the resultant was extracted with CH₂Cl₂ and water, and the organic layer was dried over MgSO₄ and concentrated, and the resulting compound was subjected to a silica gel column and recrystallized to obtain 10.6 g of the product (yield: 68%).

### 2) Synthesis Example of Sub 2-28

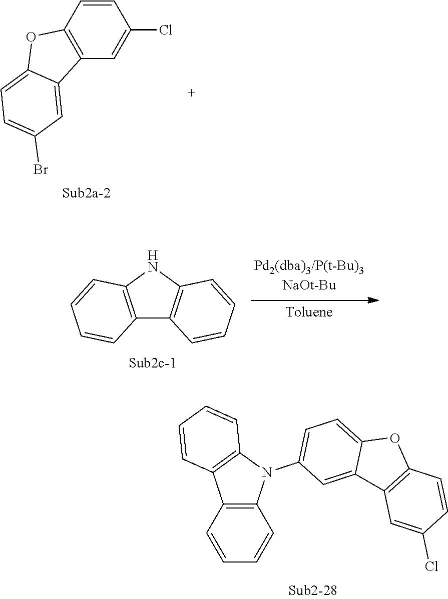 [SMILES: Clc1ccc2oc3ccc(Br)cc3c2c1 ; c1ccc2c(c1)[nH]c1ccccc12 ; Clc1ccc2oc3ccc(-n4c5ccccc5c5ccccc54)cc3c2c1]

Sub 2a-2 (10.0 g, 35.5 mmol), Sub 2c-1 (5.9 g, 35.5 mmol), Pd₂(dba)₃ (1.0 g, 1.1 mmol), P(t-Bu)₃ (50 wt % Sol.) (1.4 mL, 3.6 mmol), NaOt-Bu (10.2 g, 106.6 mmol), and toluene (200 mL) were added into a round bottom flask and stirred at 80° C. Upon completion of the reaction, the resultant was extracted with CH₂Cl₂ and water, and the organic layer was dried over MgSO₄ and concentrated, and the resulting compound was recrystallized using a silica gel column to obtain 10.3 g of the product (yield: 79%).

### 2) Synthesis Example of Sub 2-91

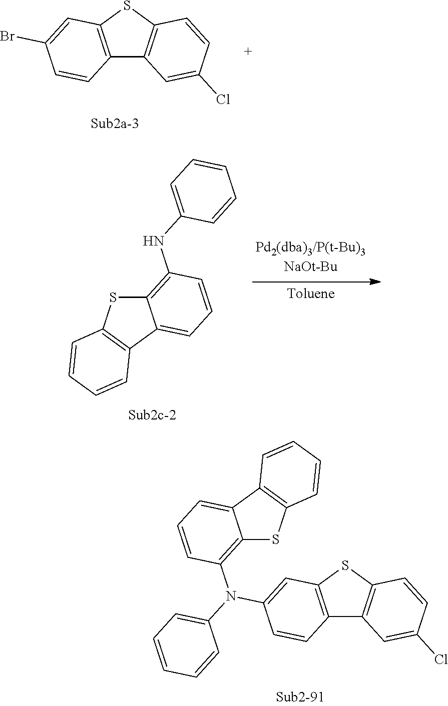 [SMILES: Clc1ccc2sc3cc(Br)ccc3c2c1 ; c1ccc(Nc2cccc3c2sc2ccccc23)cc1 ; Clc1ccc2sc3cc(N(c4ccccc4)c4cccc5c4sc4ccccc45)ccc3c2c1]

Sub 2a-3 (11.7 g, 39.3 mmol), Sub 2c-2 (10.8 g, 39.3 mmol), Pd₂(dba)₃ (1.1 g, 1.2 mmol), P(t-Bu)₃ (50 wt % Sol.) (1.6 mL, 3.4 mmol), NaOt-Bu (11.3 g, 117.95 mmol), and toluene (250 mL) were added into around bottom flask and stirred at 80° C. Upon completion of the reaction, the resultant was extracted with CH₂Cl₂ and water, and the organic layer was dried over MgSO₄ and concentrated, and the resulting compound was recrystallized using a silica gel column to obtain 15.4 g of the product (yield: 80%).

Meanwhile, the compounds belonging to Sub 2 may be the following compounds, but are not limited thereto.

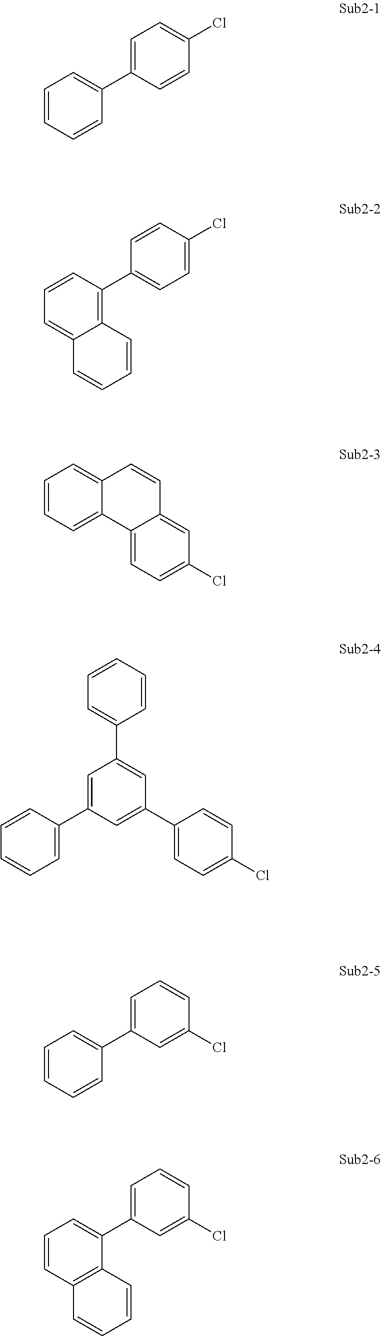 [SMILES: Clc1ccc(-c2ccccc2)cc1 ; Clc1ccc(-c2cccc3ccccc23)cc1 ; Clc1ccc2c(ccc3ccccc32)c1 ; Clc1ccc(-c2cc(-c3ccccc3)cc(-c3ccccc3)c2)cc1 ; Clc1cccc(-c2ccccc2)c1 ; Clc1cccc(-c2cccc3ccccc23)c1]

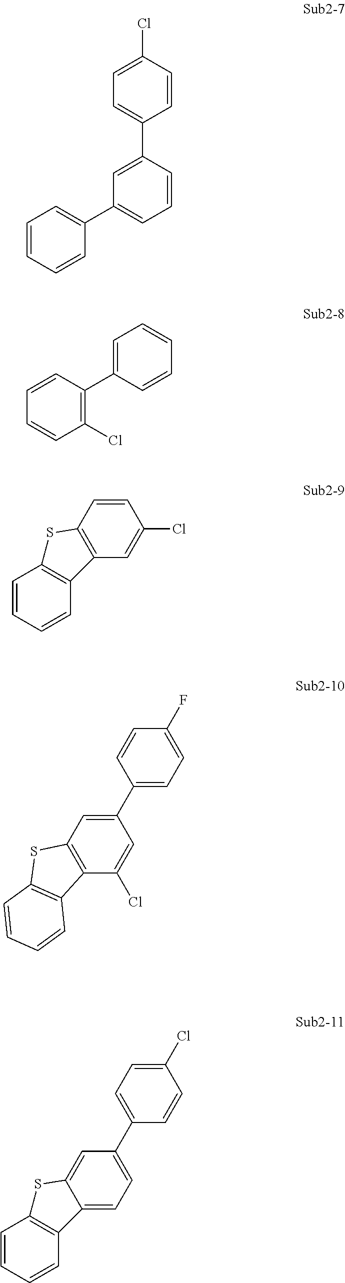 [SMILES: Clc1ccc(-c2cccc(-c3ccccc3)c2)cc1 ; Clc1ccccc1-c1ccccc1 ; Clc1ccc2sc3ccccc3c2c1 ; Fc1ccc(-c2cc(Cl)c3c(c2)sc2ccccc23)cc1 ; Clc1ccc(-c2ccc3c(c2)sc2ccccc23)cc1]

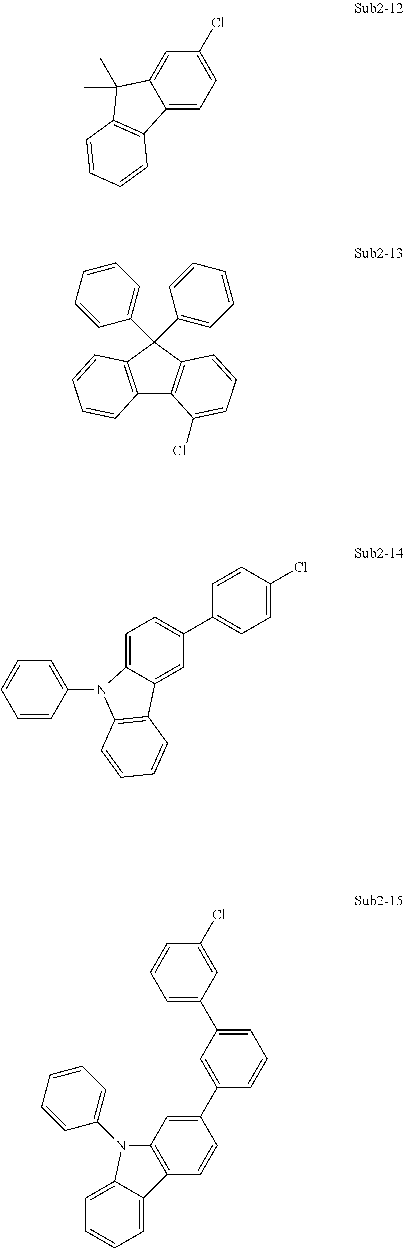 [SMILES: CC1(C)c2ccccc2-c2ccc(Cl)cc21 ; Clc1cccc2c1-c1ccccc1C2(c1ccccc1)c1ccccc1 ; Clc1ccc(-c2ccc3c(c2)c2ccccc2n3-c2ccccc2)cc1 ; Clc1cccc(-c2cccc(-c3ccc4c5ccccc5n(-c5ccccc5)c4c3)c2)c1]

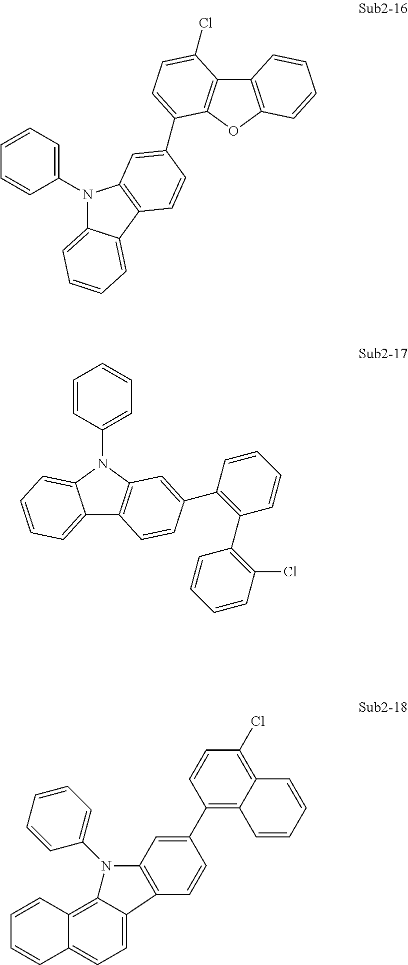 [SMILES: Clc1ccc(-c2ccc3c4ccccc4n(-c4ccccc4)c3c2)c2oc3ccccc3c12 ; Clc1ccccc1-c1ccccc1-c1ccc2c3ccccc3n(-c3ccccc3)c2c1 ; Clc1ccc(-c2ccc3c4ccc5ccccc5c4n(-c4ccccc4)c3c2)c2ccccc12]

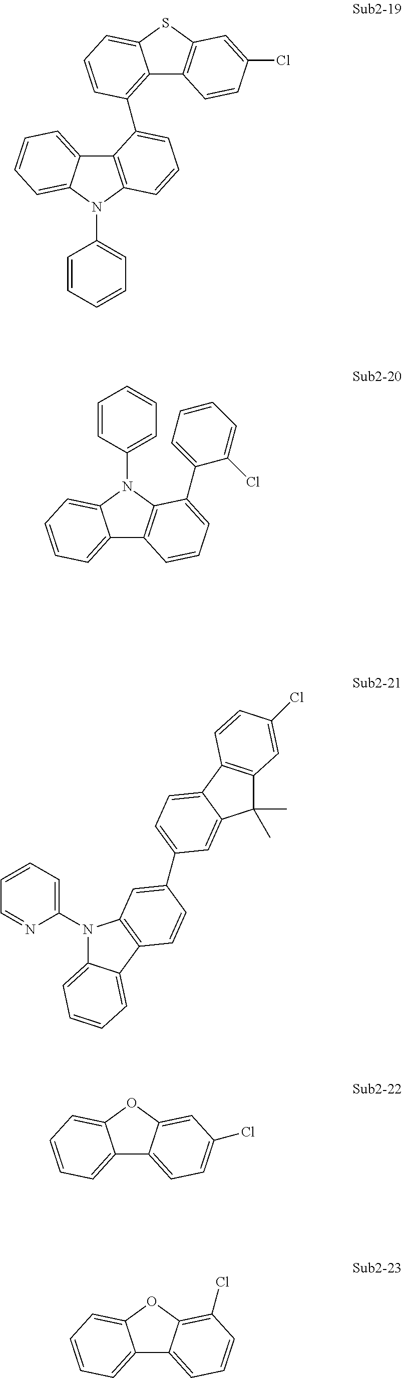 [SMILES: Clc1ccc2c(c1)sc1cccc(-c3cccc4c3c3ccccc3n4-c3ccccc3)c12 ; Clc1ccccc1-c1cccc2c3ccccc3n(-c3ccccc3)c12 ; CC1(C)c2cc(Cl)ccc2-c2ccc(-c3ccc4c5ccccc5n(-c5ccccn5)c4c3)cc21 ; Clc1ccc2c(c1)oc1ccccc12 ; Clc1cccc2c1oc1ccccc12]

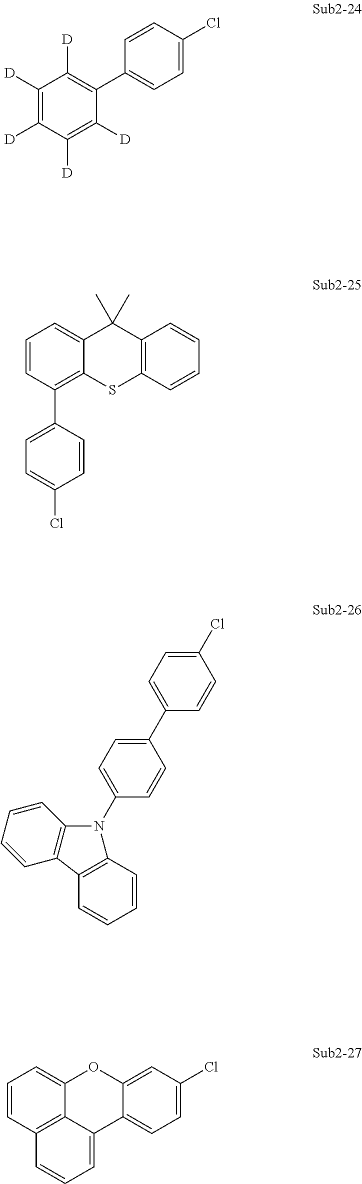 [SMILES: [2H]c1c([2H])c([2H])c(-c2ccc(Cl)cc2)c([2H])c1[2H] ; CC1(C)c2ccccc2Sc2c(-c3ccc(Cl)cc3)cccc21 ; Clc1ccc(-c2ccc(-n3c4ccccc4c4ccccc43)cc2)cc1 ; Clc1ccc2c(c1)Oc1cccc3cccc-2c13]

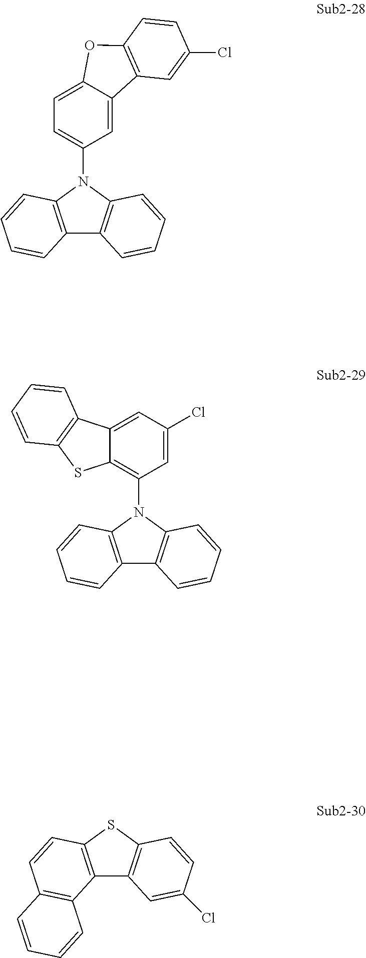 [SMILES: Clc1ccc2oc3ccc(-n4c5ccccc5c5ccccc54)cc3c2c1 ; Clc1cc(-n2c3ccccc3c3ccccc32)c2sc3ccccc3c2c1 ; Clc1ccc2sc3ccc4ccccc4c3c2c1]

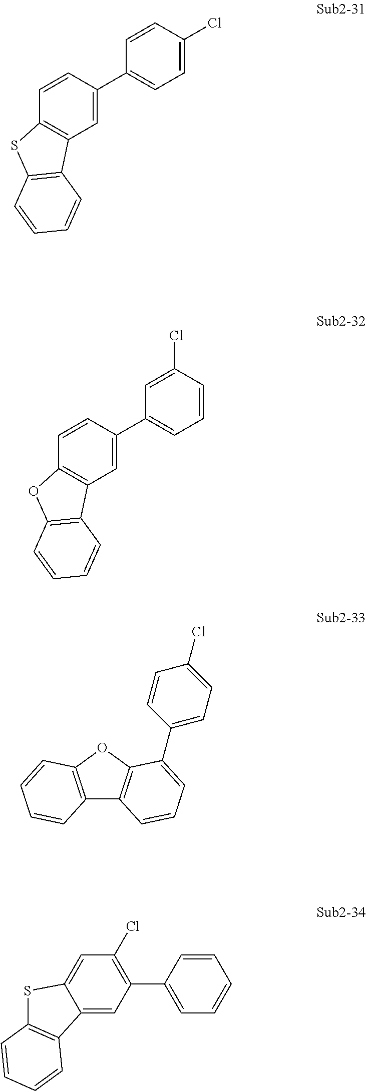 [SMILES: Clc1ccc(-c2ccc3sc4ccccc4c3c2)cc1 ; Clc1cccc(-c2ccc3oc4ccccc4c3c2)c1 ; Clc1ccc(-c2cccc3c2oc2ccccc23)cc1 ; Clc1cc2sc3ccccc3c2cc1-c1ccccc1]

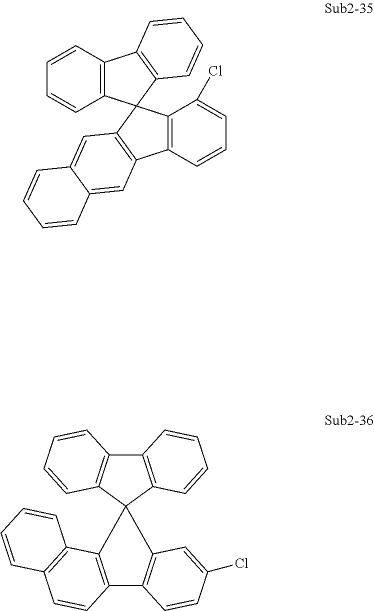 [SMILES: Clc1cccc2c1C1(c3ccccc3-c3ccccc31)c1cc3ccccc3cc1-2 ; Clc1ccc2c(c1)C1(c3ccccc3-c3ccccc31)c1c-2ccc2ccccc12]

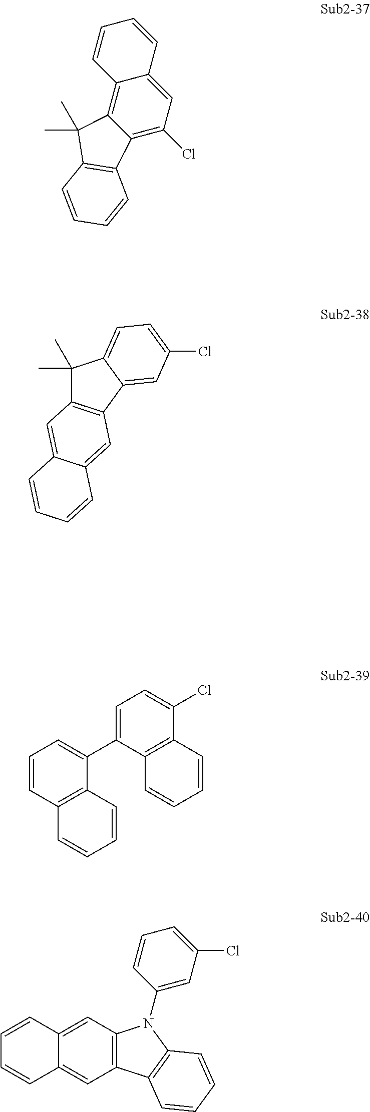 [SMILES: CC1(C)c2ccccc2-c2c(Cl)cc3ccccc3c21 ; CC1(C)c2ccc(Cl)cc2-c2cc3ccccc3cc21 ; Clc1ccc(-c2cccc3ccccc23)c2ccccc12 ; Clc1cccc(-n2c3ccccc3c3cc4ccccc4cc32)c1]

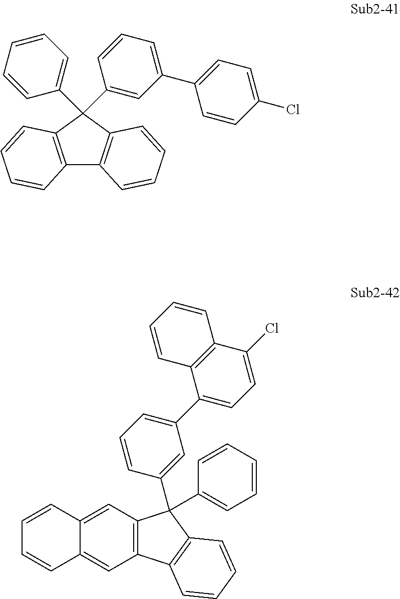 [SMILES: Clc1ccc(-c2cccc(C3(c4ccccc4)c4ccccc4-c4ccccc43)c2)cc1 ; Clc1ccc(-c2cccc(C3(c4ccccc4)c4ccccc4-c4cc5ccccc5cc43)c2)c2ccccc12]

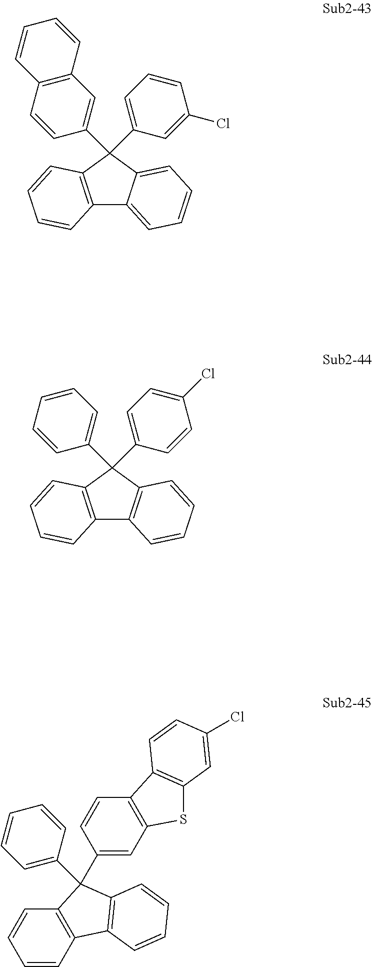 [SMILES: Clc1cccc(C2(c3ccc4ccccc4c3)c3ccccc3-c3ccccc32)c1 ; Clc1ccc(C2(c3ccccc3)c3ccccc3-c3ccccc32)cc1 ; Clc1ccc2c(c1)sc1cc(C3(c4ccccc4)c4ccccc4-c4ccccc43)ccc12]

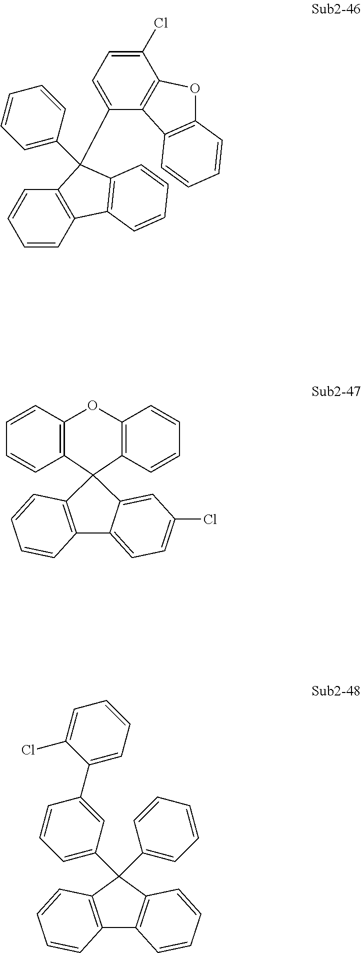 [SMILES: Clc1ccc(C2(c3ccccc3)c3ccccc3-c3ccccc32)c2c1oc1ccccc12 ; Clc1ccc2c(c1)C1(c3ccccc3Oc3ccccc31)c1ccccc1-2 ; Clc1ccccc1-c1cccc(C2(c3ccccc3)c3ccccc3-c3ccccc32)c1]

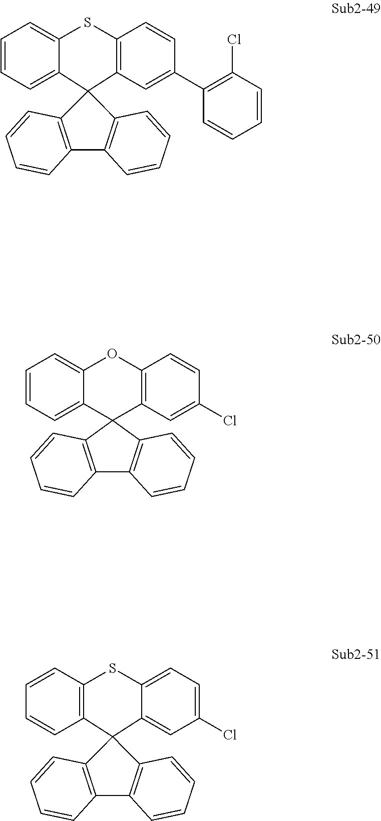 [SMILES: Clc1ccccc1-c1ccc2c(c1)C1(c3ccccc3S2)c2ccccc2-c2ccccc21 ; Clc1ccc2c(c1)C1(c3ccccc3O2)c2ccccc2-c2ccccc21 ; Clc1ccc2c(c1)C1(c3ccccc3S2)c2ccccc2-c2ccccc21]

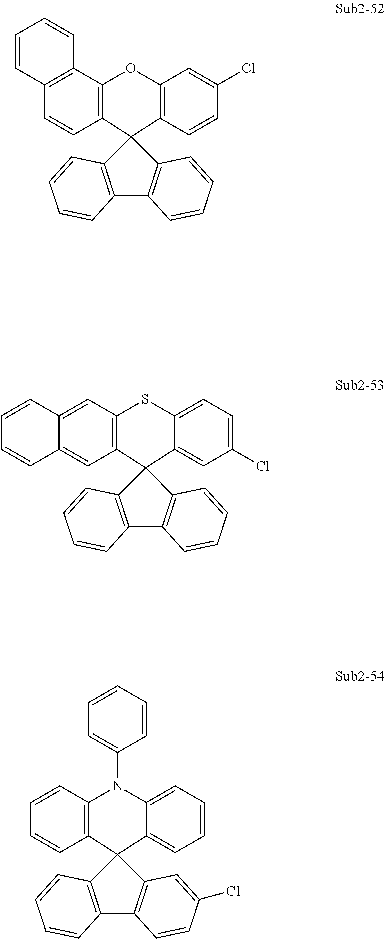 [SMILES: Clc1ccc2c(c1)Oc1c(ccc3ccccc13)C21c2ccccc2-c2ccccc21 ; Clc1ccc2c(c1)C1(c3cc4ccccc4cc3S2)c2ccccc2-c2ccccc21 ; Clc1ccc2c(c1)C1(c3ccccc3-2)c2ccccc2N(c2ccccc2)c2ccccc21]

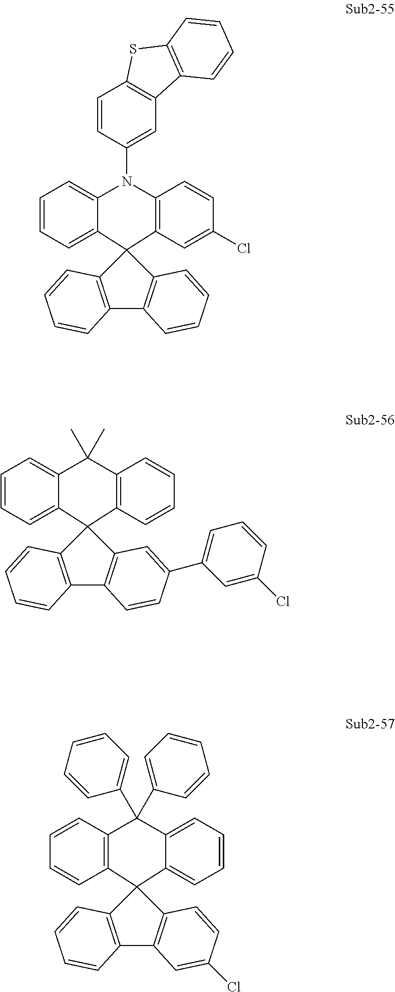 [SMILES: Clc1ccc2c(c1)C1(c3ccccc3-c3ccccc31)c1ccccc1N2c1ccc2sc3ccccc3c2c1 ; CC1(C)c2ccccc2C2(c3ccccc3-c3ccc(-c4cccc(Cl)c4)cc32)c2ccccc21 ; Clc1ccc2c(c1)-c1ccccc1C21c2ccccc2C(c2ccccc2)(c2ccccc2)c2ccccc21]

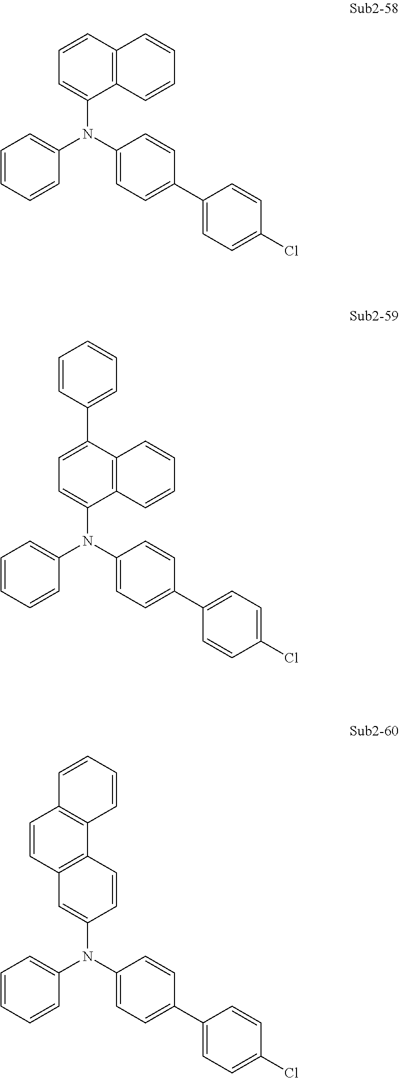 [SMILES: Clc1ccc(-c2ccc(N(c3ccccc3)c3cccc4ccccc34)cc2)cc1 ; Clc1ccc(-c2ccc(N(c3ccccc3)c3ccc(-c4ccccc4)c4ccccc34)cc2)cc1 ; Clc1ccc(-c2ccc(N(c3ccccc3)c3ccc4c(ccc5ccccc54)c3)cc2)cc1]

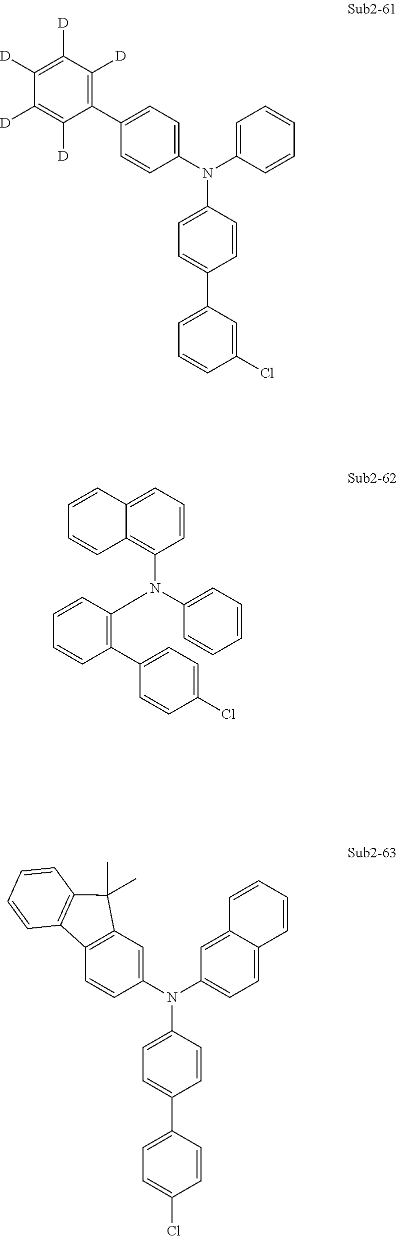 [SMILES: [2H]c1c([2H])c([2H])c(-c2ccc(N(c3ccccc3)c3ccc(-c4cccc(Cl)c4)cc3)cc2)c([2H])c1[2H] ; Clc1ccc(-c2ccccc2N(c2ccccc2)c2cccc3ccccc23)cc1 ; CC1(C)c2ccccc2-c2ccc(N(c3ccc(-c4ccc(Cl)cc4)cc3)c3ccc4ccccc4c3)cc21]

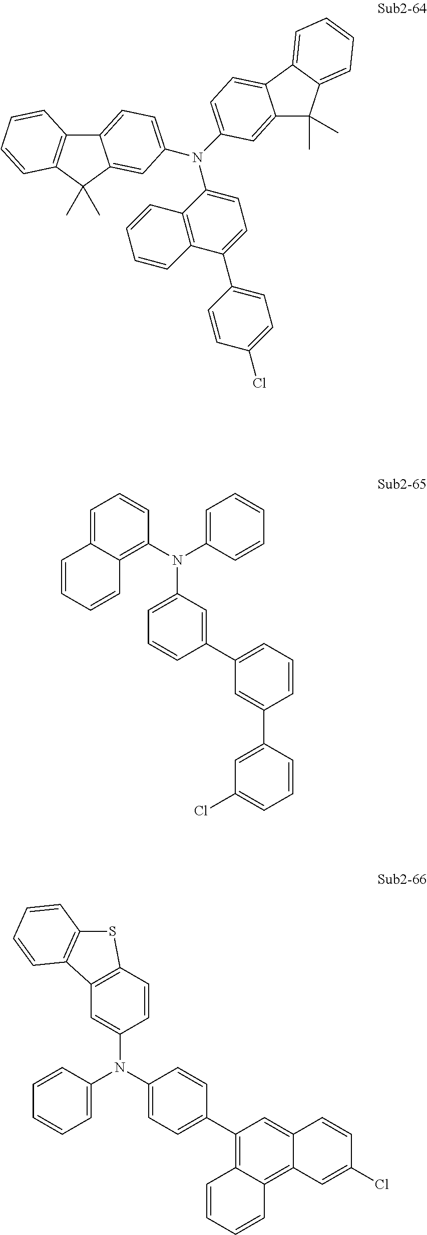 [SMILES: CC1(C)c2ccccc2-c2ccc(N(c3ccc4c(c3)C(C)(C)c3ccccc3-4)c3ccc(-c4ccc(Cl)cc4)c4ccccc34)cc21 ; Clc1cccc(-c2cccc(-c3cccc(N(c4ccccc4)c4cccc5ccccc45)c3)c2)c1 ; Clc1ccc2cc(-c3ccc(N(c4ccccc4)c4ccc5sc6ccccc6c5c4)cc3)c3ccccc3c2c1]

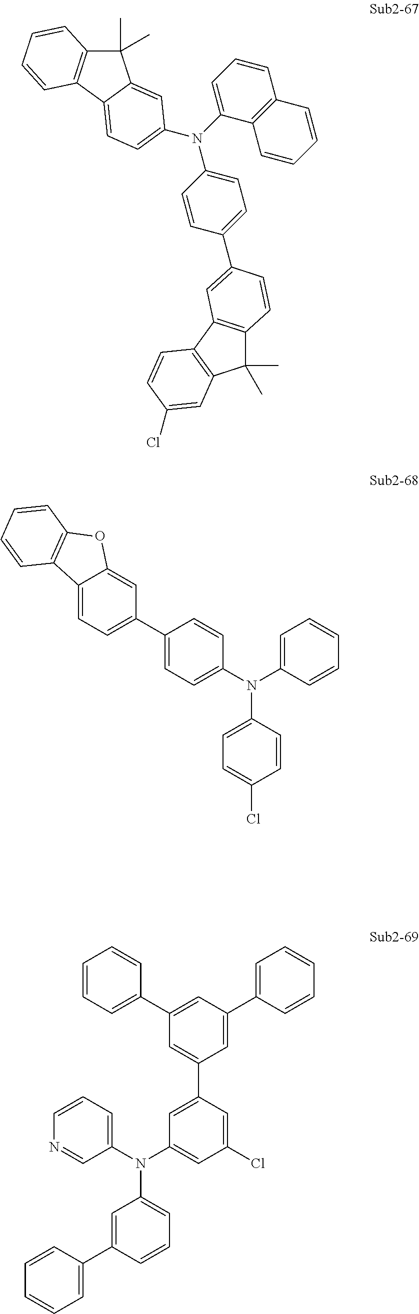 [SMILES: CC1(C)c2ccc(-c3ccc(N(c4ccc5c(c4)C(C)(C)c4ccccc4-5)c4cccc5ccccc45)cc3)cc2-c2ccc(Cl)cc21 ; Clc1ccc(N(c2ccccc2)c2ccc(-c3ccc4c(c3)oc3ccccc34)cc2)cc1 ; Clc1cc(-c2cc(-c3ccccc3)cc(-c3ccccc3)c2)cc(N(c2cccnc2)c2cccc(-c3ccccc3)c2)c1]

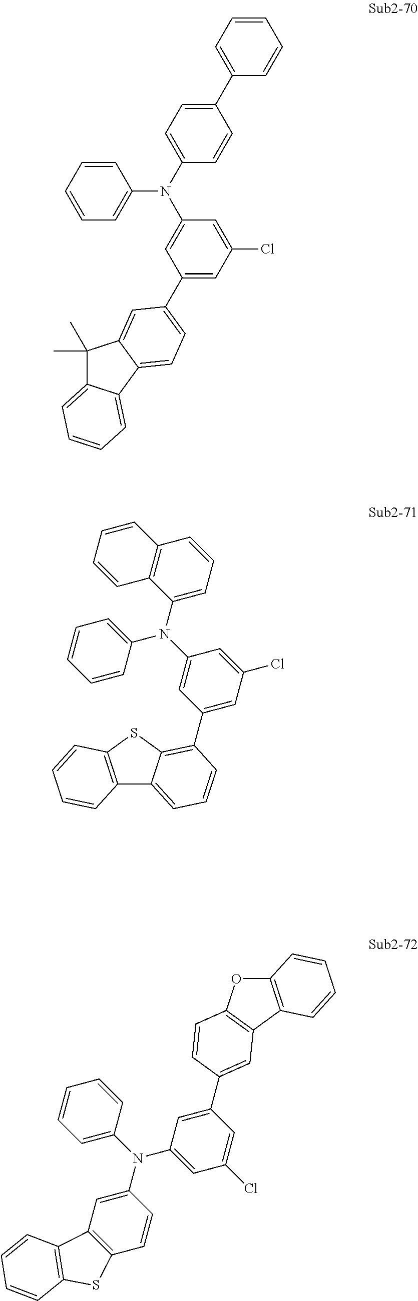 [SMILES: CC1(C)c2ccccc2-c2ccc(-c3cc(Cl)cc(N(c4ccccc4)c4ccc(-c5ccccc5)cc4)c3)cc21 ; Clc1cc(-c2cccc3c2sc2ccccc23)cc(N(c2ccccc2)c2cccc3ccccc23)c1 ; Clc1cc(-c2ccc3oc4ccccc4c3c2)cc(N(c2ccccc2)c2ccc3sc4ccccc4c3c2)c1]

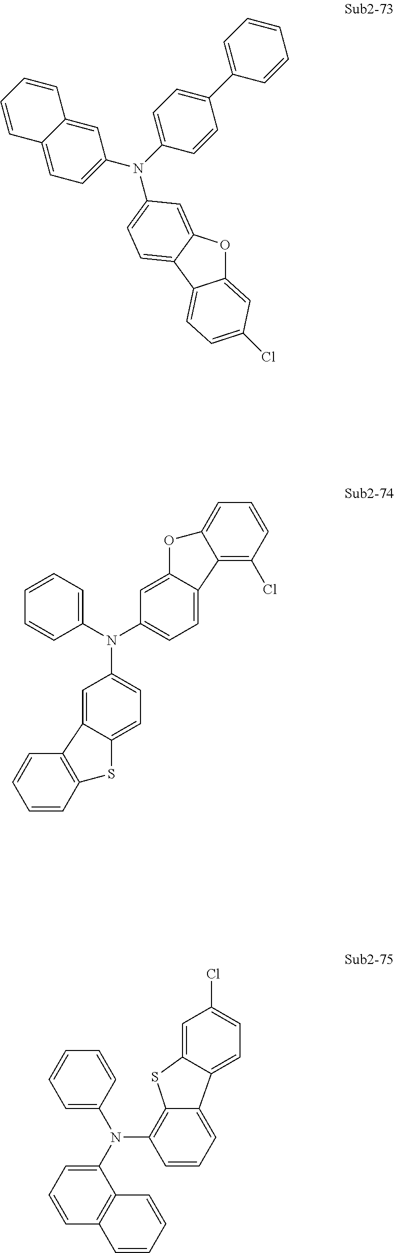 [SMILES: Clc1ccc2c(c1)oc1cc(N(c3ccc(-c4ccccc4)cc3)c3ccc4ccccc4c3)ccc12 ; Clc1cccc2oc3cc(N(c4ccccc4)c4ccc5sc6ccccc6c5c4)ccc3c12 ; Clc1ccc2c(c1)sc1c(N(c3ccccc3)c3cccc4ccccc34)cccc12]

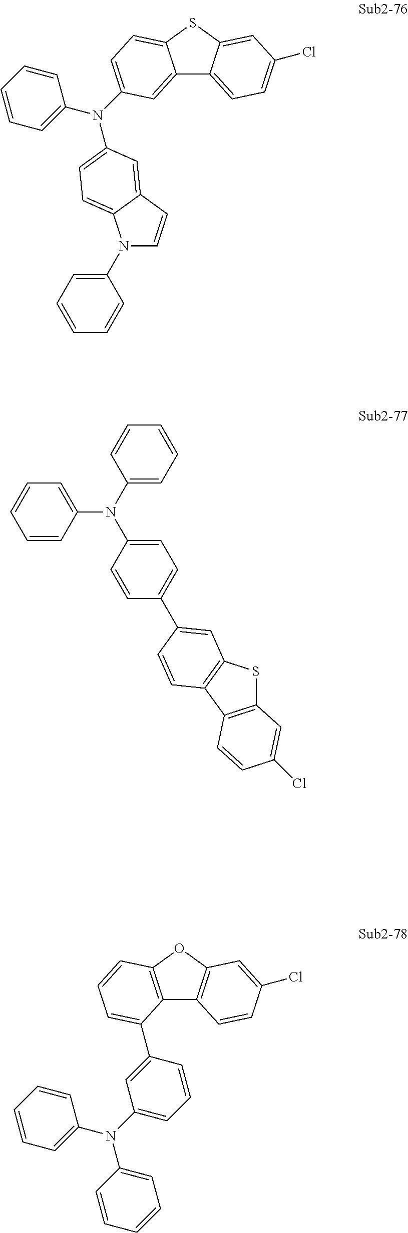 [SMILES: Clc1ccc2c(c1)sc1ccc(N(c3ccccc3)c3ccc4c(ccn4-c4ccccc4)c3)cc12 ; Clc1ccc2c(c1)sc1cc(-c3ccc(N(c4ccccc4)c4ccccc4)cc3)ccc12 ; Clc1ccc2c(c1)oc1cccc(-c3cccc(N(c4ccccc4)c4ccccc4)c3)c12]

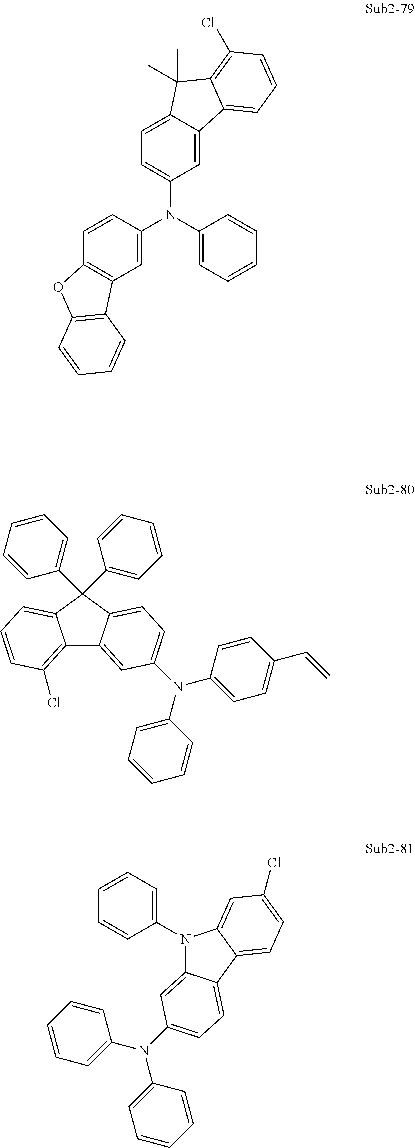 [SMILES: CC1(C)c2ccc(N(c3ccccc3)c3ccc4oc5ccccc5c4c3)cc2-c2cccc(Cl)c21 ; C=Cc1ccc(N(c2ccccc2)c2ccc3c(c2)-c2c(Cl)cccc2C3(c2ccccc2)c2ccccc2)cc1 ; Clc1ccc2c3ccc(N(c4ccccc4)c4ccccc4)cc3n(-c3ccccc3)c2c1]

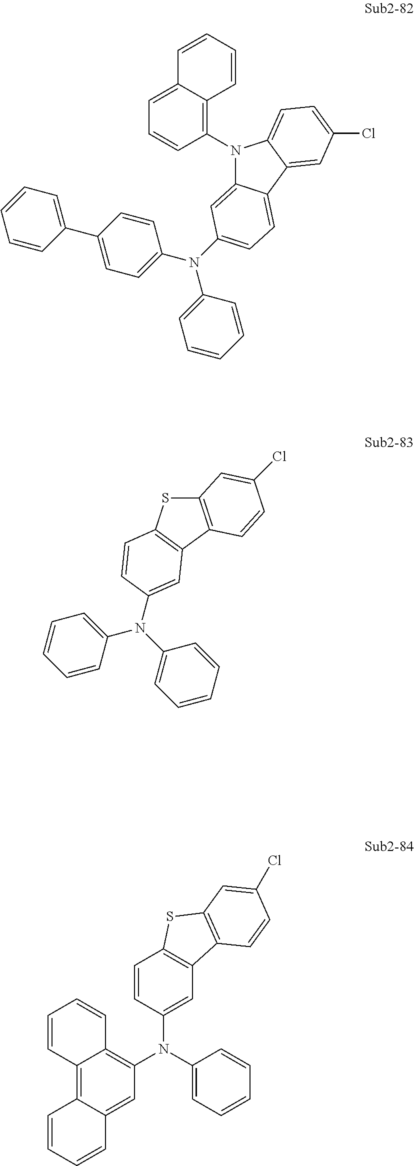 [SMILES: Clc1ccc2c(c1)c1ccc(N(c3ccccc3)c3ccc(-c4ccccc4)cc3)cc1n2-c1cccc2ccccc12 ; Clc1ccc2c(c1)sc1ccc(N(c3ccccc3)c3ccccc3)cc12 ; Clc1ccc2c(c1)sc1ccc(N(c3ccccc3)c3cc4ccccc4c4ccccc34)cc12]

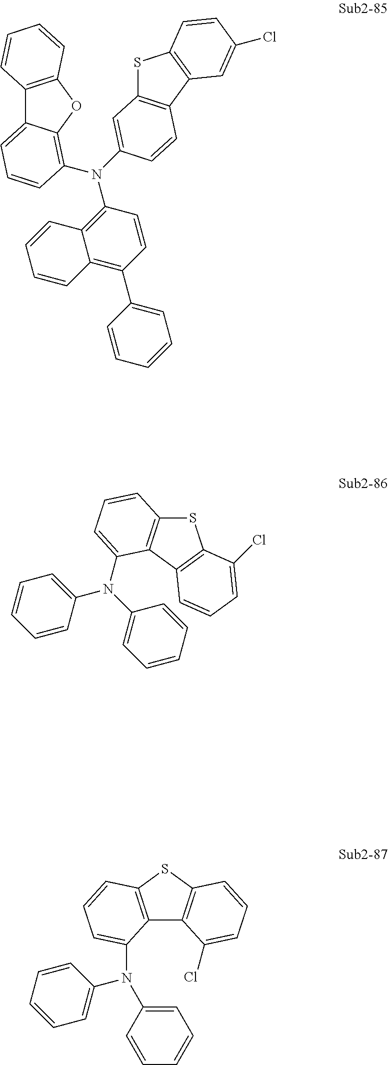 [SMILES: Clc1ccc2sc3cc(N(c4ccc(-c5ccccc5)c5ccccc45)c4cccc5c4oc4ccccc45)ccc3c2c1 ; Clc1cccc2c1sc1cccc(N(c3ccccc3)c3ccccc3)c12 ; Clc1cccc2sc3cccc(N(c4ccccc4)c4ccccc4)c3c12]

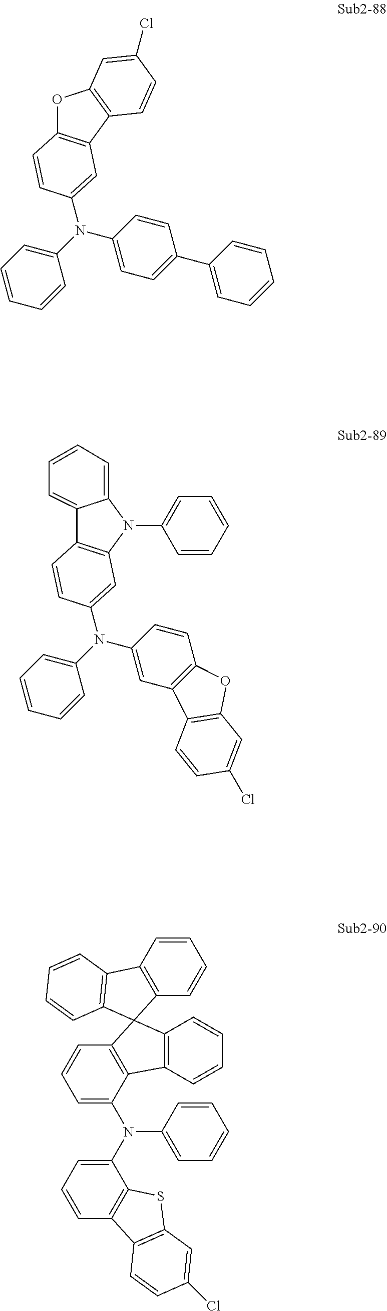 [SMILES: Clc1ccc2c(c1)oc1ccc(N(c3ccccc3)c3ccc(-c4ccccc4)cc3)cc12 ; Clc1ccc2c(c1)oc1ccc(N(c3ccccc3)c3ccc4c5ccccc5n(-c5ccccc5)c4c3)cc12 ; Clc1ccc2c(c1)sc1c(N(c3ccccc3)c3cccc4c3-c3ccccc3C43c4ccccc4-c4ccccc43)cccc12]

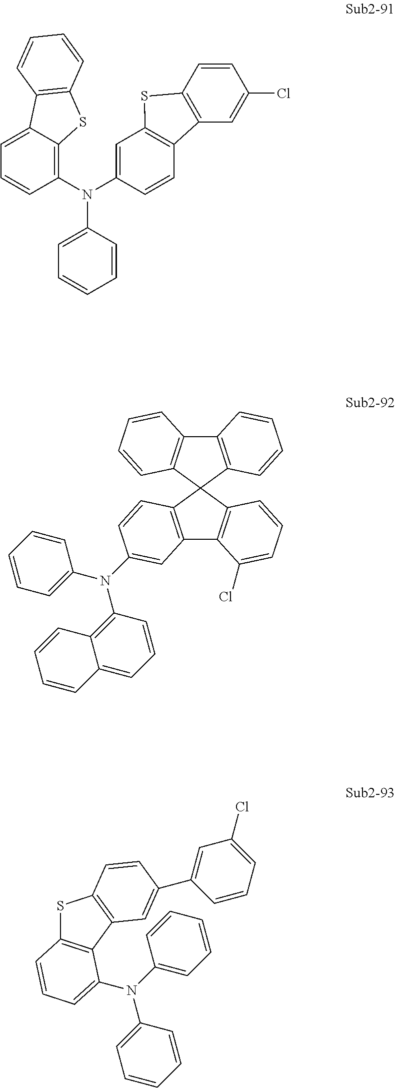 [SMILES: Clc1ccc2sc3cc(N(c4ccccc4)c4cccc5c4sc4ccccc45)ccc3c2c1 ; Clc1cccc2c1-c1cc(N(c3ccccc3)c3cccc4ccccc34)ccc1C21c2ccccc2-c2ccccc21 ; Clc1cccc(-c2ccc3sc4cccc(N(c5ccccc5)c5ccccc5)c4c3c2)c1]

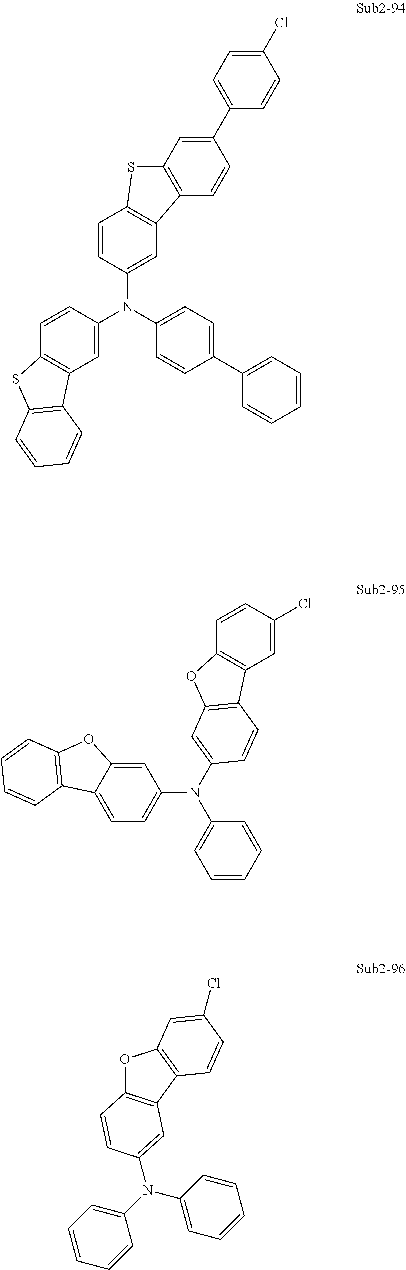 [SMILES: Clc1ccc(-c2ccc3c(c2)sc2ccc(N(c4ccc(-c5ccccc5)cc4)c4ccc5sc6ccccc6c5c4)cc23)cc1 ; Clc1ccc2oc3cc(N(c4ccccc4)c4ccc5c(c4)oc4ccccc45)ccc3c2c1 ; Clc1ccc2c(c1)oc1ccc(N(c3ccccc3)c3ccccc3)cc12]

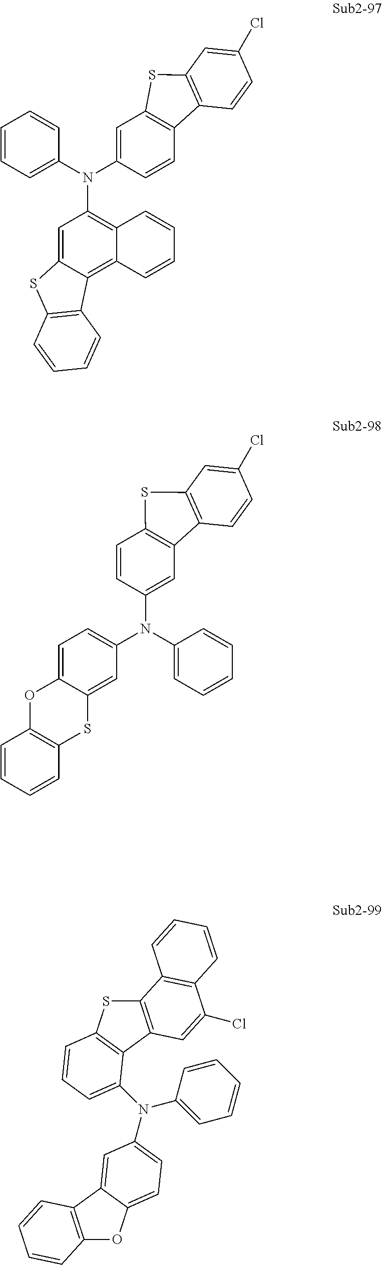 [SMILES: Clc1ccc2c(c1)sc1cc(N(c3ccccc3)c3cc4sc5ccccc5c4c4ccccc34)ccc12 ; Clc1ccc2c(c1)sc1ccc(N(c3ccccc3)c3ccc4c(c3)Sc3ccccc3O4)cc12 ; Clc1cc2c(sc3cccc(N(c4ccccc4)c4ccc5oc6ccccc6c5c4)c32)c2ccccc12]

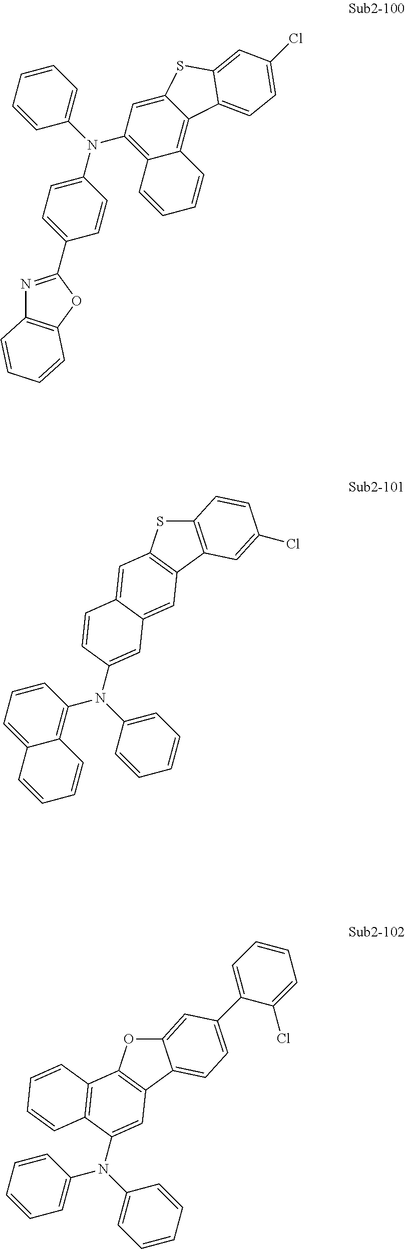 [SMILES: Clc1ccc2c(c1)sc1cc(N(c3ccccc3)c3ccc(-c4nc5ccccc5o4)cc3)c3ccccc3c12 ; Clc1ccc2sc3cc4ccc(N(c5ccccc5)c5cccc6ccccc56)cc4cc3c2c1 ; Clc1ccccc1-c1ccc2c(c1)oc1c3ccccc3c(N(c3ccccc3)c3ccccc3)cc21]

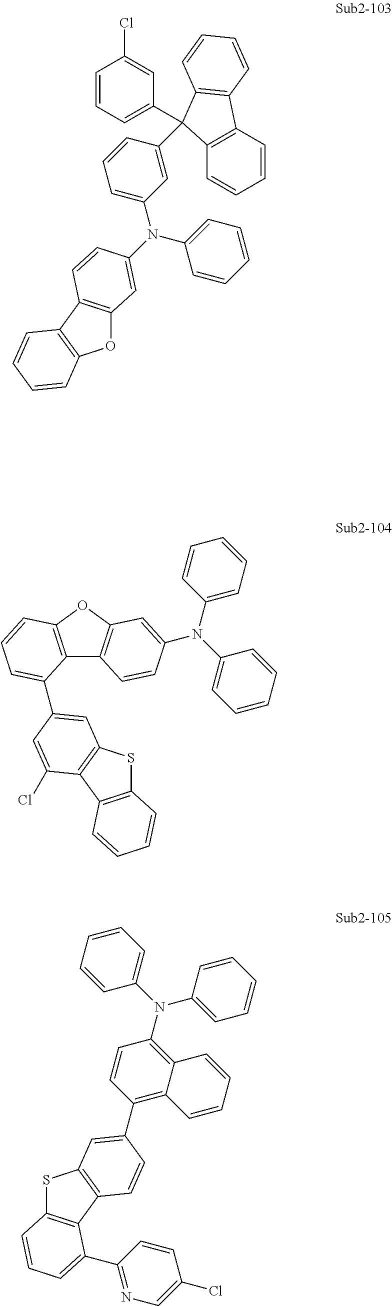 [SMILES: Clc1cccc(C2(c3cccc(N(c4ccccc4)c4ccc5c(c4)oc4ccccc45)c3)c3ccccc3-c3ccccc32)c1 ; Clc1cc(-c2cccc3oc4cc(N(c5ccccc5)c5ccccc5)ccc4c23)cc2sc3ccccc3c12 ; Clc1ccc(-c2cccc3sc4cc(-c5ccc(N(c6ccccc6)c6ccccc6)c6ccccc56)ccc4c23)nc1]

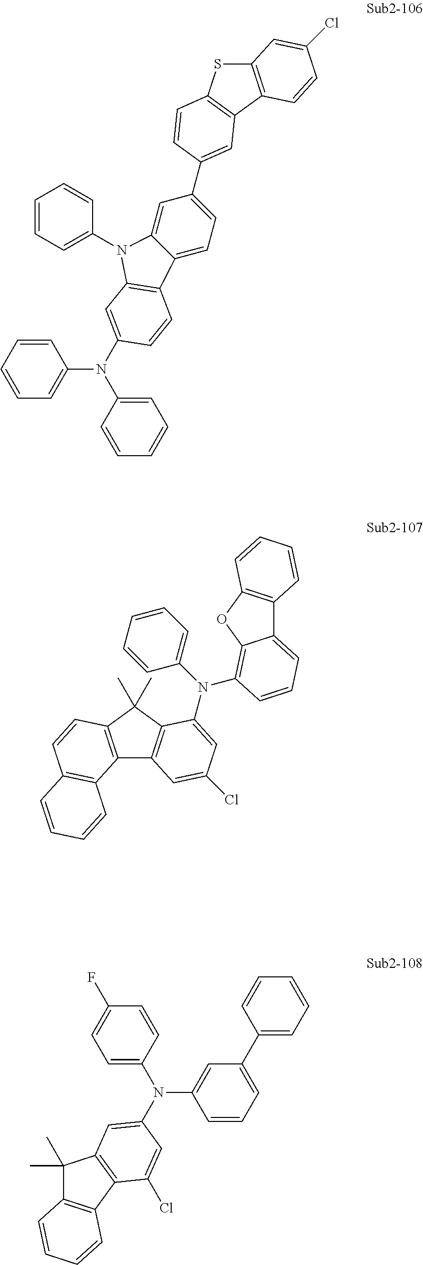 [SMILES: Clc1ccc2c(c1)sc1ccc(-c3ccc4c5ccc(N(c6ccccc6)c6ccccc6)cc5n(-c5ccccc5)c4c3)cc12 ; CC1(C)c2ccc3ccccc3c2-c2cc(Cl)cc(N(c3ccccc3)c3cccc4c3oc3ccccc34)c21 ; CC1(C)c2ccccc2-c2c(Cl)cc(N(c3ccc(F)cc3)c3cccc(-c4ccccc4)c3)cc21]

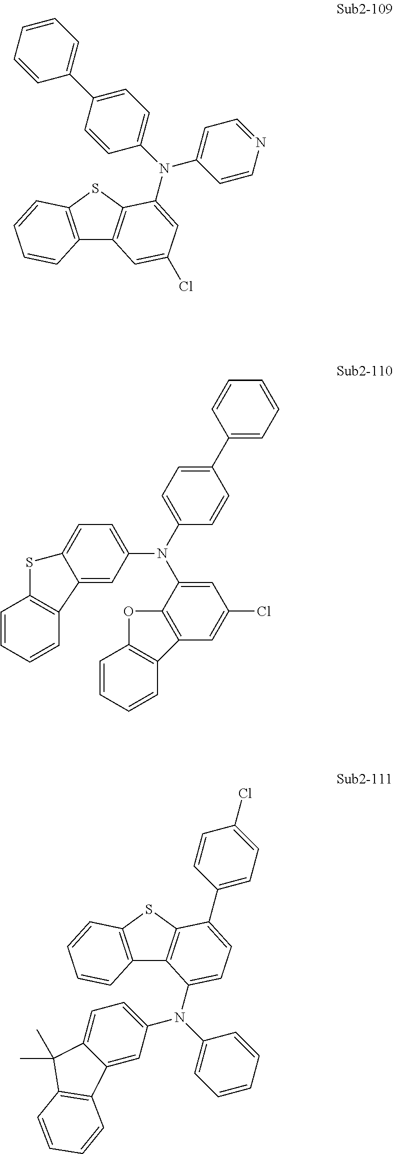 [SMILES: Clc1cc(N(c2ccncc2)c2ccc(-c3ccccc3)cc2)c2sc3ccccc3c2c1 ; Clc1cc(N(c2ccc(-c3ccccc3)cc2)c2ccc3sc4ccccc4c3c2)c2oc3ccccc3c2c1 ; CC1(C)c2ccccc2-c2cc(N(c3ccccc3)c3ccc(-c4ccc(Cl)cc4)c4sc5ccccc5c34)ccc21]

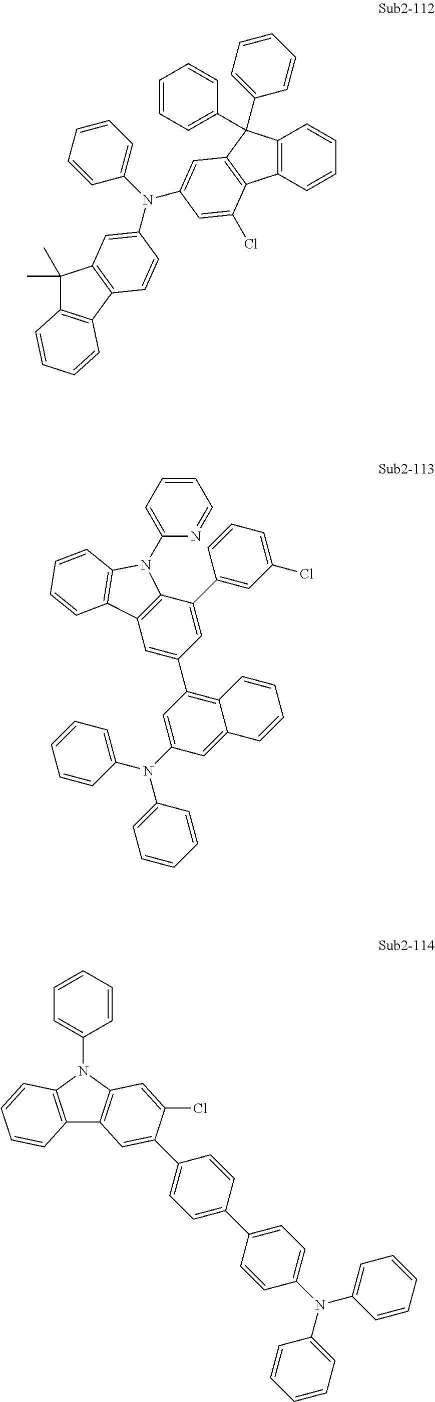 [SMILES: CC1(C)c2ccccc2-c2ccc(N(c3ccccc3)c3cc(Cl)c4c(c3)C(c3ccccc3)(c3ccccc3)c3ccccc3-4)cc21 ; Clc1cccc(-c2cc(-c3cc(N(c4ccccc4)c4ccccc4)cc4ccccc34)cc3c4ccccc4n(-c4ccccn4)c23)c1 ; Clc1cc2c(cc1-c1ccc(-c3ccc(N(c4ccccc4)c4ccccc4)cc3)cc1)c1ccccc1n2-c1ccccc1]

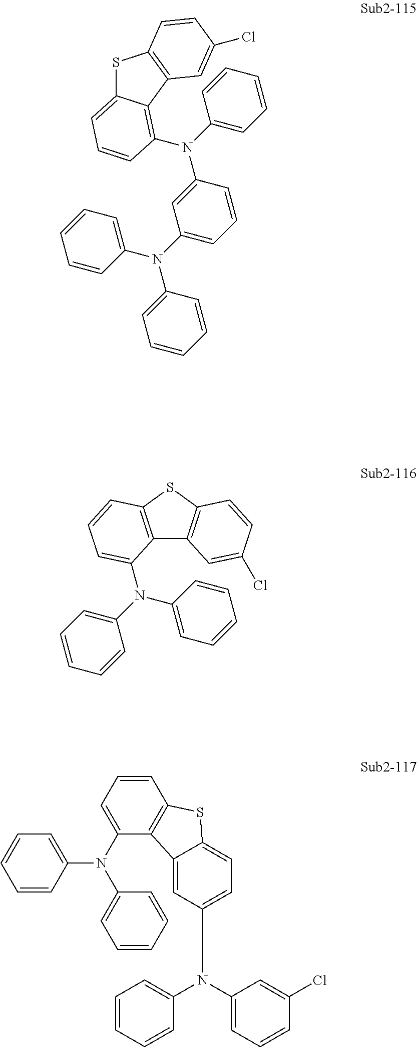 [SMILES: Clc1ccc2sc3cccc(N(c4ccccc4)c4cccc(N(c5ccccc5)c5ccccc5)c4)c3c2c1 ; Clc1ccc2sc3cccc(N(c4ccccc4)c4ccccc4)c3c2c1 ; Clc1cccc(N(c2ccccc2)c2ccc3sc4cccc(N(c5ccccc5)c5ccccc5)c4c3c2)c1]

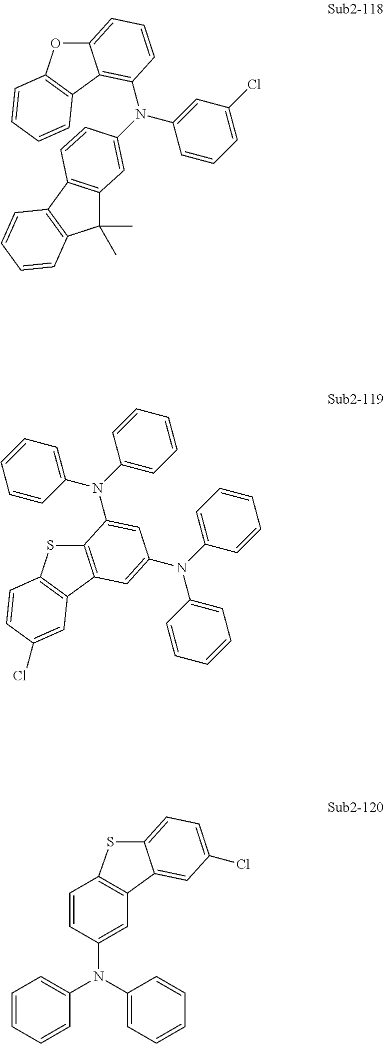 [SMILES: CC1(C)c2ccccc2-c2ccc(N(c3cccc(Cl)c3)c3cccc4oc5ccccc5c34)cc21 ; Clc1ccc2sc3c(N(c4ccccc4)c4ccccc4)cc(N(c4ccccc4)c4ccccc4)cc3c2c1 ; Clc1ccc2sc3ccc(N(c4ccccc4)c4ccccc4)cc3c2c1]

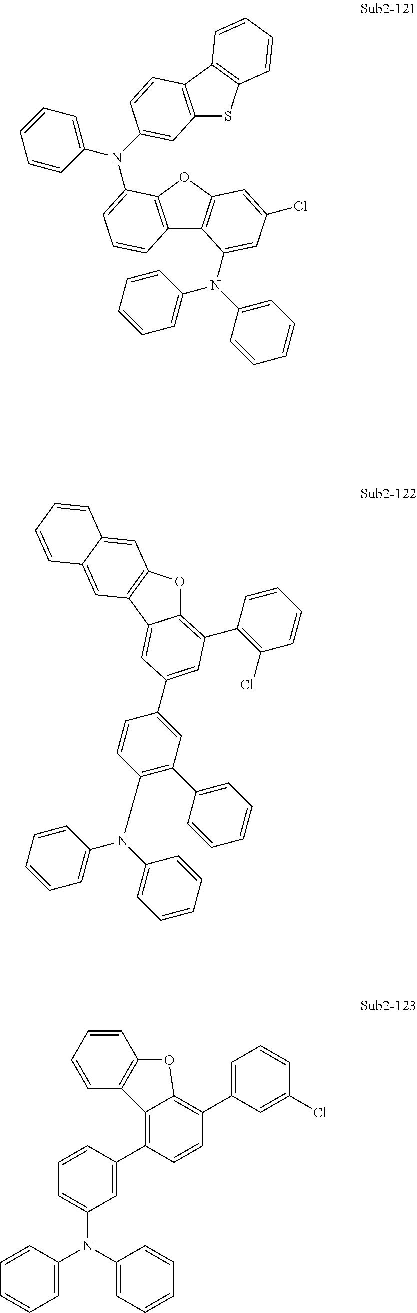 [SMILES: Clc1cc(N(c2ccccc2)c2ccccc2)c2c(c1)oc1c(N(c3ccccc3)c3ccc4c(c3)sc3ccccc34)cccc12 ; Clc1ccccc1-c1cc(-c2ccc(N(c3ccccc3)c3ccccc3)c(-c3ccccc3)c2)cc2c1oc1cc3ccccc3cc12 ; Clc1cccc(-c2ccc(-c3cccc(N(c4ccccc4)c4ccccc4)c3)c3c2oc2ccccc23)c1]

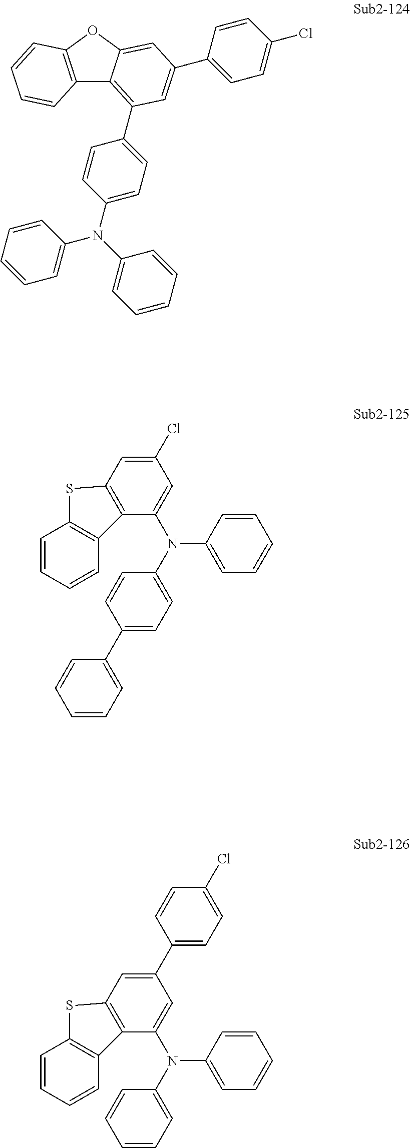 [SMILES: Clc1ccc(-c2cc(-c3ccc(N(c4ccccc4)c4ccccc4)cc3)c3c(c2)oc2ccccc23)cc1 ; Clc1cc(N(c2ccccc2)c2ccc(-c3ccccc3)cc2)c2c(c1)sc1ccccc12 ; Clc1ccc(-c2cc(N(c3ccccc3)c3ccccc3)c3c(c2)sc2ccccc23)cc1]

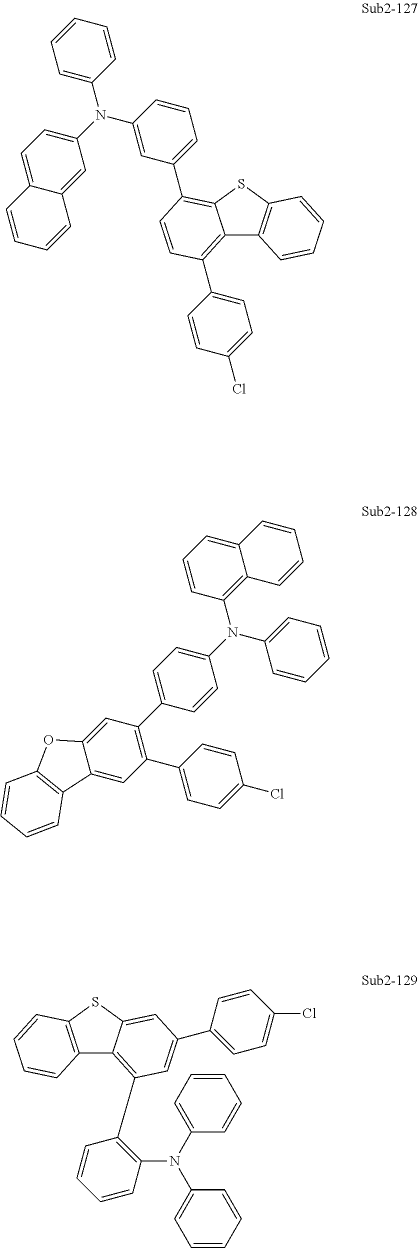 [SMILES: Clc1ccc(-c2ccc(-c3cccc(N(c4ccccc4)c4ccc5ccccc5c4)c3)c3sc4ccccc4c23)cc1 ; Clc1ccc(-c2cc3c(cc2-c2ccc(N(c4ccccc4)c4cccc5ccccc45)cc2)oc2ccccc23)cc1 ; Clc1ccc(-c2cc(-c3ccccc3N(c3ccccc3)c3ccccc3)c3c(c2)sc2ccccc23)cc1]

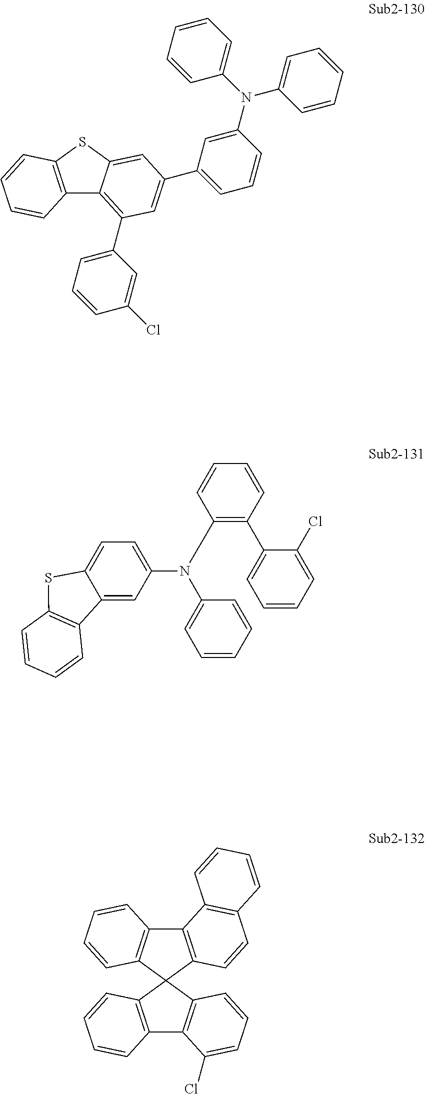 [SMILES: Clc1cccc(-c2cc(-c3cccc(N(c4ccccc4)c4ccccc4)c3)cc3sc4ccccc4c23)c1 ; Clc1ccccc1-c1ccccc1N(c1ccccc1)c1ccc2sc3ccccc3c2c1 ; Clc1cccc2c1-c1ccccc1C21c2ccccc2-c2c1ccc1ccccc21]

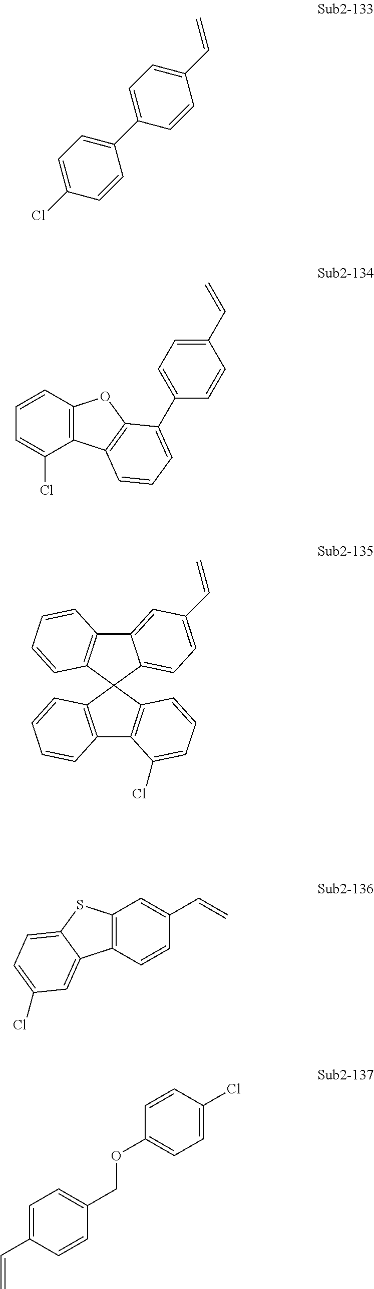 [SMILES: C=Cc1ccc(-c2ccc(Cl)cc2)cc1 ; C=Cc1ccc(-c2cccc3c2oc2cccc(Cl)c23)cc1 ; C=Cc1ccc2c(c1)-c1ccccc1C21c2ccccc2-c2c(Cl)cccc21 ; C=Cc1ccc2c(c1)sc1ccc(Cl)cc12 ; C=Cc1ccc(COc2ccc(Cl)cc2)cc1]

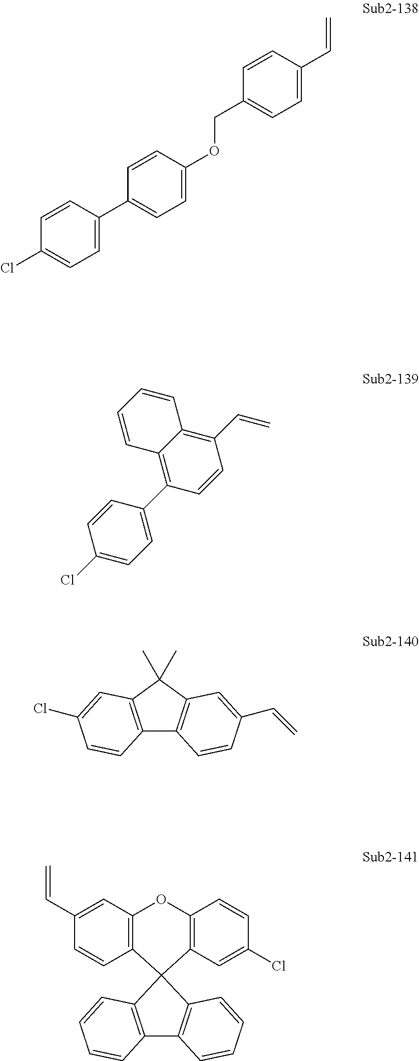 [SMILES: C=Cc1ccc(COc2ccc(-c3ccc(Cl)cc3)cc2)cc1 ; C=Cc1ccc(-c2ccc(Cl)cc2)c2ccccc12 ; C=Cc1ccc2c(c1)C(C)(C)c1cc(Cl)ccc1-2 ; C=Cc1ccc2c(c1)Oc1ccc(Cl)cc1C21c2ccccc2-c2ccccc21]

Table 2 below shows the Field Desorption-Mass Spectrometry (FD-MS) values of compounds belonging to Sub 2.

TABLE 2

| Compound | FD-MS | Compound | FD-MS |
|---|---|---|---|
| Sub2-1 | m/z = 188.04(C12H9Cl = 188.65) | Sub2-2 | m/z = 238.05(C16H11Cl = 238.71) |
| Sub2-3 | m/z = 212.04(C14H9Cl = 212.68) | Sub2-4 | m/z = 188.04(C12H9Cl = 188.65) |
| Sub2-5 | m/z = 340.10(C24H17Cl = 340.85) | Sub2-6 | m/z = 238.05(C16H11Cl = 238.71) |
| Sub2-7 | m/z = 264.07(C18H13Cl = 264.75) | Sub2-8 | m/z = 188.04(C12H9Cl = 188.65) |
| Sub2-9 | m/z = 218.00(C12H7ClS = 218.70) | Sub2-10 | m/z = 312.02(C18H10ClFS = 312.79) |
| Sub2-11 | m/z = 294.03(C18H11ClS = 294.80) | Sub2-12 | m/z = 228.07(C15H13Cl = 228.72) |
| Sub2-13 | m/z = 352.10(C25H17Cl = 352.86) | Sub2-14 | m/z = 353.10(C24H16ClN = 353.85) |
| Sub2-15 | m/z = 429.13(C30H20ClN = 429.95) | Sub2-16 | m/z = 443.11(C30H18ClNO = 443.93) |
| Sub2-17 | m/z = 429.13(C30H20ClN = 429.95) | Sub2-18 | m/z = 453.13(C32H20ClN = 453.97) |
| Sub2-19 | m/z = 459.08(C30H18ClNS = 459.99) | Sub2-20 | m/z = 353.10(C24H16ClN = 353.85) |
| Sub2-21 | m/z = 470.15(C32H23ClN2 = 471.00) | Sub2-22 | m/z = 202.02(C12H7ClO = 202.64) |
| Sub2-23 | m/z = 202.02(C12H7ClO = 202.64) | Sub2-24 | m/z = 193.07(C12H4D5Cl = 193.68) |
| Sub2-25 | m/z = 336.07(C21H17ClS = 336.88) | Sub2-26 | m/z = 353.10(C24H16ClN = 353.85) |
| Sub2-27 | m/z = 252.03(C16H9ClO = 252.70) | Sub2-28 | m/z = 367.08(C24H14ClNO = 367.83) |
| Sub2-29 | m/z = 383.05(C24H14ClNS = 383.89) | Sub2-30 | m/z = 268.01(C16H9ClS = 268.76) |
| Sub2-31 | m/z = 294.03(C18H11ClS = 294.80) | Sub2-32 | m/z = 328.07(C22H13ClO = 328.80) |
| Sub2-33 | m/z = 278.05(C18H11ClO = 278.74) | Sub2-34 | m/z = 294.03(C18H11ClS = 294.80) |
| Sub2-35 | m/z = 400.10(C29H17Cl = 400.91) | Sub2-36 | m/z = 400.10(C29H17Cl = 400.91) |
| Sub2-37 | m/z = 278.09(C19H15Cl = 278.78) | Sub2-38 | m/z = 278.09(C19H15Cl = 278.78) |
| Sub2-39 | m/z = 288.07(C20H13Cl = 288.77) | Sub2-40 | m/z = 327.08(C22H14ClN = 327.81) |
| Sub2-41 | m/z = 428.13(C31H21Cl = 428.96) | Sub2-42 | m/z = 528.16(C39H25Cl = 529.08) |
| Sub2-43 | m/z = 402.12(C29H19Cl = 402.92) | Sub2-44 | m/z = 352.10(C25H17Cl = 352.86) |
| Sub2-45 | m/z = 458.09(C31H19ClS = 459.00) | Sub2-46 | m/z = 442.11(C31H19ClO = 442.94) |
| Sub2-47 | m/z = 352.10(C25H17Cl = 352.86) | Sub2-48 | m/z = 428.13(C31H21Cl = 428.96) |
| Sub2-49 | m/z = 458.09(C31H19ClS = 459.00) | Sub2-50 | m/z = 366.08(C25H15ClO = 366.84) |
| Sub2-51 | m/z = 382.06(C25H15ClS = 382.91) | Sub2-52 | m/z = 416.10(C29H17ClO = 416.90) |
| Sub2-53 | m/z = 432.07(C29H17ClS = 432.97) | Sub2-54 | m/z = 441.13(C31H20ClN = 441.96) |
| Sub2-55 | m/z = 547.12(C37H22ClNS = 548.10) | Sub2-56 | m/z = 468.16(C34H25Cl = 469.02) |
| Sub2-57 | m/z = 516.16(C38H25Cl = 517.07) | Sub2-58 | m/z = 405.13(C28H20ClN = 405.93) |
| Sub2-59 | m/z = 481.16(C34H24ClN = 482.02) | Sub2-60 | m/z = 455.14(C32H22ClN = 455.99) |
| Sub2-61 | m/z = 436.18(C30H17D5ClN = 436.99) | Sub2-62 | m/z = 405.13(C28H20ClN = 405.93) |
| Sub2-63 | m/z = 521.19(C37H28ClN = 522.09) | Sub2-64 | m/z = 637.25(C46H36ClN = 638.25) |
| Sub2-65 | m/z = 481.16(C34H24ClN = 482.02) | Sub2-66 | m/z = 561.13(C38H24ClNS = 562.13) |
| Sub2-67 | m/z = 637.25(C46H36ClN = 638.25) | Sub2-68 | m/z = 445.12(C30H20ClNO = 445.95) |
| Sub2-69 | m/z = 584.20(C41H29ClN2 = 585.15) | Sub2-70 | m/z = 547.21(C39H30ClN = 548.13) |
| Sub2-71 | m/z = 511.12(C34H22ClNS = 512.07) | Sub2-72 | m/z = 551.11(C36H22ClNOS = 552.09) |
| Sub2-73 | m/z = 495.14(C34H22ClNO = 496.01) | Sub2-74 | m/z = 475.08(C30H18ClNOS = 475.99) |
| Sub2-75 | m/z = 435.08(C28H18ClNS = 435.97) | Sub2-76 | m/z = 500.11(C32H21ClN2S = 501.04) |
| Sub2-77 | m/z = 461.10(C30H20ClNS = 462.01) | Sub2-78 | m/z = 445.12(C30H20ClNO = 445.95) |
| Sub2-79 | m/z = 485.15(C33H24ClNO = 486.01) | Sub2-80 | m/z = 545.19(C39H28ClN = 546.11) |
| Sub2-81 | m/z = 444.14(C30H21ClN2 = 444.96) | Sub2-82 | m/z = 570.19(C40H27ClN2 = 571.12) |
| Sub2-83 | m/z = 385.07(C24H16ClNS = 385.91) | Sub2-84 | m/z = 485.10(C32H20ClNS = 486.03) |
| Sub2-85 | m/z = 601.13(C40H24ClNOS = 602.15) | Sub2-86 | m/z = 385.07(C24H16ClNS = 385.91) |
| Sub2-87 | m/z = 385.07(C24H16ClNS = 385.91) | Sub2-88 | m/z = 445.12(C30H20ClNO = 445.95) |
| Sub2-89 | m/z = 534.15(C36H23ClN2O = 535.04) | Sub2-90 | m/z = 623.15(C43H26ClNS = 624.20) |
| Sub2-91 | m/z = 491.06(C30H18ClNS2 = 492.05) | Sub2-92 | m/z = 567.18(C41H26ClN = 568.12) |
| Sub2-93 | m/z = 461.10(C30H20ClNS = 462.01) | Sub2-94 | m/z = 643.12(C42H26ClNS2 = 644.25) |
| Sub2-95 | m/z = 459.10(C30H18ClNO2 = 459.93) | Sub2-96 | m/z = 369.09(C24H16ClNO = 369.85) |
| Sub2-97 | m/z = 541.07(C34H20ClNS2 = 542.11) | Sub2-98 | m/z = 507.05(C30H18ClNOS2 = 508.05) |
| Sub2-99 | m/z = 525.10(C34H20ClNOS = 526.05) | Sub2-100 | m/z = 552.11(C35H21ClN2OS = 553.08) |
| Sub2-101 | m/z = 485.10(C32H20ClNS = 486.03) | Sub2-102 | m/z = 495.14(C34H22ClNO = 496.01) |
| Sub2-103 | m/z = 609.19(C43H28ClNO = 610.15) | Sub2-104 | m/z = 551.11(C36H22ClNOS = 552.09) |
| Sub2-105 | m/z = 588.14(C39H25ClN2S = 589.15) | Sub2-106 | m/z = 626.16(C42H27ClN2S = 627.20) |
| Sub2-107 | m/z = 535.17(C37H26ClNO = 536.07) | Sub2-108 | m/z = 489.17(C33H25ClFN = 490.02) |
| Sub2-109 | m/z = 462.10(C29H19ClN2S = 463.00) | Sub2-110 | m/z = 551.11(C36H22ClNOS = 552.09) |
| Sub2-111 | m/z = 577.16(C39H28ClNS = 578.17) | Sub2-112 | m/z = 635.24(C46H34ClN = 636.24) |
| Sub2-113 | m/z = 647.21(C45H30ClN3 = 648.21) | Sub2-114 | m/z = 596.20(C42H29ClN2 = 597.16) |
| Sub2-115 | m/z = 552.14(C36H25ClN2S = 553.12) | Sub2-116 | m/z = 385.07(C24H16ClNS = 385.91) |
| Sub2-117 | m/z = 552.14(C36H25ClN2S = 553.12) | Sub2-118 | m/z = 485.15(C33H24ClNO = 486.01) |
| Sub2-119 | m/z = 552.14(C36H25ClN2S = 553.12) | Sub2-120 | m/z = 385.07(C24H16ClNS = 385.91) |
| Sub2-121 | m/z = 642.15(C42H27ClN2OS = 643.20) | Sub2-122 | m/z = 647.20(C46H30ClNO = 648.20) |
| Sub2-123 | m/z = 521.15(C36H24ClNO = 522.04) | Sub2-124 | m/z = 521.15(C36H24ClNO = 522.04) |
| Sub2-125 | m/z = 461.10(C30H20ClNS = 462.01) | Sub2-126 | m/z = 461.10(C30H20ClNS = 462.01) |
| Sub2-127 | m/z = 587.15(C40H26ClNS = 588.17) | Sub2-128 | m/z = 571.17(C40H26ClNO = 572.10) |
| Sub2-129 | m/z = 537.13(C36H24ClNS = 538.11) | Sub2-130 | m/z = 537.13(C36H24ClNS = 538.11) |
| Sub2-131 | m/z = 461.10(C30H20ClNS = 462.01) | Sub2-132 | m/z = 400.10(C29H17Cl = 400.91) |
| Sub2-133 | m/z = 214.05(C14H11Cl = 214.69) | Sub2-134 | m/z = 320.10(C21H17ClO = 320.82) |
| Sub2-135 | m/z = 376.10(C27H17Cl = 376.88) | Sub2-136 | m/z = 244.01(C14H9ClS = 244.74) |
| Sub2-137 | m/z = 244.07(C15H13ClO = 244.72) | Sub2-138 | m/z = 320.10(C21H17ClO = 320.82) |
| Sub2-139 | m/z = 264.07(C18H13Cl = 264.75) | Sub2-140 | m/z = 254.09(C17H15Cl = 254.76) |
| Sub2-141 | m/z = 392.10(C27H17ClO = 392.88) | | |

### 3. Example of Synthesis of Final Compound

### 1) Synthesis Example of 1-12

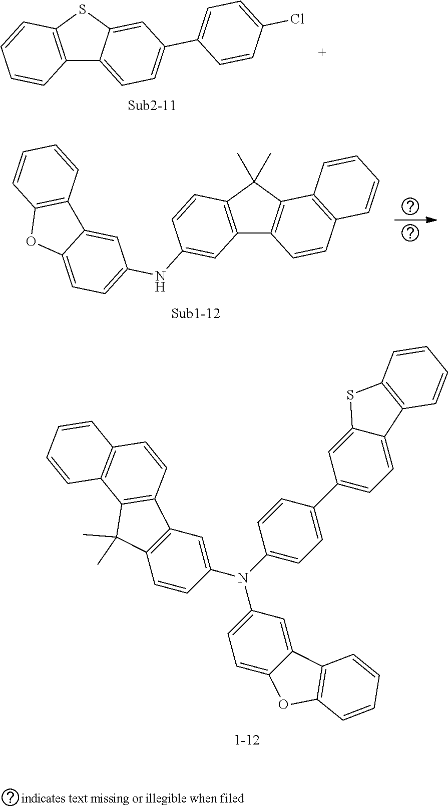 [SMILES: Clc1ccc(-c2ccc3c(c2)sc2ccccc23)cc1 ; CC1(C)c2ccc(Nc3ccc4oc5ccccc5c4c3)cc2-c2ccc3ccccc3c21 ; CC1(C)c2ccc(N(c3ccc(-c4ccc5c(c4)sc4ccccc45)cc3)c3ccc4oc5ccccc5c4c3)cc2-c2ccc3ccccc3c21]

Sub 2-11 (13.6 g, 46.1 mmol), Sub 1-12 (19.6 g, 46.1 mmol), Pd₂(dba)₃ (1.3 g, 1.4 mmol), P(t-Bu)₃ (1.9 mL, 4.6 mmol), NaOt-Bu (13.3 g, 138.4 mmol), and toluene (280 mL) were added into a round bottom flask and stirred at 80° C. Upon completion of the reaction, the resultant was extracted with CH₂Cl₂ and water, and the organic layer was dried over MgSO₄ and concentrated, and the resulting compound was recrystallized using a silica gel column to obtain 26.5 g of the product (yield: 84%).

### 2) Synthesis Example of 1-58

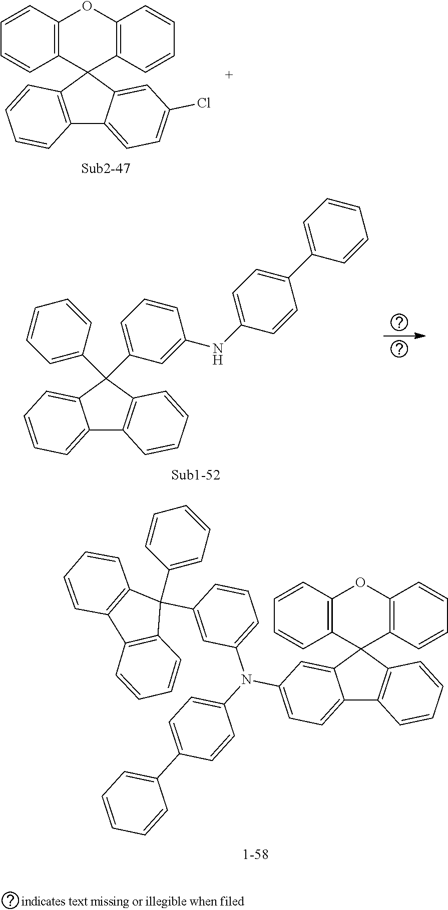 [SMILES: Clc1ccc2c(c1)C1(c3ccccc3Oc3ccccc31)c1ccccc1-2 ; c1ccc(-c2ccc(Nc3cccc(C4(c5ccccc5)c5ccccc5-c5ccccc54)c3)cc2)cc1 ; c1ccc(-c2ccc(N(c3cccc(C4(c5ccccc5)c5ccccc5-c5ccccc54)c3)c3ccc4c(c3)C3(c5ccccc5Oc5ccccc53)c3ccccc3-4)cc2)cc1]

Sub 2-47 (9.0 g, 24.5 mmol), Sub 1-52 (11.9 g, 24.5 mmol), Pd₂(dba)₃ (0.7 g, 0.7 mmol), P(t-Bu)₃ (1.0 mL, 2.5 mmol), NaOt-Bu (7.1 g, 73.6 mmol), and toluene (180 mL) were added into a round bottom flask and the experiment was performed in the same manner as in 1-12 above to obtain 92.1 g of the product (yield: 80%).

### 3) Synthesis Example of 2-40

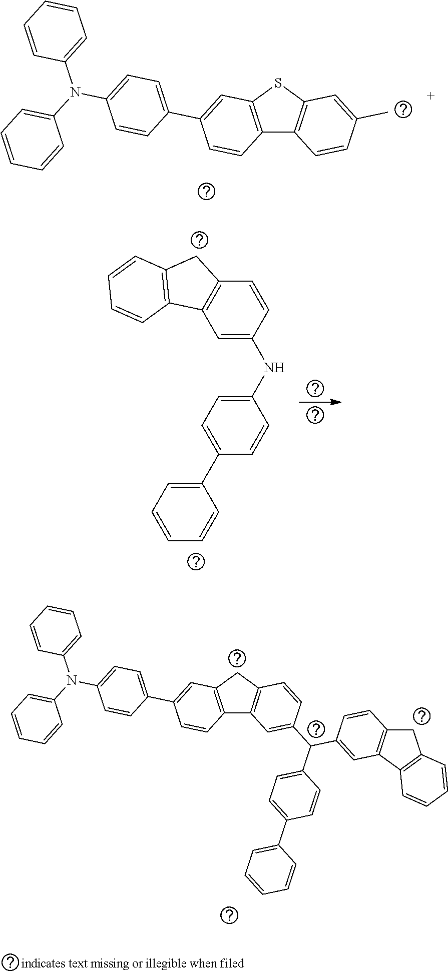 [SMILES: Cc1ccc2c(c1)sc1cc(-c3ccc(N(c4ccccc4)c4ccccc4)cc3)ccc12 ; c1ccc(-c2ccc(Nc3ccc4c(c3)-c3ccccc3C4)cc2)cc1 ; c1ccc(-c2ccc(C(c3ccc4c(c3)-c3ccccc3C4)c3ccc4c(c3)-c3ccc(-c5ccc(N(c6ccccc6)c6ccccc6)cc5)cc3C4)cc2)cc1]

Sub 2-77 (8.0 g, 17.3 mmol), Sub 1-9 (6.1 g, 17.3 mmol), Pd₂(dba)₃ (0.5 g, 0.5 mmol), P(t-Bu)₃ (0.7 mL, 1.7 mmol), NaOt-Bu (5.0 g, 52.0 mmol), and toluene (170 mL) were added into a round bottom flask and the experiment was performed in the same manner as in 1-12 above to obtain 10.3 g of the product (yield: 77%).

### 4) Synthesis Example of 2-74

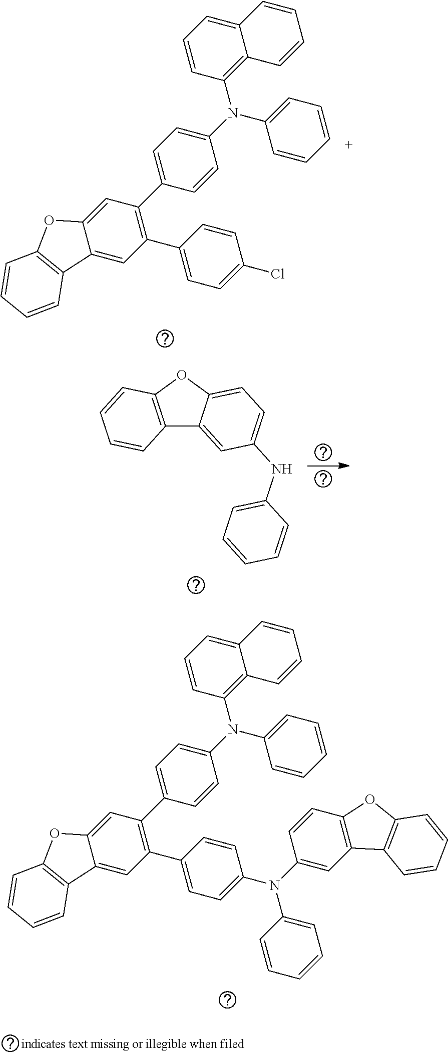 [SMILES: Clc1ccc(-c2cc3c(cc2-c2ccc(N(c4ccccc4)c4cccc5ccccc45)cc2)oc2ccccc23)cc1 ; c1ccc(Nc2ccc3oc4ccccc4c3c2)cc1 ; c1ccc(N(c2ccc(-c3cc4c(cc3-c3ccc(N(c5ccccc5)c5cccc6ccccc56)cc3)oc3ccccc34)cc2)c2ccc3oc4ccccc4c3c2)cc1]

Sub 2-128 (11.5 g, 20.1 mmol), Sub 1-89 (5.2 g, 20.1 mmol), Pd₂(dba)₃ (0.6 g, 0.6 mmol), P(t-Bu)₃ (0.8 mL, 2.0 mmol), NaOt-Bu (5.8 g, 60.3 mmol), and toluene (230 mL) were added into a round bottom flask and the experiment was performed in the same manner as in 1-12 above to obtain 11.9 g of the product (yield: 75%).

### 5) Synthesis Example of H-2

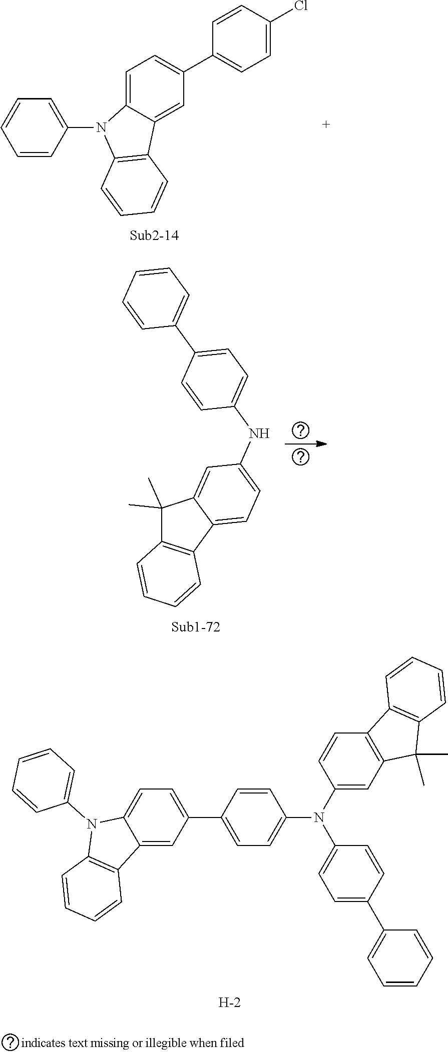

Sub 2-14 (11.0 g, 31.1 mmol), Sub 1-72 (11.2 g, 31.1 mmol), Pd₂(dba)₃ (0.9 g, 0.9 mmol), P(t-Bu)₃ (1.3 mL, 3.1 mmol), NaOt-Bu (9.0 g, 93.3 mmol), and toluene (170 mL) were added into a round bottom flask and the experiment was performed in the same manner as in 1-12 above to obtain 17.5 g of the product (yield: 83%).

### 6) Synthesis Example of H-44

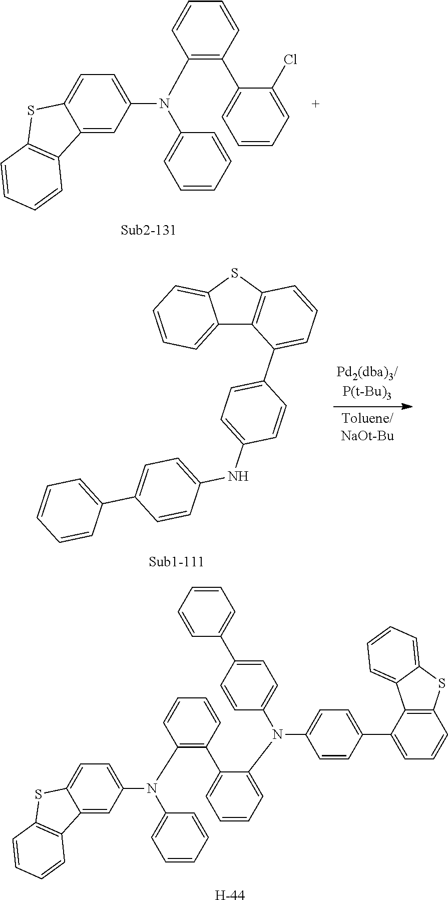

Sub 2-131 (9.6 g, 20.8 mmol), Sub 1-111 (8.9 g, 20.8 mmol), Pd₂(dba)₃ (0.6 g, 0.6 mmol), P(t-Bu)₃ (0.8 mL, 2.1 mmol), NaOt-Bu (6.0 g, 62.3 mmol), and toluene (230 mL) were added into a round bottom flask and the experiment was performed in the same manner as in 1-12 above to obtain 14.0 g of the product (yield: 79%).

### 7) Synthesis Example of H-70

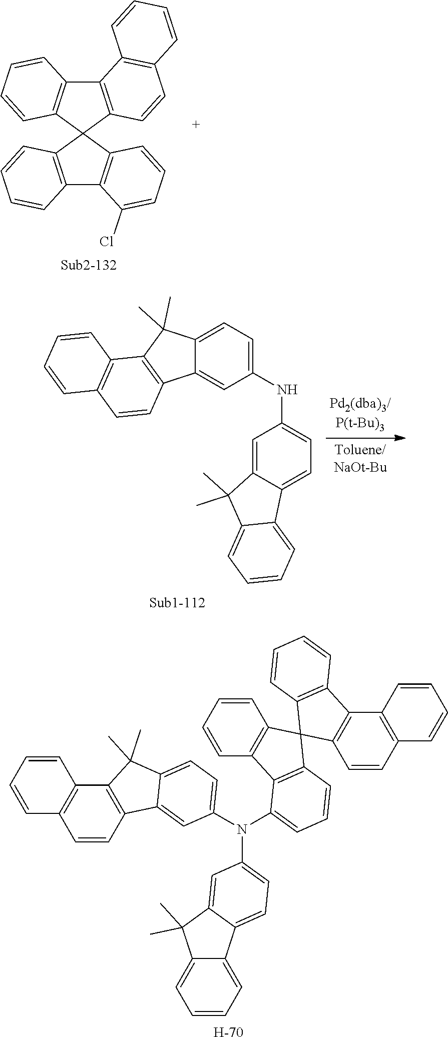

Sub 2-132 (10.0 g, 24.9 mmol), Sub 1-112 (11.3 g, 24.9 mmol), Pd₂(dba)₃ (0.7 g, 0.8 mmol), P(t-Bu)₃ (1.0 mL, 2.5 mmol), NaOt-Bu (7.2 g, 74.8 mmol), and toluene (210 mL) were added into a round bottom flask and the experiment was performed in the same manner as in 1-12 above to obtain 17.1 g of the product (yield: 84%).

Meanwhile, the FD-MS values of Compounds 1-1 to 1-80, 2-1 to 2-80, and H-1 to H-80 of the present disclosure prepared according to the above synthesis examples are shown in Table 3 below.

TABLE 3

| Compound | FD-MS | Compound | FD-MS |
|---|---|---|---|
| 1-1 | m/z = 487.19(C36H25NO = 487.60) | 1-2 | m/z = 587.22(C44H29NO = 587.72) |
| 1-3 | m/z = 687.29(C53H37N = 687.89) | 1-4 | m/z = 532.20(C38H20D5NS = 532.72) |
| 1-5 | m/z = 714.30(C54H38N2 = 714.91) | 1-6 | m/z = 611.22(C46H29NO = 611.74) |
| 1-7 | m/z = 653.22(C48H31NS = 653.84) | 1-8 | m/z = 639.26(C48H33NO = 639.8) |
| 1-9 | m/z = 503.17(C36H25NS = 503.66) | 1-10 | m/z = 545.16(C38H24FNS = 545.68) |
| 1-11 | m/z = 563.08(C36H21NS3 = 563.75) | 1-12 | m/z = 683.23(C49H33NOS = 683.87) |
| 1-13 | m/z = 675.29(C52H37N = 675.88) | 1-14 | m/z = 727.29(C55H37NO = 727.91) |
| 1-15 | m/z = 537.21(C40H27NO = 537.66) | 1-16 | m/z = 715.29(C54H37NO = 715.90) |
| 1-17 | m/z = 613.28(C47H35N = 613.80) | 1-18 | m/z = 713.31(C55H39N = 713.92) |
| 1-19 | m/z = 562.24(C42H30N2 = 562.72) | 1-20 | m/z = 638.27(C48H34N2 = 638.81) |
| 1-21 | m/z = 754.33(C57H42N2 = 754.98) | 1-22 | m/z = 892.35(C67H44N2O = 893.10) |
| 1-23 | m/z = 876.35(C67H44N2 = 877.10) | 1-24 | m/z = 663.27(C49H33N3 = 663.82) |
| 1-25 | m/z = 833.29(C60H39N3S = 834.05) | 1-26 | m/z = 652.25(C48H32N2O = 652.80) |
| 1-27 | m/z = 779.33(C58H41N3 = 779.99) | 1-28 | m/z = 718.24(C52H34N2S = 718.92) |
| 1-29 | m/z = 604.22(C43H28N2O2 = 604.71) | 1-30 | m/z = 618.27(C45H34N2O = 618.78) |
| 1-31 | m/z = 671.26(C49H37NS = 671.90) | 1-32 | m/z = 577.24(C43H31NO = 577.73) |
| 1-33 | m/z = 832.29(C61H40N2S = 833.07) | 1-34 | m/z = 732.22(C52H32N2OS = 732.9) |
| 1-35 | m/z = 668.23(C48H32N2S = 668.86) | 1-36 | m/z = 531.13(C36H21NO2S = 531.63) |
| 1-37 | m/z = 567.17(C40H25NOS = 567.71) | 1-38 | m/z = 567.17(C40H25NOS = 567.71) |
| 1-39 | m/z = 705.34(C54H43N = 705.95) | 1-40 | m/z = 655.32(C50H41N = 655.89) |
| 1-41 | m/z = 781.33(C59H43NO = 782.00) | 1-42 | m/z = 831.26(C61H37NOS = 832.03) |
| 1-43 | m/z = 583.23(C45H29N = 583.73) | 1-44 | m/z = 726.27(C54H34N2O = 726.88) |
| 1-45 | m/z = 635.32(C47H41NO = 635.85) | 1-46 | m/z = 593.22(C43H31NS = 593.79) |
| 1-47 | m/z = 677.27(C51H35NO = 677.85) | 1-48 | m/z = 757.31(C55H39N3O = 757.94) |
| 1-49 | m/z = 743.26(C55H37NS = 743.97) | 1-50 | m/z = 843.30(C63H41NS = 844.09) |
| 1-51 | m/z = 751.29(C57H37NO = 751.93) | 1-52 | m/z = 687.29(C53H37N = 687.89) |
| 1-53 | m/z = 823.33(C61H45NS = 824.10) | 1-54 | m/z = 727.29(C55H37NO = 727.91) |
| 1-55 | m/z = 637.28(C49H35N = 637.83) | 1-56 | m/z = 727.29(C55H37NO = 727.91) |
| 1-57 | m/z = 641.22(C47H31NS = 641.83) | 1-58 | m/z = 815.32(C62H41NO = 816.02) |
| 1-59 | m/z = 700.29(C53H36N2 = 700.89) | 1-60 | m/z = 606.31(C46H30D5N = 606.82) |
| 1-61 | m/z = 651.26(C49H33NO = 651.81) | 1-62 | m/z = 677.31(C52H39N = 677.89) |
| 1-63 | m/z = 843.30(C63H41NS = 844.09) | 1-64 | m/z = 753.34(C58H43N = 753.99) |
| 1-65 | m/z = 575.22(C43H29NO = 575.71) | 1-66 | m/z = 787.20(C55H33NOS2 = 788.00) |
| 1-67 | m/z = 862.25(C61H38N2S2 = 863.11) | 1-68 | m/z = 833.28(C61H39NOS = 834.05) |
| 1-69 | m/z = 783.30(C58H41NS = 784.03) | 1-70 | m/z = 705.27(C52H35NO2 = 705.86) |
| 1-71 | m/z = 845.28(C62H39NOS = 846.06) | 1-72 | m/z = 975.26(C70H41NOS2 = 976.22) |
| 1-73 | m/z = 726.30(C55H38N2 = 726.92) | 1-74 | m/z = 872.32(C64H44N2S = 873.13) |
| 1-75 | m/z = 872.32(C64H44N2S = 873.13) | 1-76 | m/z = 739.29(C56H37NO = 739.92) |
| 1-77 | m/z = 763.32(C59H41N = 763.98) | 1-78 | m/z = 635.23(C45H33NOS = 635.83) |
| 1-79 | m/z = 909.36(C68H47NO2 = 910.13) | 1-80 | m/z = 727.32(C56H41N = 727.95) |
| 2-1 | m/z = 578.24(C42H30N2O = 578.72) | 2-2 | m/z = 720.26(C52H36N2S = 720.93) |
| 2-3 | m/z = 844.38(C64H48N2 = 845.10) | 2-4 | m/z = 779.33(C58H41N3 = 779.99) |
| 2-5 | m/z = 784.36(C58H36D5N3 = 785.02) | 2-6 | m/z = 704.28(C52H36N2O = 704.87) |
| 2-7 | m/z = 876.35(C64H48N2S = 877.16) | 2-8 | m/z = 952.48(C72H60N2 = 953.29) |
| 2-9 | m/z = 904.38(C69H48N2 = 905.16) | 2-10 | m/z = 846.31(C62H42N2S = 847.09) |
| 2-11 | m/z = 936.44(C71H56N2 = 937.24) | 2-12 | m/z = 744.28(C54H36N2O2 = 744.89) |
| 2-13 | m/z = 746.28(C54H38N2S = 746.97) | 2-14 | m/z = 770.33(C57H42N2O = 770.98) |
| 2-15 | m/z = 809.29(C58H39N3S = 810.03) | 2-16 | m/z = 850.27(C60H38N2O2S = 851.04) |
| 2-17 | m/z = 754.3(C56H38N2O = 754.93) | 2-18 | m/z = 764.20(C52H32N2OS2 = 764.96) |
| 2-19 | m/z = 720.26(C52H36N2S = 720.93) | 2-20 | m/z = 748.27(C52H36N4S = 748.95) |
| 2-21 | m/z = 619.21(C43H29N3S = 619.79) | 2-22 | m/z = 704.28(C52H36N2O = 704.87) |
| 2-23 | m/z = 618.27(C45H34N2O = 618.78) | 2-24 | m/z = 754.33(C57H42N2 = 754.98) |
| 2-25 | m/z = 577.25(C42H31N3 = 577.73) | 2-26 | m/z = 859.30(C62H41N3S = 860.09) |
| 2-27 | m/z = 608.19(C42H28N2OS = 608.76) | 2-28 | m/z = 608.19(C42H28N2OS = 608.76) |
| 2-29 | m/z = 784.25(C56H36N2OS = 784.98) | 2-30 | m/z = 734.24(C52H34N2OS = 734.92) |
| 2-31 | m/z = 624.17(C42H28N2S2 = 624.82) | 2-32 | m/z = 730.16(C48H30N2S3 = 730.96) |
| 2-33 | m/z = 608.19(C42H28N2OS = 608.76) | 2-34 | m/z = 684.22(C48H32N2OS = 684.86) |
| 2-35 | m/z = 907.36(C67H45N3O = 908.12) | 2-36 | m/z = 912.26(C65H40N2S2 = 913.17) |
| 2-37 | m/z = 750.22(C52H34N2S2 = 750.98) | 2-38 | m/z = 790.30(C59H38N2O = 790.97) |
| 2-39 | m/z = 700.20(C48H32N2S2 = 700.92) | 2-40 | m/z = 776.23(C54H36N2S2 = 777.02) |
| 2-41 | m/z = 758.26(C54H34N2O3 = 758.88) | 2-42 | m/z = 642.23(C46H30N2O2 = 642.76) |
| 2-43 | m/z = 790.25(C55H38N2S2 = 791.04) | 2-44 | m/z = 796.17(C52H32N2OS3 = 797.02) |
| 2-45 | m/z = 810.27(C58H38N2OS = 811.02) | 2-46 | m/z = 761.25(C53H35N3OS = 761.94) |
| 2-47 | m/z = 724.20(C50H32N2S2 = 724.94) | 2-48 | m/z = 810.27(C58H38N2OS = 811.02) |
| 2-49 | m/z = 924.32(C67H44N2OS = 925.16) | 2-50 | m/z = 774.23(C54H34N2O2S = 774.94) |
| 2-51 | m/z = 770.28(C56H38N2S = 770.99) | 2-52 | m/z = 759.27(C54H37N3S = 759.97) |
| 2-53 | m/z = 774.27(C55H38N2OS = 774.98) | 2-54 | m/z = 749.32(C54H40FN3 = 749.93) |
| 2-55 | m/z = 671.24(C47H33N3S = 671.86) | 2-56 | m/z = 942.27(C66H42N2OS2 = 943.20) |
| 2-57 | m/z = 876.32(C63H44N2OS = 877.12) | 2-58 | m/z = 884.41(C67H52N2 = 885.17) |
| 2-59 | m/z = 946.37(C69H46N4O = 947.15) | 2-60 | m/z = 911.33(C66H45N3S = 912.17) |
| 2-61 | m/z = 891.33(C63H45N3OS = 892.13) | 2-62 | m/z = 862.27(C61H38N2O2S = 863.05) |
| 2-63 | m/z = 958.32(C66H46N4S2 = 959.24) | 2-64 | m/z = 888.32(C64H44N2OS = 889.13) |
| 2-65 | m/z = 791.24(C54H37N3S2 = 792.03) | 2-66 | m/z = 941.31(C66H43N3O2S = 942.15) |
| 2-67 | m/z = 865.28(C60H39N3O2S = 866.05) | 2-68 | m/z = 870.32(C64H42N2O2 = 871.05) |
| 2-69 | m/z = 836.29(C60H40N2OS = 837.05) | 2-70 | m/z = 760.25(C54H36N2OS = 760.96) |
| 2-71 | m/z = 852.26(C60H40N2S2 = 853.11) | 2-72 | m/z = 776.23(C54H36N2S2 = 777.02) |
| 2-73 | m/z = 810.27(C58H38N2OS = 811.02) | 2-74 | m/z = 794.29(C58H38N2O2 = 794.95) |
| 2-75 | m/z = 776.23(C54H36N2S2 = 777.02) | 2-76 | m/z = 852.26(C60H40N2S2 = 853.11) |
| 2-77 | m/z = 702.22(C48H34N2S2 = 702.93) | 2-78 | m/z = 892.31(C63H44N2O2S = 893.12) |
| 2-79 | m/z = 934.31(C65H46N2OS2 = 935.22) | 2-80 | m/z = 808.35(C60H44N2O = 809.03) |
| H-1 | m/z = 638.27(C48H34N2 = 638.81) | H-2 | m/z = 678.30(C51H38N2 = 678.88) |
| H-3 | m/z = 802.33(C61H42N2 = 803.02) | H-4 | m/z = 800.32(C61H40N2 = 801.01) |
| H-5 | m/z = 650.27(C49H34N2 = 650.83) | H-6 | m/z = 678.30(C51H38N2 = 678.88) |
| H-7 | m/z = 754.33(C57H42N2 = 754.98) | H-8 | m/z = 744.26(C54H36N2S = 744.96) |
| H-9 | m/z = 688.29(C52H36N2 = 688.87) | H-10 | m/z = 652.29(C49H36N2 = 652.84) |
| H-11 | m/z = 653.28(C48H35N3 = 653.83) | H-12 | m/z = 612.26(C46H32N2 = 612.78) |
| H-13 | m/z = 662.27(C50H34N2 = 662.84) | H-14 | m/z = 692.23(C50H32N2S = 692.88) |
| H-15 | m/z = 668.23(C48H32N2S = 668.86) | H-16 | m/z = 652.25(C48H32N2O = 652.80) |
| H-17 | m/z = 744.26(C54H36N2S = 744.96) | H-18 | m/z = 682.21(C48H30N2OS = 682.84) |
| H-19 | m/z = 818.34(C60H42N4 = 819.02) | H-20 | m/z = 835.30(C60H41N3S = 836.07) |
| H-21 | m/z = 829.35(C62H43N3 = 830.05) | H-22 | m/z = 945.41(C71H51N3 = 946.21) |
| H-23 | m/z = 743.29(C54H37N3O = 743.91) | H-24 | m/z = 802.33(C61H42N2 = 803.02) |
| H-25 | m/z = 612.26(C46H32N2 = 612.78) | H-26 | m/z = 702.30(C53H38N2 = 702.90) |
| H-27 | m/z = 742.30(C55H38N2O = 742.92) | H-28 | m/z = 612.26(C46H32N2 = 612.78) |
| H-29 | m/z = 764.32(C58H40N2 = 764.97) | H-30 | m/z = 702.27(C52H34N2O = 702.86) |
| H-31 | m/z = 741.28(C54H35N3O = 741.89) | H-32 | m/z = 668.23(C48H32N2S = 668.86) |
| H-33 | m/z = 728.28(C54H36N2O = 728.90) | H-34 | m/z = 833.29(C60H39N3S = 834.05) |
| H-35 | m/z = 802.33(C61H42N2 = 803.02) | H-36 | m/z = 800.32(C61H40N2 = 801.01) |
| H-37 | m/z = 654.27(C48H34N2O = 654.81) | H-38 | m/z = 730.30(C54H38N2O = 730.91) |
| H-39 | m/z = 704.28(C52H36N2O = 704.87) | H-40 | m/z = 831.32(C61H41N3O = 832.02) |
| H-41 | m/z = 760.25(C54H36N2OS = 760.96) | H-42 | m/z = 760.25(C54H36N2OS = 760.96) |
| H-43 | m/z = 892.29(C63H44N2S2 = 893.18) | H-44 | m/z = 852.26(C60H40N2S2 = 853.11) |
| H-45 | m/z = 759.33(C56H33D5N2O = 759.96) | H-46 | m/z = 880.35(C66H44N2O = 881.09) |
| H-47 | m/z = 852.26(C60H40N2S2 = 853.11) | H-48 | m/z = 846.32(C62H42N2O2 = 847.03) |
| H-49 | m/z = 890.30(C63H42N2O2S = 891.10) | H-50 | m/z = 780.31(C58H40N2O = 780.97) |
| H-51 | m/z = 800.34(C58H44N2O2 = 801.00) | H-52 | m/z = 848.27(C60H36N2O4 = 848.96) |
| H-53 | m/z = 760.25(C54H36N2OS = 760.96) | H-54 | m/z = 794.33(C59H42N2O = 795.00) |
| H-55 | m/z = 852.26(C60H40N2S2 = 853.11) | H-56 | m/z = 924.32(C67H44N2OS = 925.16) |
| H-57 | m/z = 815.32(C62H41NO = 816.02) | H-58 | m/z = 679.20(C49H29NOS = 679.84) |
| H-59 | m/z = 781.28(C58H39NS = 782.02) | H-60 | m/z = 863.32(C66H41NO = 864.06) |
| H-61 | m/z = 715.23(C53H33NS = 715.91) | H-62 | m/z = 755.23(C55H33NOS = 755.94) |
| H-63 | m/z = 781.28(C58H39NS = 782.02) | H-64 | m/z = 799.32(C62H41N = 800.02) |
| H-65 | m/z = 811.32(C63H41N = 812.03) | H-66 | m/z = 755.23(C55H33NOS = 755.94) |
| H-67 | m/z = 867.30(C65H41NS = 868.11) | H-68 | m/z = 899.36(C70H45N = 900.14) |
| H-69 | m/z = 775.29(C59H37NO = 775.95) | H-70 | m/z = 815.36(C63H45N = 816.06) |
| H-71 | m/z = 867.30(C65H41NS = 868.11) | H-72 | m/z = 964.35(C73H44N2O = 965.17) |
| H-73 | m/z = 771.30(C57H41NS = 772.02) | H-74 | m/z = 831.26(C61H37NOS = 832.03) |
| H-75 | m/z = 726.30(C55H38N2 = 726.92) | H-76 | m/z = 711.29(C55H37N = 711.91) |
| H-77 | m/z = 730.33(C55H42N2 = 730.96) | H-78 | m/z = 1066.45(C79H58N2O2 = 1067.35) |
| H-79 | m/z = 994.41(C72H54N2O3 = 995.24) | H-80 | m/z = 941.37(C72H47NO = 942.17) |

### II. Synthesis of Quantum Dots

### [Synthesis Example Z1] Preparation of Zn(Oleate)₂

1) 5.5 g (30 mmol) of zinc acetate and 19 mL (60 mmol) of oleic acid were added into a 250 mL flask and the pressure was reduced at room temperature (RT) for 1 hour.

2) The solution was heated to 180° C. for 20 minutes under reduced pressure and then reacted for 1 hour to produce a Zn(oleate)₂ solution.

3) After preparing the solution in an inert gas atmosphere, 20.5 mL of octadecene (ODE) was injected thereinto and the temperature was reduced to room temperature. The concentration of the mixed solution was 1 M, and 1 mL of the mixed solution contained 1 mmol of Zn(oleate)₂.

### [Synthesis Example Z2] Preparation of Zn—OXO

1) 5.5 g (30 mmol) of zinc acetate and 19 mL (60 mmol) of oleic acid were added into a 250 mL three-necked flask and the pressure was reduced at room temperature (RT) for 1 hour.

2) The solution was heated to 180° C. for 20 minutes under reduced pressure and then reacted for 1 hour to produce a Zn(oleate)₂ solution.

3) The solution was heated to 300° C. for 10 minutes under reduced pressure and then reacted for 20 minutes.

4) Ater preparing the mixed solution into an inert gas atmosphere, 20.5 mL of octadecene was injected thereinto and the temperature was reduced to room temperature. The concentration of the mixed solution was 1 M, and 1 mL of the mixed solution contained 1 mmol of Zn—OXO.

### [Synthesis Example QD_1] Preparation of Green Quantum Dots (InP/ZnSe/ZnSeS/ZnS)

1) 1 mL of a 0.5 M indium precursor solution (0.1106 g InCl₃, 1 mL of solvent trioctylphosphine (TOP)), 0.48 mL of oleic acid, and 10 mL of ODE were added into a 250 mL three-necked flask and mixed. In particular, the molar ratio of each precursor was as follows: In:oleic acid=1:3.

2) The solution was reacted at 110° C. for 1 hour while reducing the pressure.

3) The solution was replaced with an inert gas atmosphere, and the solution was heated to 260° C., and 1 mL of trimethylsilylphosphine (TMSP) was injected thereinto.

4) The solution was reacted at 260° C. for 10 minutes and then cooled to 150° C. while blowing N₂ gas to prepare an InP core.

5) 2 mL of 1 M TOP-Se (0.0789 g of selenium powder, 1 mL of TOP) was injected into the solution containing the InP core, and the mixture was heated to 300° C. and reacted for 30 minutes.

6) 1 mL of 1 M TOP-Se and 2 mL of 1 M TOP-S(0.0321 g of sulfur powder, 1 mL of TOP) were injected into the solution and the mixture was reacted for 9 hours.

7) 1 mL of 1 M TOP-S was injected into the solution and the mixture was reacted for 1 hour to form a ZnSe/ZnSeS/ZnS shell.

8) Isopropanol, an anti-solvent, in an amount of 8-fold compared to 5 mL of quantum dots was added into a falcon tube, centrifuged at 7,000 rpm for 10 minutes, and the supernatant was discarded.

9) Hexane was added to the separated precipitate and mixed, and the above centrifugation process was repeated to dry the mixture to obtain quantum dots, which were dispersed in octane at 10 wt %.

### [Synthesis Example QD_2] Preparation of Green Quantum Dots (InZnP/ZnSe/ZnSeS/ZnS)

1) Zn(oleate)₂, which was synthesized in Synthesis Example Z1 above, and 1 mL of a 0.5 M indium precursor solution (0.1106 g InCl₃, 1 mL of solvent trioctylphosphine (TOP)) were added into a 250 mL three-necked flask and mixed. In particular, the molar ratio of each precursor was as follows: In:Zn=1:25.

2) The solution was reacted at 110° C. for 1 hour while reducing the pressure.

3) The solution was replaced with an inert gas atmosphere, and the solution was heated to 260° C., and 1 mL of trimethylsilylphosphine (TMSP) was injected thereinto.

4) The solution was reacted at 260° C. for 1 hour and then cooled to 150° C. while blowing N₂ gas to prepare an InZnP core.

5) 2 mL of 1 M TOP-Se (0.0789 g of selenium powder, 1 mL of TOP) was injected into the solution containing the InZnP core, and the mixture was heated to 300° C. and reacted for 30 minutes.

6) 1 mL of 1 M TOP-Se and 2 mL of 1 M TOP-S(0.0321 g of sulfur powder, 1 mL of TOP) were injected into the solution and the mixture was reacted for 9 hours.

7) 1 mL of 1 M TOP-S was injected into the solution and the mixture was reacted for 1 hour to form a ZnSe/ZnSeS/ZnS shell.

8) Isopropanol, an anti-solvent, in an amount of 8-fold compared to 5 mL of quantum dots was added into a falcon tube, centrifuged at 7,000 rpm for 10 minutes, and the supernatant was discarded.

9) Hexane was added to the separated precipitate and mixed, and the above centrifugation process was repeated to dry the mixture to obtain quantum dots, which were dispersed in octane at 10 wt %.

### [Synthesis Example QD_3] Preparation of Green Quantum Dots (InZnP/ZnSe/ZnSeS/ZnS)

Quantum dots were prepared in the same manner as in the QD_2 Synthesis Example, except that 25 mL of Zn—OXO synthesized in Synthesis Example Z2 was used instead of 25 mL of Zn(oleate)₂ in the QD_2 Synthesis Example. The manufactured quantum dots formed a ZnSe/ZnSeS/ZnS shell on the InZnP core.

### [Synthesis Example QD_4] Preparation of Green Quantum Dots (InZnP/ZnSeS/ZnS)

1) 25 mL of Zn—OXO, which was synthesized in Synthesis Example Z2, and 1 mL of a 0.5 M indium precursor solution were added into a 250 mL three-necked flask and mixed. In particular, the molar ratio of each precursor was as follows: In:Zn=1:25.

2) The solution was reacted at 110° C. for 1 hour while reducing the pressure.

3) The solution was replaced with an inert gas atmosphere, and the solution was heated to 260° C., and 1 mL of TMSP solution was injected thereinto.

4) The solution was reacted at 260° C. for 1 hour and then cooled to 150° C. while blowing N₂ gas to prepare an InZnP core.

5) 3 mL of 1 M TOP-Se and 1.5 mL of TOP-S were injected onto the InZnP core, and the mixture was heated to 300° C. and reacted for 9 hours.

6) 1.5 mL of 1 M TOP-S was injected into the solution and the mixture was reacted for 1 hour to form a ZnSeS/ZnS shell.

7) Isopropanol, an anti-solvent, in an amount of 8-fold compared to 5 mL of quantum dots was added into a falcon tube, centrifuged at 7,000 rpm for 10 minutes, and the supernatant was discarded.

8) Hexane was added to the separated precipitate and mixed, and the above centrifugation process was repeated to dry the mixture to obtain quantum dots, which were dispersed in octane at 10 wt %.

### [Synthesis Example QD_5] Preparation of Green Quantum Dots (InP/ZnSe/ZnS)

1) 25 mL of Zn—OXO, which was synthesized in Synthesis Example Z2, and 1 mL of a 0.5 M indium precursor solution were added into a 250 mL three-necked flask and mixed. In particular, the molar ratio of each precursor was as follows: In:Zn=1:25.

2) The solution was reacted at 110° C. for 1 hour while reducing the pressure.

3) The solution was replaced with an inert gas atmosphere, and the solution was heated to 260° C., and 1 mL of trimethylsilylphosphine (TMSP) was injected thereinto.

4) The solution was reacted at 260° C. for 1 hour and then cooled to 150° C. while blowing N₂ gas to prepare an InZnP core.

5) 6 mL of 1 M TOP-Se was injected onto the InZnP core, and the mixture was heated to 300° C. and reacted for 9 hours.

6) 2 mL of 1 M TOP-Se was injected into the solution and the mixture was reacted for 1 hour to form a ZnSe/ZnS shell.

7) Isopropanol, an anti-solvent, in an amount of 8-fold compared to 5 mL of quantum dots was added into a falcon tube, centrifuged at 7,000 rpm for 10 minutes, and the supernatant was discarded.

8) Hexane was added to the separated precipitate and mixed, and the above centrifugation process was repeated to dry the mixture to obtain quantum dots, which were dispersed in octane at 10 wt %.

### [Synthesis Example QD_6] Preparation of Red Quantum Dots (InZnP/ZnSeS/ZnS)

1 mmol indium (In) acetylacetonate, 0.5 mmol Zn acetylacetonate, 4 mmol oleic acid, and 10 mL ODE were added into a 100 mL three-necked flask and mixed.

2) The solution was reacted at 110° C. for 1 hour while reducing the pressure, replaced with an inert gas, and cooled to room temperature.

3) TMSP solution (1 mL of 0.07 mmol TMSP in TOP) was added to the solution and the mixture was reacted for 1 hour.

4) 1 mmol indium (In) acetate, 3 mmol palmitic acid, and 10 mL of ODE were added to a 250 mL three-necked flask and mixed.

5) The solution was reacted at 110° C. for 1 hour while reducing the pressure.

6) The solution was replaced with an inert gas atmosphere, heated to 260° C., and 1 mL of TMSP solution was injected thereinto.

7) After reacting the solution at 260° C. for 10 minutes, 5 mL of the solution prepared in step 3 above was injected at the same temperature at a rate of 1 mL/h.

8) After cooling the solution to 150° C., 25 mL of Zn OXO synthesized in Synthesis Example Z2, 3 mL of 1 M TOP-Se, and 1.5 mL of 1 M TOP-S were injected thereto, and the mixture was heated to 300° C., and then reacted for 9 hours.

9) 1.5 mL of 1 M TOP-S was injected into the solution and reacted for 1 hour to form a ZnSeS/ZnS shell.

10) Isopropanol, an anti-solvent, in an amount of 8-fold compared to 5 mL of quantum dots was added into a falcon tube, centrifuged at 7,000 rpm for 10 minutes, and the supernatant was discarded.

11) Hexane was added to the separated precipitate and mixed, and the above centrifugation process was repeated to dry the mixture to obtain quantum dots, which were dispersed at 10 wt % in octane.

### Experimental Examples of Optical Properties of Quantum Dots

The quantum dots of QD_1 Synthesis Example to QD_6 Synthesis Example prepared in this way were each dissolved in hexane, and thereby the photoluminescence data [Emission Peak, Quantum Yield, and Full Width at Half Maximum (FWHM)] analyzed by light irradiation at a wavelength of 450 nm using QE-2000 (Otsuka Electronics) were confirmed. Table 4 below shows the results of evaluating photoluminescence data.

TABLE 4

| | | Full Width | |
|---|---|---|---|
| | | at Half | |
| | Emission | Maximum | Luminous |
| | Wavelength | (FWHM) | efficiency |
| | (nm) | (nm) | (%) |
| QD_1 | 532 | 57 | 67 |
| QD_2 | 537 | 54 | 74 |
| QD_3 | 535 | 35 | 80 |
| QD_4 | 530 | 36 | 87 |
| QD_5 | 534 | 37 | 88 |
| QD_6 | 617 | 44 | 85 |

### Evaluation of Manufacture of Quantum Dot Light Emitting Devices

### Conventional Structure

### (Example 1) Green Quantum Dot Light Emitting Device (Auxiliary Light Emitting Layer)

First, in an inert gas atmosphere, poly(3,4-ethylenedioxythiophene):polystyrenesulfonate (PEDOT:PSS) (Al 4083, Heraeus Clevios) was spin-coated at 3,500 rpm on the ITO layer formed on a glass substrate and then heat treated at 150° C. for 10 minutes to form a hole injection layer with a thickness of 30 nm.

Poly[9,9-dioctylfluorene-co-N-[4-(3-methylpropyl)]-diphenylamine](TFB) (Sumitomo Chemical) dispersed in chlorobenzene at 10 mg/mL on the hole injection layer was spin-coated at 3,000 rpm and then heat treated at 150° C. for 10 minutes to form a hole transport layer with a thickness of 25 nm.

On top of the hole transport layer, Compound 1-2 of the present disclosure was vacuum deposited to a thickness of 10 nm to form an auxiliary light emitting layer.

On top of the auxiliary light emitting layer, QD_1 quantum dots dispersed in octane at 10 wt % were spin-coated at 2,000 rpm and then heat-treated at 60° C. for 5 minutes to form a light emitting layer with a thickness of 20 nm.

On top of the light emitting layer, ZnMgO was spin-coated at 5,000 rpm and then heat treated at 180° C. for 10 minutes to form an electron transport layer with a thickness of 40 nm.

Then, a quantum dot light emitting device was manufactured by forming electrodes by depositing Al to a thickness of 100 nm.

### (Example 2) to (Example 8)

A quantum dot light emitting device was manufactured in the same manner as in Example 1, except that the compounds of the present disclosure shown in Table 5 below were used as the hole transport layer material, the auxiliary light emitting layer material, and the light emitting layer material.

### Comparative Example 1

A quantum dot light emitting device was manufactured in the same manner as Example 1, except that the auxiliary light emitting layer was not used.

### Comparative Example 2

A quantum dot light emitting device was manufactured in the same manner as Example 1 above, except that the following comparative compound 1 (NPD: N4,N4′-di(naphthalen-1-yl)-N4,N4′-bis(4-vinylphenyl)biphenyl-4,4′) was used as the auxiliary light emitting layer material.

### Comparative Compound 1

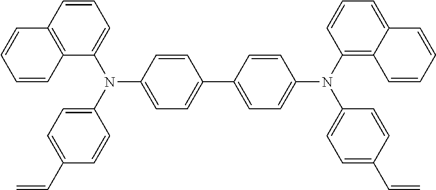 [SMILES: C=Cc1ccc(N(c2ccc(-c3ccc(N(c4ccc(C=C)cc4)c4cccc5ccccc45)cc3)cc2)c2cccc3ccccc23)cc1]

### Comparative Example 3

A quantum dot light emitting device was manufactured in the same manner as Example 1, except that Comparative Compound 1 was used as the auxiliary light emitting layer material and QD_6 quantum dot material was used as the light emitting layer material.

The electroluminescence (EL) characteristics of the quantum dot light emitting devices manufactured according to Examples 1 to 8 and Comparative Examples 1 to 3 were measured by applying thereto a forward bias direct current voltage using PR-650 from Photoresearch, and T50 lifetime was measured using a lifetime measurement equipment manufactured by McScience at a standard luminance of 500 cd/m². Table 5 below shows the manufactured devices and evaluation results thereof.

TABLE 5

| | | Auxiliary | | | | | |
|---|---|---|---|---|---|---|---|
| | Hole | Light | Light | Emission | | | |
| | Transport | Emitting | Emitting | Wavelength | Voltage | EQE | T50 (h) @ |
| | Layer | Layer | Layer | (nm) | (V) | (%) | 500 nit |
| Comparative | TFB | — | QD_1 | 533 | 3.2 | 2.61 | 0.28 |
| Example (1) | | | | | | | |
| Comparative | TFB | Comparative | QD_1 | 532 | 3.1 | 3.05 | 0.33 |
| Example (2) | | Compound 1 | | | | | |
| Comparative | TFB | Comparative | QD_6 | 618 | 3.8 | 5.09 | 0.45 |
| Example (3) | | Compound 1 | | | | | |
| Example (1) | TFB | 1-2 | QD_1 | 532 | 3.0 | 7.01 | 0.61 |
| Example (2) | H-77 | 1-2 | QD_1 | 534 | 2.9 | 7.51 | 0.73 |
| Example (3) | H-77 | 2-27 | QD_1 | 533 | 2.9 | 7.68 | 0.78 |
| Example (4) | H-77 | 2-27 | QD_2 | 538 | 2.9 | 8.77 | 0.81 |
| Example (5) | H-77 | 2-27 | QD_3 | 536 | 2.8 | 11.08 | 0.90 |
| Example (6) | H-77 | 2-27 | QD_4 | 531 | 2.8 | 11.10 | 0.89 |
| Example (7) | H-77 | 2-27 | QD_5 | 535 | 2.7 | 11.25 | 0.92 |
| Example (8) | H-77 | 2-27 | QD_6 | 617 | 3.6 | 14.63 | 1.02 |

As can be seen from the results in Table 5 above, compared to Comparative Examples 1 to 3 in which an auxiliary light emitting layer was not formed in the quantum dot light emitting device or Comparative Compound 1 was used, when a quantum dot light emitting device was manufactured using the compound of the present disclosure as an auxiliary light emitting layer material, it can be seen that not only the operating voltage can be lowered, but also the luminous efficiency and lifetime can be significantly improved.

To describe in detail, it can be seen that the overall performance of the device of Comparative Example 2, in which the auxiliary light emitting layer was formed using Comparative Compound 1, was slightly improved compared to that of Comparative Example 1, in which the auxiliary light emitting layer was not used. This shows that by forming the auxiliary light emitting layer, the movement of holes from the hole transport layer can be efficiently controlled, thereby improving device performance.

In particular, it can be seen that the devices of Examples 1 to 8, in which the compound of the present disclosure was used as an auxiliary light emitting layer material, shows more excellent results compared to that of Comparative Compound 1. These results show that when 3- or more-membered cyclic compounds (e.g., dibenzofuran, dibenzothiophene, fluorene derivatives, etc.) are introduced as substituents, there is a large difference in hole mobility, and it is determined that this difference in mobility affects the overall device performance.

In addition, it can be confirmed that among the examples using the compound of the present disclosure as an auxiliary light emitting layer material, compared to the quantum dot light emitting device of Example 4 in which QD_2 quantum dots using zinc oleate were applied as the light emitting layer material, the luminous efficiency of the quantum dot light emitting devices of Examples 5 to 8, in which QD_3 to QD_6 quantum dots using a metal oxo cluster (i.e., zinc oxo (Zn-Oxo)) were applied as the light emitting layer material, was further increased.

This shows that as can be seen from the results in Table 4 above, the quantum dot material using zinc oxo (Zn-Oxo) has a narrow full width at half maximum and shows excellent luminous efficiency compared to that of QD_2 quantum dots using zinc oleate, thereby improving the device performance of the quantum dot light emitting device.

### B) Inverted Structure

### (Example 9) Quantum Dot Light Emitting Device (Auxiliary Light Emitting Layer)

First, ZnMgO was spin-coated at 5,000 rpm on the ITO layer formed on a glass substrate, and then heat treated at 180° C. for 10 minutes to form an electron transport layer with a thickness of 40 nm.

On top of the electron transport layer, QD_1 quantum dots dispersed in octane at 10 wt % were spin-coated at 2,000 rpm and then heat treated at 100° C. for 5 minutes to form a light emitting layer with a thickness of 20 nm.

On top of the light emitting layer, Compound 1-1 of the present disclosure was vacuum deposited to a thickness of 10 nm to form an auxiliary light emitting layer.

On top of the auxiliary light emitting layer, Compound H-2 of the present disclosure was vacuum deposited to a thickness of 30 nm to form a hole transport layer.

On top of the hole transport layer, hexaazatriphenylenehexacarbonitrile (HATCN) was vacuum deposited to a thickness of 7 nm to form a hole injection layer on top of the hole transport layer.

Then, a quantum dot light emitting device was manufactured by depositing Al to a thickness of 100 nm to form electrodes.

### (Example 10) to (Example 32)

A quantum dot light emitting device was manufactured in the same manner as in Example 9, except that the compounds of the present disclosure shown in Table 6 below were used as the hole transport layer material, the light emitting auxiliary layer material, and the light emitting layer material.

### Comparative Example 4

A quantum dot light emitting device was manufactured in the same manner as Example 9, except that an auxiliary light emitting layer was not used.

### Comparative Example 5

A quantum dot light emitting device was manufactured in the same manner as Example 9, except that Comparative Compound 2 was used as an auxiliary light emitting layer material.

### Comparative Example 2

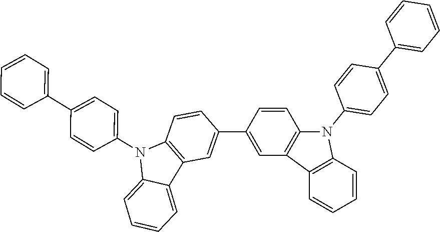 [SMILES: c1ccc(-c2ccc(-n3c4ccccc4c4cc(-c5ccc6c(c5)c5ccccc5n6-c5ccc(-c6ccccc6)cc5)ccc43)cc2)cc1]

### Comparative Example 6

A quantum dot light emitting device was manufactured in the same manner as in Example 9, except that Comparative Compound 2 was used as an auxiliary light emitting layer material and QD_6 quantum dot material was used as a light emitting layer material.

The electroluminescence (EL) characteristics of the quantum dot light emitting devices manufactured according to Examples 9 to 32 and Comparative Examples 4 to 6 were measured by applying thereto a forward bias direct current voltage using PR-650 from Photoresearch, and T50 lifetime was measured using a lifetime measurement equipment manufactured by McScience at a standard luminance of 500 cd/m². Table 6 below shows the manufactured devices and evaluation results thereof.

TABLE 6

| | | Auxiliary | | | | | |
|---|---|---|---|---|---|---|---|
| | Hole | Light | Light | Emission | | | |
| | Transport | Emitting | Emitting | Wavelength | Voltage | EQE | T50 (h) @ |
| | Layer | Layer | Layer | (nm) | (V) | (%) | 500 nit |
| Comparative | H-2 | — | QD_1 | 532 | 3.3 | 1.84 | 0.17 |
| Example (4) | | | | | | | |
| Comparative | H-2 | Comparative | QD_1 | 534 | 3.2 | 2.51 | 0.28 |
| Example (5) | | Compound 1 | | | | | |
| Comparative | H-2 | Comparative | QD_6 | 617 | 4.1 | 3.22 | 0.36 |
| Example (6) | | Compound 1 | | | | | |
| Example (9) | H-2 | 1-1 | QD_1 | 533 | 3.1 | 6.95 | 0.68 |
| Example (10) | H-2 | 1-1 | QD_2 | 537 | 3.1 | 7.69 | 0.72 |
| Example (11) | H-2 | 1-1 | QD_3 | 536 | 3.0 | 8.21 | 0.76 |
| Example (12) | H-2 | 1-1 | QD_4 | 531 | 2.9 | 8.35 | 0.78 |
| Example (13) | H-2 | 1-1 | QD_5 | 536 | 3.0 | 8.40 | 0.79 |
| Example (14) | H-2 | 1-36 | QD_4 | 532 | 3.0 | 8.63 | 0.80 |
| Example (15) | H-38 | 1-52 | QD_4 | 530 | 3.1 | 8.24 | 0.77 |
| Example (16) | H-60 | 1-61 | QD_4 | 531 | 3.0 | 8.56 | 0.79 |
| Example (17) | H-18 | 1-65 | QD_5 | 535 | 3.0 | 9.06 | 0.75 |
| Example (18) | H-47 | 1-70 | QD_5 | 536 | 2.9 | 9.35 | 0.77 |
| Example (19) | H-75 | 2-7 | QD_5 | 536 | 2.9 | 9.60 | 0.82 |
| Example (20) | H-75 | 2-17 | QD_5 | 535 | 2.9 | 9.61 | 0.81 |
| Example (21) | H-63 | 2-14 | QD_5 | 537 | 3.0 | 9.64 | 0.80 |
| Example (22) | H-2 | 2-31 | QD_5 | 535 | 2.8 | 10.82 | 0.85 |
| Example (23) | H-38 | 2-31 | QD_5 | 535 | 2.9 | 10.80 | 0.82 |
| Example (24) | H-60 | 2-31 | QD_5 | 536 | 2.8 | 10.62 | 0.80 |
| Example (25) | H-47 | 2-31 | QD_5 | 537 | 2.9 | 10.11 | 0.81 |
| Example (26) | H-2 | 2-72 | QD_5 | 536 | 2.8 | 10.54 | 0.84 |
| Example (27) | H-2 | 1-1 | QD_6 | 617 | 4.0 | 9.80 | 1.22 |
| Example (28) | H-2 | 1-61 | QD_6 | 619 | 4.0 | 10.29 | 1.24 |
| Example (29) | H-2 | 2-31 | QD_6 | 618 | 3.8 | 12.32 | 1.31 |
| Example (30) | H-38 | 2-31 | QD_6 | 617 | 3.9 | 12.30 | 1.29 |
| Example (31) | H-60 | 2-31 | QD_6 | 618 | 3.8 | 11.86 | 1.28 |
| Example (32) | H-2 | 2-70 | QD_6 | 619 | 3.9 | 11.64 | 1.25 |

As can be seen from the results in Table 6 above, compared to Comparative Examples 4 to 6 in which an auxiliary light emitting layer was not formed in the quantum dot light emitting device or Comparative Compound 2 was used, when a quantum dot light emitting device was manufactured using the compound of the present invention as a light emitting auxiliary layer material, it can be seen that not only the operating voltage can be lowered, but also the luminous efficiency and lifetime can be significantly improved.

As described in Table 5 above, the overall performance of the device of Comparative Example 5, in which the auxiliary light emitting layer was formed using Comparative Compound 2, was slightly improved compared to that of Comparative Example 4, in which the auxiliary light emitting layer was not used, and it can be confirmed that the performance of the devices of Examples 9 to 32, in which the compounds of the present disclosure into which a specific substituent was introduced, were used as an auxiliary light emitting layer was more excellent.

In particular, it can be seen that the device results were further improved when, among the compounds of the present disclosure, those compounds, in which two amine groups were substituted in the core, were used as an auxiliary light emitting layer. These results show that even though these compounds have the same backbone, depending on the type and bonding position of the substituent, the physical properties of the compounds (e.g., hole characteristics, light efficiency characteristics, energy levels (LUMO, HOMO level, T1 level), hole injection and mobility characteristics, and electron blocking characteristics) may vary, thus suggesting that completely different device results may be derived.

The above description is merely illustrative of the present disclosure, and those skilled in the art will be able to make various modifications without departing from the essential characteristics of the present disclosure.

Accordingly, the embodiments disclosed herein are illustrative and not intended to limit the invention, and the spirit and scope of the present disclosure are not limited by these embodiments. The protection scope of the present disclosure should be construed according to the claims, and all techniques within the equivalent range should be construed as being included in the scope of the present disclosure.

1. A quantum dot light emitting device comprising a first electrode; a second electrode; a light emitting layer comprising quantum dots and a hole transport layer between the first electrode and the second electrode; an auxiliary light emitting layer between the hole transport layer and the light emitting layer, wherein the auxiliary light emitting layer comprises a compound represented by Formula 1: 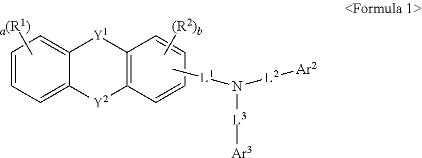
wherein in Formula 1 above,
1) Ar² and Ar³ are each independently selected from the group consisting of a C₆₋₆₀ aryl group; a fluorenyl group; a C₂₋₆₀ heterocyclic group comprising at least one heteroatom among O, N, S, Si, and P; a fused ring group of a C₃₋₆₀ aliphatic ring and a C₁₋₆₀ aromatic ring; a C₁₋₅₀ alkyl group; a C₂₋₂₀ alkenyl group; a C₂₋₂₀ alkynyl group; a C₁₋₃₀ alkoxyl group; a C₆₋₃₀ aryloxy group; and -L′-N(Rₐ)(R_{b});
2) L¹ to L³ are each independently selected from the group consisting of a single bond; a C₁₋₆₀ arylene group; a fluorenylene group; a fused ring group of a C₃₋₆₀ aliphatic ring and a C₁₋₆₀ aromatic ring; and a C₂₋₆₀ heterocyclic ring group;
3) R¹ and R² are each the same or different, and are each independently selected from the group consisting of hydrogen; deuterium, tritium; a halogen; a cyano group; a nitro group; a C₆₋₆₀ aryl group; a fluorenyl group; a C₂₋₆₀ heterocyclic group comprising at least one heteroatom among O, N, S, Si, and P; a fused ring group of a C₃₋₆₀ aliphatic ring and a C₆₋₆₀ aromatic ring; a C₁₋₅₀ alkyl group; a C₂₋₂₀ alkenyl group; a C₂₋₂₀ alkynyl group; a C₁₋₃₀ alkoxyl group; a C₆₋₃₀ aryloxy group; and -L′-N(Rₐ)(R_{b});
4) Y¹ and Y² are each independently absent, or a single bond, NR, O, S, or CR′R″, excluding the case where Y¹ and Y² are simultaneously a single bond or absent;
5) R, R′, and R″ are each independently selected from the group consisting of hydrogen; deuterium, tritium; a halogen; a cyano group; a nitro group; a C₁₋₆₀ aryl group; a fluorenyl group; a C₂₋₆₀ heterocyclic group comprising at least one heteroatom among O, N, S, Si, and P; a fused ring group of a C₃₋₆₀ aliphatic ring and a C₆₋₆₀ aromatic ring; a C₁₋₅₀ alkyl group; a C₂₋₂₀ alkenyl group; a C₂₋₂₀ alkynyl group; a C₁₋₃₀ alkoxyl group; a C₆₋₃₀ aryloxy group; and -L′-N(Rₐ)(R_{b}); wherein R′ and R″ may combine with each other to form a spiro ring;
6) a is an integer of 0 to 4 and b is an integer of 0 to 3, with the proviso that when Y¹ or Y² is absent, a is an integer of 0 to 5, and b is an integer of 0 to 4;
7) where a or b is an integer of 2 or more, R¹ and R² are each plural being the same or different from each other, and a plurality of neighboring R¹ or a plurality of neighboring R² may combine with each other to form a ring;
8) L′ is selected from the group consisting of a single bond; a C₆₋₆₀ arylene group; a fluorenylene group; a C₂₋₆₀ heterocyclic group comprising at least one heteroatom among O, N, S, Si, and P; a C₃₋₆₀ aliphatic ring; and a fused ring group of a C₃₋₆₀ aliphatic ring and a C₁₋₆₀ aromatic ring;
9) Rₐ and R_{b} are each independently selected from the group consisting of a C₁₋₆₀ aryl group; a fluorenyl group; a C₂₋₆₀ heterocyclic group comprising at least one heteroatom among O, N, S, Si, and P; a C₃₋₆₀ aliphatic ring; and a fused ring group of a C₃₋₆₀ aliphatic ring and a C₆₋₆₀ aromatic ring; and
10) the rings formed by binding between the L′, L¹ to L³, Rₐ, R_{b}, Ar² and Ar³, R¹ and R², R, R′, R″, and neighboring groups thereof may each be further substituted with one or more substituents selected from the group consisting of deuterium; a halogen; a silane group substituted or unsubstituted with a C₁₋₃₀ alkyl group or C₆₋₃₀ aryl group; a siloxane group; a boron group; a germanium group; a cyano group; an amino group; a nitro group; a C₁₋₃₀ alkylthio group; a C₁₋₃₀ alkoxy group; a C₆₋₃₀ arylalkoxy group; a C₁₋₃₀ alkyl group; a C₂₋₃₀ alkenyl group; a C₂₋₃₀ alkynyl group; a C₆₋₃₀ aryl group; a C₆₋₃₀ aryl group substituted with deuterium; a fluorenyl group; a C₂₋₃₀ heterocyclic group comprising at least one heteroatom among O, N, S, Si, and P; a C₃₋₃₀ alicyclic group; a C₇₋₃₀ arylalkyl group; a C₆₋₃₀ arylalkenyl group; and a combination thereof; or may form a ring between the neighboring substituents.

2. The quantum dot light emitting device of claim 1, wherein Formula 1 is represented by any one of Formula 1-1 to Formula 1-3: 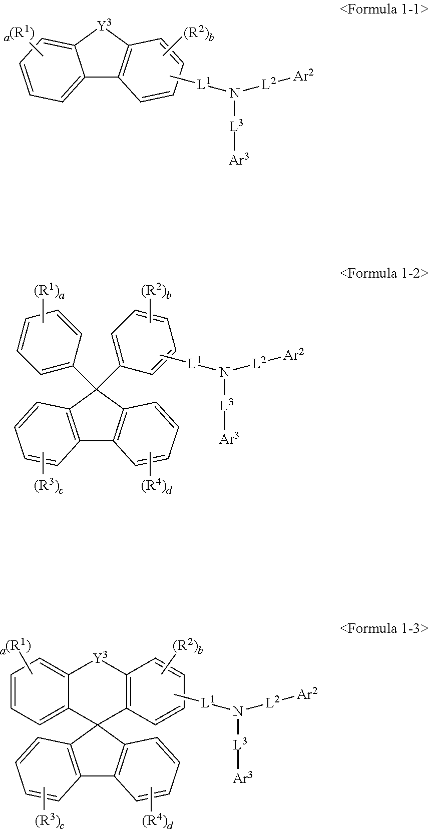
wherein
1) L¹ to L³, Ar² and Ar³, R¹ and R², and a and b are the same as defined in claim 1;
2) Y³ is NR_{c}, O, S, or CR_{d}Rₑ;
3) R³ and R⁴, and R_{c} to Rₑ are each independently selected from the group consisting of hydrogen; deuterium, tritium; a halogen; a cyano group; a nitro group; a C₆₋₆₀ aryl group; a fluorenyl group; a C₂₋₆₀ heterocyclic group comprising at least one heteroatom among O, N, S, Si, and P; a fused ring group of a C₃₋₆₀ aliphatic ring and a C₆₋₆₀ aromatic ring; a C₁₋₅₀ alkyl group; a C₂₋₂₀ alkenyl group; a C₂₋₂₀ alkynyl group; a C₁₋₃₀ alkoxyl group; a C₆₋₃₀ aryloxy group; and -L′-N(Rₐ)(R_{b}); or R_{d} and Rₑ may combine with each other to form a spiro ring;
4) L′ is selected from the group consisting of a single bond; a C₆₋₆₀ arylene group; a fluorenylene group; a C₂₋₆₀ heterocyclic group comprising at least one heteroatom among O, N, S, Si, and P; a C₃₋₆₀ aliphatic ring; and a fused ring group of a C₃₋₆₀ aliphatic ring and a C₆₋₆₀ aromatic ring;
5) Rₐ and R_{b} are each independently selected from the group consisting of a C₆₋₆₀ aryl group; a fluorenyl group; a C₂₋₆₀ heterocyclic group comprising at least one heteroatom among O, N, S, Si, and P; a C₃₋₆₀ aliphatic ring; and a fused ring group of a C₃₋₆₀ aliphatic ring and a C₆₋₆₀ aromatic ring; and
6) c and d are independently an integer of 0 to 4.

3. The quantum dot light emitting device of claim 1, wherein Formula 1 is represented by Formula 2-1 or Formula 2-2: 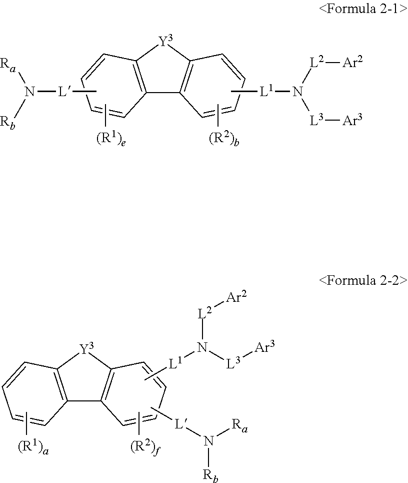
wherein
1) L¹ to L³, Ar² and Ar³, R¹ and R², and a and b are the same as defined in claim 1;
2) Y³ is NR_{c}, O, S, or CR_{d}Rₑ;
3) R_{c} to Rₑ are each independently selected from the group consisting of hydrogen; deuterium, tritium; a halogen; a cyano group; a nitro group; a C₆₋₆₀ aryl group; a fluorenyl group;
a C₂₋₆₀ heterocyclic group comprising at least one heteroatom among O, N, S, Si, and P; a fused ring group of a C₃₋₆₀ aliphatic ring and a C₆₋₆₀ aromatic ring; a C₁₋₅₀ alkyl group; a C₂₋₂₀ alkenyl group; a C₂₋₂₀ alkynyl group; a C₁₋₃₀ alkoxyl group; a C₆₋₃₀ aryloxy group; and -L′-N(Rₐ)(R_{b}); or R_{d} and Rₑ may combine with each other to form a Spiro ring;
4) L′ is selected from the group consisting of a single bond; a C₁₋₆₀ arylene group; a fluorenylene group; a C₂₋₆₀ heterocyclic group comprising at least one heteroatom among O, N, S, Si, and P; a C₃₋₆₀ aliphatic ring; and a fused ring group of a C₃₋₆₀ aliphatic ring and a C₆₋₆₀ aromatic ring;
5) Rₐ and R_{b} are each independently selected from the group consisting of a C₁₋₆₀ aryl group; a fluorenyl group; a C₂₋₆₀ heterocyclic group comprising at least one heteroatom among O, N, S, Si, and P; a C₃₋₆₀ aliphatic ring; and a fused ring group of a C₃₋₆₀ aliphatic ring and a C₆₋₆₀ aromatic ring; and
6) e is an integer of 0 to 3; and f is an integer of 0 to 2.

4. The quantum dot light emitting device of claim 1, wherein Formula 1 is represented by Formula 2-3 or Formula 2-4: 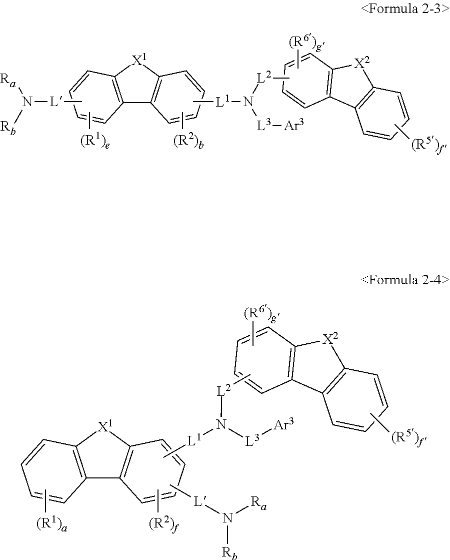
wherein
1) L¹ to L³, Ar³, R¹ and R², and a and b are the same as defined in claim 1;
2) e is an integer of 0 to 3; and f is an integer of 0 to 2;
3) X¹ is O or S;
4) X² is NR_{c}, O, S, or CR_{d}Rₑ;
5) R_{c} to Rₑ are each independently selected from the group consisting of hydrogen; deuterium, tritium; a halogen; a cyano group; a nitro group; a C₆₋₆₀ aryl group; a fluorenyl group; a C₂₋₆₀ heterocyclic group comprising at least one heteroatom among O, N, S, Si, and P; a fused ring group of a C₃₋₆₀ aliphatic ring and a C₆₋₆₀ aromatic ring; a C₁₋₅₀ alkyl group; a C₂₋₂₀ alkenyl group; a C₂₋₂₀ alkynyl group; a C₁₋₃₀ alkoxyl group; a C₆₋₃₀ aryloxy group; and -L′-N(Rₐ)(R_{b}); or R_{d} and Rₑ may combine with each other to form a spiro ring;
6) L′ is selected from the group consisting of a single bond; a C₆₋₆₀ arylene group; a fluorenylene group; a C₂₋₆₀ heterocyclic group comprising at least one heteroatom among O, N, S, Si, and P; a C₃₋₆₀ aliphatic ring; and a fused ring group of a C₃₋₆₀ aliphatic ring and a C₆₋₆₀ aromatic ring;
7) Rₐ and R_{b} are each independently selected from the group consisting of a C₆₋₆₀ aryl group; a fluorenyl group; a C₂₋₆₀ heterocyclic group comprising at least one heteroatom among O, N, S, Si, and P; a C₃₋₆₀ aliphatic ring; and a fused ring group of a C₃₋₆₀ aliphatic ring and a C₆₋₆₀ aromatic ring;
8) R^{5′} and R^{6′} are each independently selected from the group consisting of hydrogen; deuterium, tritium; a halogen; a cyano group; a nitro group; a C₆₋₆₀ aryl group; a fluorenyl group; a C₂₋₆₀ heterocyclic group comprising at least one heteroatom among O, N, S, Si, and P; a fused ring group of a C₃₋₆₀ aliphatic ring and a C₆₋₆₀ aromatic ring; a C₁₋₅₀ alkyl group; a C₂₋₂₀ alkenyl group; a C₂₋₂₀ alkynyl group; a C₁₋₃₀ alkoxyl group; a C₆₋₃₀ aryloxy group; and -L′-N(Rₐ)(R_{b}); and
9) f′ is an integer of 0 to 4; and f is an integer of 0 to 2.

5. The quantum dot light emitting device of claim 1, wherein the compound represented by Formula 1 is any one of Compounds 1-1 to 1-80 and 2-1 to 2-80:

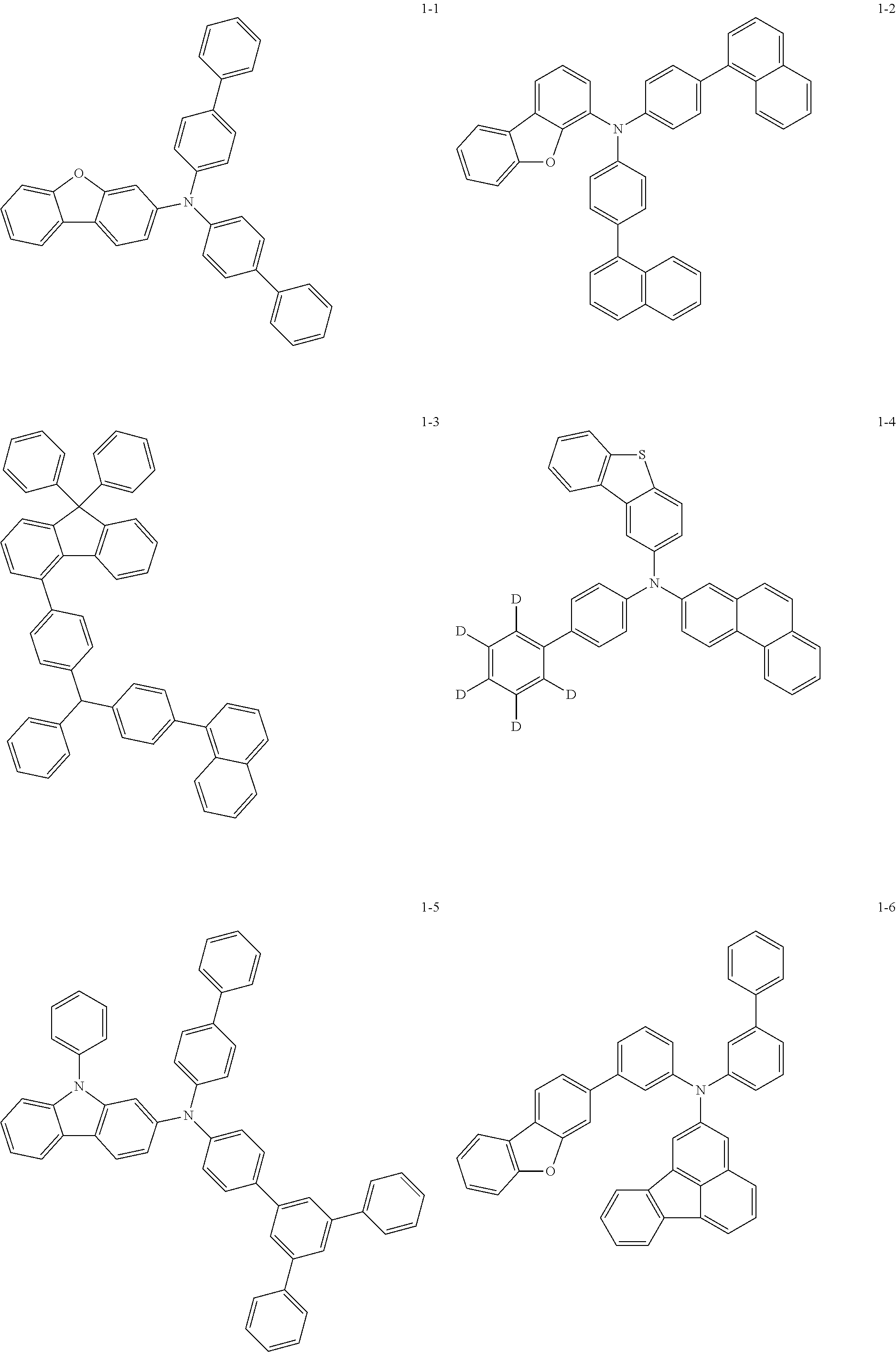

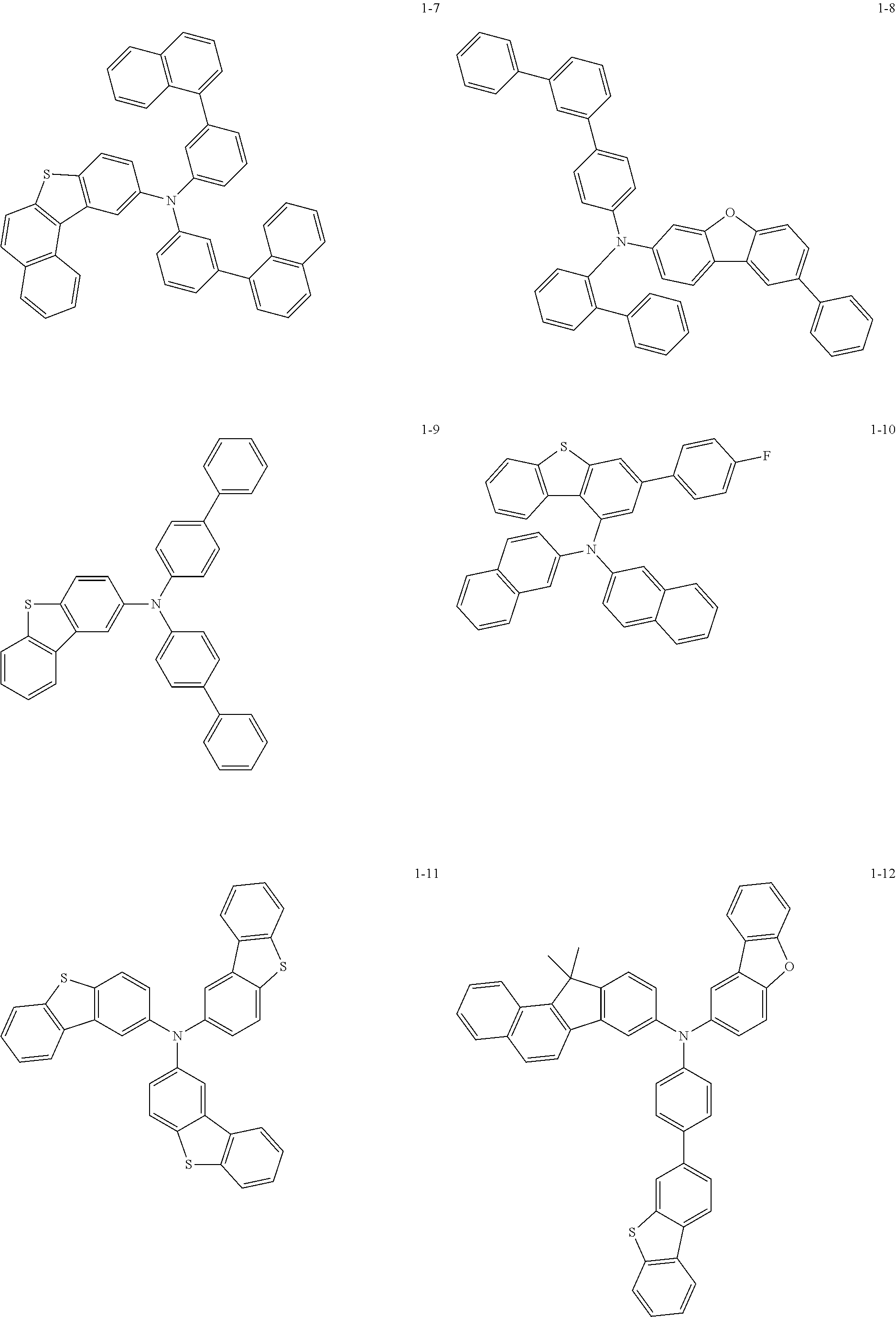 [SMILES: c1cc(-c2cccc3ccccc23)cc(N(c2cccc(-c3cccc4ccccc34)c2)c2ccc3sc4ccc5ccccc5c4c3c2)c1 ; c1ccc(-c2cccc(-c3ccc(N(c4ccc5c(c4)oc4ccc(-c6ccccc6)cc45)c4ccccc4-c4ccccc4)cc3)c2)cc1 ; c1ccc(-c2ccc(N(c3ccc(-c4ccccc4)cc3)c3ccc4sc5ccccc5c4c3)cc2)cc1 ; Fc1ccc(-c2cc(N(c3ccc4ccccc4c3)c3ccc4ccccc4c3)c3c(c2)sc2ccccc23)cc1 ; c1ccc2c(c1)sc1ccc(N(c3ccc4sc5ccccc5c4c3)c3ccc4sc5ccccc5c4c3)cc12 ; CC1(C)c2ccc(N(c3ccc(-c4ccc5c(c4)sc4ccccc45)cc3)c3ccc4oc5ccccc5c4c3)cc2-c2ccc3ccccc3c21]

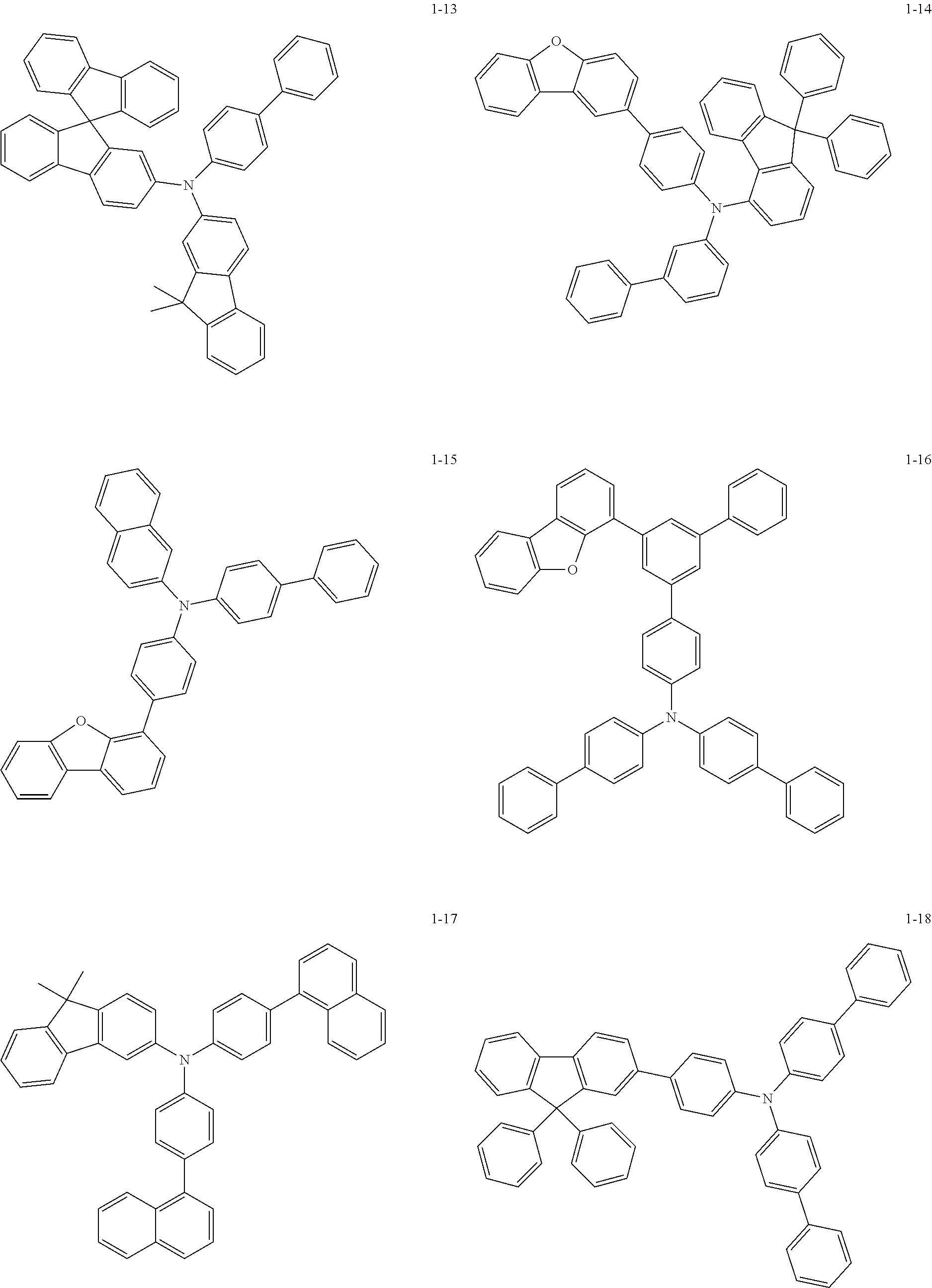

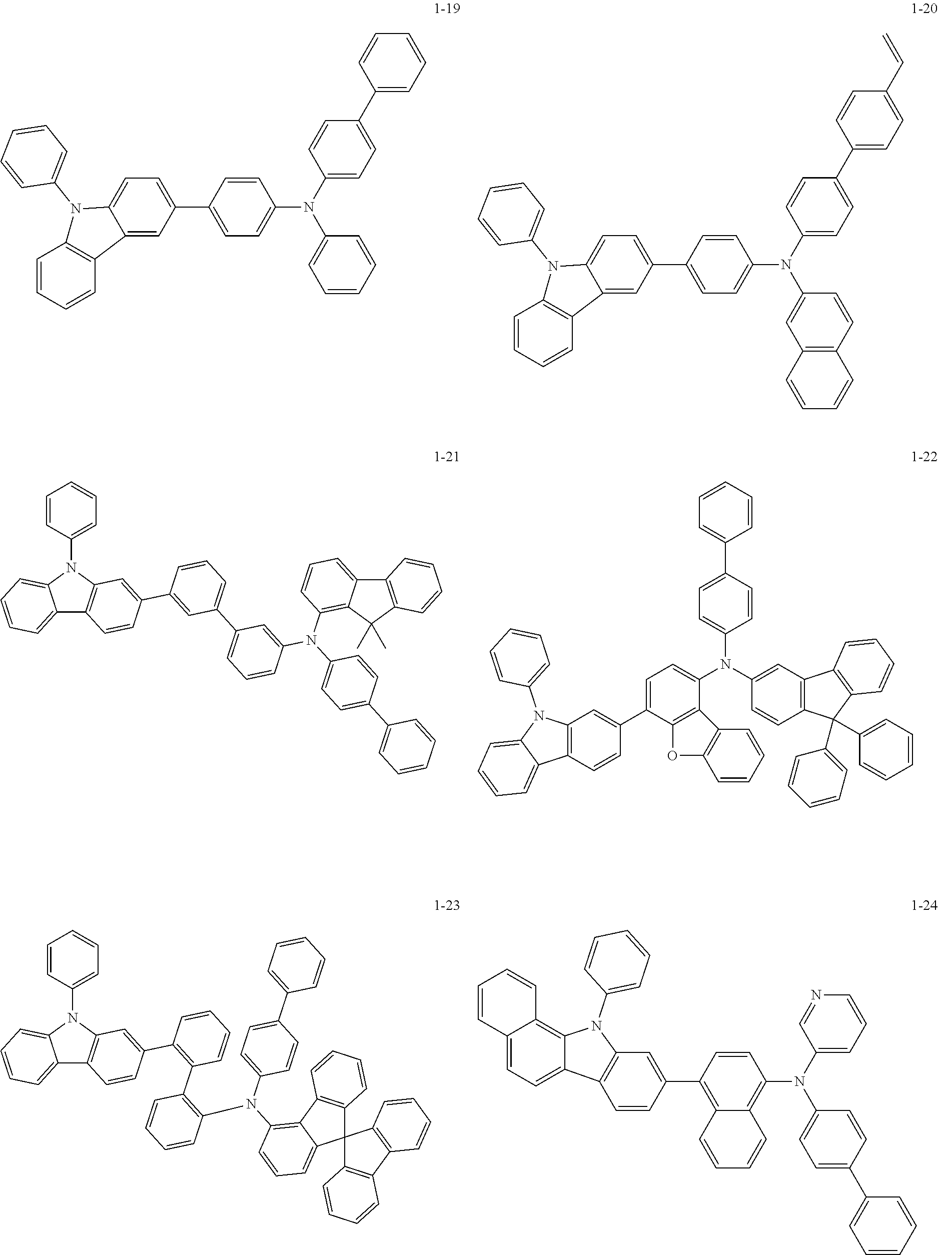

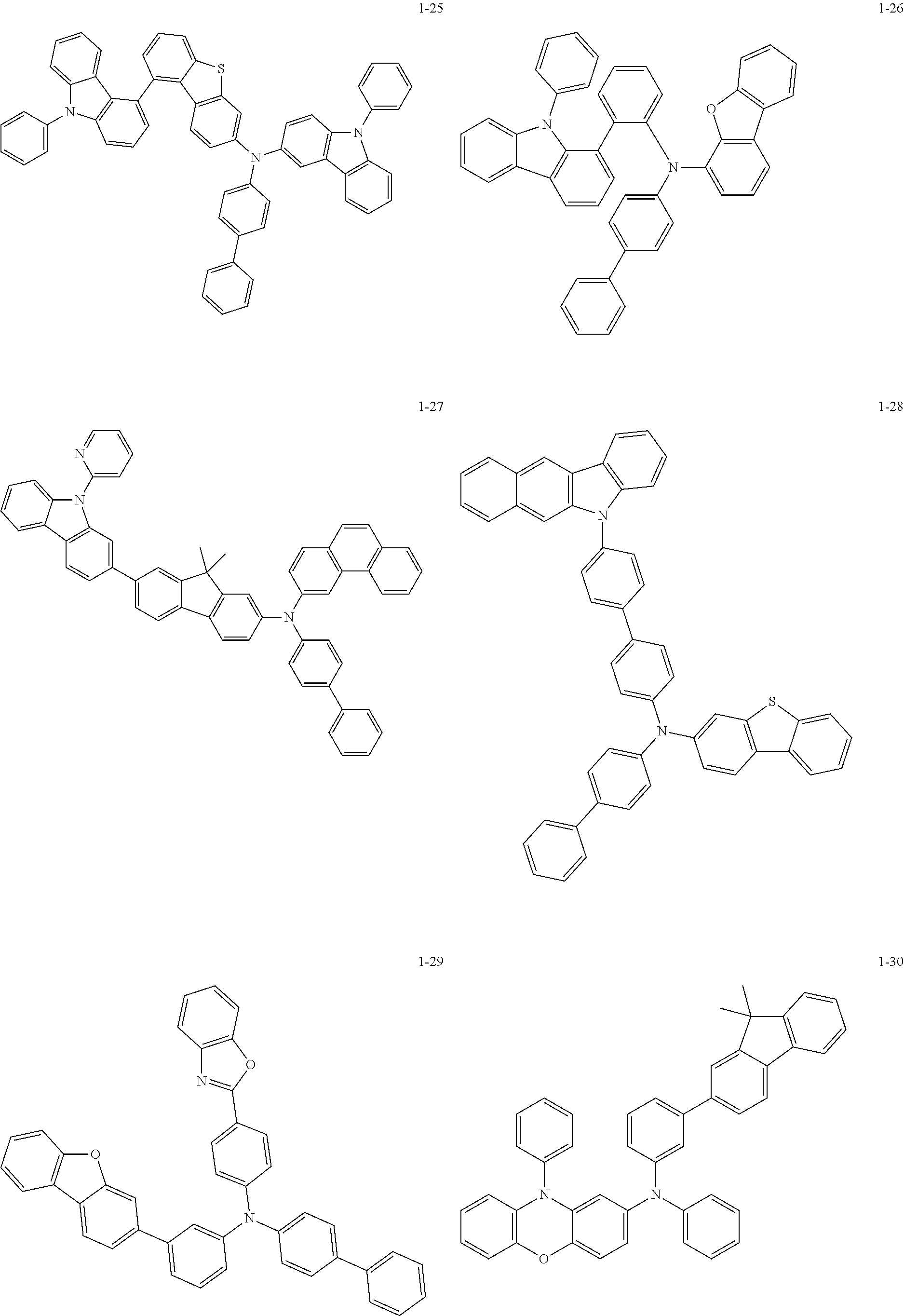

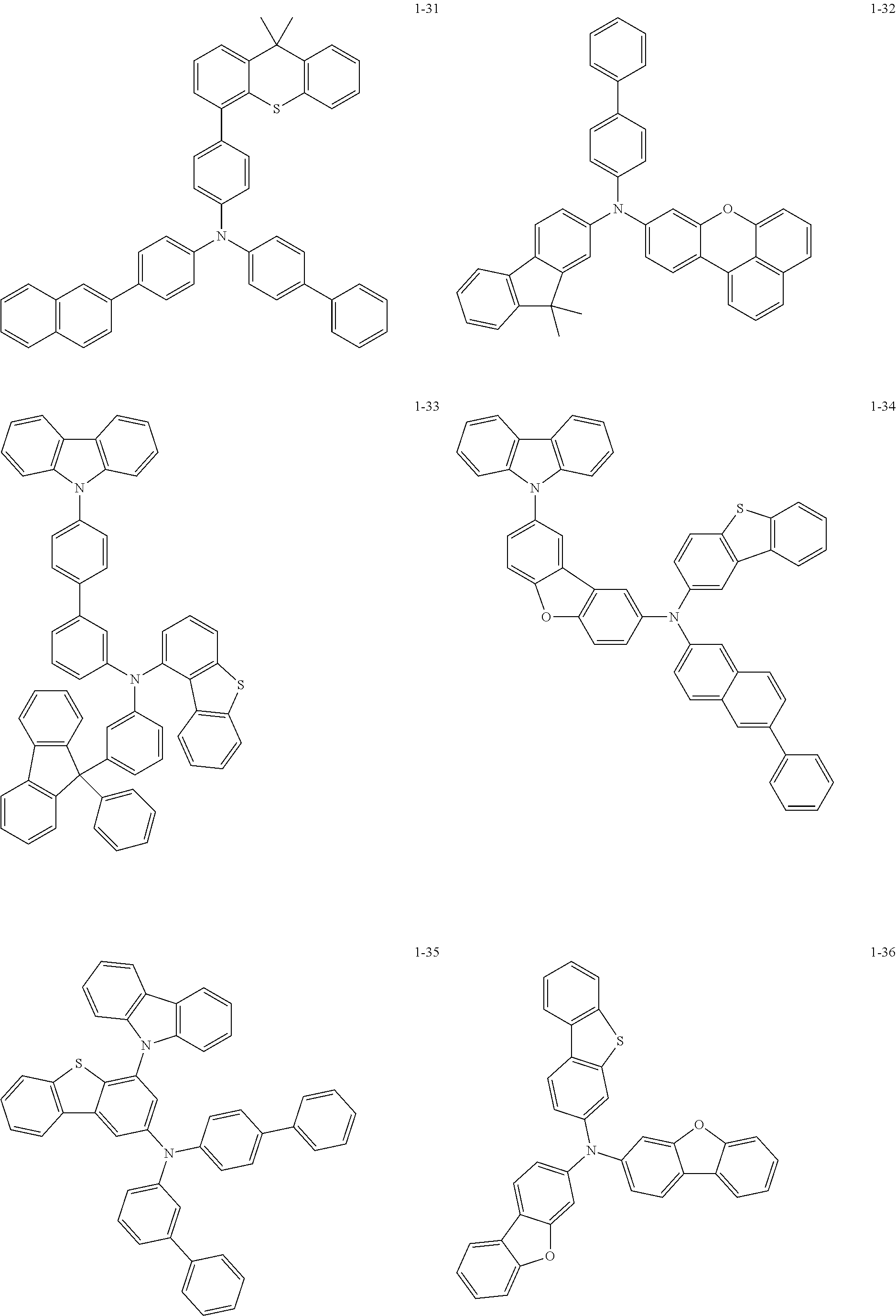

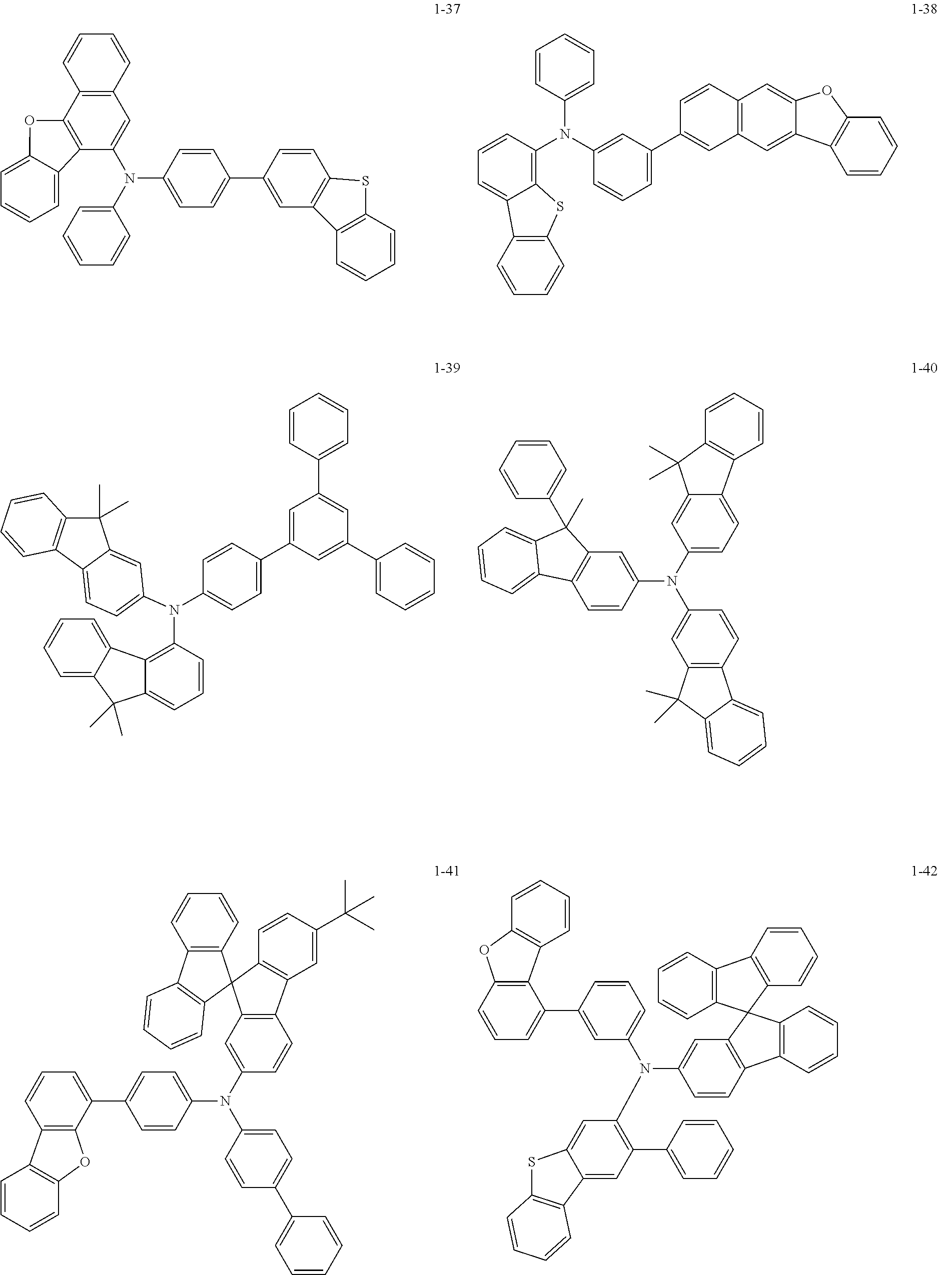

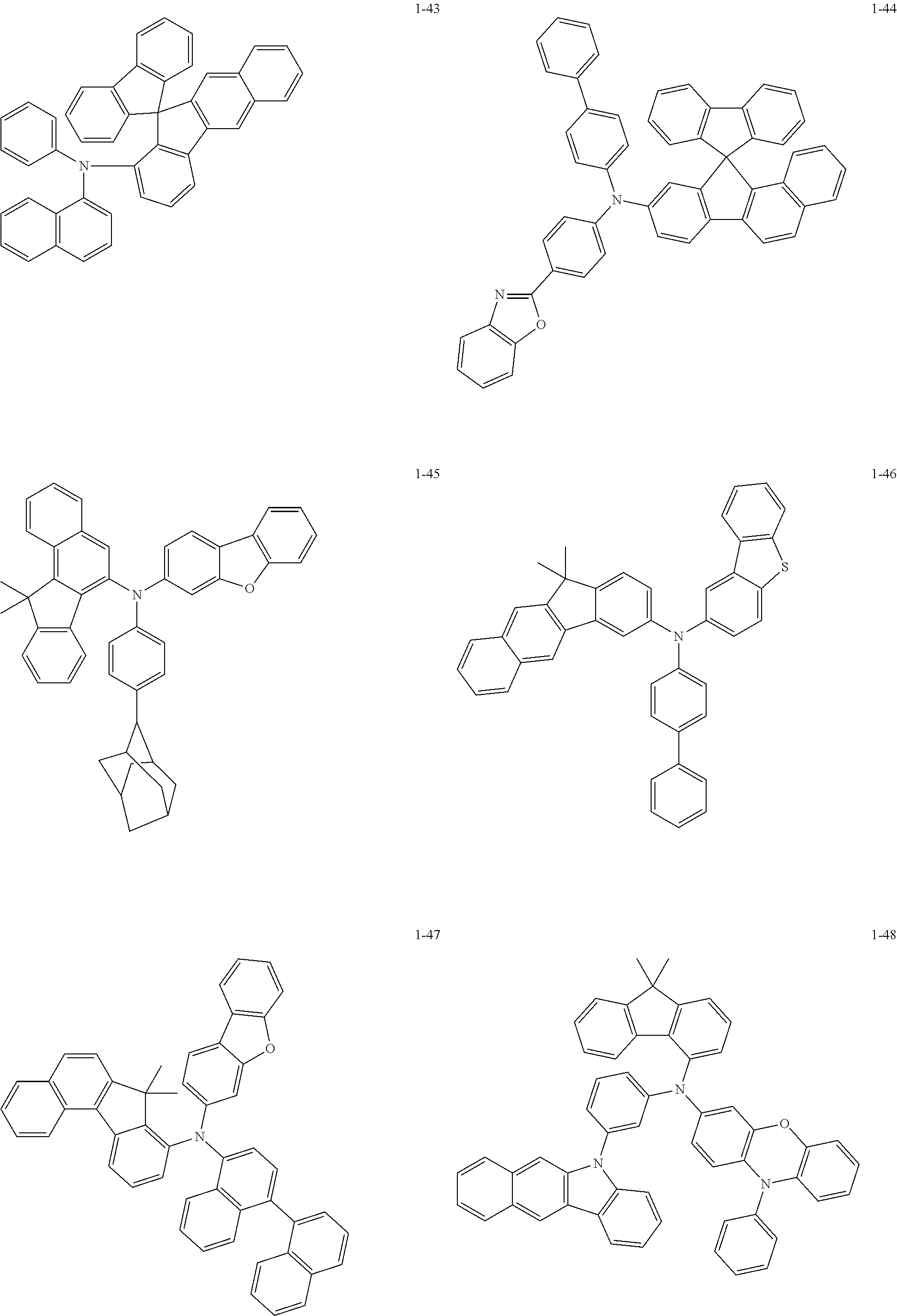

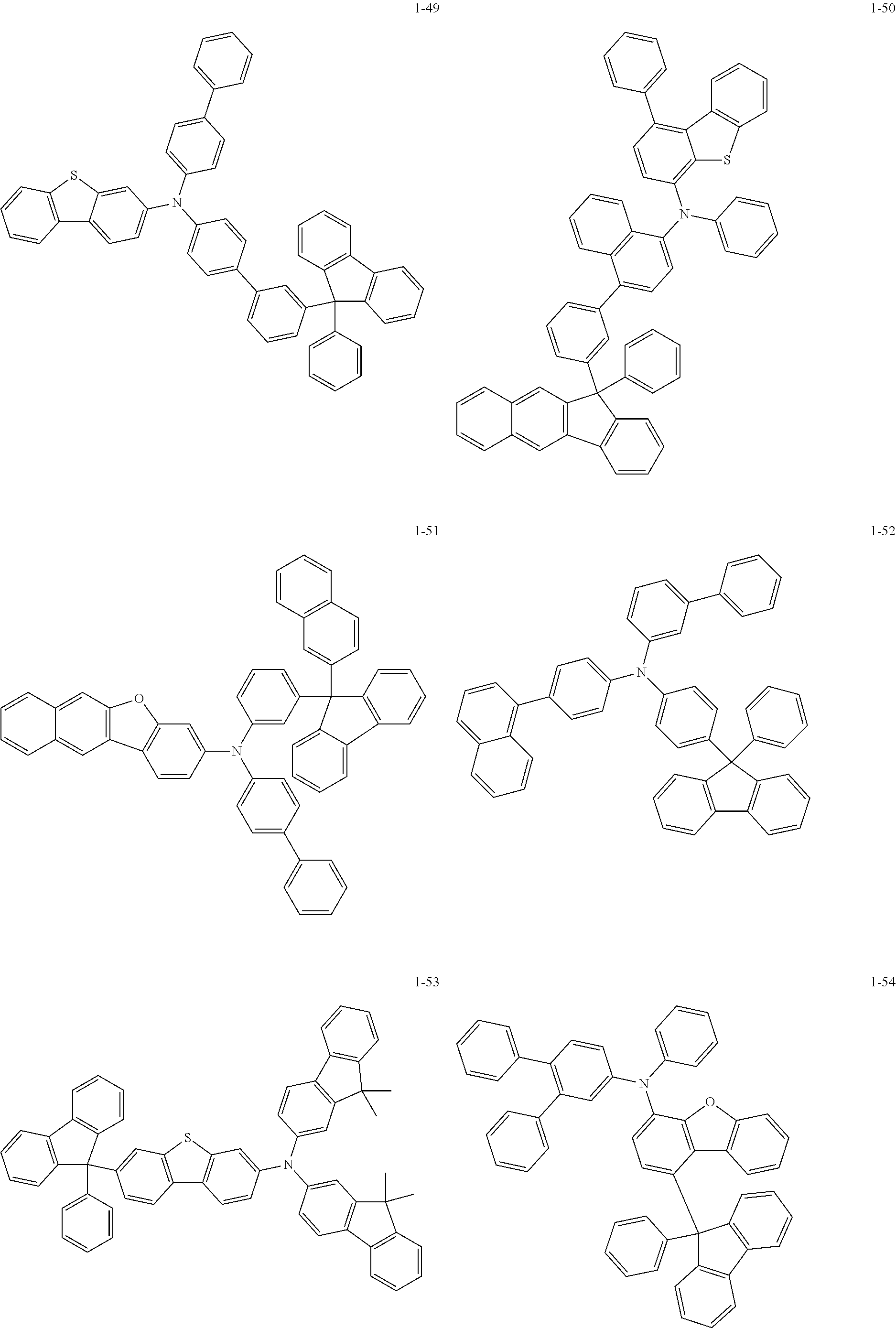

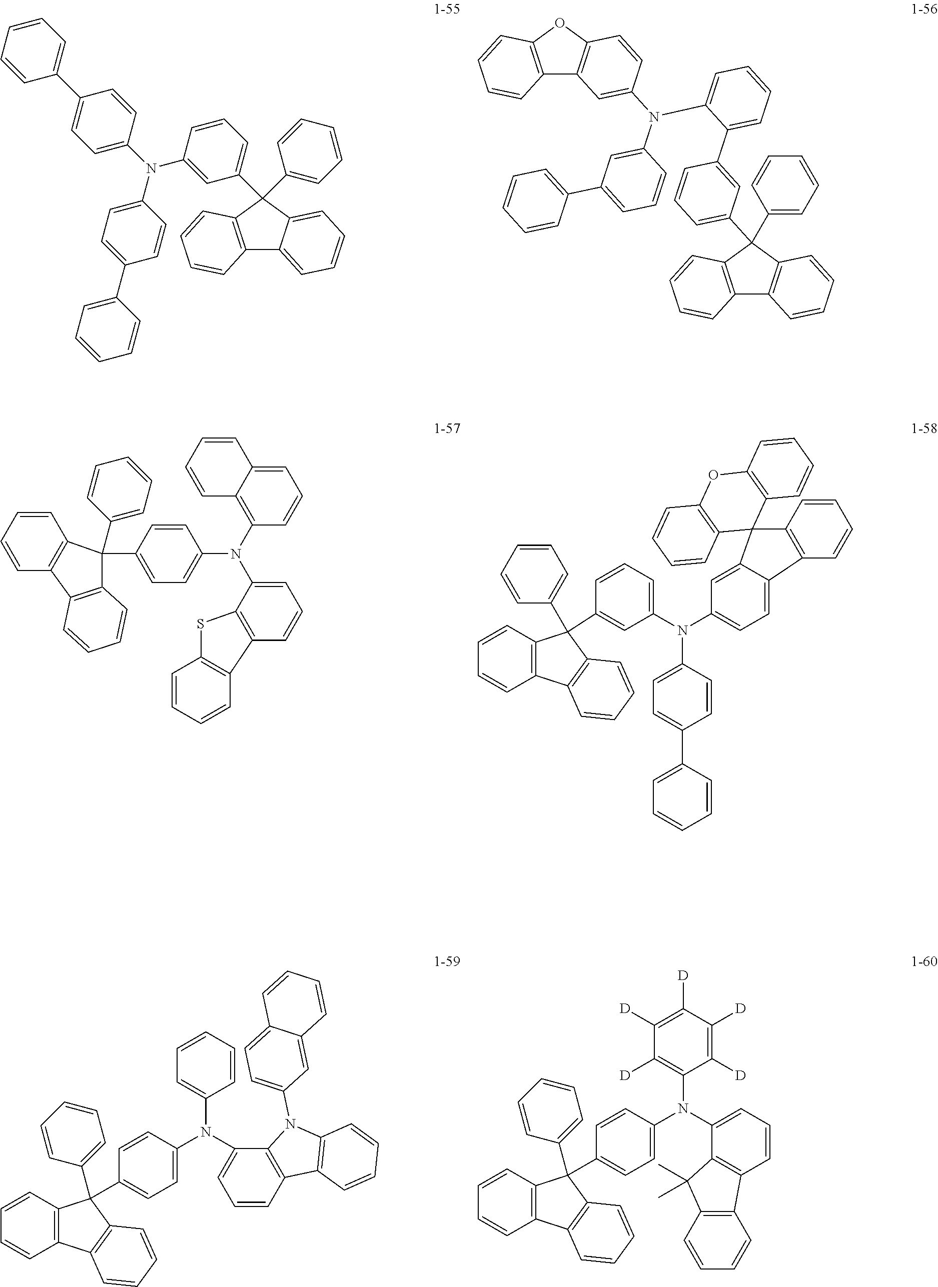

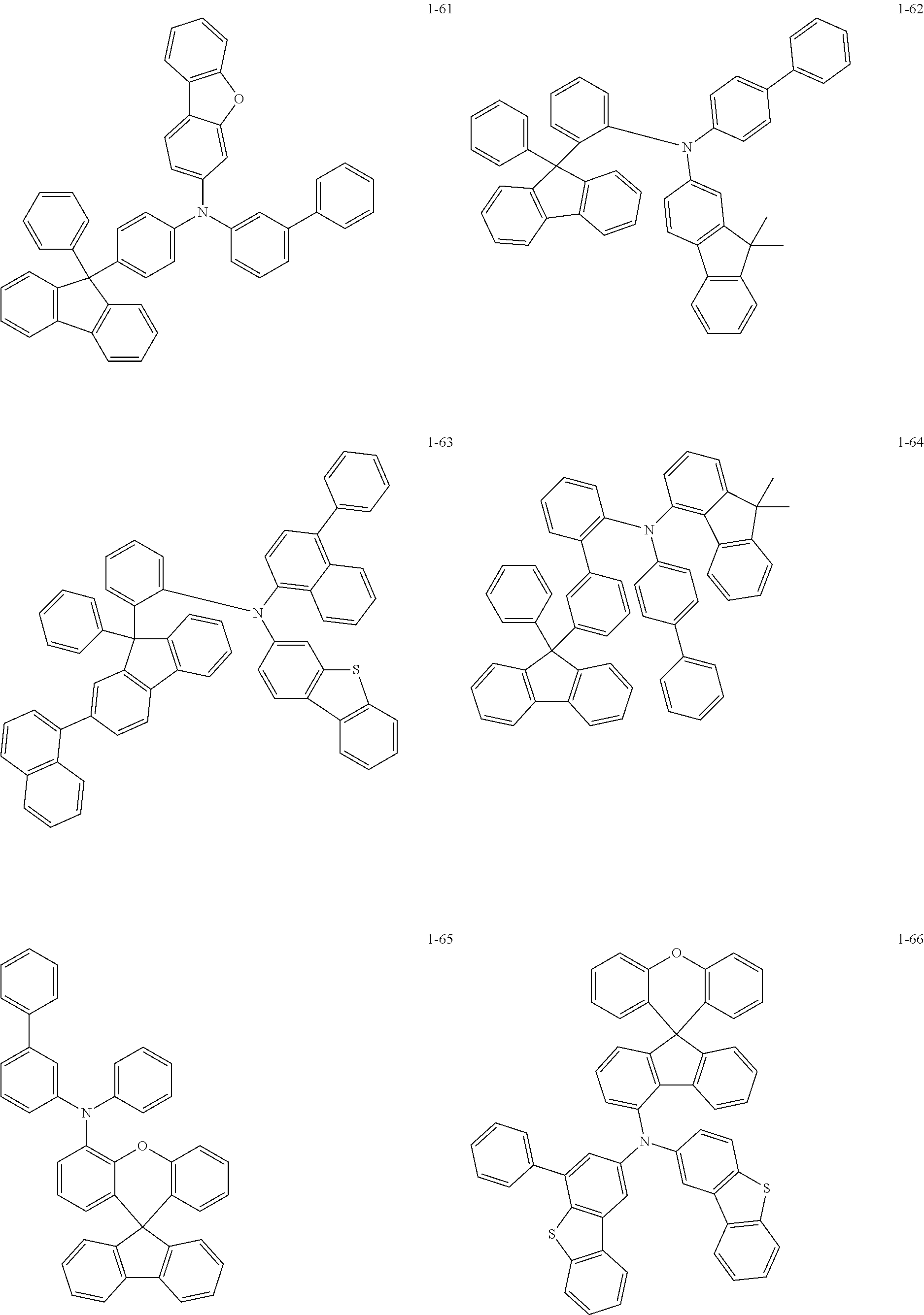

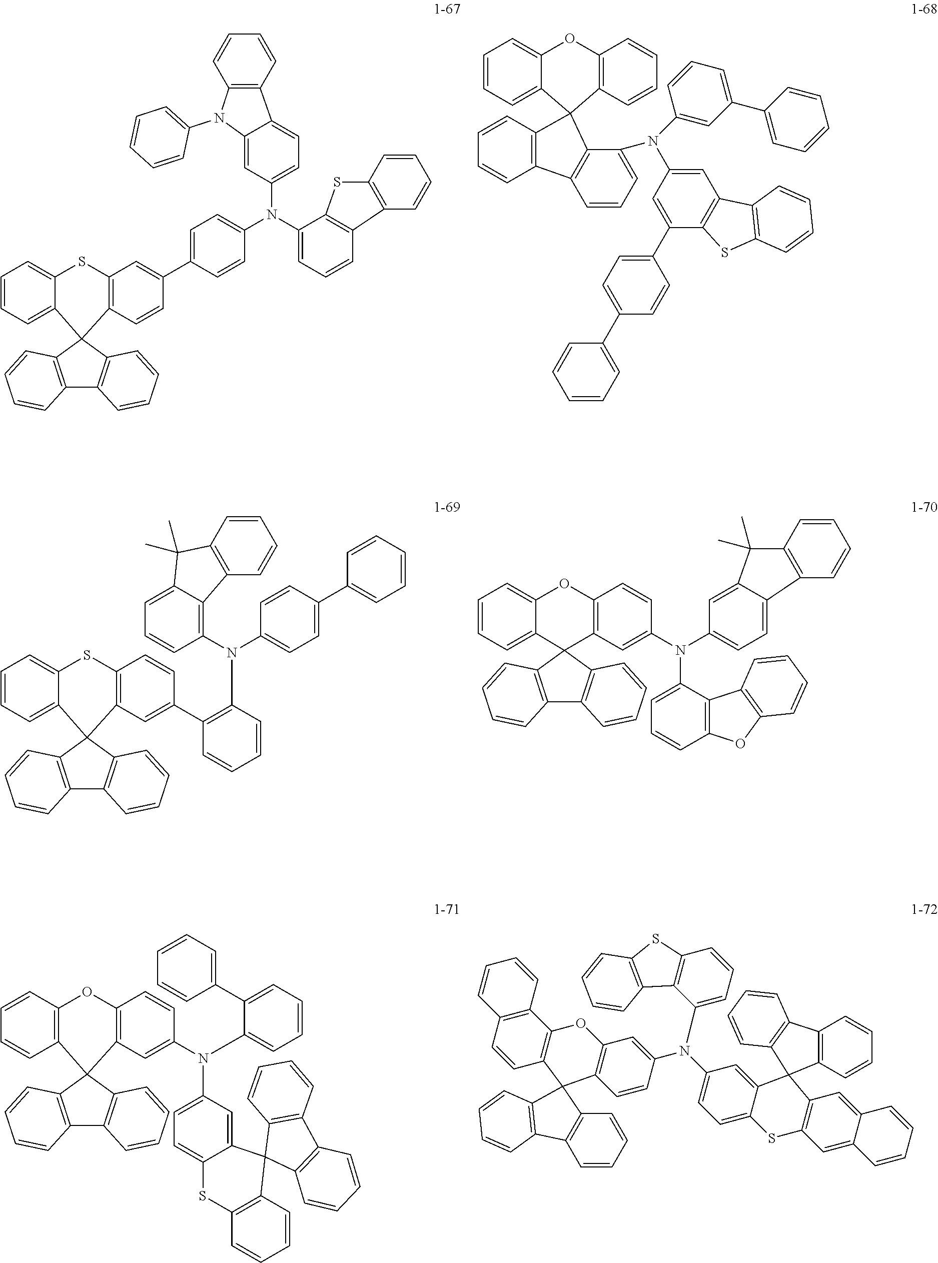

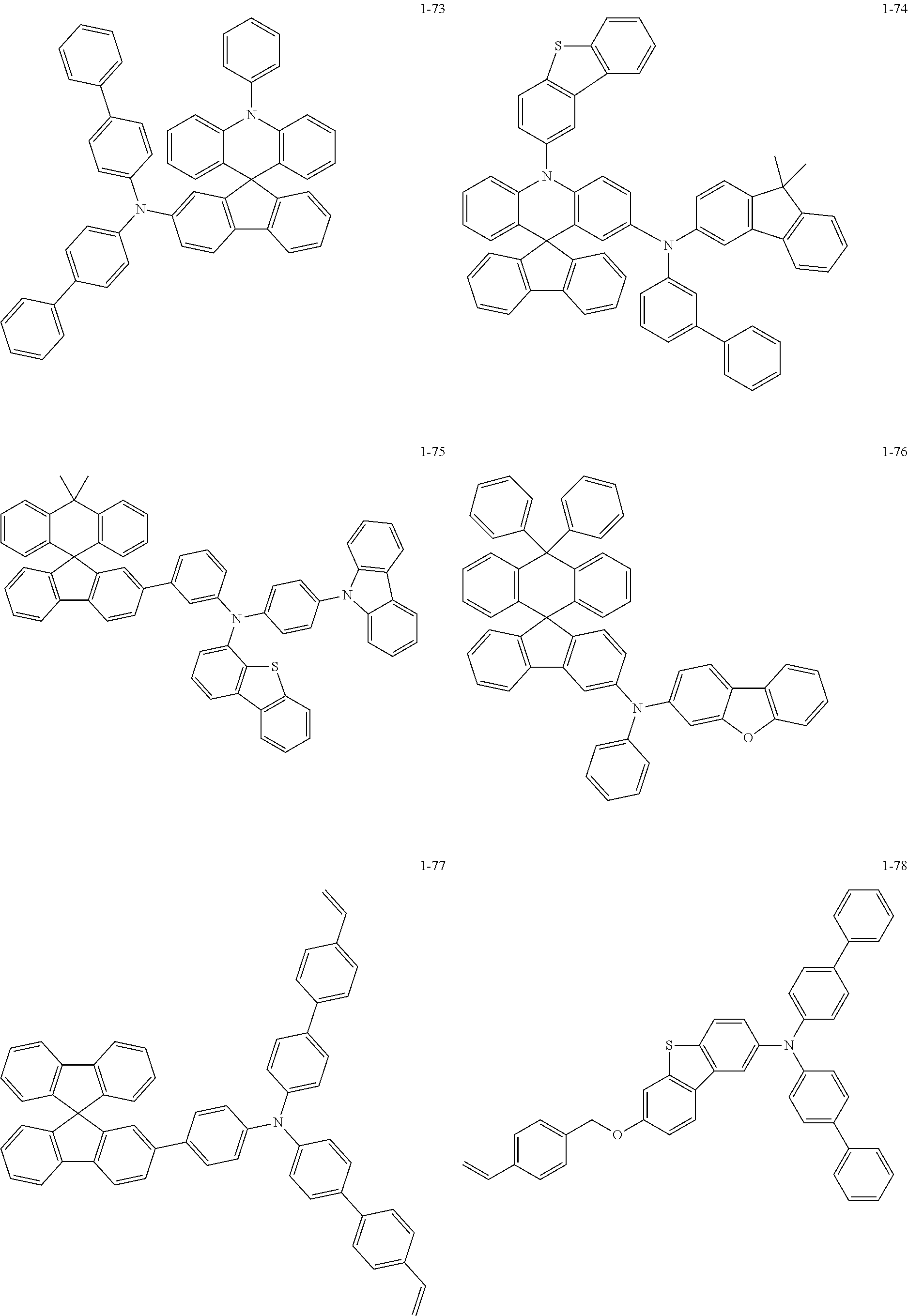

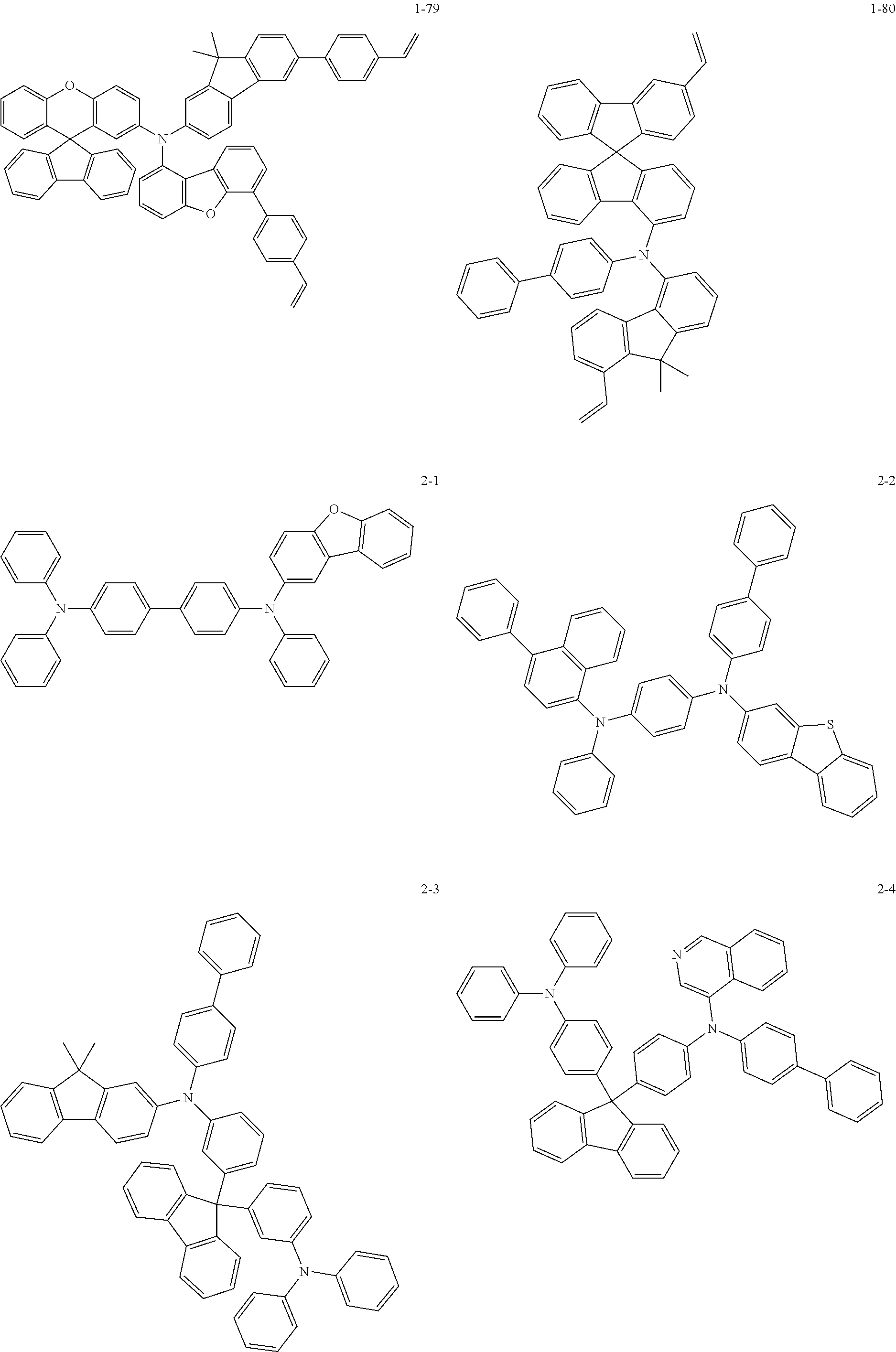

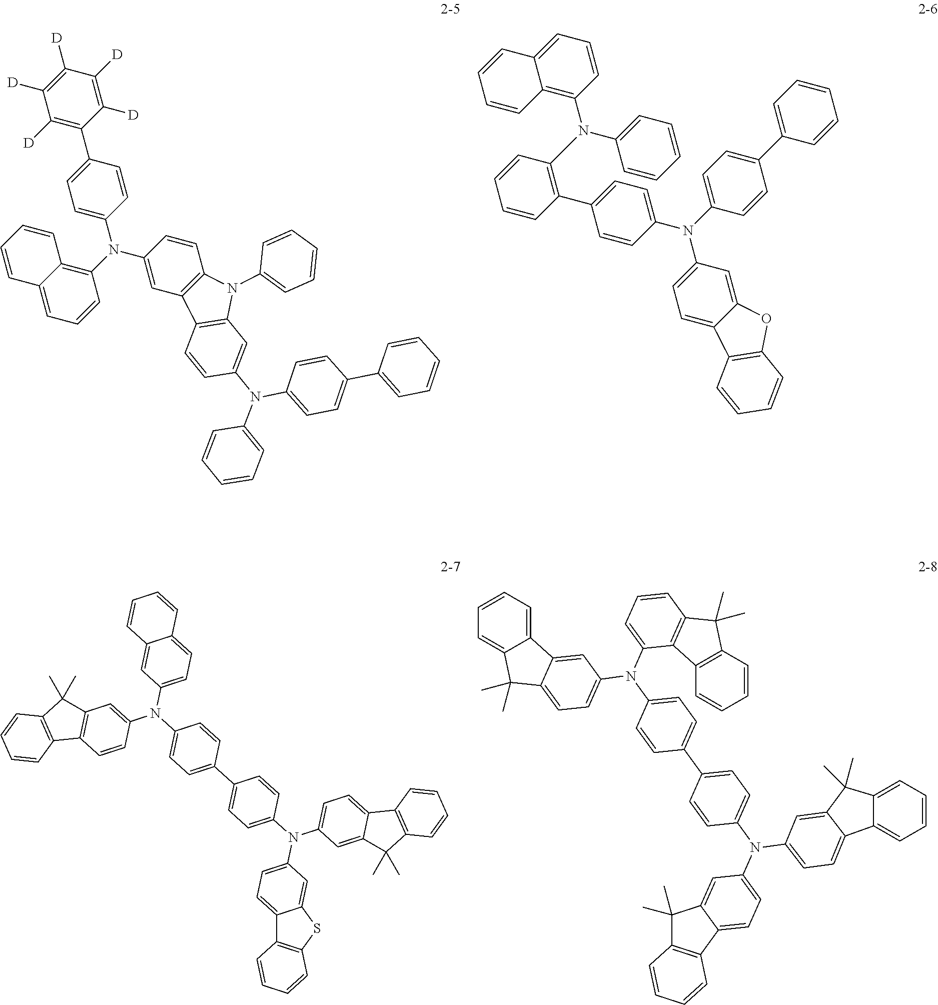 [SMILES: [2H]c1c([2H])c([2H])c(-c2ccc(N(c3ccc4c(c3)c3ccc(N(c5ccccc5)c5ccc(-c6ccccc6)cc5)cc3n4-c3ccccc3)c3cccc4ccccc34)cc2)c([2H])c1[2H] ; c1ccc(-c2ccc(N(c3ccc(-c4ccccc4N(c4ccccc4)c4cccc5ccccc45)cc3)c3ccc4c(c3)oc3ccccc34)cc2)cc1 ; CC1(C)c2ccccc2-c2ccc(N(c3ccc(-c4ccc(N(c5ccc6c(c5)C(C)(C)c5ccccc5-6)c5ccc6c(c5)sc5ccccc56)cc4)cc3)c3ccc4ccccc4c3)cc21 ; CC1(C)c2ccccc2-c2cc(N(c3ccc(-c4ccc(N(c5ccc6c(c5)C(C)(C)c5ccccc5-6)c5ccc6c(c5)C(C)(C)c5ccccc5-6)cc4)cc3)c3cccc4c3-c3ccccc3C4(C)C)ccc21]

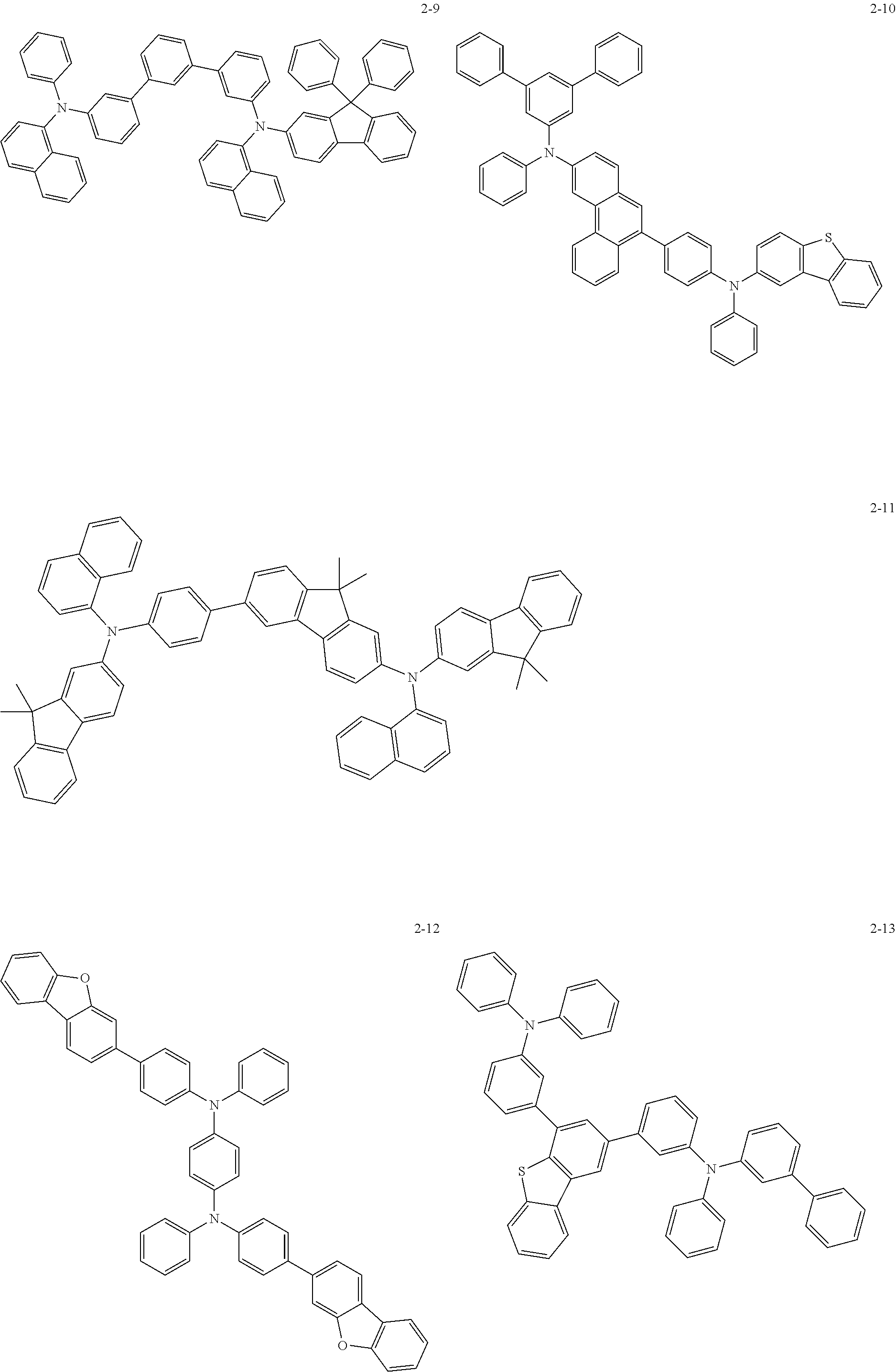

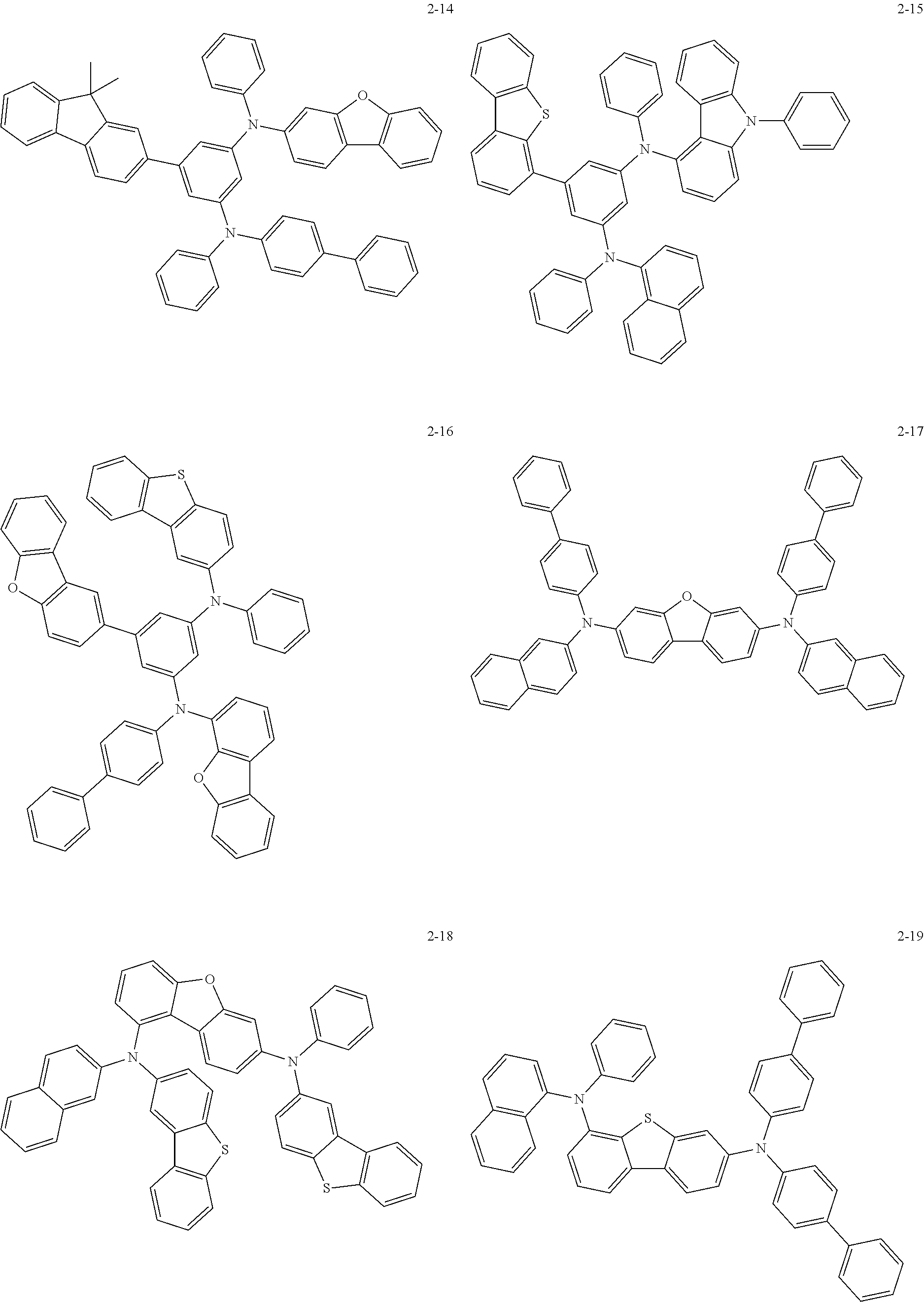

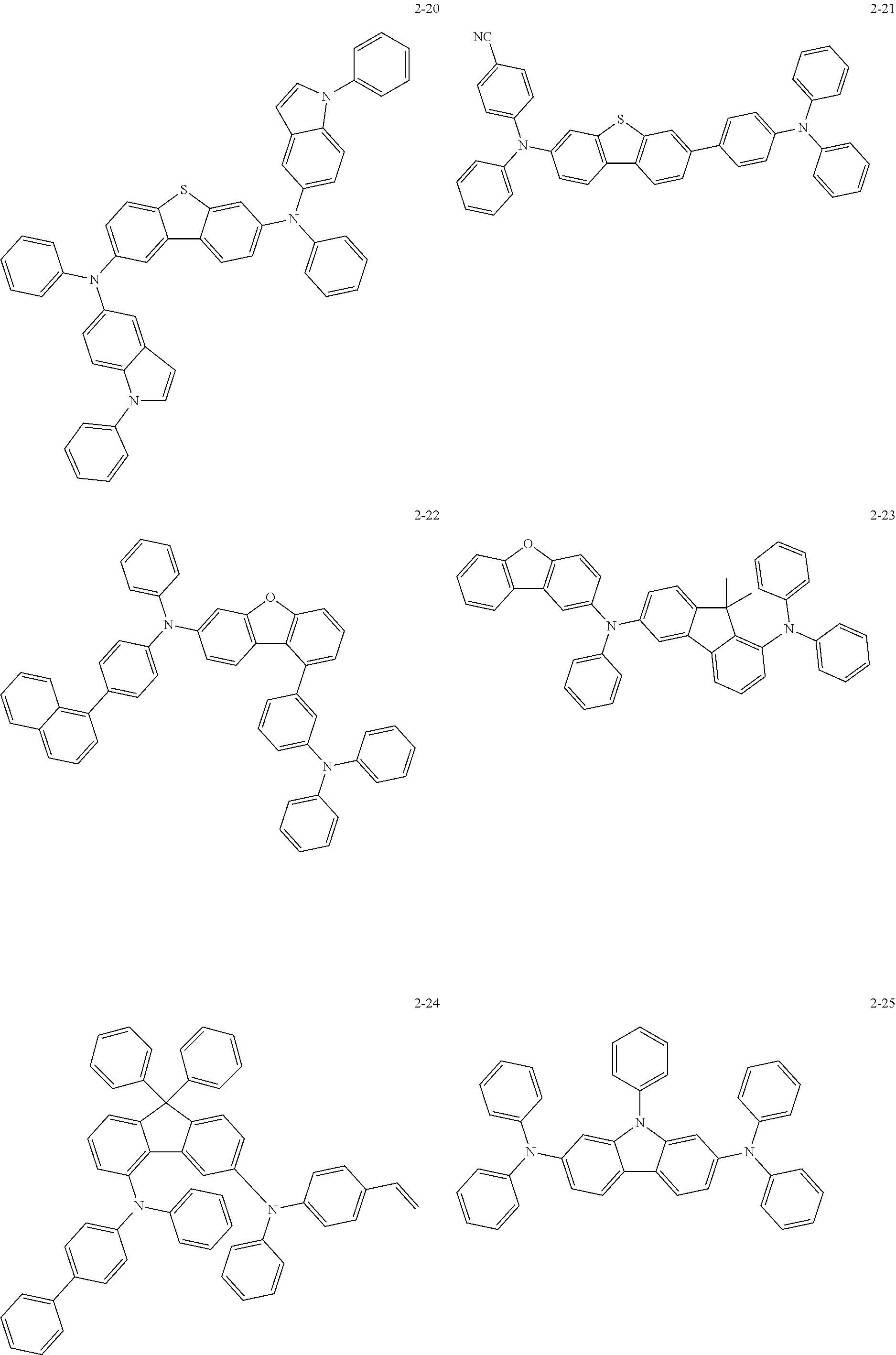

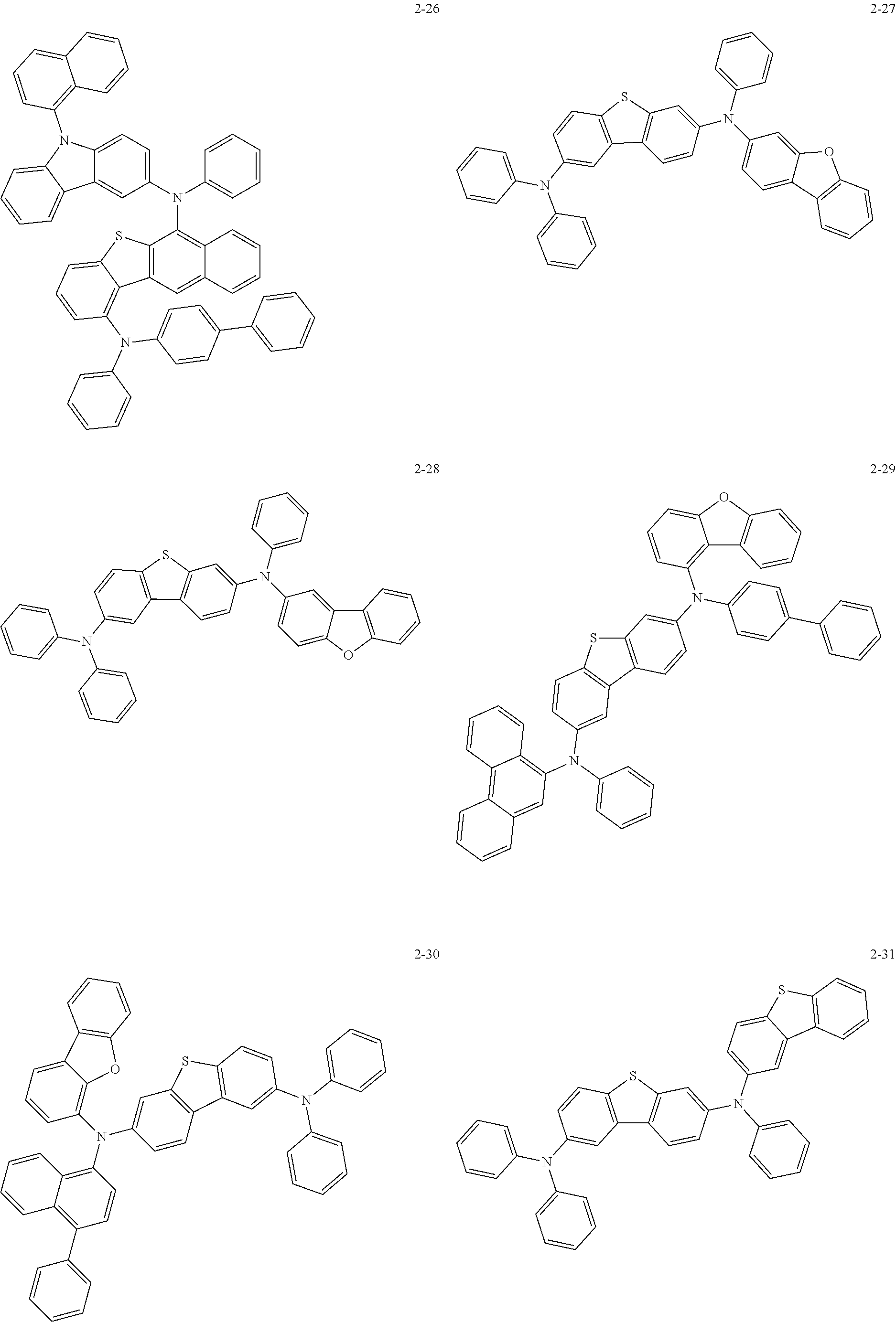

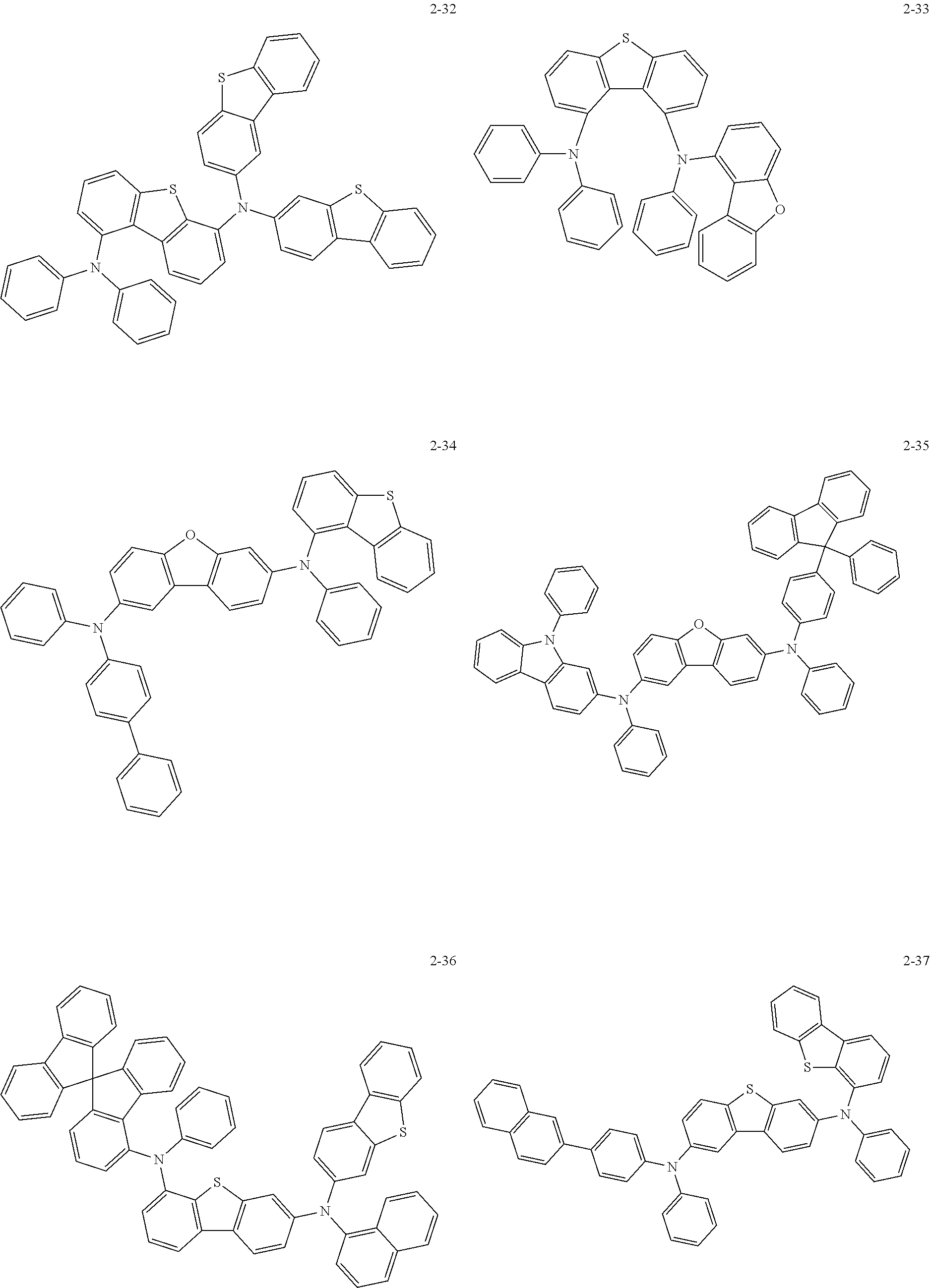

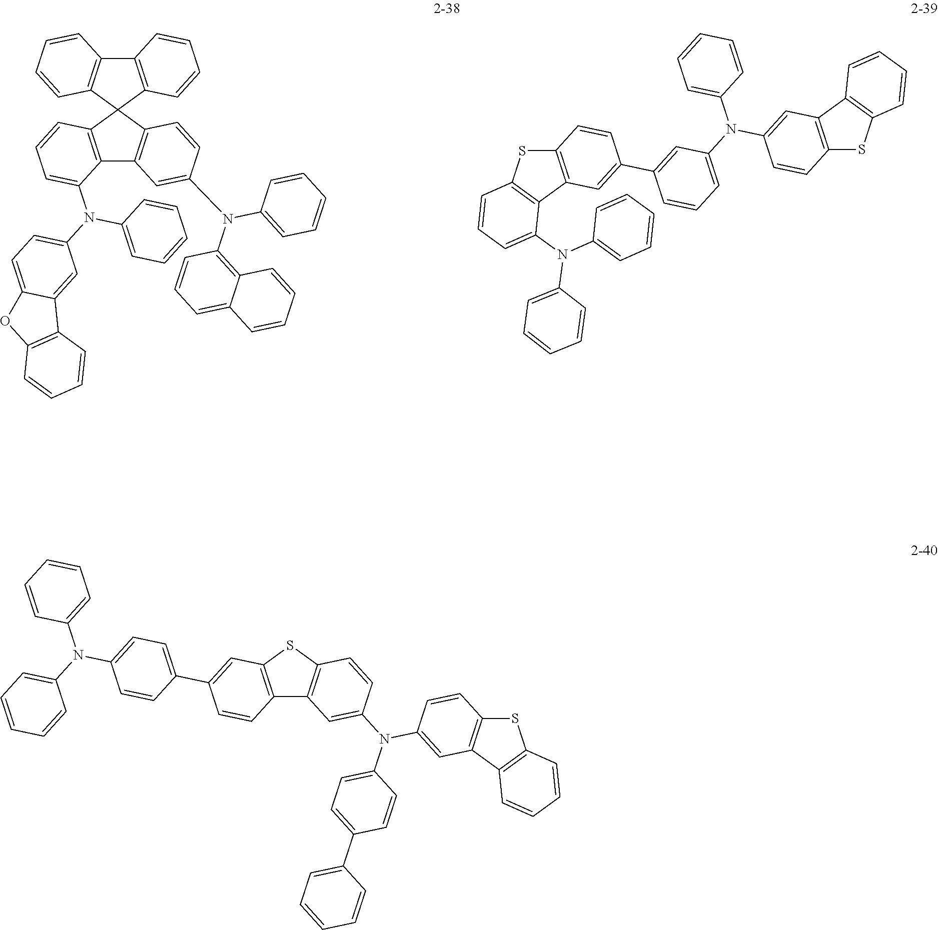 [SMILES: c1ccc(N(c2ccc3oc4ccccc4c3c2)c2cccc3c2-c2cc(N(c4ccccc4)c4cccc5ccccc45)ccc2C32c3ccccc3-c3ccccc32)cc1 ; c1ccc(N(c2cccc(-c3ccc4sc5cccc(N(c6ccccc6)c6ccccc6)c5c4c3)c2)c2ccc3sc4ccccc4c3c2)cc1 ; c1ccc(-c2ccc(N(c3ccc4sc5ccccc5c4c3)c3ccc4sc5cc(-c6ccc(N(c7ccccc7)c7ccccc7)cc6)ccc5c4c3)cc2)cc1]

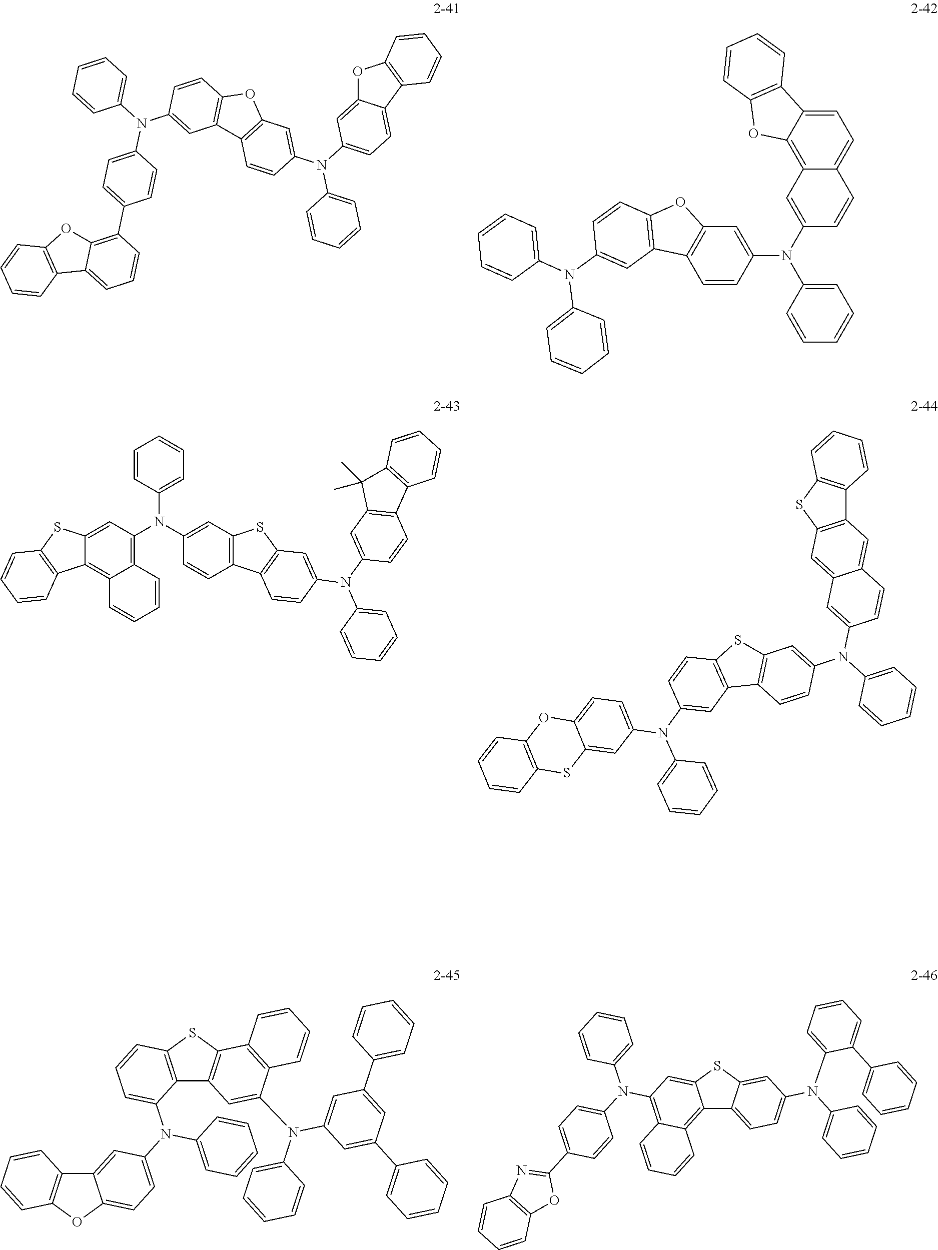

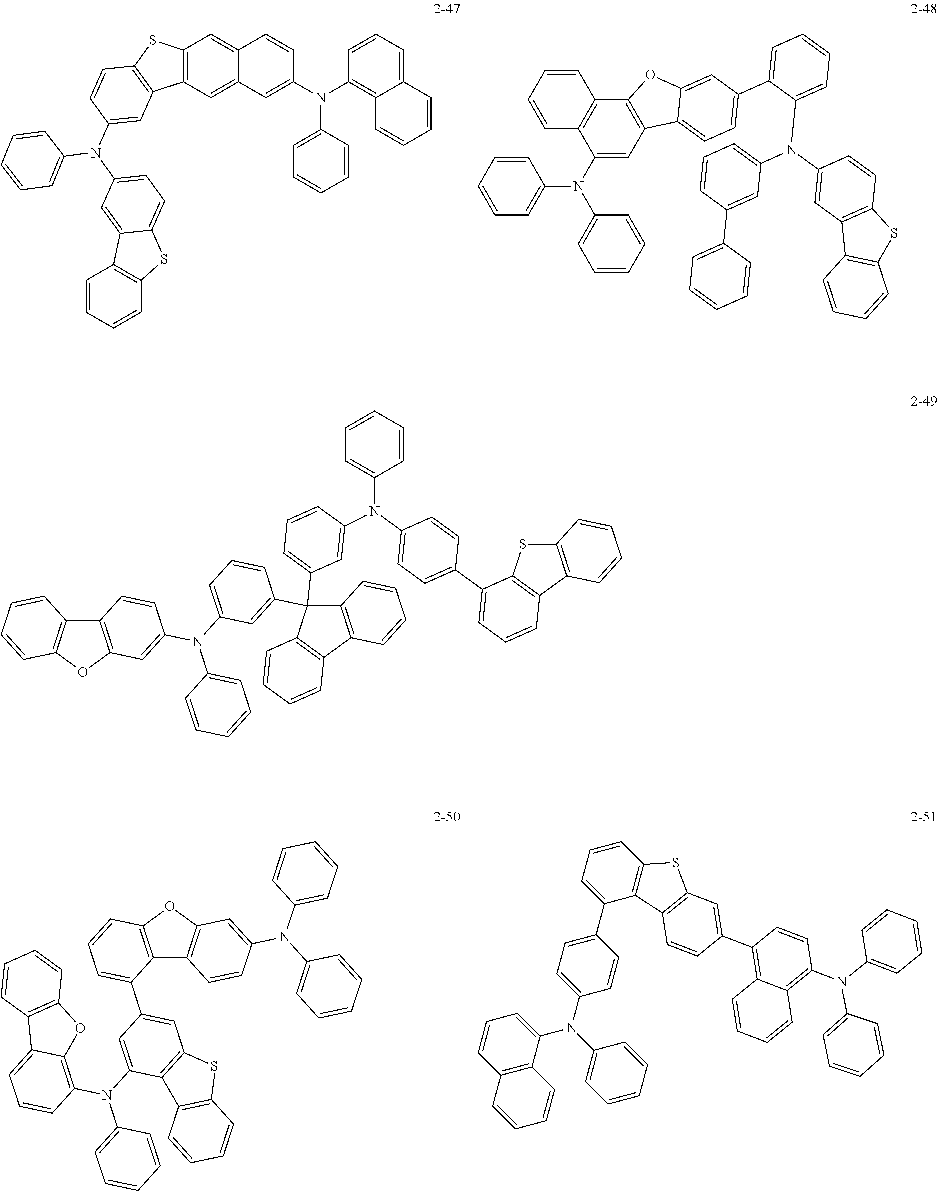

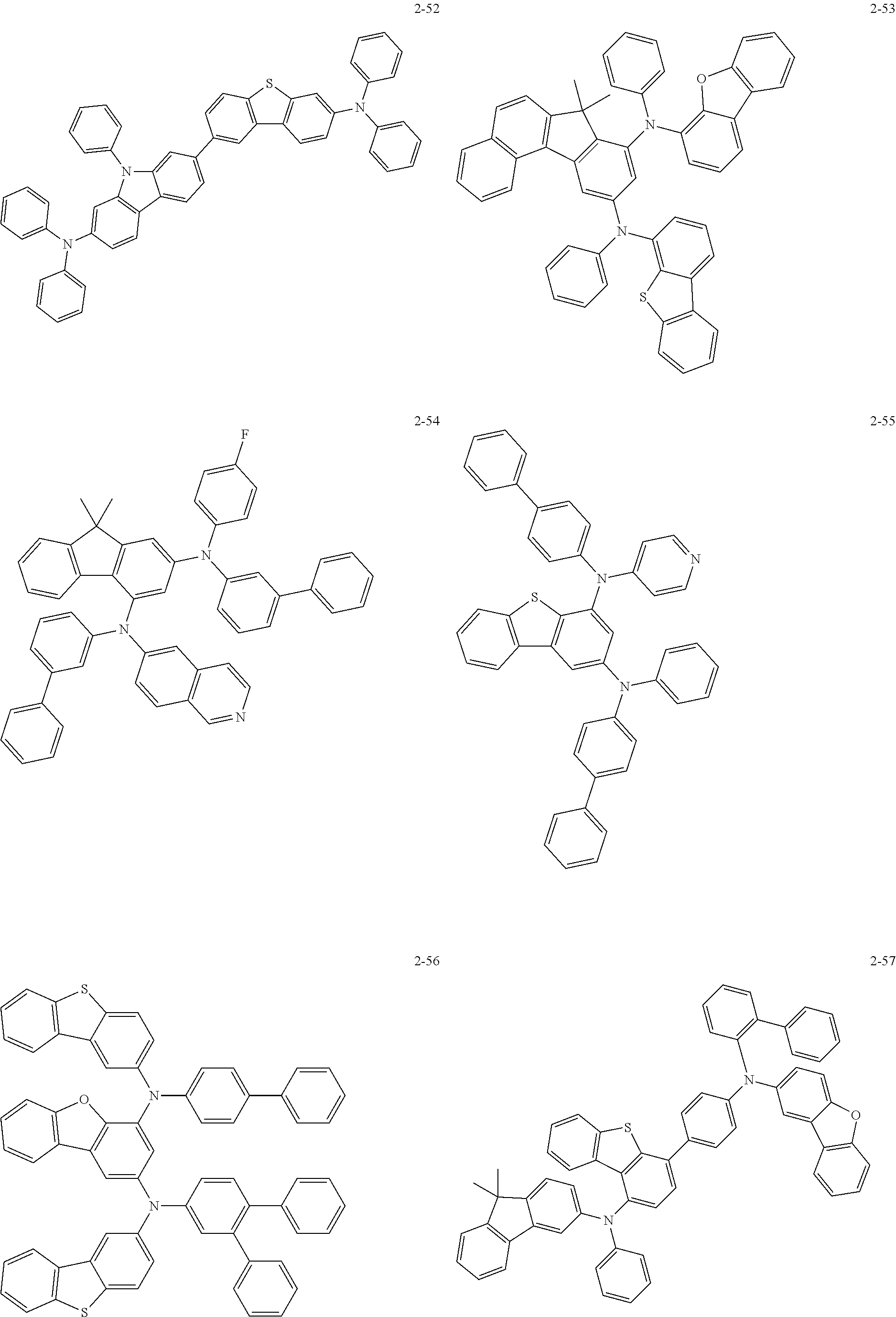

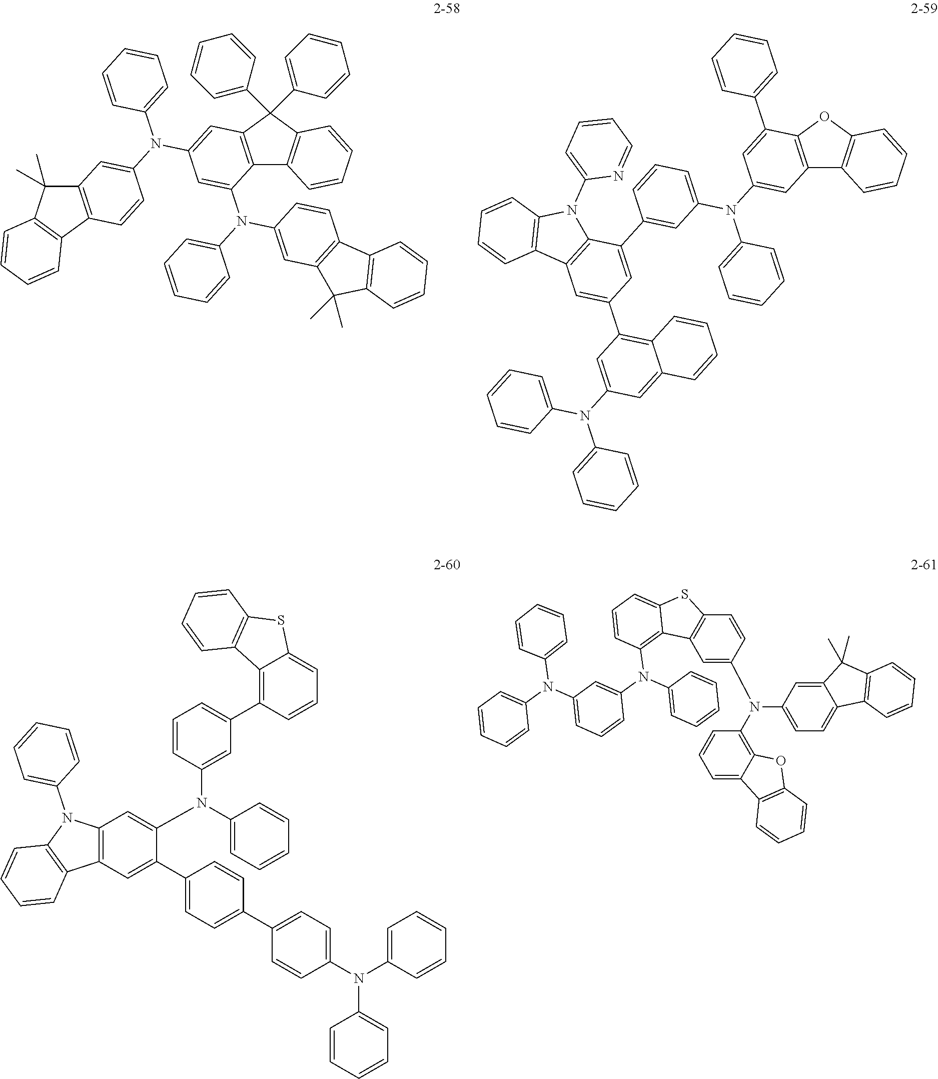 [SMILES: CC1(C)c2ccccc2-c2ccc(N(c3ccccc3)c3cc(N(c4ccccc4)c4ccc5c(c4)C(C)(C)c4ccccc4-5)c4c(c3)C(c3ccccc3)(c3ccccc3)c3ccccc3-4)cc21 ; c1ccc(-c2cc(N(c3ccccc3)c3cccc(-c4cc(-c5cc(N(c6ccccc6)c6ccccc6)cc6ccccc56)cc5c6ccccc6n(-c6ccccn6)c45)c3)cc3c2oc2ccccc23)cc1 ; c1ccc(N(c2ccccc2)c2ccc(-c3ccc(-c4cc5c6ccccc6n(-c6ccccc6)c5cc4N(c4ccccc4)c4cccc(-c5cccc6sc7ccccc7c56)c4)cc3)cc2)cc1 ; CC1(C)c2ccccc2-c2ccc(N(c3ccc4sc5cccc(N(c6ccccc6)c6cccc(N(c7ccccc7)c7ccccc7)c6)c5c4c3)c3cccc4c3oc3ccccc34)cc21]

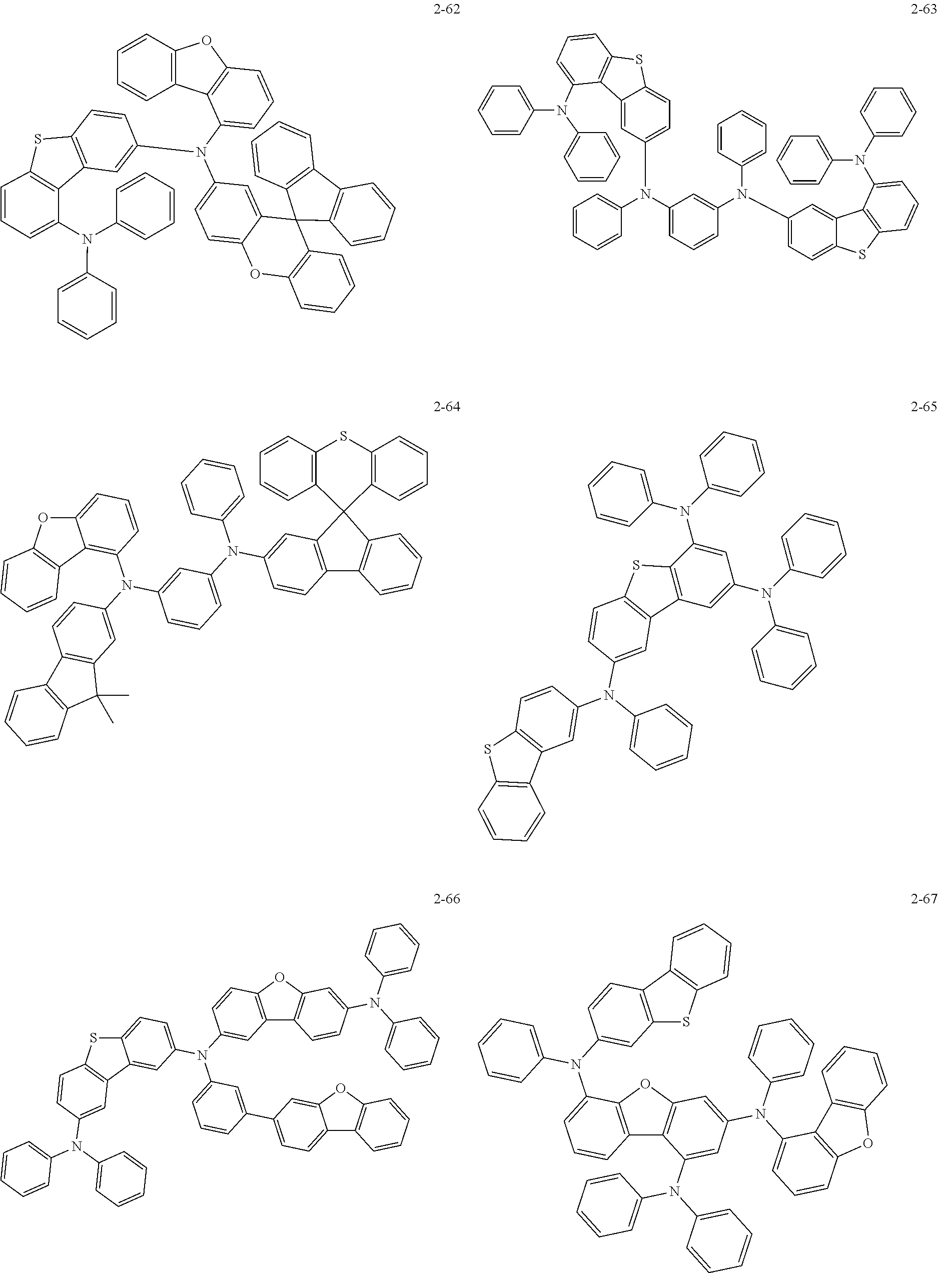

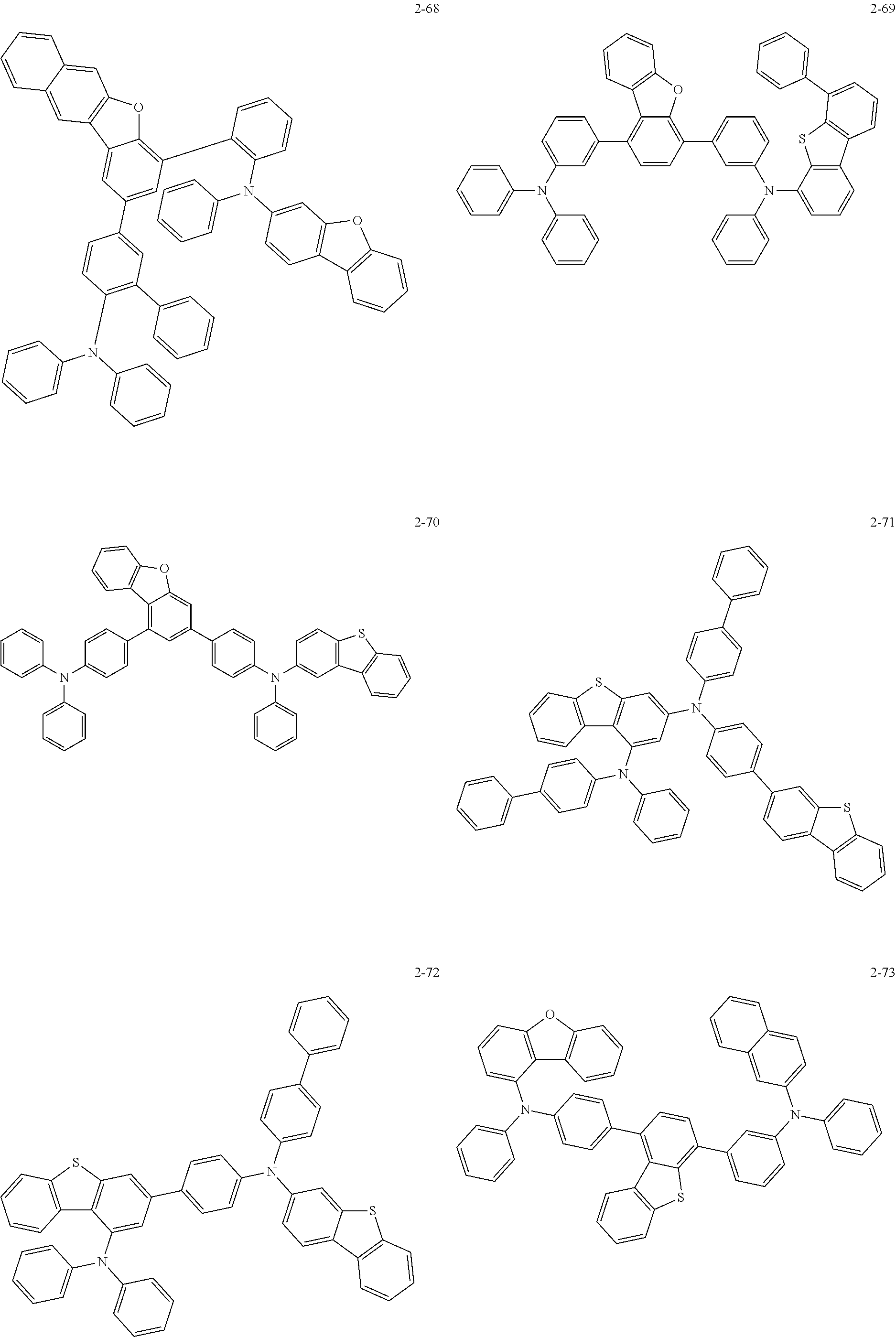

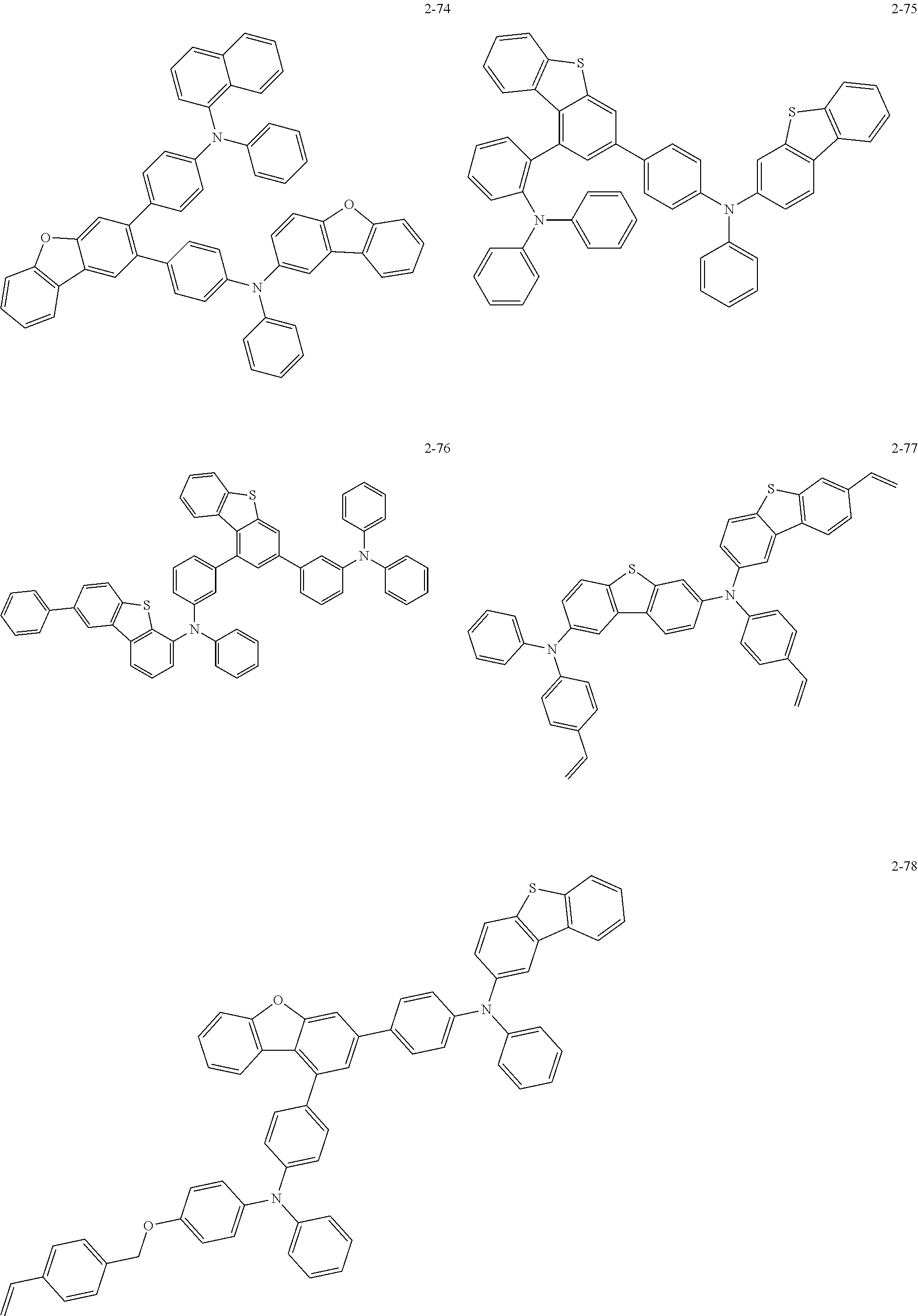

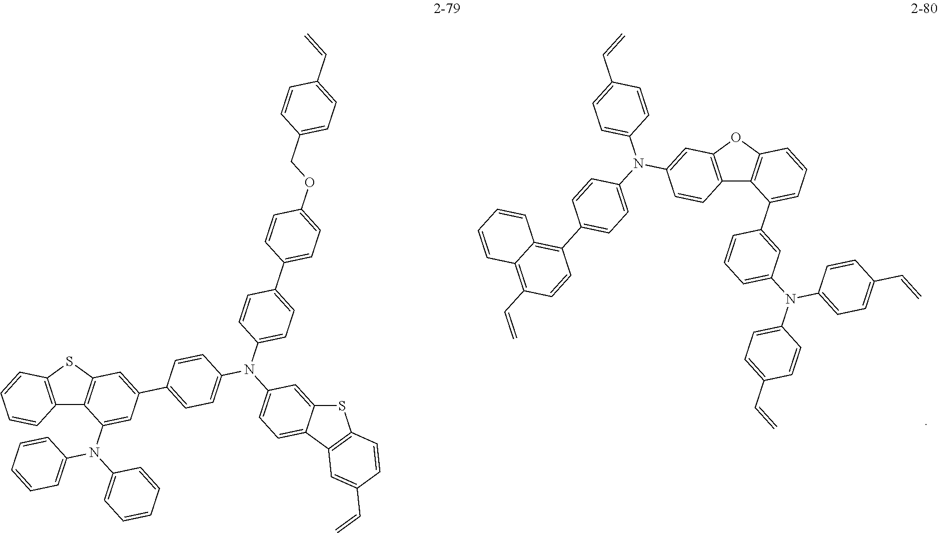 [SMILES: C=Cc1ccc(COc2ccc(-c3ccc(N(c4ccc(-c5cc(N(c6ccccc6)c6ccccc6)c6c(c5)sc5ccccc56)cc4)c4ccc5c(c4)sc4ccc(C=C)cc45)cc3)cc2)cc1 ; C=Cc1ccc(N(c2ccc(C=C)cc2)c2cccc(-c3cccc4oc5cc(N(c6ccc(C=C)cc6)c6ccc(-c7ccc(C=C)c8ccccc78)cc6)ccc5c34)c2)cc1]

6. The quantum dot light emitting device of claim 1, wherein the hole transport layer comprises a compound represented by any of Formula 3 to Formula 5: 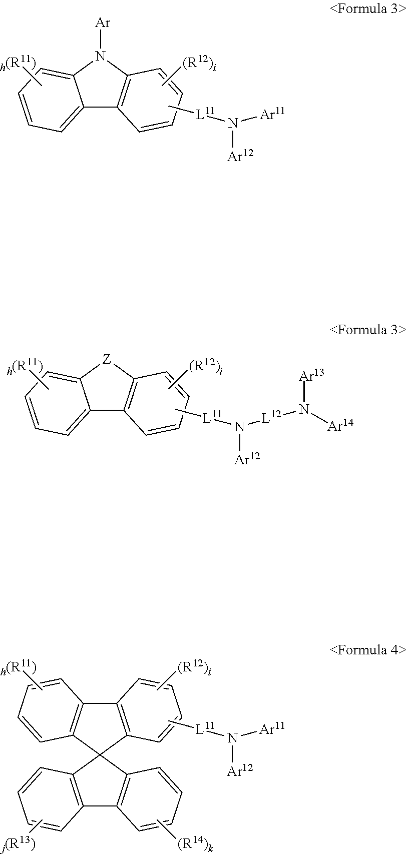
wherein
1) Z is O or S;
2) Ar and Ar¹¹ to Ar¹⁴ are each independently selected from the group consisting of a C₆₋₆₀ aryl group; a fluorenyl group; a C₂₋₆₀ heterocyclic group comprising at least one heteroatom among O, N, S, Si, and P; a fused ring group of a C₃₋₆₀ aliphatic ring and a C₆₋₆₀ aromatic ring; a C₁₋₆₀ alkyl group; a C₂₋₂₀ alkenyl group; a C₂₋₂₀ alkynyl group; a C₁₋₃₀ alkoxyl group; and a C₆₋₃₀ aryloxy group;
3) L¹¹ is selected from the group consisting of a single bond; a C₆₋₆₀ arylene group; a fluorenylene group; a fused ring group of a C₃₋₆₀ aliphatic ring and a C₆₋₆₀ aromatic ring; and a C₂₋₆₀ heterocyclic ring group;
4) L¹² is selected from the group consisting of a C₆₋₆₀ arylene group; a fluorenylene group; a fused ring group of a C₃₋₆₀ aliphatic ring and a C₆₋₆₀ aromatic ring; and a C₂₋₆₀ heterocyclic ring group;
5) R¹¹ to R¹⁴ are each the same or different, and are each independently selected from the group consisting of hydrogen; deuterium, tritium; a halogen; a cyano group; a nitro group; a C₆₋₆₀ aryl group; a fluorenyl group; a C₂₋₆₀ heterocyclic group comprising at least one heteroatom among O, N, S, Si, and P; a fused ring group of a C₃₋₆₀ aliphatic ring and a C₆₋₆₀ aromatic ring; a C₁₋₅₀ alkyl group; a C₂₋₂₀ alkenyl group; a C₂₋₂₀ alkynyl group; a C₁₋₃₀ alkoxyl group; a C₆₋₃₀ aryloxy group; and -L′-N(Rₐ)(R_{b});
6) h, j, and k are each independently an integer of 0 to 4; and i is an integer of 0 to 3;
7) where h to k are each an integer of 2 or more, R¹¹ to R¹⁴ are each plural being the same or different from each other; and a plurality of neighboring R¹¹, or a plurality of neighboring R¹², or a plurality of neighboring R¹³ may combine with each other to form a ring;
8) L′ is selected from the group consisting of a single bond; a C₁₋₆₀ arylene group; a fluorenylene group; a C₂₋₆₀ heterocyclic group comprising at least one heteroatom among O, N, S, Si, and P; a C₃₋₆₀ aliphatic ring; and a fused ring group of a C₃₋₆₀ aliphatic ring and a C₆₋₆₀ aromatic ring;
9) Rₐ and R_{b} are each independently selected from the group consisting of a C₁₋₆₀ aryl group; a fluorenyl group; a C₂₋₆₀ heterocyclic group comprising at least one heteroatom among O, N, S, Si, and P; a C₃₋₆₀ aliphatic ring; and a fused ring group of a C₃₋₆₀ aliphatic ring and a C₁₋₆₀ aromatic ring; and
10) the rings formed by binding between Ar, Ar¹¹ to Ar¹⁴, L′, L¹¹ and L¹², Rₐ, R_{b}, R¹¹ to R¹⁴ and neighboring groups thereof may each be further substituted with one or more substituents selected from the group consisting of deuterium; a halogen; a silane group substituted or unsubstituted with a C₁₋₃₀ alkyl group or C₆₋₃₀ aryl group; a siloxane group; a boron group; a germanium group; a cyano group; an amino group; a nitro group; a C₁₋₃₀ alkylthio group; a C₁₋₃₀alkoxy group; a C₆₋₃₀ arylalkoxy group; a C₁₋₃₀ alkyl group; a C₂₋₃₀ alkenyl group; a C₂₋₃₀ alkynyl group; a C₆₋₃₀ aryl group; a C₆₋₃₀ aryl group substituted with deuterium; a fluorenyl group; a C₂₋₃₀ heterocyclic group comprising at least one heteroatom among O, N, S, Si, and P; a C₃₋₃₀ alicyclic group; a C₇₋₃₀ arylalkyl group; a C₆₋₃₀ arylalkenyl group; and a combination thereof; or may form a ring between the neighboring substituents.

7. The quantum dot light emitting device of claim 1, wherein the compound comprised by the hole transport layer is any one of Compounds H-1 to H-80:

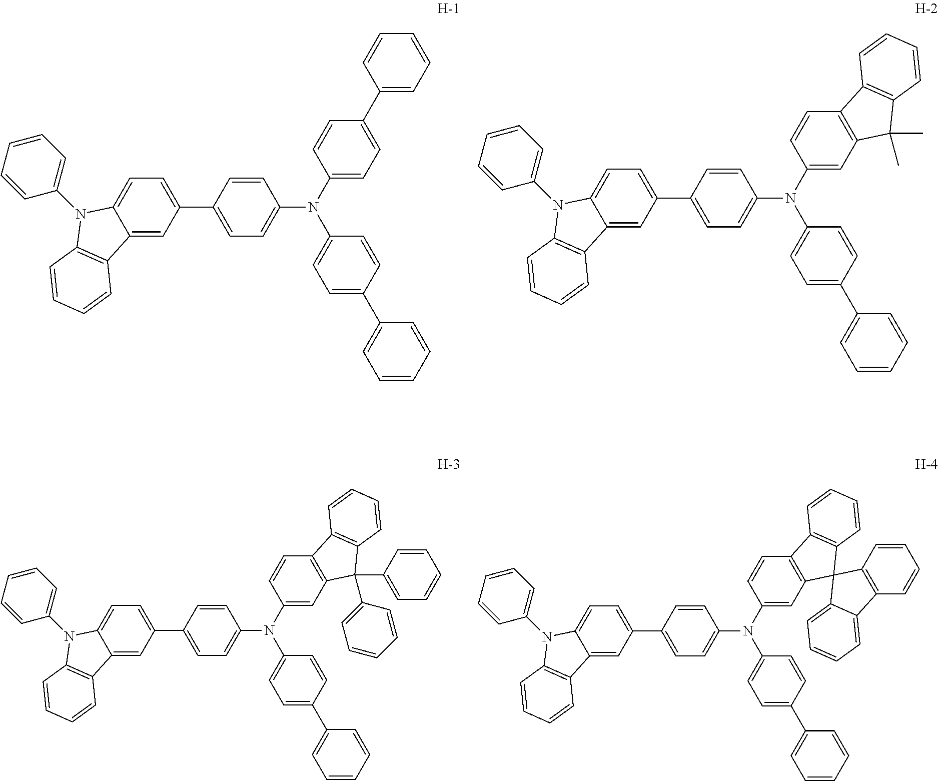 [SMILES: c1ccc(-c2ccc(N(c3ccc(-c4ccccc4)cc3)c3ccc(-c4ccc5c(c4)c4ccccc4n5-c4ccccc4)cc3)cc2)cc1 ; CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1]

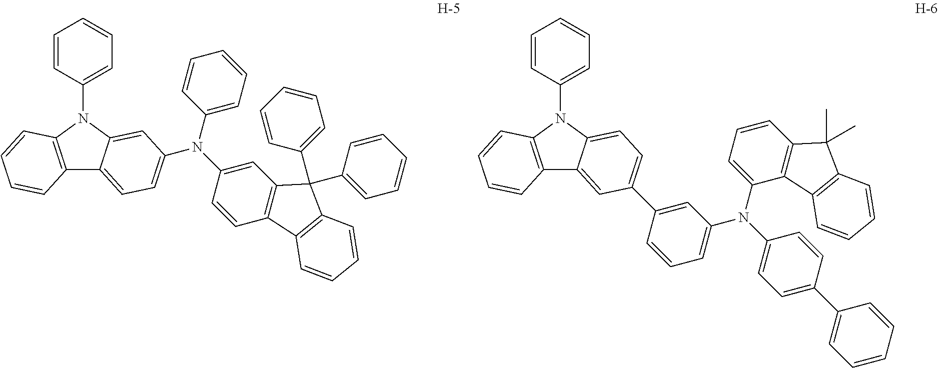 [SMILES: c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2c(N(c3ccc(-c4ccccc4)cc3)c3cccc(-c4ccc5c(c4)c4ccccc4n5-c4ccccc4)c3)cccc21]

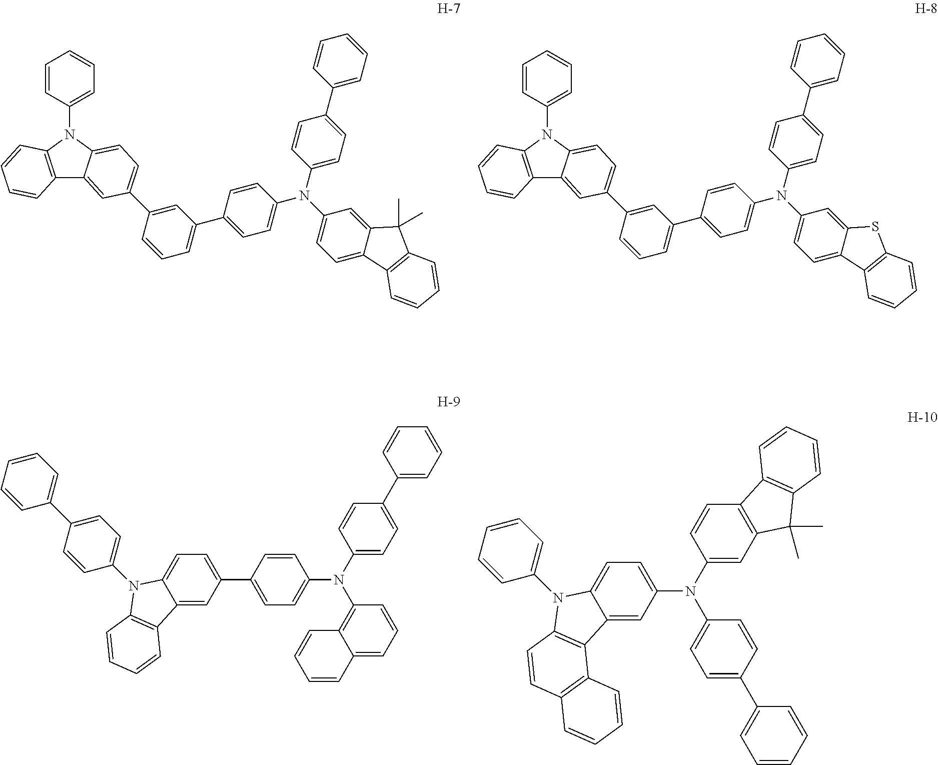 [SMILES: CC1(C)c2ccccc2-c2ccc(N(c3ccc(-c4ccccc4)cc3)c3ccc(-c4cccc(-c5ccc6c(c5)c5ccccc5n6-c5ccccc5)c4)cc3)cc21 ; c1ccc(-c2ccc(N(c3ccc(-c4cccc(-c5ccc6c(c5)c5ccccc5n6-c5ccccc5)c4)cc3)c3ccc4c(c3)sc3ccccc34)cc2)cc1 ; c1ccc(-c2ccc(N(c3ccc(-c4ccc5c(c4)c4ccccc4n5-c4ccc(-c5ccccc5)cc4)cc3)c3cccc4ccccc34)cc2)cc1 ; CC1(C)c2ccccc2-c2ccc(N(c3ccc(-c4ccccc4)cc3)c3ccc4c(c3)c3c5ccccc5ccc3n4-c3ccccc3)cc21]

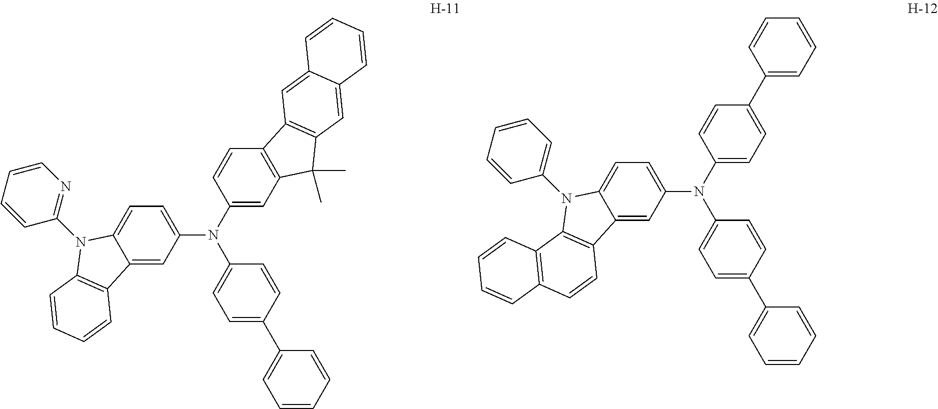 [SMILES: CC1(C)c2cc(N(c3ccc(-c4ccccc4)cc3)c3ccc4c(c3)c3ccccc3n4-c3ccccn3)ccc2-c2cc3ccccc3cc21 ; c1ccc(-c2ccc(N(c3ccc(-c4ccccc4)cc3)c3ccc4c(c3)c3ccc5ccccc5c3n4-c3ccccc3)cc2)cc1]

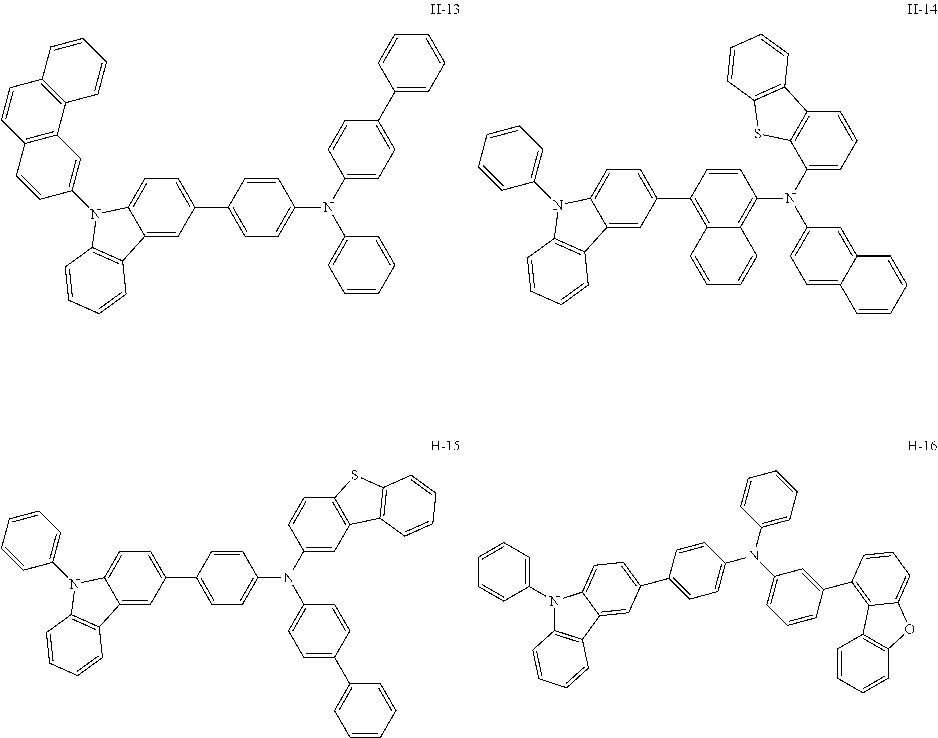 [SMILES: c1ccc(-c2ccc(N(c3ccccc3)c3ccc(-c4ccc5c(c4)c4ccccc4n5-c4ccc5ccc6ccccc6c5c4)cc3)cc2)cc1 ; c1ccc(-n2c3ccccc3c3cc(-c4ccc(N(c5ccc6ccccc6c5)c5cccc6c5sc5ccccc56)c5ccccc45)ccc32)cc1 ; c1ccc(-c2ccc(N(c3ccc(-c4ccc5c(c4)c4ccccc4n5-c4ccccc4)cc3)c3ccc4sc5ccccc5c4c3)cc2)cc1 ; c1ccc(N(c2ccc(-c3ccc4c(c3)c3ccccc3n4-c3ccccc3)cc2)c2cccc(-c3cccc4oc5ccccc5c34)c2)cc1]

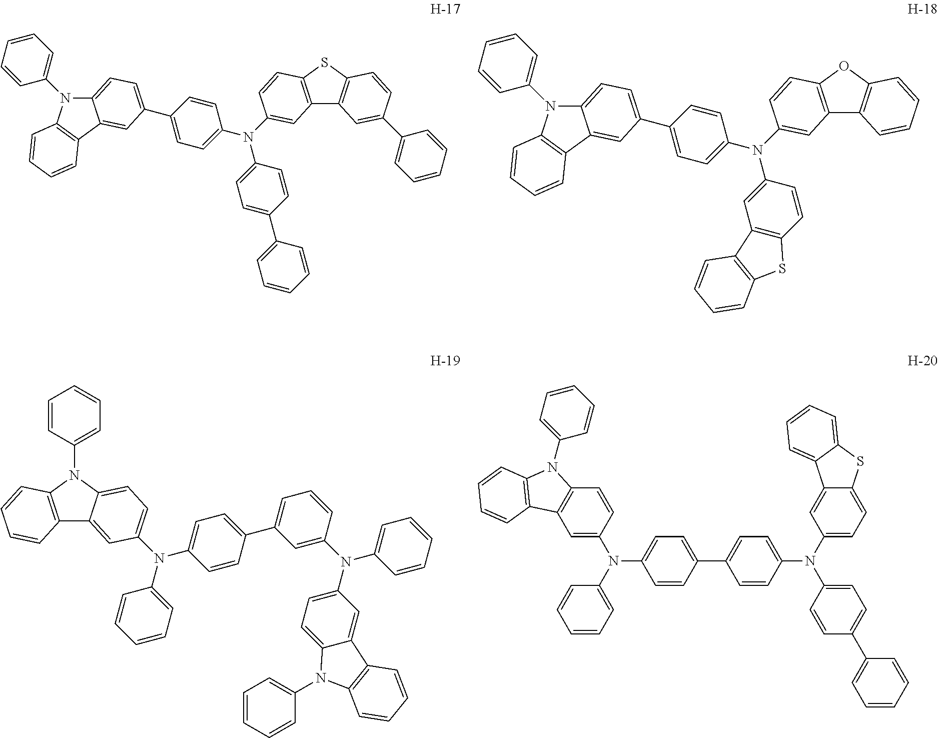 [SMILES: c1ccc(-c2ccc(N(c3ccc(-c4ccc5c(c4)c4ccccc4n5-c4ccccc4)cc3)c3ccc4sc5ccc(-c6ccccc6)cc5c4c3)cc2)cc1 ; c1ccc(-n2c3ccccc3c3cc(-c4ccc(N(c5ccc6oc7ccccc7c6c5)c5ccc6sc7ccccc7c6c5)cc4)ccc32)cc1 ; c1ccc(N(c2ccc(-c3cccc(N(c4ccccc4)c4ccc5c(c4)c4ccccc4n5-c4ccccc4)c3)cc2)c2ccc3c(c2)c2ccccc2n3-c2ccccc2)cc1 ; c1ccc(-c2ccc(N(c3ccc(-c4ccc(N(c5ccccc5)c5ccc6c(c5)c5ccccc5n6-c5ccccc5)cc4)cc3)c3ccc4sc5ccccc5c4c3)cc2)cc1]

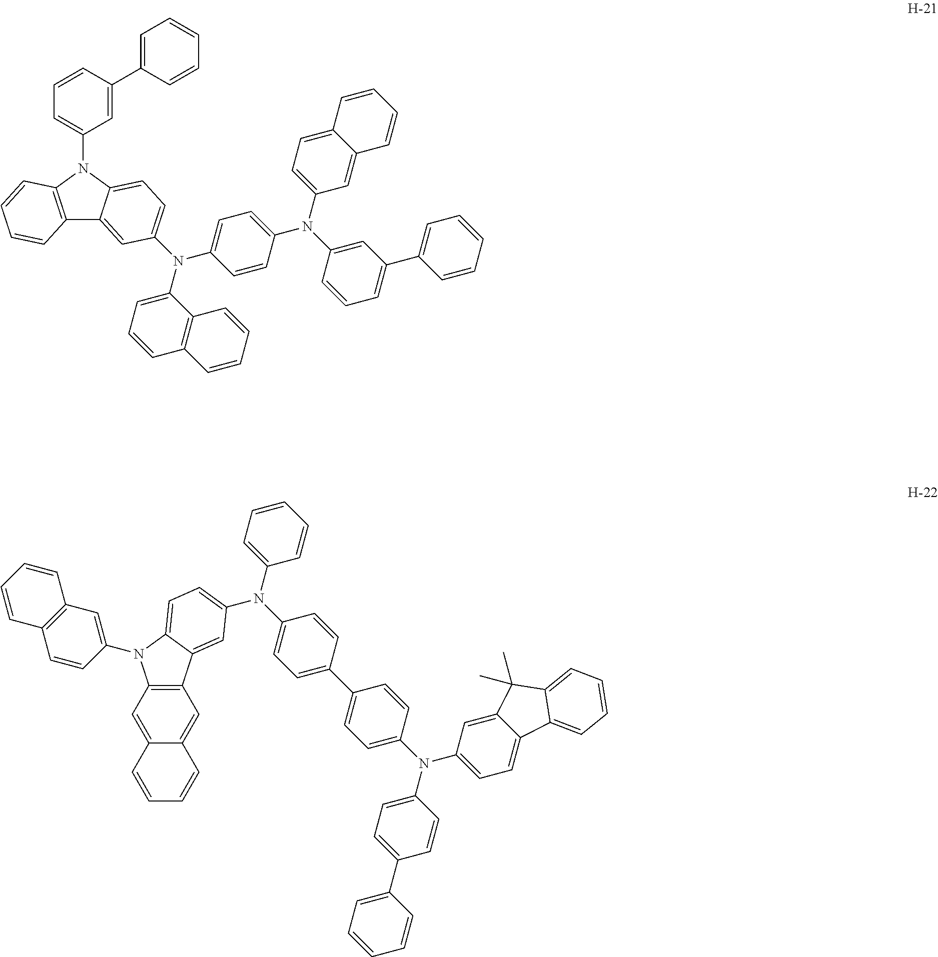 [SMILES: c1ccc(-c2cccc(N(c3ccc(N(c4ccc5c(c4)c4ccccc4n5-c4cccc(-c5ccccc5)c4)c4cccc5ccccc45)cc3)c3ccc4ccccc4c3)c2)cc1 ; CC1(C)c2ccccc2-c2ccc(N(c3ccc(-c4ccccc4)cc3)c3ccc(-c4ccc(N(c5ccccc5)c5ccc6c(c5)c5cc7ccccc7cc5n6-c5ccc6ccccc6c5)cc4)cc3)cc21]

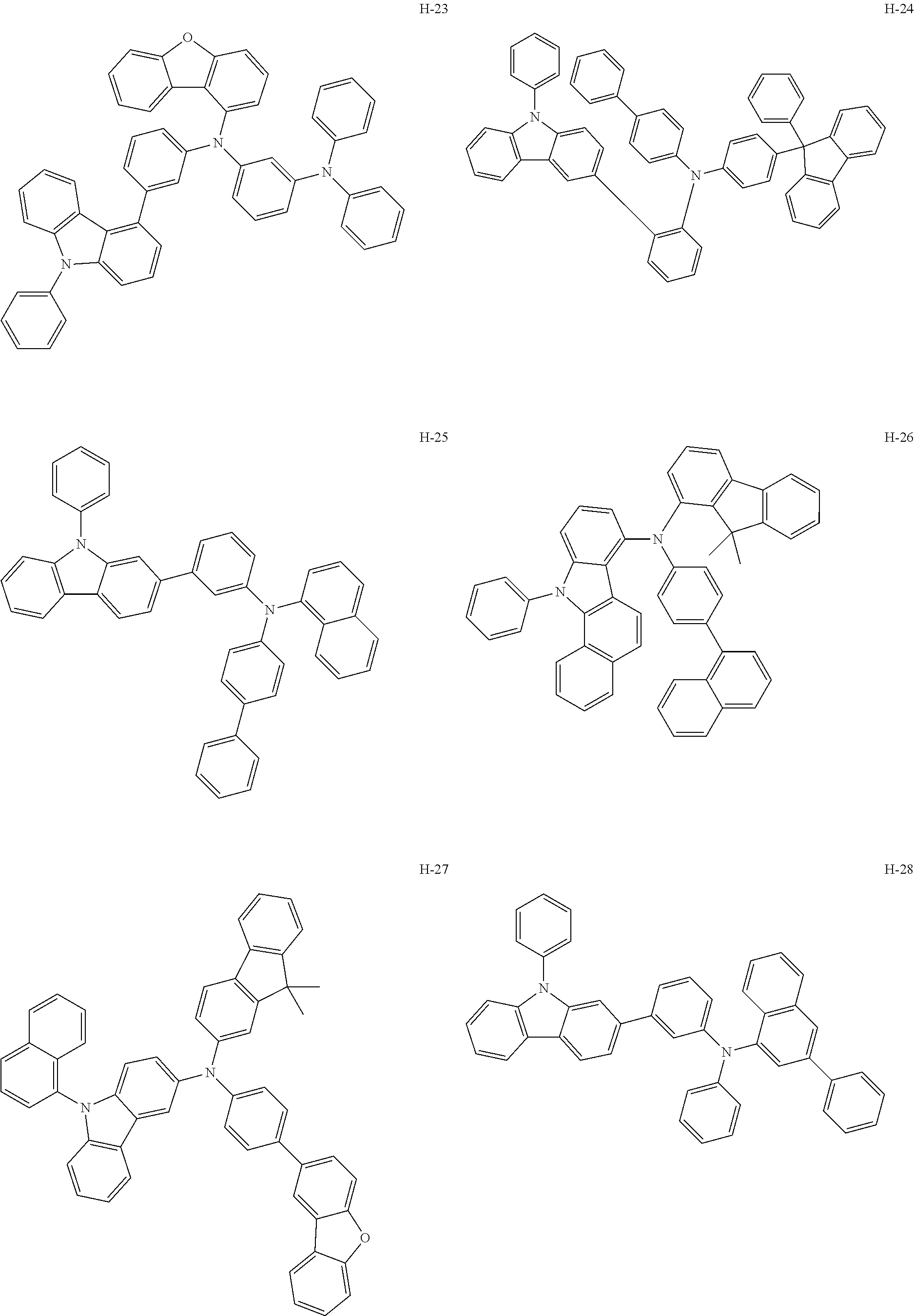

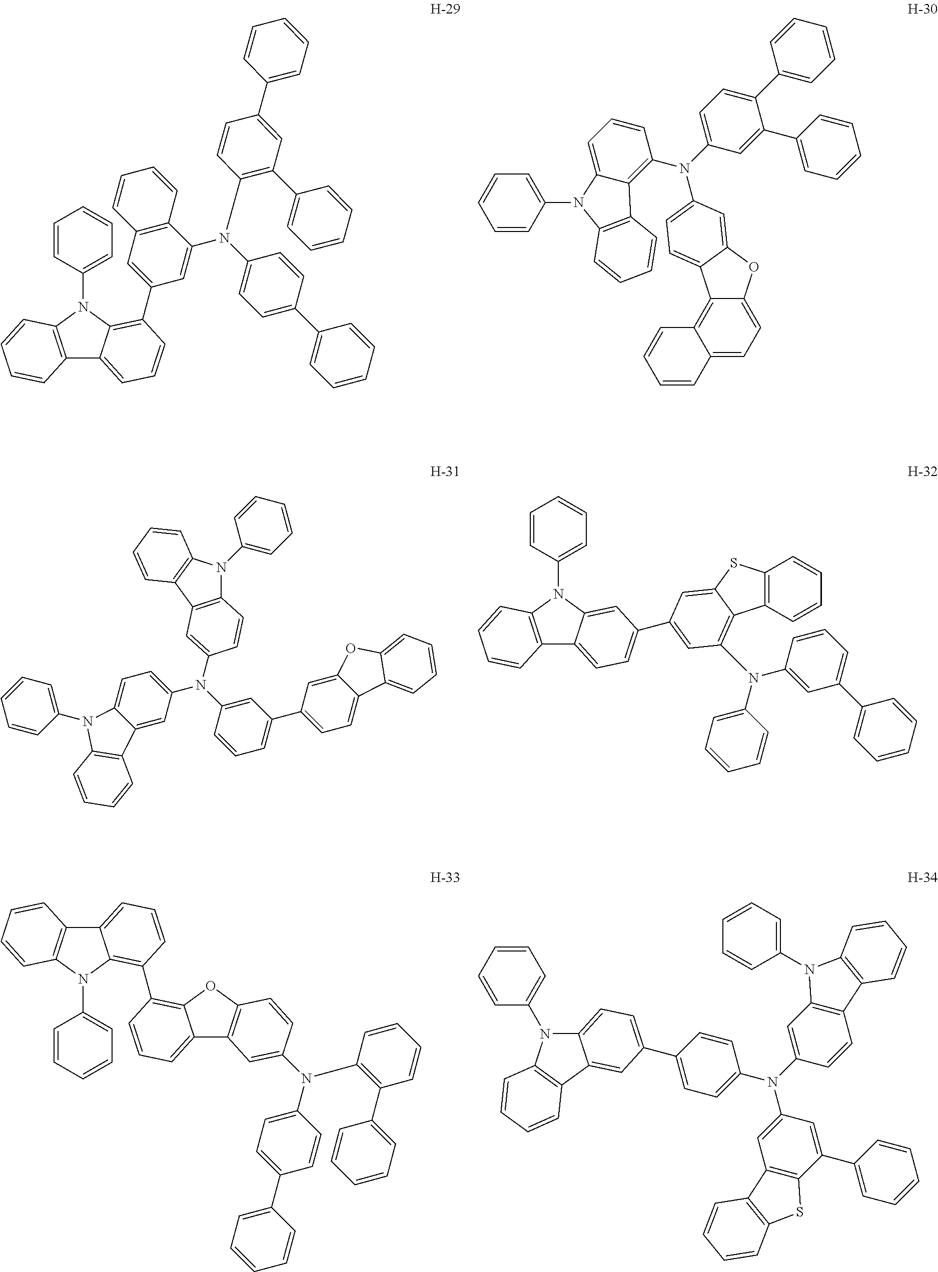

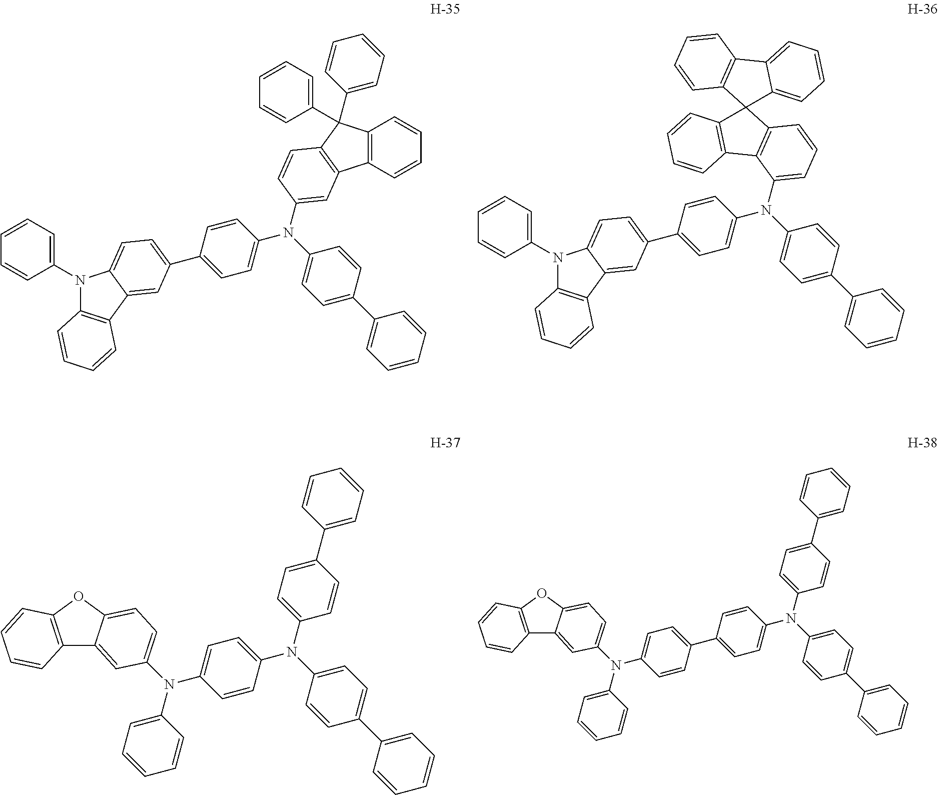 [SMILES: c1ccc(-c2ccc(N(c3ccc(-c4ccc5c(c4)c4ccccc4n5-c4ccccc4)cc3)c3ccc4c(c3)-c3ccccc3C4(c3ccccc3)c3ccccc3)cc2)cc1 ; c1ccc(-c2ccc(N(c3ccc(-c4ccc5c(c4)c4ccccc4n5-c4ccccc4)cc3)c3cccc4c3-c3ccccc3C43c4ccccc4-c4ccccc43)cc2)cc1 ; c1ccc(-c2ccc(N(c3ccc(-c4ccccc4)cc3)c3ccc(N(c4ccccc4)c4ccc5oc6ccccc6c5c4)cc3)cc2)cc1 ; c1ccc(-c2ccc(N(c3ccc(-c4ccccc4)cc3)c3ccc(-c4ccc(N(c5ccccc5)c5ccc6oc7ccccc7c6c5)cc4)cc3)cc2)cc1]

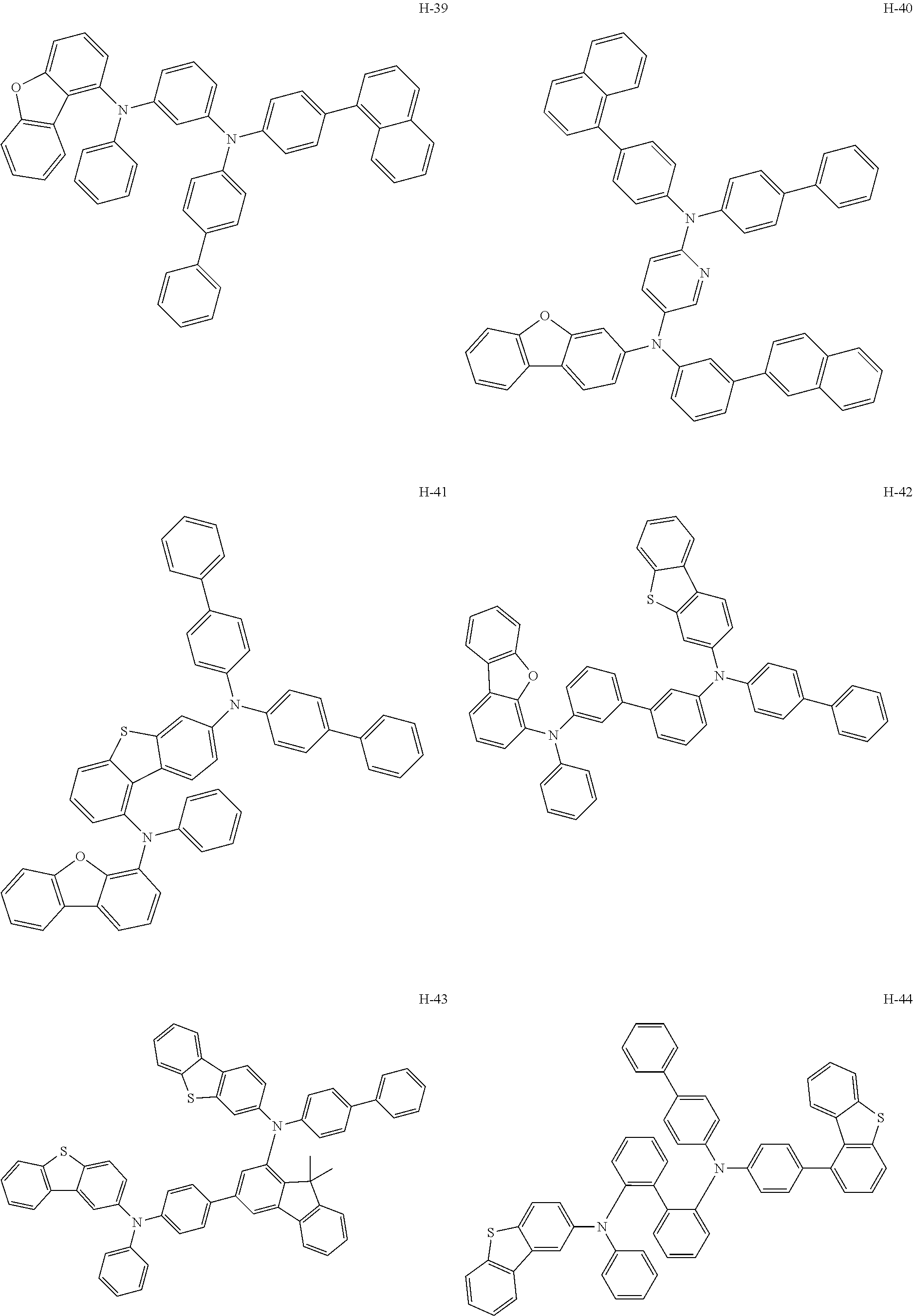

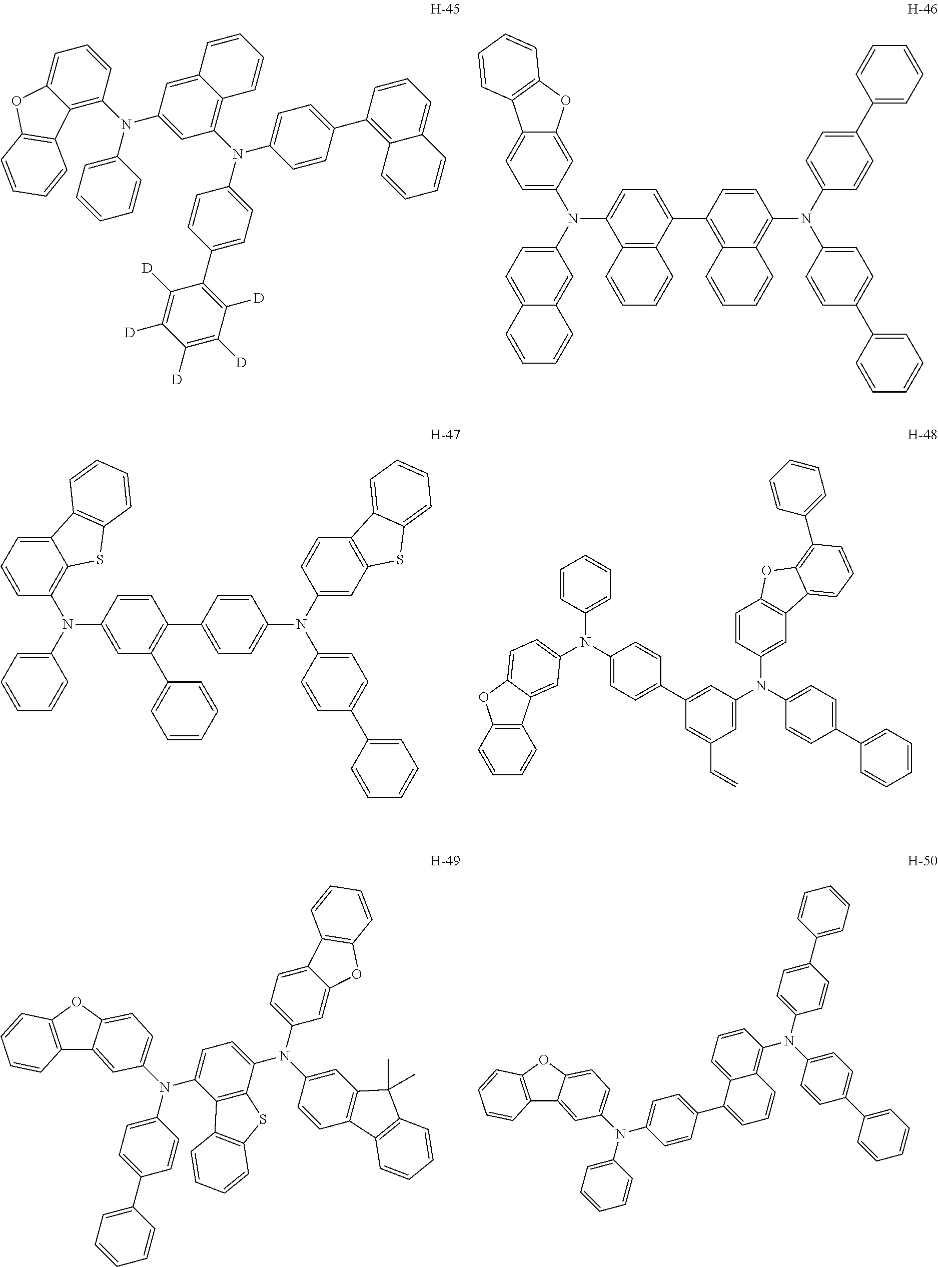

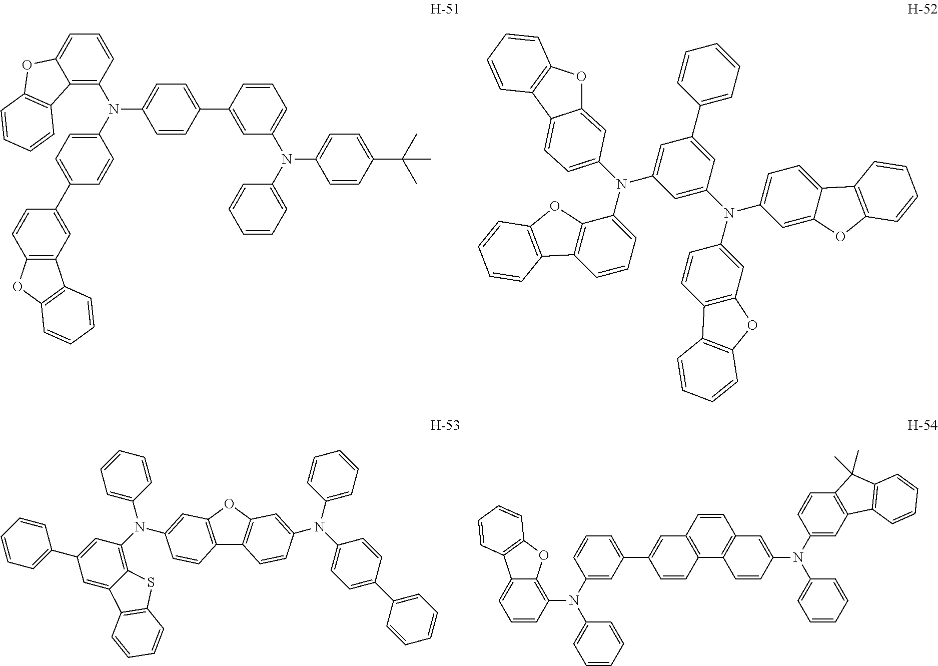 [SMILES: CC(C)(C)c1ccc(N(c2ccccc2)c2cccc(-c3ccc(N(c4ccc(-c5ccc6oc7ccccc7c6c5)cc4)c4cccc5oc6ccccc6c45)cc3)c2)cc1 ; c1ccc(-c2cc(N(c3ccc4c(c3)oc3ccccc34)c3ccc4c(c3)oc3ccccc34)cc(N(c3ccc4c(c3)oc3ccccc34)c3cccc4c3oc3ccccc34)c2)cc1 ; c1ccc(-c2ccc(N(c3ccccc3)c3ccc4c(c3)oc3cc(N(c5ccccc5)c5cc(-c6ccccc6)cc6c5sc5ccccc56)ccc34)cc2)cc1 ; CC1(C)c2ccccc2-c2cc(N(c3ccccc3)c3ccc4c(ccc5cc(-c6cccc(N(c7ccccc7)c7cccc8c7oc7ccccc78)c6)ccc54)c3)ccc21]

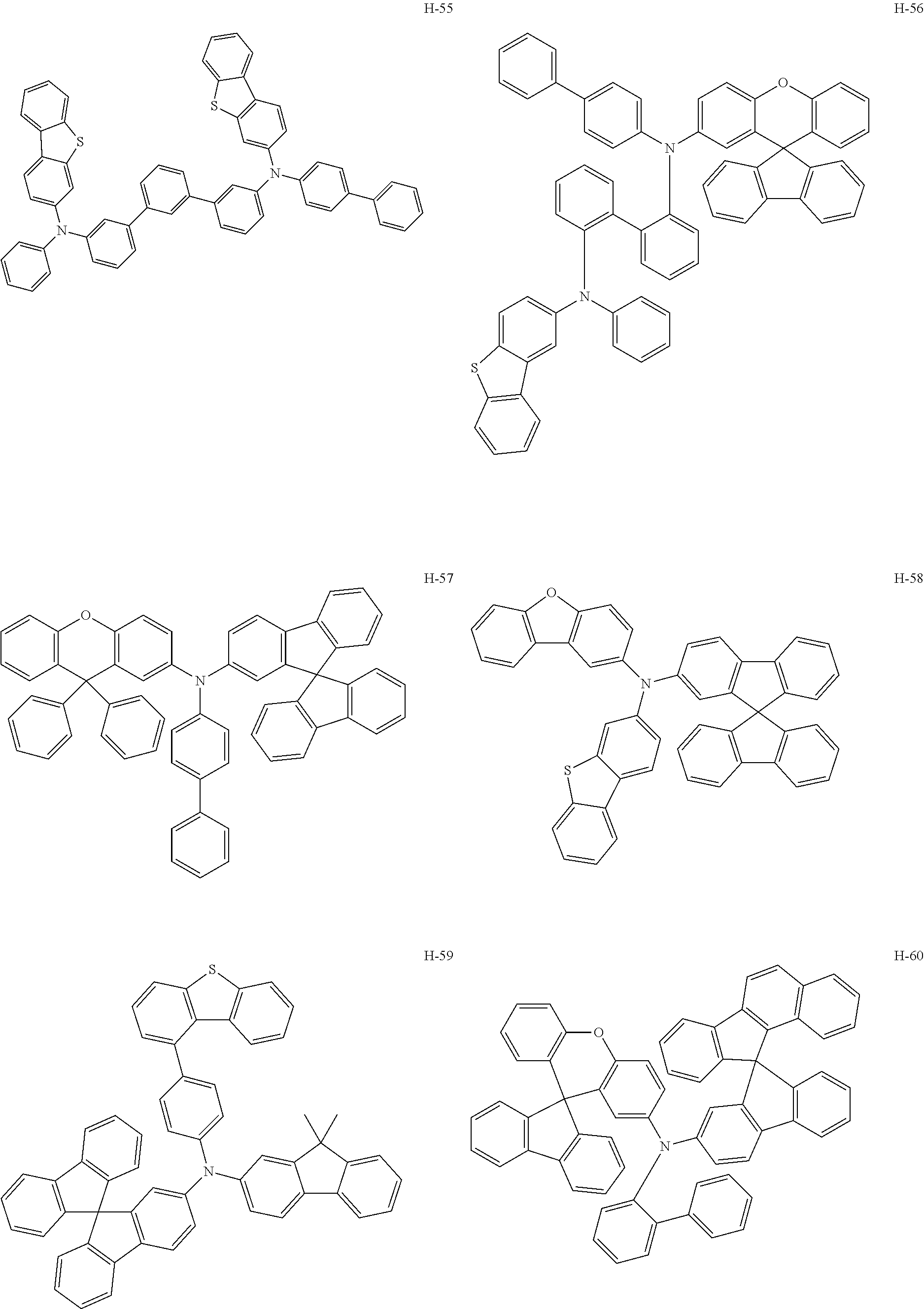

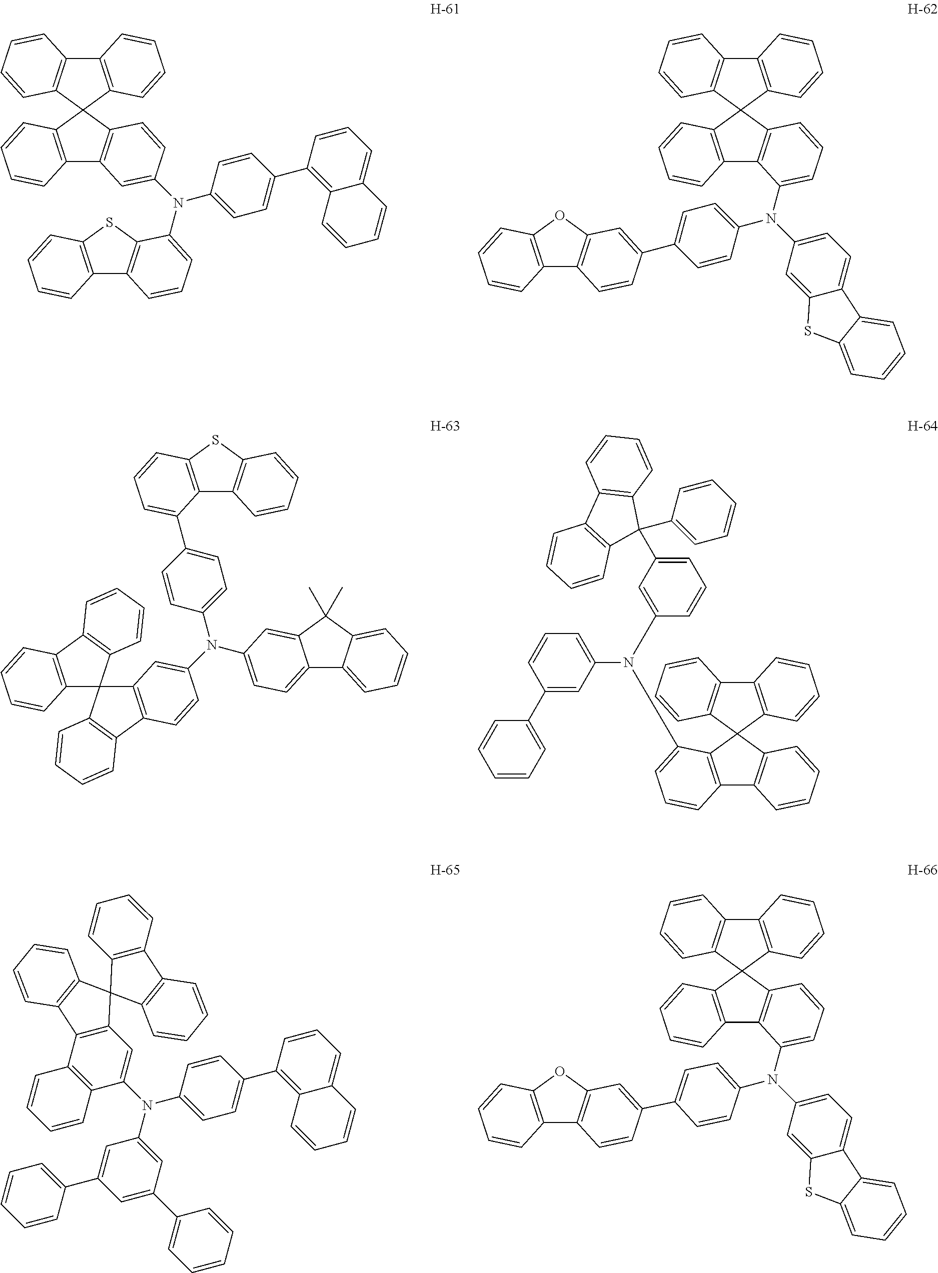

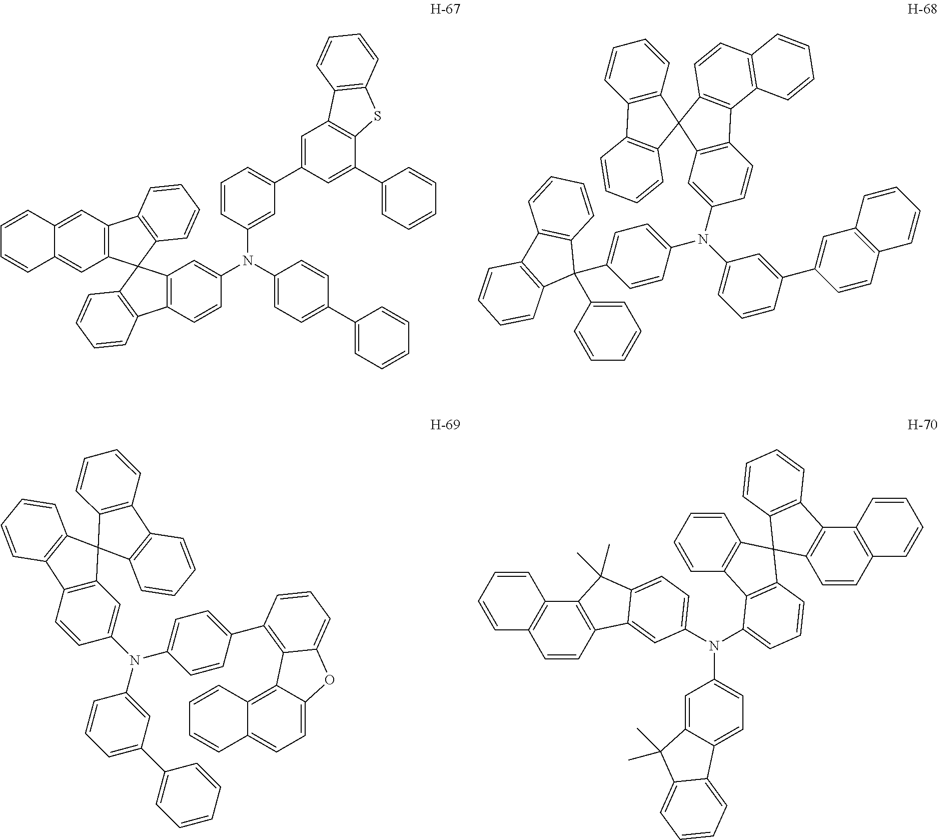 [SMILES: c1ccc(-c2ccc(N(c3cccc(-c4cc(-c5ccccc5)c5sc6ccccc6c5c4)c3)c3ccc4c(c3)C3(c5ccccc5-4)c4ccccc4-c4cc5ccccc5cc43)cc2)cc1 ; c1ccc(C2(c3ccc(N(c4cccc(-c5ccc6ccccc6c5)c4)c4ccc5c(c4)C4(c6ccccc6-c6ccccc64)c4ccc6ccccc6c4-5)cc3)c3ccccc3-c3ccccc32)cc1 ; c1ccc(-c2cccc(N(c3ccc(-c4cccc5oc6ccc7ccccc7c6c45)cc3)c3ccc4c(c3)C3(c5ccccc5-c5ccccc53)c3ccccc3-4)c2)cc1 ; CC1(C)c2ccccc2-c2ccc(N(c3ccc4c(c3)-c3ccc5ccccc5c3C4(C)C)c3cccc4c3-c3ccccc3C43c4ccccc4-c4c3ccc3ccccc43)cc21]

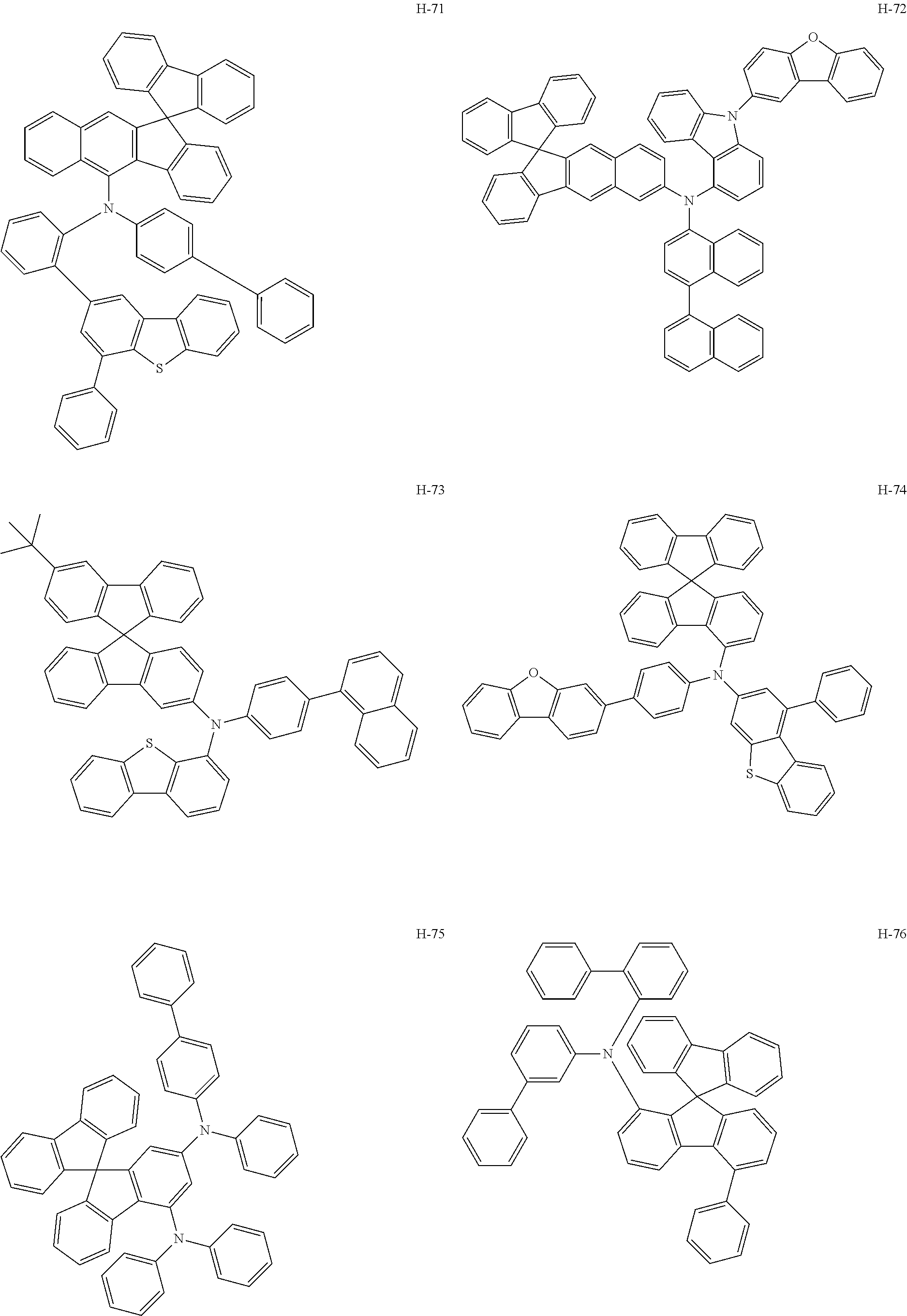

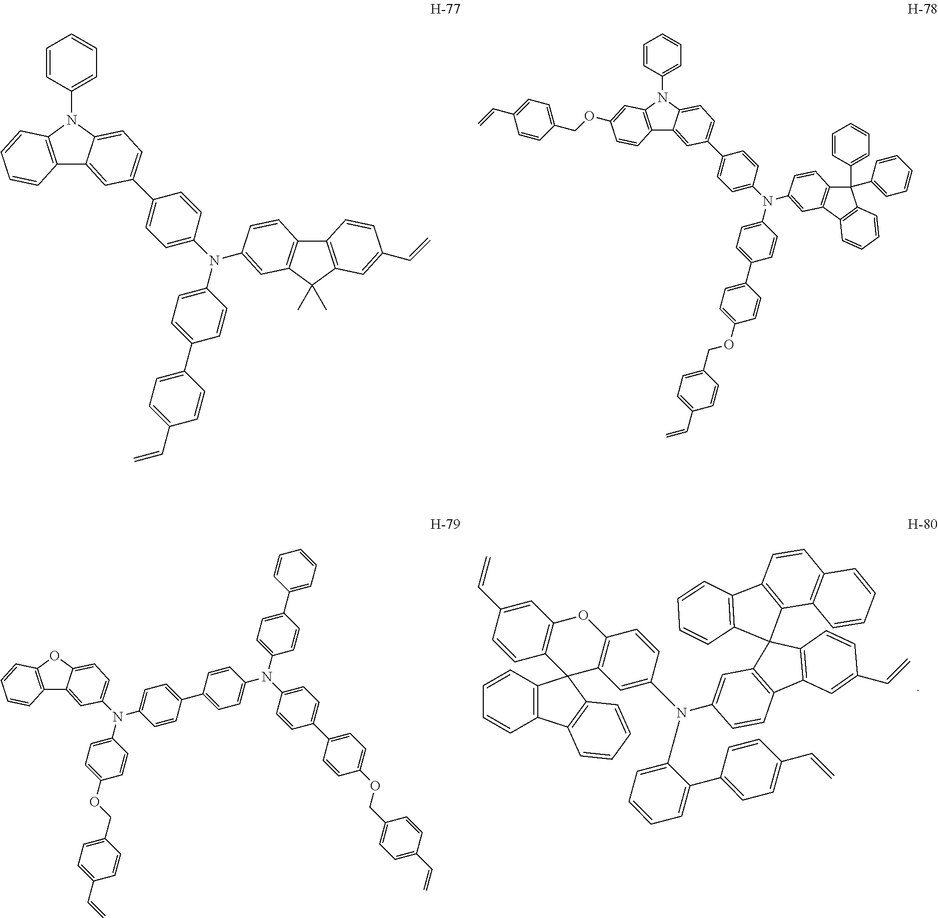 [SMILES: C=Cc1ccc(-c2ccc(N(c3ccc(-c4ccc5c(c4)c4ccccc4n5-c4ccccc4)cc3)c3ccc4c(c3)C(C)(C)c3cc(C=C)ccc3-4)cc2)cc1 ; C=Cc1ccc(COc2ccc(-c3ccc(N(c4ccc(-c5ccc6c(c5)c5ccc(OCc7ccc(C=C)cc7)cc5n6-c5ccccc5)cc4)c4ccc5c(c4)-c4ccccc4C5(c4ccccc4)c4ccccc4)cc3)cc2)cc1 ; C=Cc1ccc(COc2ccc(-c3ccc(N(c4ccc(-c5ccccc5)cc4)c4ccc(-c5ccc(N(c6ccc(OCc7ccc(C=C)cc7)cc6)c6ccc7oc8ccccc8c7c6)cc5)cc4)cc3)cc2)cc1 ; C=Cc1ccc(-c2ccccc2N(c2ccc3c(c2)C2(c4ccc(C=C)cc4O3)c3ccccc3-c3ccccc32)c2ccc3c(c2)C2(c4ccc(C=C)cc4-3)c3ccccc3-c3ccc4ccccc4c32)cc1]

8. The quantum dot light emitting device of claim 1, wherein the quantum dot light emitting device comprises two or more stacks comprising a hole transport layer, a quantum dot light emitting layer, and an electron transport layer sequentially formed on a positive electrode.

9. The quantum dot light emitting device of claim 1, further comprising a charge generation layer formed between the two or more stacks.

10. The quantum dot light emitting device of claim 1, further comprising an auxiliary electron transport layer or buffer layer between the light emitting layer and the electron transport layer.

11. The quantum dot light emitting device of claim 1, wherein the quantum dot light emitting layer comprises a semiconductor nanocrystal core comprising a group Ill-V element, and a shell layer which is disposed on the semiconductor nanocrystal core and comprises a group II-VI element.

12. The quantum dot light emitting device of claim 1, wherein the quantum dot light emitting layer comprises quantum dots which comprises a semiconductor nanocrystal core comprising a group Ill element and a group V element.

13. The quantum dot light emitting device of claim 11, wherein the semiconductor nanocrystal core further comprises a group II element.

14. The quantum dot light emitting device of claim 13, wherein in the semiconductor nanocrystal core, the molar ratio of the group III element and the group II element is 1:5 to 1:30.

15. The quantum dot light emitting device of claim 11, comprising a semiconductor nanocrystal shell that comprises a group II element and a group VI element on the semiconductor nanocrystal core.

16. The quantum dot light emitting device of claim 1, wherein the average diameter of the quantum dot is 3 nm to 12 nm.

17. The quantum dot light emitting device of claim 1, wherein the LUMO level of the quantum dot is −2.7 eV to −4.0 eV and the HOMO level is −4.5 eV to −6.5 eV.

18. An electronic device comprising a display device comprising the quantum dot light emitting device according to claim 1; and a control unit that operates the display device.

19. An electronic device, wherein the quantum dot light emitting device according to claim 18 is selected from the group consisting of next-generation high-brightness light emitting diode (LED), a biosensor, a laser, and a solar cell nanomaterial.
